(19) United States
(12) Patent Application Publication
(10) Pub. No.: US 2022/0216433 A1
(43) Pub. Date: Jul. 7, 2022

(54) ELECTROLUMINESCENT DEVICE

(71) Applicant: BEIJING SUMMER SPROUT TECHNOLOGY CO., LTD., Beijing (CN)

(72) Inventors: Chi Yuen Raymond Kwong, Beijing (CN); Qi Zhang, Beijing (CN); Junfei Wang, Beijing (CN); Le Wang, Beijing (CN); Qiang Wang, Beijing (CN); Han Zhang, Beijing (CN); Xueyu Lu, Beijing (CN); Xinfang Hao, Beijing (CN); Menglan Xie, Beijing (CN); Chuanjun Xia, Beijing (CN)

(73) Assignee: BEIJING SUMMER SPROUT TECHNOLOGY CO., LTD., Beijing (CN)

(21) Appl. No.: 17/523,608

(22) Filed: Nov. 10, 2021

(30) Foreign Application Priority Data
Dec. 17, 2020 (CN) 202011492494.1

(51) Int. Cl. H01L 51/00; C07F 15/00; C09K 11/06

(52) U.S. Cl. CPC H01L 51/0094; H01L 51/5012; C09K 11/06; C07F 15/0033

(57) ABSTRACT

Provided is an electroluminescent device. The electroluminescent device includes an anode, a cathode, and an organic layer disposed between the anode and the cathode, wherein the organic layer includes a first metal complex of a ligand having a structure represented by Formula 1 and a first compound having a structure represented by Formula 2. The novel material combination comprising the first metal complex and the first compound can be used in an emissive layer in an electroluminescent device. The novel material combination can enable the novel electroluminescent device to obtain a darker red color, a lower voltage, higher efficiency, and a longer lifetime and can provide better device performance. Further provided are an electronic device and a compound combination.

### CROSS-REFERENCE TO RELATED APPLICATION(S)

This application claims priority to Chinese Patent Application No. CN 202011492494.1 filed on Dec. 17, 2020, the disclosure of which is incorporated herein by reference in its entirety.

### TECHNICAL FIELD

The present disclosure relates to electronic devices, for example, an electroluminescent device. More particularly, a novel material combination comprising a first metal complex and a first compound is used in the electroluminescent device. The present disclosure further provides an electronic apparatus and a compound combination.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

In order to meet the increasing demands for various aspects of the performance of electroluminescent device such as the emitted color, saturation of the emitted color, drive voltage, luminous efficiency, device lifetime, and so on, the research on phosphorescent devices is still in urgent need. In the research on phosphorescent devices, the combination of phosphorescent luminescent materials and host materials is very important, and the combination of phosphorescent light-emitting materials and host materials is directly related to the luminescent performance of devices. Therefore, the selection and optimization of the combination of phosphorescent light-emitting materials and host materials is an important part of related research in the industry.

### SUMMARY

The present disclosure aims to provide an electroluminescent device having a novel material combination to solve at least part of the above-mentioned problems. The electroluminescent device adopts a novel material combination comprising a first metal complex and a first compound. The novel material combination may be used in an emissive layer of the electroluminescent device. The novel material combination can enable the novel electroluminescent device to obtain a darker red color, a lower voltage, higher efficiency, and a longer lifetime, and can provide better device performance.

According to an embodiment of the present disclosure, disclosed is an electroluminescent device, comprising:

an anode,

a cathode, and

an organic layer disposed between the anode and the cathode, wherein the organic layer includes a first metal complex and a first compound;

wherein

the first metal complex includes a ligand Lₐ coordinated with a metal, and the metal is selected from metals having a relative atomic mass greater than 40; Lₐ has a structure represented by Formula 1:

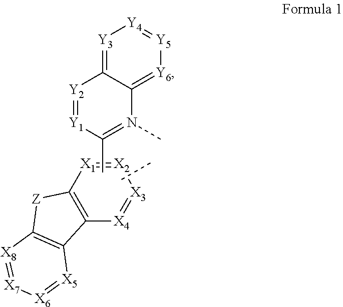

wherein X₁ to X₈ are, at each occurrence identically or differently, selected from C, CRₓ or N;

Y₁ to Y₆ are, at each occurrence identically or differently, selected from CR_{y1}, CR_{y2} or N; the R_{y2} has a structure of -L₁-SiRₛ₁Rₛ₂Rₛ₃;

Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{y1}, Rₛ₁, Rₛ₂, Rₛ₃ can be optionally joined to form a ring;

Z is selected from O, S or Se;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof; and

wherein

the first compound has a structure represented by Formula 2:

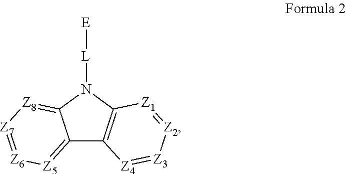

wherein Z₁ and Z₈ are, at each occurrence identically or differently, selected from CR_{z1} or N;

Z₂, Z₃, Z₆, and Z₇ are, at each occurrence identically or differently, selected from CR_{z2} or N;

Z₄ and Z₅ are, at each occurrence identically or differently, selected from CR_{z3} or N;

E has a structure represented by Formula 3-1 or Formula 3-2:

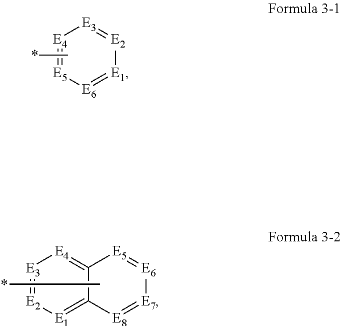

in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;

* represents a position where E is joined to L;

L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2}, R_{z3}, and Rₑ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R_{z1}, R_{z2}, R_{z3} can be optionally joined to form a ring;

adjacent substituents Rₑ can be optionally joined to form a ring.

According to another embodiment of the present disclosure, further provided is an electronic apparatus, comprising the electroluminescent device described above.

According to another embodiment of the present disclosure, further provided is a compound combination, comprising the first metal complex and the first compound.

The present disclosure provides an electroluminescent device having a novel material combination. The electroluminescent device adopts a novel material combination comprising a first metal complex and a first compound. The novel material combination may be used in an emissive layer of the electroluminescent device. The novel material combination can enable the novel electroluminescent device to obtain a darker red color, a lower voltage, higher efficiency, and a longer lifetime, and can provide better device performance.

### BRIEF DESCRIPTION OF DRAWINGS

FIG. 1 is a schematic diagram of an organic light-emitting apparatus that may include an electroluminescent device disclosed in the present disclosure.

FIG. 2 is a schematic diagram of another organic light-emitting apparatus that may include an electroluminescent device disclosed in the present disclosure

### DETAILED DESCRIPTION

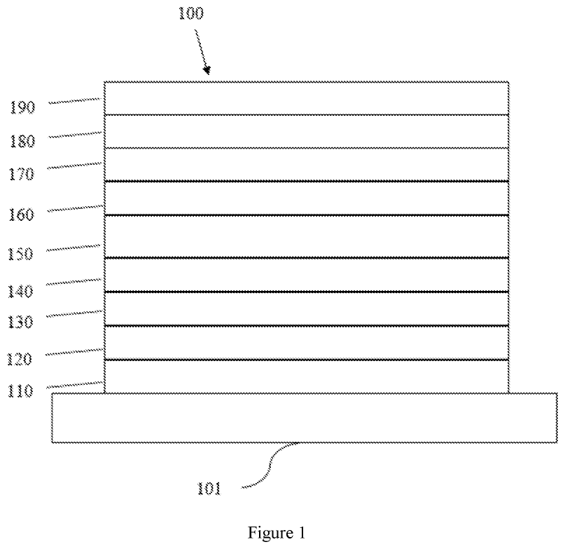

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

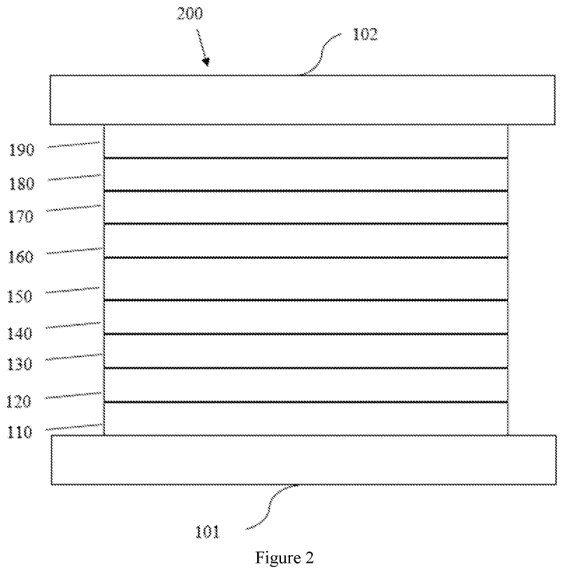

An OLED can be encapsulated by a barrier layer. FIG. 2 schematically shows an organic light-emitting device 200 without limitation. FIG. 2 differs from FIG. 1 in that the organic light-emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin-film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Additionally, the alkyl may be optionally substituted. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylsilyl, dimethylethylsilyl, dimethylisopropylsilyl, t-butyldimethylsilyl, triethylsilyl, triisopropylsilyl, trimethylsilylmethyl, trimethylsilylethyl, and trimethylsilylisopropyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, propenyl, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Additionally, the aryl may be optionally substituted. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heteroaryl—as used herein, includes non-condensed and condensed hetero-aromatic groups having 1 to 5 hetero-atoms, wherein at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indenoazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, or —O-heteroalkyl. Examples and preferred examples of alkyl, cycloalkyl, and heteroalkyl are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms.

Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyl di-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl, tri-t-butylsilyl, dimethyl t-butylsilyl, methyl di-t-butylsilyl. Additionally, the arylsilyl group may be optionally substituted.

The term “aza” in azadibenzofuran, aza-dibenzothiophene, etc. means that one or more of the C—H groups in the respective aromatic fragment are replaced by a nitrogen atom. For example, azatriphenylene encompasses dibenzo[f,h]quinoxaline, dibenzo[f,h]quinoline and other analogues with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted arylalkyl, substituted alkoxy, substituted aryloxy, substituted alkenyl, substituted alkynyl, substituted aryl, substituted heteroaryl, substituted alkylsilyl, substituted arylsilyl, substituted amine, substituted acyl, substituted carbonyl, substituted carboxylic acid group, substituted ester group, substituted sulfinyl, substituted sulfonyl and substituted phosphino is used, it means that any group of alkyl, cycloalkyl, heteroalkyl, arylalkyl, alkoxy, aryloxy, alkenyl, alkynyl, aryl, heteroaryl, alkylsilyl, arylsilyl, amine, acyl, carbonyl, carboxylic acid group, ester group, sulfinyl, sulfonyl and phosphino may be substituted with one or more groups selected from the group consisting of deuterium, a halogen, an unsubstituted alkyl group having 1 to 20 carbon atoms, an unsubstituted cycloalkyl group having 3 to 20 ring carbon atoms, an unsubstituted heteroalkyl group having 1 to 20 carbon atoms, an unsubstituted arylalkyl group having 7 to 30 carbon atoms, an unsubstituted alkoxy group having 1 to 20 carbon atoms, an unsubstituted aryloxy group having 6 to 30 carbon atoms, an unsubstituted alkenyl group having 2 to 20 carbon atoms, an unsubstituted alkynyl group having 2 to 20 carbon atoms, an unsubstituted aryl group having 6 to 30 carbon atoms, an unsubstituted heteroaryl group having 3 to 30 carbon atoms, an unsubstituted alkylsilyl group having 3 to 20 carbon atoms, an unsubstituted arylsilyl group having 6 to 20 carbon atoms, an unsubstituted amino group having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group and a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In the compounds mentioned in the present disclosure, the hydrogen atoms can be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a double substitution, up to the maximum available substitutions. When a substitution in the compounds mentioned in the present disclosure represents multiple substitutions (including di, tri, tetra substitutions etc.), that means the substituent may exist at a plurality of available substitution positions on its linking structure, the substituents present at a plurality of available substitution positions may be the same structure or different structures.

In the compounds mentioned in the present disclosure, adjacent substituents can be optionally joined to form a ring, including both the case where adjacent substituents can be joined to form a ring, and the case where adjacent substituents are not joined to form a ring. When adjacent substituents can be optionally joined to form a ring, the ring formed may be monocyclic or polycyclic, as well as alicyclic, heteroalicyclic, aromatic or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

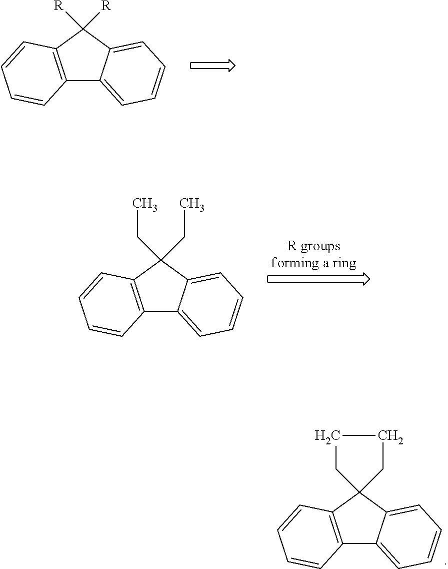

The expression that adjacent substituents can be optionally joined to form a ring is also intended to mean that two substituents bonded to carbon atoms which are directly bonded to each other are joined to each other via a chemical bond to form a ring, which can be exemplified by the following formula:

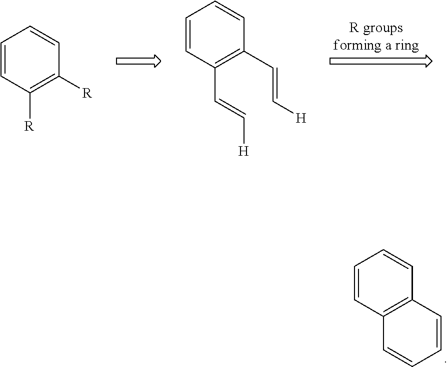

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

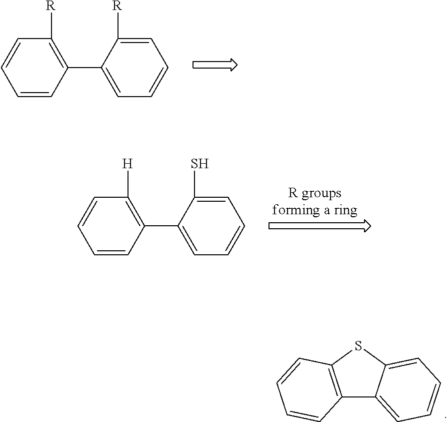

According to an embodiment of the present disclosure, provided is an electroluminescent device, comprising:

an anode,

a cathode, and

an organic layer disposed between the anode and the cathode, wherein the organic layer comprises a first metal complex and a first compound;

wherein

the first metal complex comprises a ligand Lₐ coordinated with a metal, and the metal is selected from metals having a relative atomic mass greater than 40; Lₐ has a structure represented by Formula 1:

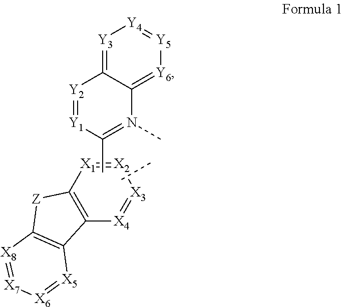

wherein X₁ to X₈ are, at each occurrence identically or differently, selected from C, CRₓ or N;

Y₁ to Y₆ are, at each occurrence identically or differently, selected from CR_{y1}, CR_{y2} or N; the R_{y2} has a structure of -L₁-SiRₛ₁Rₛ₂Rₛ₃;

Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{y1}, Rₛ₁, Rₛ₂, Rₛ₃ can be optionally joined to form a ring;

Z is selected from O, S or Se;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof; and

wherein

the first compound has a structure represented by Formula 2:

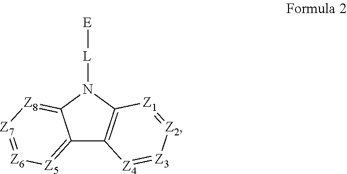

wherein Z₁ and Z₈ are, at each occurrence identically or differently, selected from CR_{z1} or N;

Z₂, Z₃, Z₆, and Z₇ are, at each occurrence identically or differently, selected from CR_{z2} or N;

Z₄ and Z₅ are, at each occurrence identically or differently, selected from CR_{z3} or N;

E has a structure represented by Formula 3-1 or Formula 3-2:

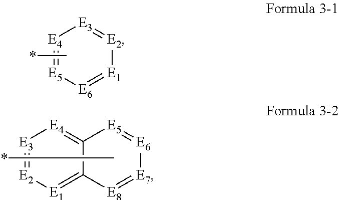

in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;

* represents a position where E is joined to L;

L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2}, R_{z3}, and Rₑ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R_{z1}, R_{z2}, R_{z3} can be optionally joined to form a ring;

adjacent substituents Rₑ can be optionally joined to form a ring.

In the present embodiment, the expression that adjacent substituents Rₓ, R_{y1}, Rₛ₁, Rₛ₂, Rₛ₃ can be optionally joined to form a ring is intended to mean that any one or more of groups of adjacent substituents, such as two substituents Rₓ, two substituents R_{y1}, substituents Rₛ₁ and Rₛ₂, substituents Rₛ₁ and Rₛ₃, and substituents Rₛ₂ and Rₛ₃, can be joined to form a ring. Obviously, it is possible that none of these groups of substituents are joined to form a ring. None of the adjacent substituents R_{ye} are joined to form a ring.

In the present disclosure, the expression that adjacent substituents R_{z1}, R_{z2}, R_{z3} can be optionally joined to form a ring is intended to mean that when a plurality of substituents R_{z1}, R_{z2}, and R_{z3} is present, any one or more of groups of adjacent substituents, such as adjacent substituents R_{z2}, adjacent substituents R_{z1} and R_{z2}, adjacent substituents R_{z2} and R_{z3}, and two substituents R_{z3}, can be optionally joined to form a ring. Obviously, when a plurality of substituents R_{z1}, R_{z2}, and R_{z3} is present, it is possible that none of these groups of adjacent substituents R_{z1}, R_{z2}, and R_{z3} are joined to form a ring.

In the present disclosure, the expression that adjacent substituents Rₑ can be optionally joined to form a ring is intended to mean that when a plurality of substituents Rₑ is present, any adjacent substituents Rₑ can be joined to form a ring. Obviously, when a plurality of substituents Rₑ is present, it is possible that none of the adjacent substituents Rₑ are joined to form a ring.

According to an embodiment of the present disclosure, in Formula 1, Y₁ to Y₆ are, at each occurrence identically or differently, selected from CR_{y1}, CR_{y2} or N, and when multiple substituents R_{y1} exist, none of the adjacent substituents R_{y1} are joined to form a ring.

According to an embodiment of the present disclosure, in Formula 1, Y₁ to Y₆ are, at each occurrence identically or differently, selected from CR_{y1}, CR_{y2} or N, at least one of Y₁ to Y₆ is selected from CR_{y2}, and the R_{ye} has a structure of -L₁-SiRₛ₁Rₛ₂Rₛ₃;

Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

adjacent substituents Rₛ₁, Rₛ₂ Rₛ₃ can be optionally joined to form a ring.

In the present disclosure, the expression that adjacent substituents Rₛ₁, Rₛ₂, Rₛ₃ can be optionally joined to form a ring is intended to mean that any one or more of groups of adjacent substituents, such as substituents Rₛ₁ and Rₛ₂, substituents Rₛ₁ and Rₛ₃, and substituents Rₛ₂ and Rₛ₃, can be joined to form a ring. Obviously, it is possible that none of these groups of substituents are joined to form a ring. None of the adjacent substituents R_{y1} are joined to form a ring.

According to an embodiment of the present disclosure, in Formula 1, two adjacent ones of X₁ to X₄ are C, one of the two C is joined to the metal by a carbon-metal bond, the one of X₁ to X₄ at the ortho position of the carbon-metal bond is selected from CRₓ, and the Rₓ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or combinations thereof.

In this embodiment, two adjacent ones of X₁ to X₄ are C, and one of the two C is joined to the metal by a carbon-metal bond, and in this case, the one of X₁ to X₄ at the ortho position of the carbon-metal bond is selected from CRₓ, and the Rₓ is selected from the group of substituents. For example, when X₁ is C and X₂ is also C and forms a carbon-metal bond with the metal, Lₐ has a structure of

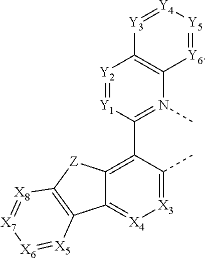

In this case, the one of X₁ to X₄ at the ortho position of the carbon-metal bond refers to X₃, X₃ is selected from CRₓ, and the Rₓ is selected from the group of substituents. In another example, in Formula 1, when X₂ is C and X₁ is also C and forms a carbon-metal bond with the metal, Lₐ has a structure of

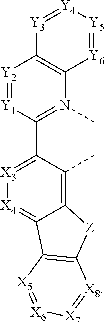

In this case, none of X₁ to X₄ is at the ortho position of the carbon-metal bond and can be substituted, which is obviously not a case included in this embodiment.

According to an embodiment of the present disclosure, in Formula 1, at least one of X₁ to X₈ and Y₁ to Y₆ is selected from CRₓ or CR_{y1}, and the Rₓ and R_{y1} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

In this embodiment, the expression that at least one of X₁ to X₈ and Y₁ to Y₆ is selected from CRₓ or CR_{y1} means that at least one of X₁ to X₈ is selected from CRₓ or at least one of Y₁ to Y₆ is selected from CR_{y1}, and the Rₓ and R_{y1} are, at each occurrence identically or differently, selected from groups of substituents that are not hydrogen.

According to an embodiment of the present disclosure, in Formula 1, at least two or three of X₁ to X₈ and Y₁ to Y₆ are selected from CRₓ and/or CR_{y1}, and the Rₓ and R_{y1} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

In this embodiment, the expression that at least two or three of X₁ to X₈ and Y₁ to Y₆ are selected from CRₓ and/or CR_{y1} means that for X₁ to X₈ and Y₁ to Y₆, there at least include any one or more of the following cases: (1) at least two of X₁ to X₈ are selected from CRₓ; (2) at least two of Y₁ to Y₆ are selected from CR_{y1}; (3) at least two of X₁ to X₈ are selected from CRₓ and at least one of Y₁ to Y₆ is selected from CR_{y1}; (4) at least one of X₁ to X₈ is selected from CRₓ and at least two of Y₁ to Y₆ are selected from CR_{y1}; (5) at least three of X₁ to X₈ are selected from CRₓ; (6) at least three of Y₁ to Y₆ are selected from CR_{y1}; (7) at least one of X₁ to X₈ is selected from CRₓ and at least one of Y₁ to Y₆ is selected from CR_{y1}. In any one of the above cases, Rₓ and R_{y1} are, at each occurrence identically or differently, selected from groups of substituents that are not hydrogen.

According to an embodiment of the present disclosure, in Formula 1, X₇ is selected from CRₓ or N, wherein Rₓ is selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, in Formula 3-1, E₁ to E₆ are, at each occurrence identically or differently, selected from C, CRₑ or N, and at least two of E₁ to E₆ are N, wherein none of the adjacent substituents Rₑ are joined to form a ring.

According to an embodiment of the present disclosure, wherein, the first metal complex has a structure of M(Lₐ)ₘ(L_{b})ₙ(L_{c})_{q};

wherein the metal M is selected from Ir, Rh, Re, Os, Pt, Au or Cu;

Lₐ, L_{b}, and L_{c} are a first ligand, a second ligand, and a third ligand of the complex, respectively; m is selected from 1, 2 or 3, n is selected from 0, 1 or 2, q is selected from 0, 1 or 2, and m+n+q is equal to the oxidation state of the metal M; when m is greater than 1, the plurality of Lₐ may be identical or different; when n is 2, two L_{b} may be identical or different; when q is 2, two L_{c} may be identical or different;

Lₐ, L_{b}, and L_{c} can be optionally joined to form a multi-dentate ligand;

L_{b} and L_{c} are, at each occurrence identically or differently, selected from the group consisting of the following structures:

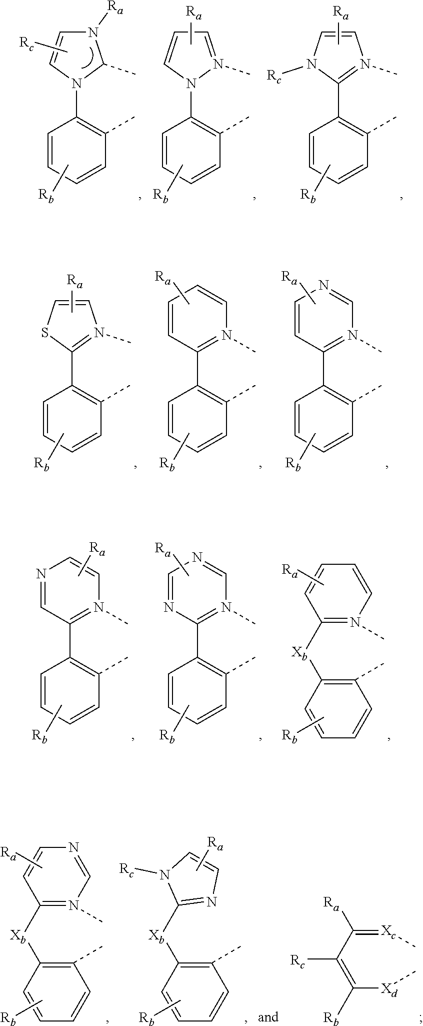

wherein Rₐ, R_{b}, and R_{c}, represent, at each occurrence identically or differently, mono-substitution, multiple substitutions or non-substitution;

X_{b} is, at each occurrence identically or differently, selected from the group consisting of: O, S, Se, NR_{N1}, and CR_{C1}R_{C2};

X_{c} and X_{d} are, at each occurrence identically or differently, selected from the group consisting of: O, S, Se, and NR_{N2};

Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₐ, R_{b}, R_{c}, R_{N1}, R_{N2}, R_{C1}, and R_{C2} can be optionally joined to form a ring.

In this embodiment, the expression that adjacent substituents Rₐ, R_{b}, R_{c}, R_{N1}, R_{N2}, R_{C1}, and R_{C2} can be optionally joined to form a ring is intended to mean that any one or more of groups of adjacent substituents, such as two substituents Rₐ, two substituents R_{b}, two substituents substituents Rₐ and R_{b}, substituents Rₐ and R_{C}, substituents R_{b} and R_{C}, substituents Rₐ and R_{N1}; substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. Obviously, it is possible that none of these groups of substituents are joined to form a ring.

In this embodiment, the expression that Lₐ, L_{b}, and L_{c} can be optionally joined to form a multi-dentate ligand is intended to mean that Lₐ, L_{b}, and L_{c} can be optionally joined to form a tetradentate ligand or a hexadentate ligand. Obviously, it is possible that none of Lₐ, L_{b}, and L_{c} are joined to form a multi-dentate ligand.

According to an embodiment of the present disclosure, wherein, the first metal complex has a structure of M(Lₐ)ₘ(L_{b})ₙ(L_{c})_{q};

wherein the metal M is selected from Ir, Rh, Re, Os, Pt, Au or Cu;

Lₐ, L_{b}, and L_{c} are a first ligand, a second ligand, and a third ligand of the metal complex, respectively; m is selected from 1, 2 or 3, n is selected from 0, 1 or 2, q is selected from 0, 1 or 2, and m+n+q is equal to the oxidation state of the metal M; when m is greater than 1, the plurality of Lₐ may be identical or different; when n is 2, two L_{b} may be identical or different; when q is 2, two L_{c} may be identical or different; Lₐ, L_{b}, and L_{c} can be optionally joined to form a multi-dentate ligand;

L_{b} is, at each occurrence identically or differently, selected from the following structure:

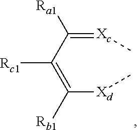

wherein X_{c} and X_{d} are, at each occurrence identically or differently, selected from the group consisting of: O, S, Se, and NR_{N2};

Rₐ₁, R_{b1}, R_{c1}, and R_{N2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₐ₁, R_{b1}, and R_{c1} can be optionally joined to from a ring;

L_{c} is, at each occurrence identically or differently, selected from the group consisting of the following structures:

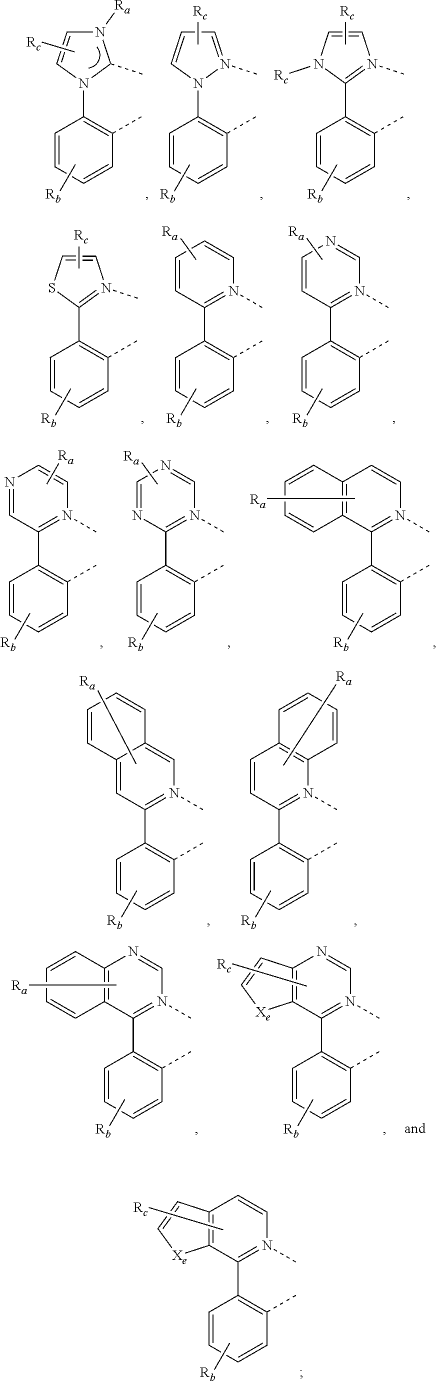

wherein Rₐ, R_{b}, and R_{c} represent, at each occurrence identically or differently, mono-substitution, multiple substitutions or non-substitution;

Xₑ is, at each occurrence identically or differently, selected from the group consisting of: O, S, Se, and NR_{N3};

Rₐ, R_{b}, R_{c}, and R_{N3} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

wherein adjacent substituents R_{b}, R_{c} can be optionally joined to form a ring.

In this embodiment, the expression that adjacent substituents Rₐ₁, R_{b1}, R_{c1} can be optionally joined to form a ring is intended to mean that substituents Rₐ₁ and R_{c1} or substituents R_{b1} and R_{c1} can be joined to form a ring. Obviously, it is possible that neither the substituents Rₐ₁ and R_{c1} nor the substituents R_{b1} and R_{c1} are joined to form a ring.

In this embodiment, the expression that adjacent substituents R_{b}, R_{c} can be optionally joined to form a ring is intended to mean that when a plurality of substituents R_{b} and a plurality of substituents R_{c} is present, adjacent substituents R_{b} or adjacent substituents R_{c} can be joined to form a ring. Obviously, when a plurality of substituents R_{b} and a plurality of substituents R_{c} is present, it is possible that neither the adjacent substituents R_{b} or the adjacent substituents R_{c} are joined to form a ring.

According to an embodiment of the present disclosure, wherein, the metal M is selected from Ir, Pt or Os.

According to an embodiment of the present disclosure, wherein, the metal M is Ir.

According to an embodiment of the present disclosure, wherein, Lₐ has a structure represented by Formula 4:

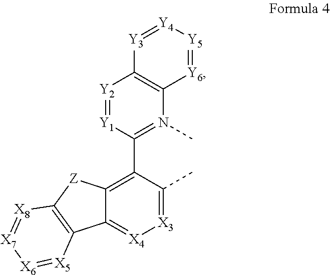

wherein

Z is selected from O or S;

X₃ to X₈ are, at each occurrence identically or differently, selected from CRₓ or N;

Y₁ to Y₆ are, at each occurrence identically or differently, selected from CR_{y1}, CR_{y2} or N, wherein at least one of Y₁ to Y₆ is selected from CR_{y2}, and the R_{y2} has a structure of -L-SiRₛ₁Rₛ₂Rₛ₃;

Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

adjacent substituents Rₓ, Rₛ₁, Rₛ₂, Rₛ₃ can be optionally joined to form a ring.

In the present disclosure, the expression that adjacent substituents Rₓ, Rₛ₁, Rₛ₂, Rₛ₃ can be optionally joined to form a ring is intended to mean that any one or more of groups of adjacent substituents, such as two substituents Rₓ, substituents Rₛ₁ and Rₛ₂, substituents Rₛ₁ and Rₛ₃, and substituents Rₛ₂ and Rₛ₃, can be joined to form a ring. Obviously, it is possible that none of these groups of substituents are joined to form a ring.

According to an embodiment of the present disclosure, wherein, the first metal complex has a structure represented by Formula 5:

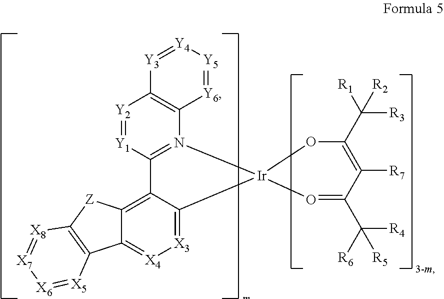

wherein

m is 1 or 2;

Z is, at each occurrence identically or differently, selected from O or S; preferably, Z is O;

X₃ to X₈ are, at each occurrence identically or differently, selected from CRₓ or N;

Y₁ to Y₆ are, at each occurrence identically or differently, selected from CR_{y1}, CR_{y2} or N, wherein at least one of Y₁ to Y₆ is selected from CR_{y2}, and the R_{y2} has a structure of -L-SiRₛ₁Rₛ₂Rₛ₃;

Rₓ, R_{y1}, Rₛ₁, Rₛ₂, Rₛ₃, R₁, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

adjacent substituents Rₓ, Rₛ₁, Rₛ₂, Rₛ₃ can be optionally joined to form a ring;

adjacent substituents R₁, R₂, R₃, R₄, R₅, R₆, R₇ can be optionally joined to form a ring.

In this embodiment, the expression that adjacent substituents Rₓ, Rₛ₁, Rₛ₂, Rₛ₃ can be optionally joined to form a ring is intended to mean that any one or more of groups of adjacent substituents, such as two substituents Rₓ, substituents Rₛ₁ and Rₛ₂, substituents Rₛ₁ and Rₛ₃, and substituents Rₛ₂ and Rₛ₃, can be joined to form a ring. Obviously, it is possible that none of these groups of substituents are joined to form a ring.

In this embodiment, the expression that adjacent substituents R₁, R₂, R₃, R₄, R₅, R₆, R₇ can be optionally joined to form a ring is intended to mean that any one or more of groups of adjacent substituents, such as substituents R₁ and R₂, substituents R₁ and R₃, substituents R₂ and R₃, substituents R₄ and R₅, substituents R₅ and R₆, substituents R₄ and R₆, substituents R₁ and R₇, substituents R₂ and R₇, substituents R₃ and R₇, substituents R₄ and R₇, substituents R₅ and R₇, and substituents R₆ and R₇, can be joined to form a ring. Obviously, it is possible that none of these groups of substituents are joined to form a ring.

According to an embodiment of the present disclosure, wherein, the first metal complex has a structure represented by Formula 5, wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof; when R₁ to R₇ are each independently selected from substituted alkyl having 1 to 20 carbon atoms, substituted cycloalkyl having 3 to 20 ring carbon atoms, substituted heteroalkyl having 1 to 20 carbon atoms, substituted aryl having 6 to 30 carbon atoms or substituted heteroaryl having 3 to 30 carbon atoms, the substitutions are selected from the group consisting of: hydrogen, deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof.

According to an embodiment of the present disclosure, wherein, the first metal complex has a structure represented by Formula 5, wherein Z is O.

According to an embodiment of the present disclosure, wherein, the first metal complex has a structure represented by Formula 5:

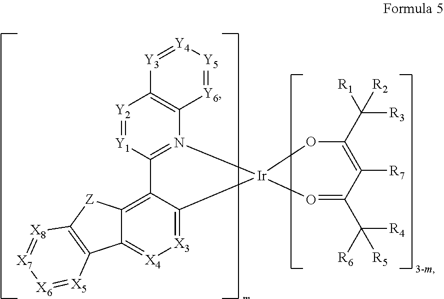

wherein

m is 1 or 2;

Z is, at each occurrence identically or differently, selected from O or S;

R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group, and combinations thereof.

According to an embodiment of the present disclosure, wherein, the first metal complex has a structure represented by Formula 5:

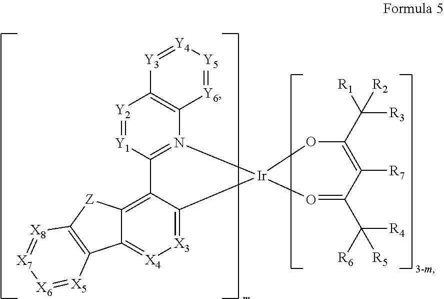

wherein

m is 1 or 2;

Z is, at each occurrence identically or differently, selected from O or S;

wherein at least one of R₁ to R₃ is selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R₄ to R₆ is substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof.

According to an embodiment of the present disclosure, wherein, the first metal complex has a structure represented by Formula 5:

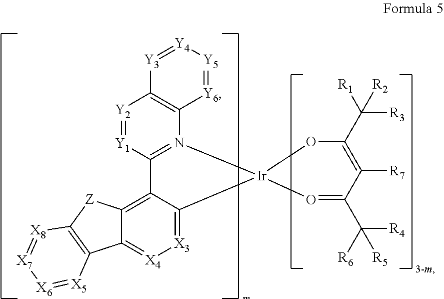

wherein

m is 1 or 2;

Z is, at each occurrence identically or differently, selected from O or S;

wherein at least two of R₁ to R₃ are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R₄ to R₆ is substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof.

According to an embodiment of the present disclosure, wherein, the first metal complex has a structure represented by Formula 5:

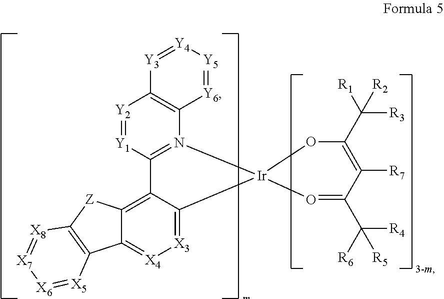

wherein

m is 1 or 2;

Z is, at each occurrence identically or differently, selected from O or S;

wherein at least two of R₁ to R₃ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R₆ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

According to an embodiment of the present disclosure, wherein, Y₁ and Y₂ are, at each occurrence identically or differently, selected from CR_{y1} or N; Y₃ to Y₆ are, at each occurrence identically or differently, selected from CR_{y1}, CR_{y2} or N, at least one of Y₃ to Y₆ is selected from CR_{y2}, and the R_{ye} has a structure of -L₁-SiRₛ₁Rₛ₂Rₛ₃;

R_{y1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

adjacent substituents Rₛ₁, Rₛ₂, Rₛ₃ can be optionally joined to form a ring.

In the present disclosure, the expression that adjacent substituents Rₛ₁, Rₛ₂, Rₛ₃ can be optionally joined to form a ring is intended to mean that any one or more of groups of adjacent substituents, such as substituents Rₛ₁ and Rₛ₂, substituents Rₛ₁ and Rₛ₃, and substituents Rₛ₂ and Rₛ₃, can be joined to form a ring. Obviously, it is possible that none of these groups of substituents are joined to form a ring. None of the adjacent substituents R_{y1} are joined to form a ring.

According to an embodiment of the present disclosure, wherein, Y₁ and Y₂ are, at each occurrence identically or differently, selected from CR_{y1} or N; R_{y1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; when R_{y1} is selected from a substituted alkyl group, a substituted cycloalkyl group, a substituted heteroalkyl group, a substituted arylalkyl group, a substituted alkoxy group, a substituted aryloxy group, a substituted alkenyl group, a substituted alkynyl group, a substituted aryl group, a substituted heteroaryl group, a substituted amino group, a substituted acyl group, a substituted carbonyl group, a substituted carboxylic acid group, a substituted ester group, a substituted sulfinyl group, a substituted sulfonyl group or a substituted phosphino group, it refers to that any one of the alkyl group, the cycloalkyl group, the heteroalkyl group, the arylalkyl group, the alkoxy group, the aryloxy group, the alkenyl group, the alkynyl group, the aryl group, the heteroaryl group, the amino group, the acyl group, the carbonyl group, the carboxylic acid group, the ester group, the sulfinyl group, the sulfonyl group or the phosphino group may be substituted by one or more groups selected from deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted amino having 0 to 20 carbon atoms, an acyl group, a carbonyl group, a carboxylic acid group, an ester group, a cyano group, an isocyano group, a sulfanyl group, a sulfinyl group, a sulfonyl group, a phosphino group or combinations thereof.

According to an embodiment of the present disclosure, wherein, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₛ₁, Rₛ₂, Rₛ₃ can be optionally joined to form a ring.

According to an embodiment of the present disclosure, wherein, Y₁ and Y₂ are, at each occurrence identically or differently, selected from CR_{y1} or N; Y₃ to Y₆ are, at each occurrence identically or differently, selected from CR_{y1}, CR_{y2} or N, at least one of Y₃ to Y₆ is selected from CR_{y2}, and the R_{ye} has a structure of -L₁-SiRₛ₁Rₛ₂Rₛ₃;

R_{y1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Rₛ₁, Rₛ₂, and Rₛ₃ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, and combinations thereof;

L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

adjacent substituents Rₛ₁, Rₛ₂, Rₛ₃ can be optionally joined to form a ring.

According to an embodiment of the present disclosure, wherein, in Formula 4 and/or Formula 5, Y₁ to Y₆ are each independently selected from CR_{y1} or CR_{y2}.

According to an embodiment of the present disclosure, wherein, in Formula 4 and/or Formula 5, at least one of Y₁ to Y₆ is selected from N.

According to an embodiment of the present disclosure, wherein, in Formula 4 and/or Formula 5, Z is selected from O.

According to an embodiment of the present disclosure, wherein, in Formula 4 and/or Formula 5, at least one of X₃ to X₈ is selected from N.

According to an embodiment of the present disclosure, wherein, in Formula 4 and/or Formula 5, one of X₃ to X₈ is selected from N.

According to an embodiment of the present disclosure, wherein, in Formula 4 and/or Formula 5, X₈ is N.

According to an embodiment of the present disclosure, wherein, in Formula 4 and/or Formula 5, X₃ to X₈ are each independently selected from CRₓ.

According to an embodiment of the present disclosure, wherein, in Formula 4 and/or Formula 5, X₃ to X₈ are each independently selected from CRₓ, and the Rₓ is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, a cyano group or combinations thereof.

According to an embodiment of the present disclosure, wherein, in Formula 4 and/or Formula 5, X₃ to X₈ are each independently selected from CRₓ, and the Rₓ is selected from the group consisting of: hydrogen, deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, and combinations thereof.

According to an embodiment of the present disclosure, wherein, in Formula 4 and/or Formula 5, X₃ is selected from CRₓ, and the Rₓ is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, a cyano group or combinations thereof.

According to an embodiment of the present disclosure, wherein, in Formula 4 and/or Formula 5, X₃ is selected from CRₓ, and the Rₓ is selected from deuterium, halogen, substituted or unsubstituted alkyl having 1 to 20 carbon atoms, substituted or unsubstituted cycloalkyl having 3 to 20 ring carbon atoms, a cyano group or combinations thereof.

According to an embodiment of the present disclosure, wherein, in Formula 4 and/or Formula 5, X₃ is selected from CRₓ, and the Rₓ is selected from methyl or deuterated methyl.

According to an embodiment of the present disclosure, wherein, in Formula 4 and/or Formula 5, Y₂ is selected from CR_{y1} or CR_{y2}; the R_{y1} is selected from the group consisting of: substituted or unsubstituted alkyl having 1 to 20 carbon atoms, substituted or unsubstituted cycloalkyl having 3 to 20 ring carbon atoms and combinations thereof; the R_{y2} has a structure of -L₁-SiRₛᵢRₛ₂Rₛ₃; Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof; adjacent substituents Rₛ₁, Rₛ₂, Rₛ₃ can be optionally joined to form a ring.

According to an embodiment of the present disclosure, wherein, when R_{y1} is selected from substituted alkyl having 1 to 20 carbon atoms or substituted cycloalkyl having 3 to 20 ring carbon atoms, the substitutions are preferably selected from deuterium, fluorine, cyano or combinations thereof.

According to an embodiment of the present disclosure, wherein, in Formula 4 and/or Formula 5, Y₁ to Y₆ are each independently selected from CR_{y1} or CR_{y2}, at least one of Y₁ to Y₆ is selected from CR_{y2}, and the R_{ye} has a structure of -L₁-SiRₛ₁Rₛ₂Rₛ₃, wherein L is selected from a single bond, and Rₛ₁, Rₛ₂, and Rₛ₃ are each independently selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms and combinations thereof.

According to an embodiment of the present disclosure, wherein, in Formula 4 and/or Formula 5, at least one of Y₂ and Y₄ is selected from CR_{y2}; and the R_{ye} has a structure of -L₁-SiRₛᵢRₛ₂Rₛ₃, wherein Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms or combinations thereof, and at least one or two of Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms or combinations thereof.

According to an embodiment of the present disclosure, wherein, in Formula 4 and/or Formula 5, Y₂ or Y₄ is selected from CR_{y2}, and the R_{y2} has a structure of -L₁-SiRₛ₁Rₛ₂Rₛ₃, wherein Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms or combinations thereof, and at least one or two of Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms or combinations thereof.

According to an embodiment of the present disclosure, wherein, in Formula 4 and/or Formula 5, Y₂ is selected from CR_{y2}, and the R_{ye} has a structure of -L₁-SiRₛ₁Rₛ₂Rₛ₃, wherein Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms or combinations thereof, and at least one or two of Rₛ₁, Rₛ₂, and Rₛ₃ are each independently selected from substituted or unsubstituted alkyl having 1 to 20 carbon atoms, substituted or unsubstituted cycloalkyl having 3 to 20 ring carbon atoms or combinations thereof.

According to an embodiment of the present disclosure, wherein, in Formula 4 and/or Formula 5, Y₁ to Y₆ are each independently selected from CR_{y1} or CR_{y2}, at least one of Y₁ to Y₆ is selected from CR_{y2}, and the R_{ye} has a structure of -L₁-SiRₛ₁Rₛ₂Rₛ₃, wherein Rₛ₁, Rₛ₂, and Rₛ₃ are each independently selected from the group consisting of: methyl, ethyl, isopropyl, isobutyl, t-butyl, neopentyl, cyclopentyl, cyclopentylmethyl, cyclohexyl, norbornyl, adamantyl, trifluoromethyl, phenyl, and combinations thereof.

According to an embodiment of the present disclosure, in Formula 1, Y₁ to Y₆ are, at each occurrence identically or differently, selected from CR_{y} or N; R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; when R_{y} is selected from substituted alkyl having 1 to 20 carbon atoms, substituted cycloalkyl having 3 to 20 ring carbon atoms or substituted heteroalkyl having 1 to 20 carbon atoms, the substitutions are selected from the group consisting of: hydrogen, deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof.

According to an embodiment of the present disclosure, in Formula 1, X₁ to X₈ are, at each occurrence identically or differently, selected from C, CRₓ or N; Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof.

According to an embodiment of the present disclosure, wherein, Lₐ is, at each occurrence identically or differently, selected from the group consisting of Lₐ₁ to Lₐ₃₂₃, and for the specific structures of Lₐ₁ to Lₐ₃₂₃, reference is made to claim 20.

According to an embodiment of the present disclosure, wherein, L_{b} is, at each occurrence identically or differently, selected from any one of the group consisting of L_{b1} to L_{b322}, and for the specific structures of L_{b1} to L_{b322}, reference is made to claim 21.

According to an embodiment of the present disclosure, wherein, L_{c} is, at each occurrence identically or differently, selected from any one of the group consisting of L_{c1} to L_{c231}, and for the specific structures of L_{c1} to L_{c231}, reference is made to claim 21.

According to an embodiment of the present disclosure, wherein, the first metal complex has a structure of Ir(Lₐ)₂(L_{b}) or Ir(Lₐ)₂(L_{c}) or Ir(Lₐ)(L_{c})₂;

wherein when the first metal complex has a structure of Ir(Lₐ)₂(L_{b}), Lₐ is, at each occurrence identically or differently, selected from any one or any two of the group consisting of Lₐ₁ to Lₐ₃₂₃, and L_{b} is selected from any one of the group consisting of L_{b1} to L_{b322}; when the first metal complex has a structure of Ir(Lₐ)₂(L_{c}), Lₐ is, at each occurrence identically or differently, selected from any one or any two of the group consisting of Lₐ₁ to Lₐ₃₂₃, and L_{c} is selected from any one of the group consisting of L_{c1} to L_{c231}; when the first metal complex has a structure of Ir(Lₐ)(L_{c})₂, Lₐ is selected from any one of the group consisting of Lₐ₁ to Lₐ₃₂₃, and L_{c} is, at each occurrence identically or differently, selected from any one or any two of the group consisting of L_{c1} to L_{c231}.

According to an embodiment of the present disclosure, wherein, the first metal complex is selected from the group consisting of Compound 1 to Compound 612, and for the specific structures of Compound 1 to Compound 612, reference is made to claim 22.

According to an embodiment of the present disclosure, wherein, the first compound has a structure represented by Formula 6:

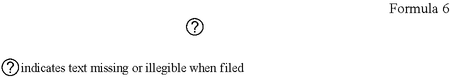

wherein

Zₕ₁ and Zₕ₈ are, at each occurrence identically or differently, selected from CR_{z1} or N; Zₕ₂, Zₕ₃, Zₕ₆, and Zₕ₇ are, at each occurrence identically or differently, selected from C, CR_{z2} or N; Zₕ₄ and Zₕ₅ are, at each occurrence identically or differently, selected from C, CR_{z3} or N; Zₕ₉ to Zₕ₁₆ are, at each occurrence identically or differently, selected from CR_{zh} or N;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2}, R_{z3}, and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

in Formula 6, adjacent substituents R_{z2}, R_{z3} can be optionally joined to form a 6- to 10-membered ring; adjacent substituents R_{zh} on the same 6-membered ring can be optionally joined to form a ring;

the E and L are defined as in Formula 2.

In the present disclosure, the expression that adjacent substituents R_{z2}, R_{z3} can be optionally joined to form a 6- to 10-membered ring is intended to mean that when a plurality of R_{z2} and R_{z3} are present, adjacent substituents R_{z2}, or adjacent substituents R_{z2} and R_{z3} can be joined to form a 6-membered ring, a 7-membered ring, an 8-membered ring, a 9-membered ring or a 10-membered ring. Obviously, when a plurality of substituents R_{z2} and R_{z3} are present, it is possible that none of these groups of adjacent substituents R_{z2} and R_{z3} are joined to form a ring.

In the present disclosure, the expression that adjacent substituents R_{zh} on the same 6-membered ring can be optionally joined to form a 6- to 10-membered ring is intended to mean that when a plurality of substituents R_{zh} are present on the same 6-membered ring, any two adjacent substituents R_{zh} can be joined to form a ring. For example, in Formula 6, Zₕ₁₃ to Zₕ₁₆ are all selected from CR_{zh}, these substituents R_{zh} are all on the same 6-membered ring, and in this case, any adjacent substituents R_{zh} can be joined to form a ring. In another example, in Formula 6, Zₕ₁₂ and Zₕ₁₃ are both selected from CR_{zh}, these two substituents R_{zh} are not on the same 6-membered ring, and then these two substituents R_{zh} cannot be joined to form a ring. Obviously, when a plurality of substituents R_{zh} is present on the same 6-membered ring, none of the adjacent substituents R_{zh} may be joined to form a ring.

According to an embodiment of the present disclosure, wherein, the first compound has a structure represented by Formula 7:

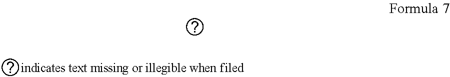

wherein

Zₕ₁ and Zₕ₈ are, at each occurrence identically or differently, selected from CR_{z1} or N; Zₕ₂, Zₕ₃, Zₕ₆, and Zₕ₇ are, at each occurrence identically or differently, selected from C, CR_{z2} or N; Zₕ₄ and Zₕ₅ are, at each occurrence identically or differently, selected from C, CR_{z3} or N; Zₕ₉ to Zₕ₁₂ are, at each occurrence identically or differently, selected from C, CR_{zh} or N; Zₕ₁₃ to Zₕ₂₁ are, at each occurrence identically or differently, selected from CR_{zh} or N;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2}, R_{z3}, and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

in Formula 7, adjacent substituents R_{z2}, R_{z3} can be optionally joined to form a 6- to 10-membered ring; adjacent substituents R_{zh} on the same 6-membered ring can be optionally joined to form a ring;

the E and L are defined as in Formula 2.

According to an embodiment of the present disclosure, wherein, the first compound has a structure represented by Formula 8:

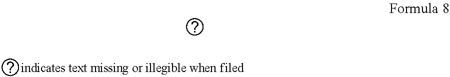

wherein

Zₕ₁ and Zₕ₈ are, at each occurrence identically or differently, selected from CR_{z1} or N; Zₕ₂, Zₕ₃, Zₕ₆, and Zₕ₇ are, at each occurrence identically or differently, selected from C, CR_{z2} or N; Zₕ₄ and Zₕ₅ are, at each occurrence identically or differently, selected from C, CR_{z3} or N; Zₕ₉ to Zₕ₁₃ are, at each occurrence identically or differently, selected from C, CR_{zh} or N; Zₕ₁₄ to Zₕ₂₃ are, at each occurrence identically or differently, selected from CR_{zh} or N;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2}, R_{z3}, and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

in Formula 8, adjacent substituents R_{z2}, R_{z3} can be optionally joined to form a 6- to 10-membered ring; adjacent substituents R_{zh} on the same 6-membered ring can be optionally joined to form a ring;

the E and L are defined as in Formula 2.

According to an embodiment of the present disclosure, wherein, the first compound has a structure represented by Formula 9:

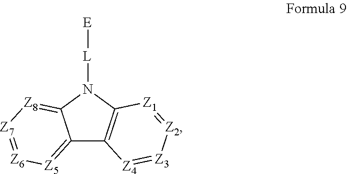

wherein

Z₁ and Z₈ are, at each occurrence identically or differently, selected from CR_{z1} or N; Z₂, Z₃, Z₆, and Z₇ are, at each occurrence identically or differently, selected from CR_{z2} or N; Z₄ and Z₅ are, at each occurrence identically or differently, selected from CR_{z3}, and two substituents R_{z3} in Z₄ and Z₅ are joined to form a ring;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R_{z3} is, at each occurrence identically or differently, selected from the group consisting of: hydrogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof;

adjacent substituents R_{z2}, R_{z3} can be optionally joined to form a ring;

the E and L are defined as in Formula 2.

In this embodiment, the expression that adjacent substituents R_{z2}, R_{z3} can be optionally joined to form a ring is intended to mean that any one or more of groups of adjacent substituents, such as adjacent substituents R_{z2} in Z₂ and Z₃, adjacent substituents R_{z2} in Z₆ and Z₇, substituent R_{z2} in Z₃ and substituent R_{z3} in Z₄, substituent R_{z2} in Z₃ and substituent R_{z3} in Z₅, substituent R_{z2} in Z₆ and substituent R_{z3} in Z₄, and substituent R_{z2} in Z₆ and substituent R_{z3} in Z₅, can be joined to form a ring. Obviously, it is possible that none of these groups of substituents are joined to form a ring.

In the present disclosure, the expression that adjacent substituents Rₑ can be optionally joined to form a ring is intended to mean that any adjacent Rₑ can be joined to form a ring. Obviously, it is possible that none of adjacent substituents Rₑ are joined to form a ring.

According to an embodiment of the present disclosure, wherein, in Formula 9, a ring formed by joining two substituents R_{z3} in Z₄ and Z₅ has at least 7 ring atoms.

According to an embodiment of the present disclosure, wherein, the first compound has a structure represented by any one of Formula 10, Formula 11, Formula 12, Formula 13, Formula 14 or Formula 15:

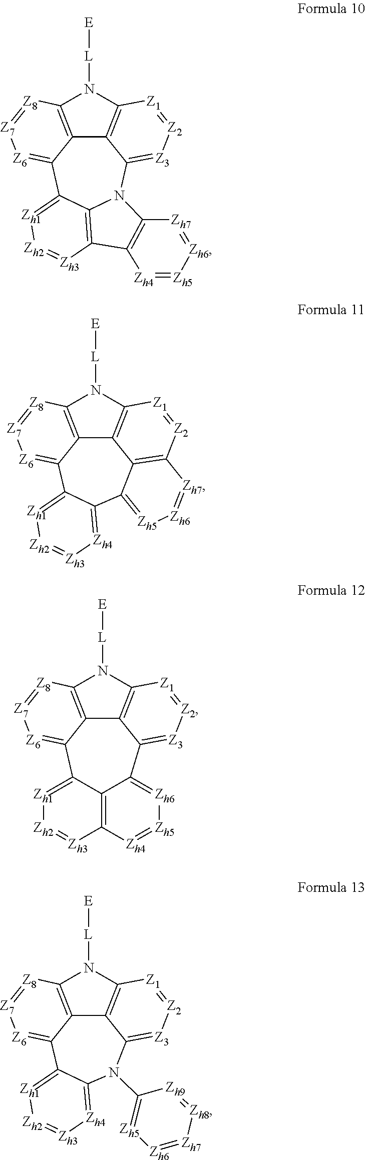

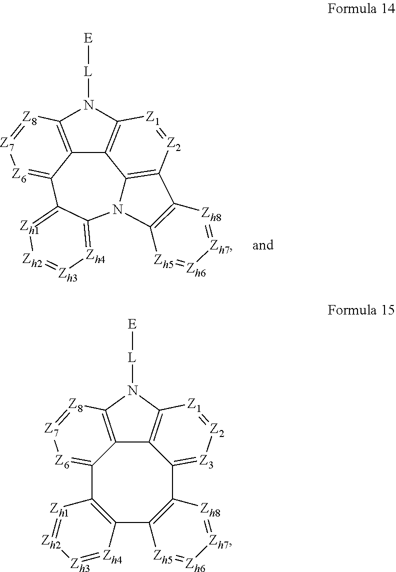

wherein

in Formula 10, Z₁ and Z₈ are, at each occurrence identically or differently, selected from CR_{z1} or N; Z₂, Z₃, Z₆, and Z₇ are, at each occurrence identically or differently, selected from CR_{z2} or N; Zₕ₁ to Zₕ₇ are, at each occurrence identically or differently, selected from CR_{zh} or N;

in Formula 11, Z₁ and Z₈ are, at each occurrence identically or differently, selected from CR_{z1} or N; Z₂, Z₆, and Z₇ are, at each occurrence identically or differently, selected from CR_{z2} or N; Zₕ₁ to Zₕ₇ are, at each occurrence identically or differently, selected from CR_{zh} or N;

in Formula 12, Z₁ and Z₈ are, at each occurrence identically or differently, selected from CR_{z1} or N; Z₂, Z₃, Z₆, and Z₇ are, at each occurrence identically or differently, selected from CR_{z2} or N; Zₕ₁ to Zₕ₆ are, at each occurrence identically or differently, selected from CR_{zh} or N;

in Formula 13, Z₁ and Z₈ are, at each occurrence identically or differently, selected from CR_{z1} or N; Z₂, Z₃, Z₆, and Z₇ are, at each occurrence identically or differently, selected from CR_{z2} or N; Zₕ₁ to Zₕ₉ are, at each occurrence identically or differently, selected from CR_{zh} or N;

in Formula 14, Z₁ and Z₈ are, at each occurrence identically or differently, selected from CR_{z1} or N; Z₂, Z₆, and Z₇ are, at each occurrence identically or differently, selected from CR_{z2} or N; Zₕ₁ to Zₕ₈ are, at each occurrence identically or differently, selected from CR_{zh} or N;

in Formula 15, Z₁ and Z₈ are, at each occurrence identically or differently, selected from CR_{z1} or N; Z₂, Z₃, Z₆, and Z₇ are, at each occurrence identically or differently, selected from CR_{z2} or N; Zₕ₁ to Zₕ₈ are, at each occurrence identically or differently, selected from CR_{zh} or N;

R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;

R_{z2} and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents R_{z1}/R_{z2}, R_{zh} can be optionally joined to form a ring;

the E and L are defined as in Formula 2.

In this embodiment, the expression that adjacent substituents R_{z1}/R_{z2}, R_{zh} can be optionally joined to form a ring is intended to mean that any one or more of groups of adjacent substituents, such as adjacent substituents R_{z1} and R_{z2}, adjacent substituents R_{z2}, adjacent substituents R_{z2} and R_{zh}, and adjacent substituents R_{zh}, can be joined to form a ring. Obviously, it is possible that none of these groups of substituents are joined to form a ring.

According to an embodiment of the present disclosure, wherein, in Formula 10, Formula 11, Formula 12, Formula 13, Formula 14 or Formula 15, R_{z2} and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, an isocyano group, a hydroxyl group, a sulfanyl group, and combinations thereof;

adjacent substituents R_{z2}, R_{zh} can be optionally joined to form a ring.

In this embodiment, the expression that adjacent substituents R_{z2}, R_{zh} can be optionally joined to form a ring is intended to mean that any one or more of groups of adjacent substituents, such as adjacent substituents R_{z2}, adjacent substituents R_{z2} and R_{zh}, and adjacent substituents R_{zh}, can be joined to form a ring. Obviously, it is possible that none of these groups of substituents are joined to form a ring.

According to an embodiment of the present disclosure, wherein, in Formula 6 to Formula 8, Zₕ₁ and Zₕ₈ are, at each occurrence identically or differently, selected from CR_{zi}; in Formula 9 to Formula 15, Z₁ and Z₈ are, at each occurrence identically or differently, selected from CR_{z1}.

According to an embodiment of the present disclosure, wherein, in Formula 6 to Formula 15, the E is selected from the group consisting of: substituted or unsubstituted pyrimidyl, substituted or unsubstituted triazinyl, substituted or unsubstituted quinazolinyl, substituted or unsubstituted quinoxalinyl, substituted or unsubstituted benzoquinazolinyl, and substituted or unsubstituted benzoquinoxalinyl; optionally, hydrogens in the above groups can be partially or completely substituted by deuterium.

According to an embodiment of the present disclosure, wherein, in Formula 6 to Formula 15, the E is selected from the group consisting of the following structures:

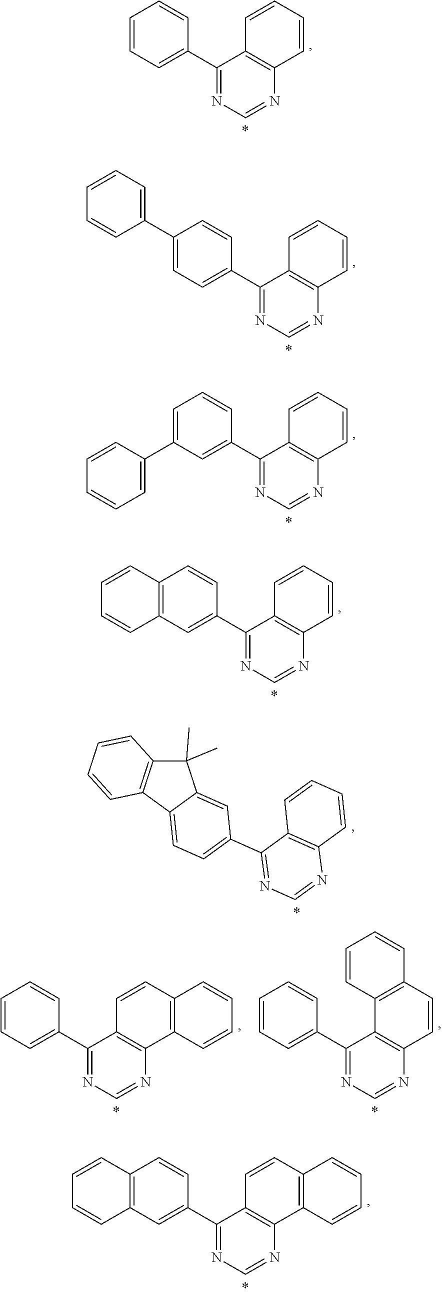

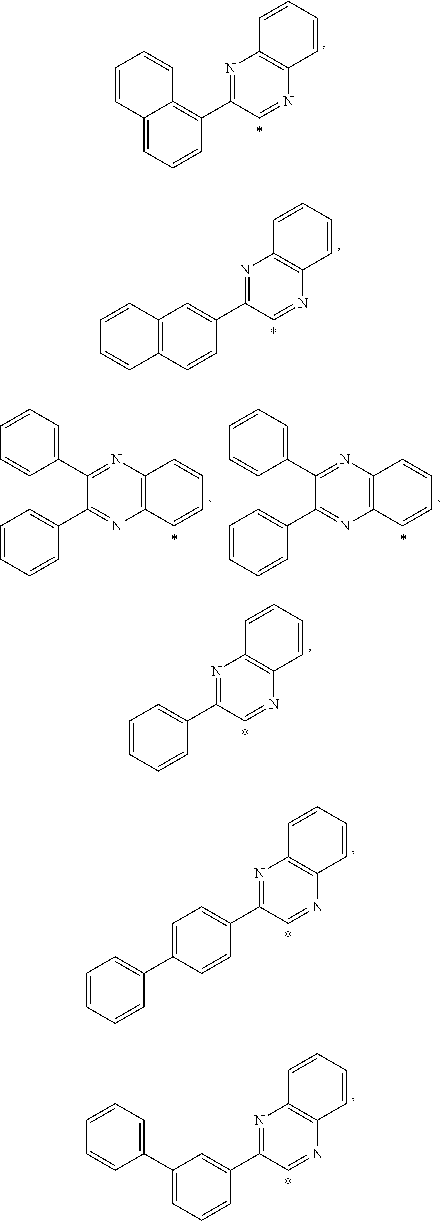

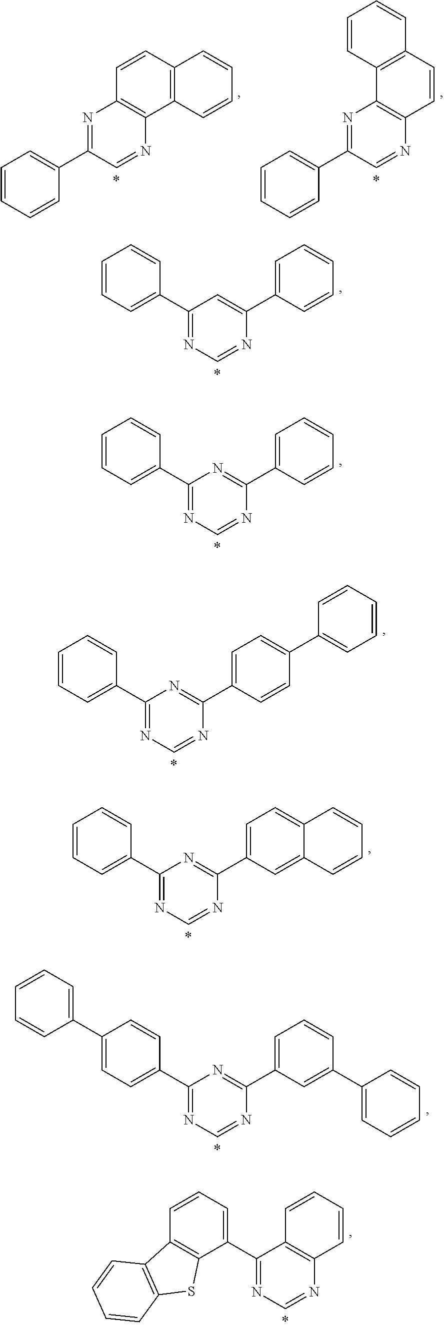

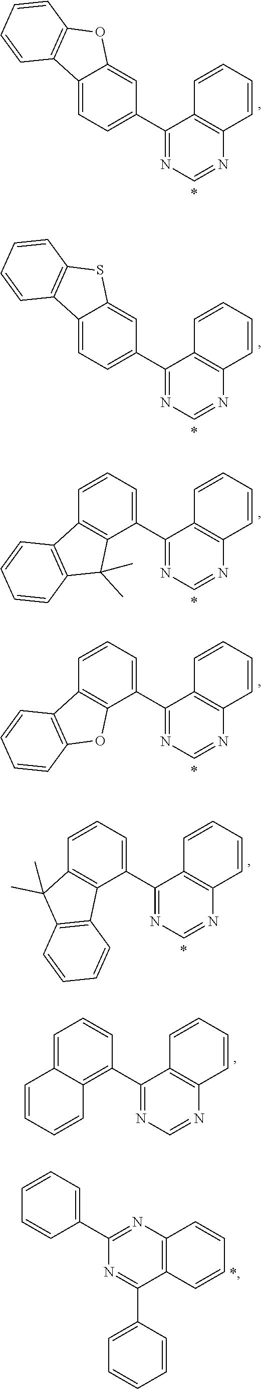

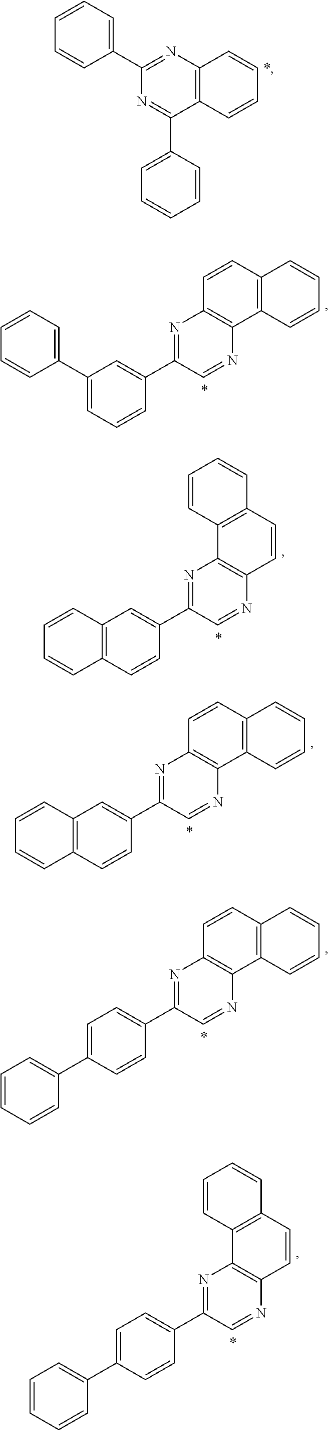 [SMILES: c1ccc(-c2nc(-c3ccccc3)c3ccccc3n2)cc1 ; c1ccc(-c2cccc(-c3cnc4c(ccc5ccccc54)n3)c2)cc1 ; c1ccc2cc(-c3cnc4ccc5ccccc5c4n3)ccc2c1 ; c1ccc2cc(-c3cnc4c(ccc5ccccc54)n3)ccc2c1 ; c1ccc(-c2ccc(-c3cnc4c(ccc5ccccc54)n3)cc2)cc1 ; c1ccc(-c2ccc(-c3cnc4ccc5ccccc5c4n3)cc2)cc1]

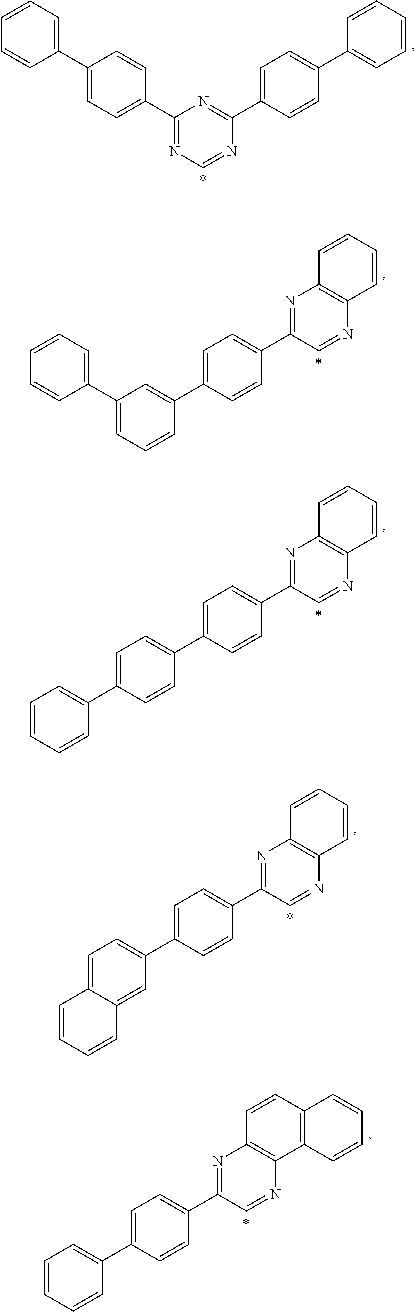 [SMILES: c1ccc(-c2ccc(-c3ncnc(-c4ccc(-c5ccccc5)cc4)n3)cc2)cc1 ; c1ccc(-c2cccc(-c3ccc(-c4cnc5ccccc5n4)cc3)c2)cc1 ; c1ccc(-c2ccc(-c3ccc(-c4cnc5ccccc5n4)cc3)cc2)cc1 ; c1ccc2cc(-c3ccc(-c4cnc5ccccc5n4)cc3)ccc2c1 ; c1ccc(-c2ccc(-c3cnc4c(ccc5ccccc54)n3)cc2)cc1]

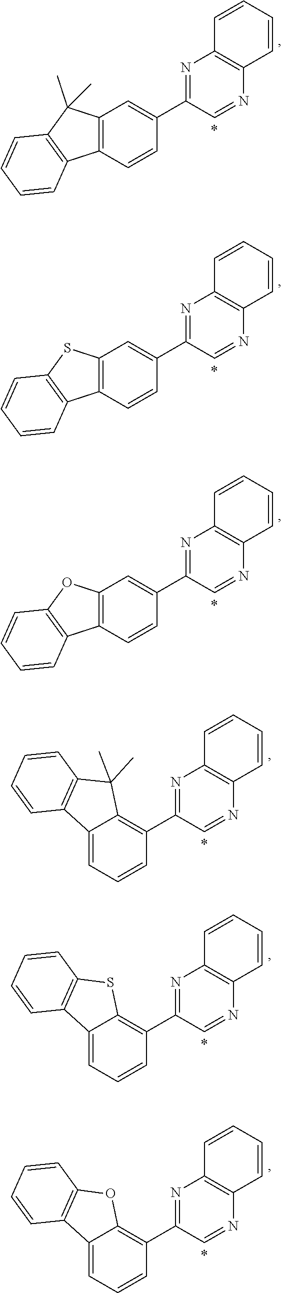 [SMILES: CC1(C)c2ccccc2-c2ccc(-c3cnc4ccccc4n3)cc21 ; c1ccc2nc(-c3ccc4c(c3)sc3ccccc34)cnc2c1 ; c1ccc2nc(-c3ccc4c(c3)oc3ccccc34)cnc2c1 ; CC1(C)c2ccccc2-c2cccc(-c3cnc4ccccc4n3)c21 ; c1ccc2nc(-c3cccc4c3sc3ccccc34)cnc2c1 ; c1ccc2nc(-c3cccc4c3oc3ccccc34)cnc2c1]

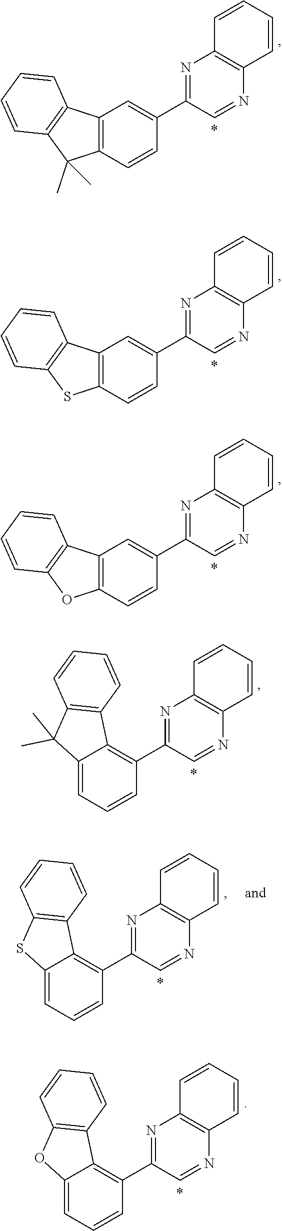 [SMILES: CC1(C)c2ccccc2-c2cc(-c3cnc4ccccc4n3)ccc21 ; c1ccc2nc(-c3ccc4sc5ccccc5c4c3)cnc2c1 ; c1ccc2nc(-c3ccc4oc5ccccc5c4c3)cnc2c1 ; CC1(C)c2ccccc2-c2c(-c3cnc4ccccc4n3)cccc21 ; c1ccc2nc(-c3cccc4sc5ccccc5c34)cnc2c1 ; c1ccc2nc(-c3cccc4oc5ccccc5c34)cnc2c1]

According to an embodiment of the present disclosure, wherein, in Formula 6 to Formula 15, the L is selected from the group consisting of: a single bond, phenylene, naphthylene, biphenylene, terphenylene, triphenylenylene, pyridylene, furylene, thienylene, dibenzofurylene, dibenzothienylene, and combinations thereof; optionally, hydrogens in the above groups can be partially or completely substituted by deuterium.

According to an embodiment of the present disclosure, wherein, in Formula 6 to Formula 15, L is selected from a single bond or phenylene.

According to an embodiment of the present disclosure, wherein, the first compound is selected from the group consisting of compound H1-1 to compound H1-40, and for the specific structures of the compound H1-1 to compound H1-40, reference is made to claim 30.

According to an embodiment of the present disclosure, wherein, the first compound is selected from the group consisting of compound H2-1 to compound H2-40, and for the specific structures of the compound H2-1 to compound H2-40, reference is made to claim 30.

According to an embodiment of the present disclosure, wherein, the first compound is selected from the group consisting of compound H3-1 to compound H3-40, and for the specific structures of the compound H3-1 to compound H3-40, reference is made to claim 30.

According to an embodiment of the present disclosure, wherein, the first compound is selected from the group consisting of compound H4-1 to compound H4-34, and for the specific structures of the compound H4-1 to compound H4-34, reference is made to claim 31.

According to an embodiment of the present disclosure, wherein, the first compound is selected from the group consisting of compound H5-1 to compound H5-37, and for the specific structures of the compound H5-1 to compound H5-37, reference is made to claim 31.

According to an embodiment of the present disclosure, wherein, the first compound is selected from the group consisting of compound H6-1 to compound H6-33, and for the specific structures of the compound H6-1 to compound H6-33, reference is made to claim 31.

According to an embodiment of the present disclosure, wherein, the first compound is selected from the group consisting of compound H7-1 to compound H7-29, and for the specific structures of the compound H7-1 to compound H7-29, reference is made to claim 31.

According to an embodiment of the present disclosure, wherein, the first compound is selected from the group consisting of compound H8-1 to compound H8-32, and for the specific structures of the compound H8-1 to compound H8-32, reference is made to claim 31.

According to an embodiment of the present disclosure, wherein, the first compound is selected from the group consisting of compound H9-1 to compound H9-14, and for the specific structures of the compound H9-1 to compound H9-14, reference is made to claim 31.

According to an embodiment of the present disclosure, in the device, the organic layer is an emissive layer, the first metal complex is a light-emitting material, and the first compound is a host material.

According to an embodiment of the present disclosure, the device emits red light.

According to an embodiment of the present disclosure, the device emits white light.

According to another embodiment of the present disclosure, further provided is an electronic apparatus, comprising an electroluminescent device whose specific structure is as shown in any one of the embodiments described above.

According to another embodiment of the present disclosure, further provided is a compound combination, comprising the first metal complex and the first compound.

In this embodiment, the first metal complex and the first compound may be further selected from the structures described in any one of the embodiments described above.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety.

The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of hosts, emissive dopants, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### MATERIAL SYNTHESIS EXAMPLE

The method for preparing a compound in the present disclosure is not limited herein.

Typically, the following compounds are taken as examples without limitations, and synthesis routes and preparation methods thereof are described below.

### Synthesis Example 1: Synthesis of Compound 198

Step 1: Synthesis of Intermediate 1

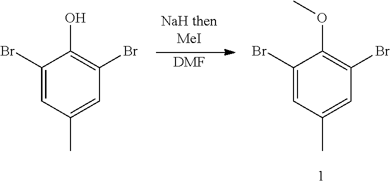

2,6-dibromo-4-methylphenol (58.2 g, 218.9 mmol) was dissolved in 700 mL of dry DMF, then the reaction solution was cooled to 0° C., and NaH (10.6 g, 281.5 mmol) was added to the reaction solution portion-wise. Upon completion of the addition, the reaction solution was stirred at 0° C. until no gas was obviously escaped from the reaction solution. Then, iodomethane (46.7 g, 328.4 mmol) was added to the reaction solution, and then the reaction was warmed to room temperature and stirred overnight. After TLC showed that the reaction was complete, water and ethyl acetate were added to the reaction solution, and then the reaction solution was extracted. The organic phases were combined, washed several times with saturated brine, dried, and subjected to rotary evaporation to dryness to give the crude product. The crude product was separated by silica gel column chromatography (petroleum ether as eluent) to give the target product, Intermediate 1, as colorless oily liquid (57.7 g, 94.3%).

Step 2: Synthesis of Intermediate 2

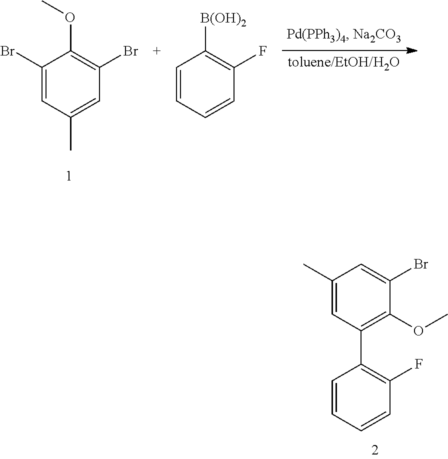

Intermediate 1 (57.7 g, 206 mmol), 2-fluorophenylboronic acid (28.8 g, 206 mmol), tetrakis(triphenylphosphine)palladium (4.76 g, 4.1 mmol), and sodium carbonate (42.7 g, 309 mmol) were put in a 1 L reaction flask, and then 300 mL of toluene, 100 mL of ethanol, and 100 mL of water were added to the reaction flask. The system was evacuated followed by the introduction of nitrogen gas, and then refluxed overnight. After TLC detected that the reaction was complete, the reaction mixture was cooled to room temperature, diluted with water, and extracted with dichloromethane. The organic phases were combined, dried, subjected to rotary evaporation, and separated by silica gel column chromatography (ethyl acetate:petroleum ether (1:100, v/v) as eluent) to give Intermediate 2 as colorless oily liquid (39 g, 64.1%).

Step 3: Synthesis of Intermediate 3

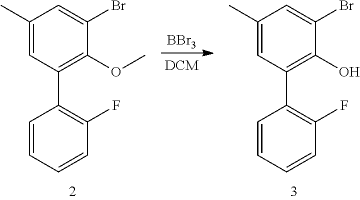

Intermediate 2 (39 g, 132.1 mmol) was dissolved in 500 mL of dichloromethane, then the reaction solution was cooled to 0° C., and boron tribromide (49.7 g, 198.2 mmol) was slowly added to the reaction solution. Then, the reaction proceeded for 2 hours at this temperature. After TLC showed that the reaction was complete, the reaction was carefully quenched by adding water, and the reaction mixture was extracted with dichloromethane. The organic phases were combined, dried, subjected to rotary evaporation, and separated by silica gel column chromatography (ethyl acetate:petroleum ether (1:50, v/v) as eluent) to give Intermediate 3 as white solid (31.8 g, 85.5%).

Step 4: Synthesis of Intermediate 4

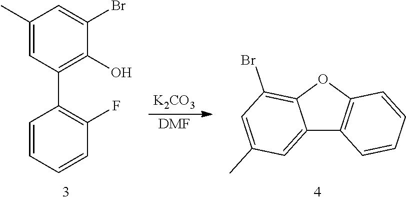

Intermediate 3 (31.8 g, 113 mmol), potassium carbonate (31.3 g, 226 mmol), and DMF (300 mL) were added to a 500 mL three-necked flask, and then the resulting reaction mixture was heated to 100° C. under nitrogen protection and reacted overnight. After the reaction mixture was cooled to room temperature, water and ethyl acetate were added to the reaction solution, and the reaction solution was extracted. The organic phases were combined, washed several times with saturated brine, dried, and subjected to rotary evaporation to dryness to give the crude product. The crude product was separated by silica gel column chromatography (petroleum ether as eluent) to give the target product, Intermediate 4, as white solid (16.4 g, 55.6%).

Step 5: Synthesis of Intermediate 5

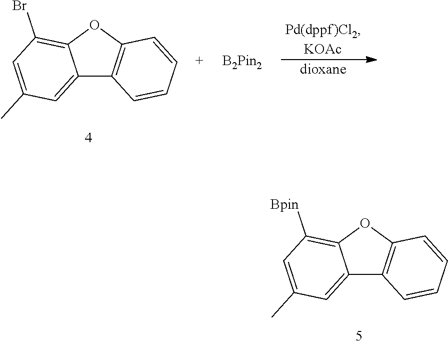

Intermediate 4 (16.4 g, 62.8 mmol), bis(pinacolato)diboron (20.7 g, 81.6 mmol), Pd(dppf)Cl₂ (1.4 g, 1.9 mmol), potassium acetate (9.2 g, 94.2 mmol), and 1,4-dioxane (300 mL) were added to a 500 mL three-necked flask, and then the resulting reaction mixture was heated to reflux overnight under nitrogen protection. After the reaction mixture was cooled to room temperature, water and ethyl acetate were added to the reaction solution, and the reaction solution was extracted. The organic phases were combined, washed several times with saturated brine, dried, and subjected to rotary evaporation to dryness to give the crude product. The crude product was separated by silica gel column chromatography (ethyl acetate:petroleum ether (1:50, v/v) as eluent) to give the target product, Intermediate 5, as white solid (13.5 g, 69.8%).

Step 6: Synthesis of Intermediate 6

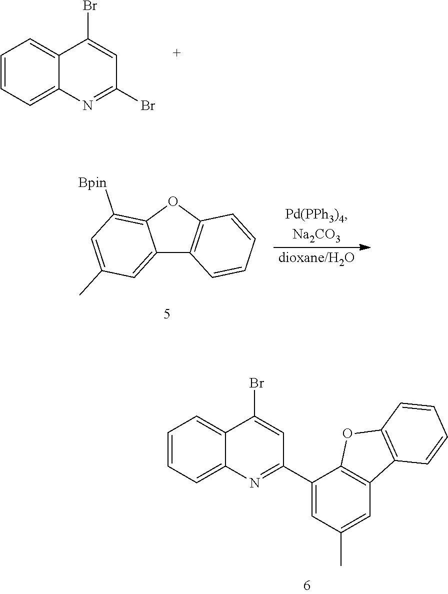

2,4-dibromoquinoline (6.15 g, 21.4 mmol), Intermediate 5 (6.6 g, 21.4 mmol), tetrakis(triphenylphosphine)palladium (1.2 g, 1.1 mmol), sodium carbonate (3.4 g, 32.1 mmol), 1,4-dioxane (90 mL), and water (20 mL) were added to a 250 mL three-necked flask, and then the resulting reaction mixture was heated to reflux overnight under nitrogen protection. After the reaction mixture was cooled to room temperature, the reaction solution was filtered, and the resulting solid was washed several times with water and petroleum ether and dried to give the crude product. The crude product was separated by silica gel column chromatography (dichloromethane:petroleum ether (1:3, v/v) as eluent) to give the target product, Intermediate 6, as white solid (5.2 g, 62.6%).

Step 7: Synthesis of Intermediate 7

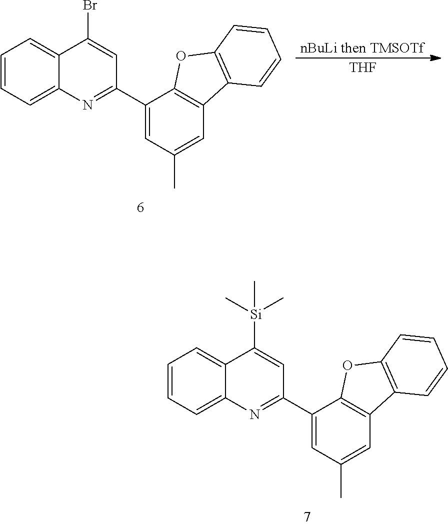 [SMILES: Cc1cc(-c2cc(Br)c3ccccc3n2)c2oc3ccccc3c2c1 ; "nBuLi then TMSOTf" ; Cc1cc(-c2cc([Si](C)(C)C)c3ccccc3n2)c2oc3ccccc3c2c1 ; "THF"]

Intermediate 6 (5.2 g, 13.4 mmol) was dissolved in 134 mL of ultra-dry tetrahydrofuran, the reaction solution was cooled to −72° C., and a solution of n-butyl lithium (6.4 mL, 12.0 mmol) was added dropwise to the reaction solution under nitrogen protection. Upon the completion of dropwise addition, the reaction solution was maintained at this temperature for 30 minutes, and trimethylsilyl trifluoromethanesulfonate (TMSOTf) (4.2 g, 18.8 mmol) was added to the reaction solution. Upon completion of the addition, the reaction was warmed to room temperature and proceeded for 2 hours. Then, the reaction was quenched by adding a saturated solution of sodium bicarbonate. Ethyl acetate was added to the reaction, and layers were separated. The aqueous phase was extracted with ethyl acetate. The organic phases were combined, dried, and subjected to rotary evaporation to dryness to give the crude product. The crude product was separated by silica gel column chromatography (dichloromethane:petroleum ether (1:2, v/v) as eluent) to give the target product, Intermediate 7, as white solid (3.2 g, 62.7%).

Step 8: Synthesis of Iridium Dimer

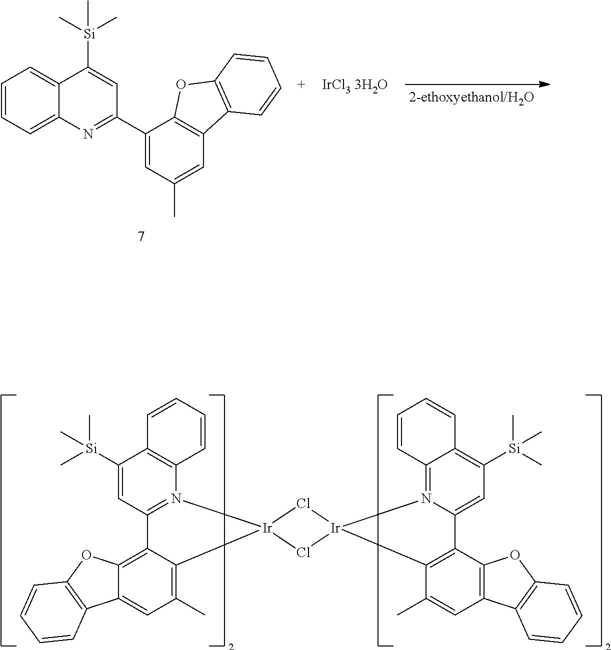

A mixture of Intermediate 7 (3 g, 7.9 mmol), iridium (III) chloride trihydrate (693 mg, 2.0 mmol), 2-ethoxyethanol (21 mL), and water (7 mL) was refluxed under a nitrogen atmosphere for 24 hours. The mixture was cooled to room temperature, and subjected to rotary evaporation to carefully remove the water in the solution, to give the solution of iridium dimer in ethoxyethanol, which was used for the next step without further purification.

Step 9: Synthesis of Compound 198

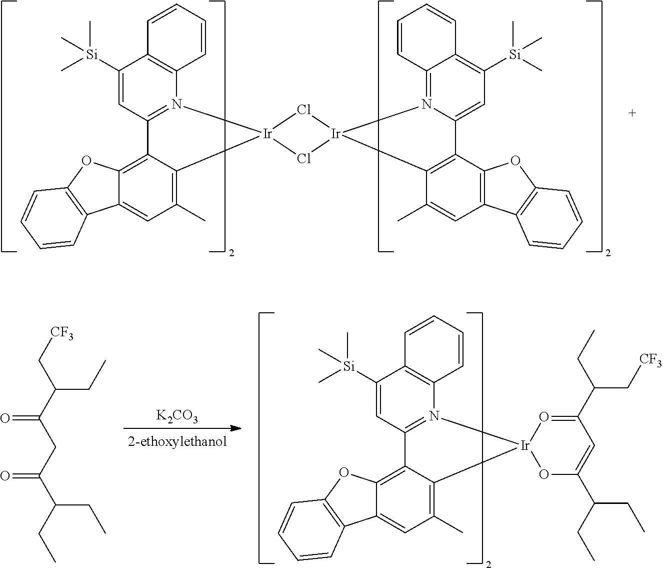

The solution of iridium dimer in ethoxyethanol from Step 8, 3,7-diethyl-1,1,1-trifluorononane-4,6-dione (798 mg, 3.0 mmol), and potassium carbonate (1.38 g, 10.0 mmol) were added to a 100 mL round-bottom flask and reacted at room temperature for 24 hours under nitrogen protection. Then, the reaction solution was poured into a funnel filled with Celite, filtered, and washed with ethanol. Dichloromethane was added to the resulting solid, and the filtrate was collected. Then ethanol was added, and the resulting solution was concentrated but not concentrated to dryness. The solution was filtered to give 1.2 g of Compound 198 (with a yield of 49.2%). The product was further purified by column chromatography. The structure of the compound was confirmed through NMR and LC-MS as the target product with a molecular weight of 1218.4.

### Synthesis Example 2: Synthesis of Compound 268

Step 1: Synthesis of Iridium Dimer

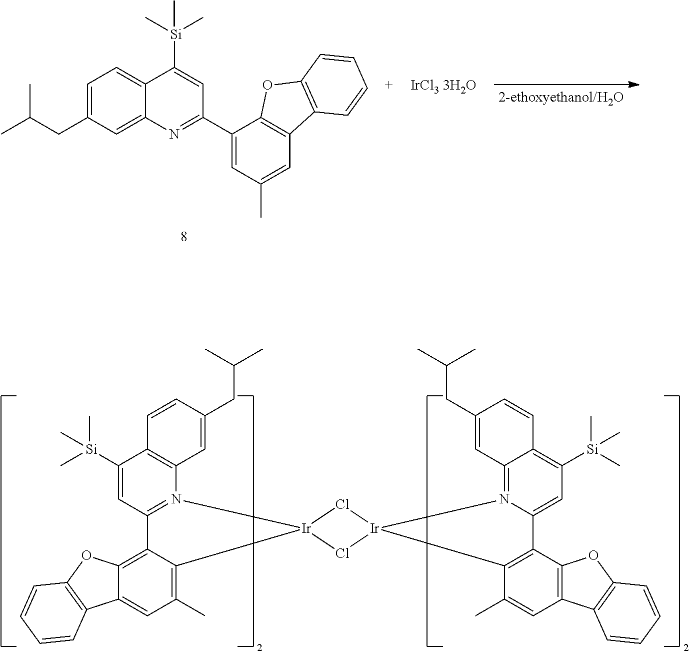

A mixture of Intermediate 8 (0.3 g, 0.69 mmol), iridium (III) chloride trihydrate (60 mg, 0.17 mmol), 2-ethoxyethanol (6 mL), and water (2 mL) was refluxed under a nitrogen atmosphere for 24 hours. The mixture was cooled to room temperature, and subjected to rotary evaporation to remover water in the solution, to give the solution of iridium dimer in ethoxyethanol, which was used for the next step without further purification.

Step 2: Synthesis of Compound 268

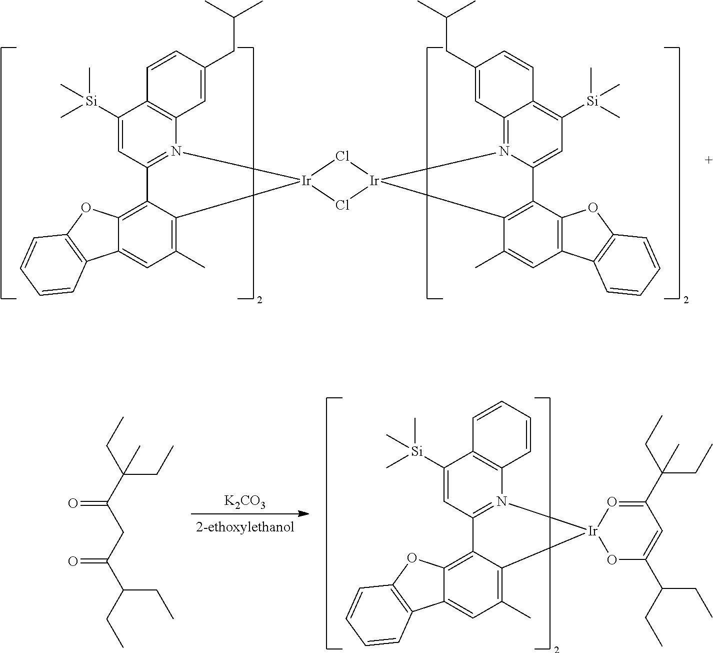

The solution of iridium dimer in ethoxyethanol given in Step 1, 3,7-diethyl-3-methylnonane-4,6-dione (77 mg, 0.34 mmol), and potassium carbonate (117 mg, 0.85 mmol) were added to a 50 mL round-bottom flask and reacted at room temperature for 24 hours under nitrogen protection. Then, the reaction solution was poured into a funnel filled with Celite, filtered, and washed with ethanol. Dichloromethane was added to the resulting solid, and the filtrate was collected. Then ethanol was added, and the resulting solution was concentrated but not concentrated to dryness. The solution was filtered to give 80 mg of Compound 268 (with a yield of 36.5%). The product was further purified by column chromatography. The structure of the compound was confirmed through NMR and LC-MS as the target product with a molecular weight of 1290.6.

### Synthesis Example 3: Synthesis of Compound 490

Step 1: Synthesis of Iridium Dimer

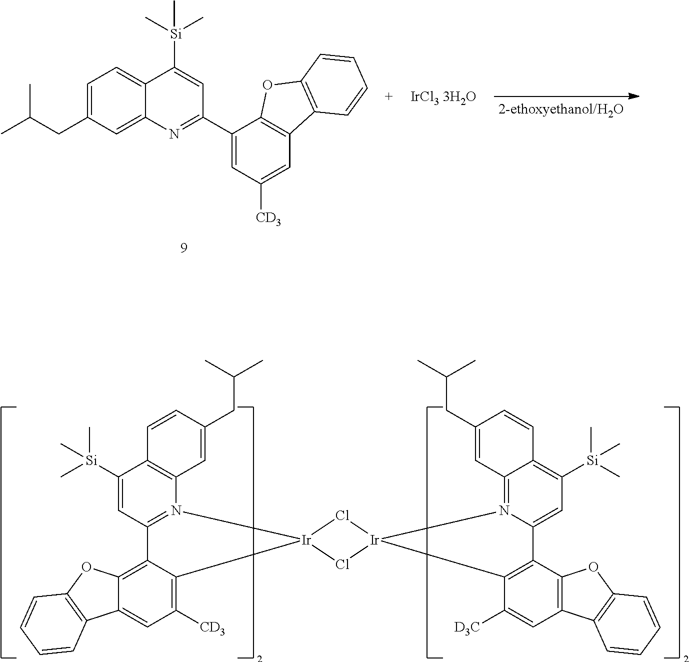

A mixture of Intermediate 9 (2.4 g, 5.52 mmol), iridium (III) chloride trihydrate (480 mg, 1.36 mmol), 2-ethoxyethanol (30 mL), and water (10 mL) was refluxed in a nitrogen atmosphere for 24 hours. The mixture was cooled to room temperature, and subjected to rotary evaporation to remover water in the solution, to give the solution of iridium dimer in ethoxyethanol, which was used for the next step without further purification.

Step 2: Synthesis of Compound 490

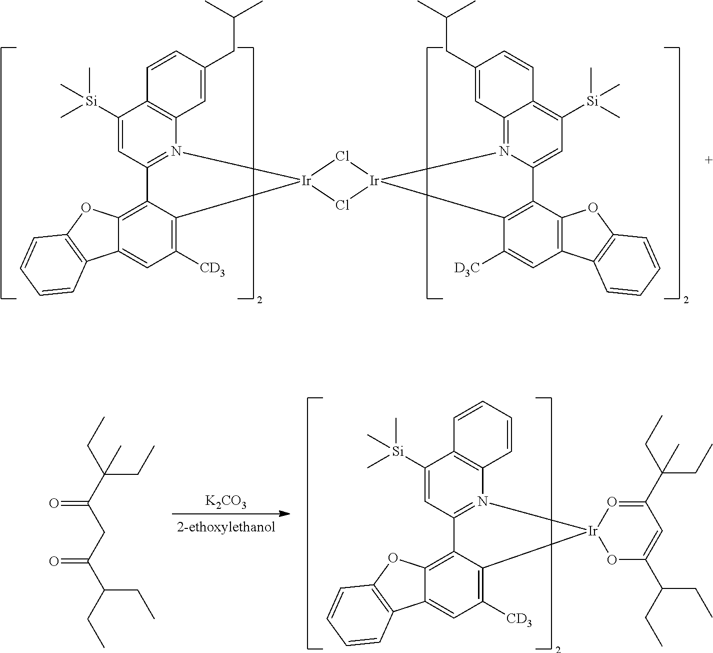

The solution of iridium dimer in ethoxyethanol from Step 1, 3,7-diethyl-3-methylnonane-4,6-dione (462 mg, 2.04 mmol), and potassium carbonate (936 mg, 5.8 mmol) were added to a 100 mL round-bottom flask and reacted at room temperature for 24 hours under nitrogen protection. Then, the reaction solution was poured into a funnel filled with Celite, filtered, and washed with ethanol. Dichloromethane was added to the resulting solid, and the filtrate was collected. Then ethanol was added, and the resulting solution was concentrated but not concentrated to dryness. The solution was filtered to give 640 mg of Compound 490 (with a yield of 72.6%). The product was further purified by column chromatography. The structure of the compound was confirmed through NMR and LC-MS as the target product with a molecular weight of 1296.6.

The persons skilled in the art will appreciate that the above preparation methods are merely illustrative. The persons skilled in the art can obtain other structures of the first metal complex of the present disclosure through the modifications of the preparation methods. The first metal complex and the first compound used in the present disclosure may also be purchased, obtained with reference to the preparation methods in the prior art, or obtained with reference to Chinese application Nos. CN2020102702502 and CN2020102850167, which are not described herein.

The method for preparing an electroluminescent device is not limited. The preparation methods in the following examples are merely illustrative and not to be construed as a limitation. The persons skilled in the art can make reasonable improvements on the preparation methods in the following examples based on the prior art. For example, the proportions of various materials in the emissive layer are not particularly limited. The persons skilled in the art can reasonably select the proportions of materials within a certain range based on the prior art. For example, based on the total weight of the materials in the emissive layer, the host material may account for 80% to 99% and the light-emitting material may account for 1% to 20%; or the host material may account for 90% to 99% and the light-emitting material may account for 1% to 10%; or the host material may account for 95% to 99% and the light-emitting material may account for 1% to 5%. In addition, the host material may be one or two materials, wherein the two host materials may be in a ratio of 100:0 to 1:99, or in a ratio of 80:20 to 20:80, or in a ratio of 60:40 to 40:60. In the device examples, devices were tested for properties using conventional equipment in the art (including, but not limited to, evaporator produced by ANGSTROM ENGINEERING, optical measurement system and lifetime test systems produced by SUZHOU F STAR, ellipsometer manufactured by BEIJING ELLITOP SCIENTIFIC CO., LTD., etc.) by methods well known to the persons skilled in the art.

### Device Example 1

First, a glass substrate having an indium tin oxide (ITO) anode with a thickness of 120 nm was cleaned and then treated with oxygen plasma and UV ozone. After the treatment, the substrate was dried in a glovebox to remove moisture. Next, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was used as a hole injection layer (HIL). Compound HT was used as a hole transport layer (HTL). Compound EB1 was used as an electron blocking layer (EBL). Compound 198 was doped in the host compound H2-4 to be used as an emissive layer (EML). Compound HB was used as a hole blocking layer (HBL). On the HBL, Compound ET and 8-hydroxyquinolinolato-lithium (Liq) were co-deposited as an electron transport layer (ETL). Finally, Liq with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Example 2

The preparation method in Device Example 2 was the same as the preparation method in Device Example 1 except that Compound H2-4 was replaced with Compound H4-17 in the EML.

### Device Example 3

The preparation method in Device Example 3 was the same as the preparation method in Device Example 1 except that Compound H2-4 was replaced with Compound H5-1 in the EML.

### Device Example 4

The preparation method in Device Example 4 was the same as that in Device Example 1 except that Compound 198 was replaced with Compound 268 in the EML (the weight ratio of Compound 268 to Compound H2-4 was 2.5:97.5).

### Device Example 5

The preparation method in Device Example 5 was the same as the preparation method in Device Example 2 except that Compound 198 was replaced with Compound 268 in the EML.

### Device Example 6

The preparation method in Device Example 6 was the same as the preparation method in Device Example 4 except that Compound 268 was replaced with Compound 490 in the EML.

### Device Example 7

The preparation method in Device Example 7 was the same as the preparation method in Device Example 2 except that Compound 198 was replaced with Compound 490 in the EML.

### Device Comparative Example 1

The preparation method in Device Comparative Example 1 was the same as the preparation method in Device Example 1 except that Compound H2-4 was replaced with Comparative Compound CBP in the EML.

The structures and thicknesses of layers of the devices are shown in the following table. The layer using more than one material was obtained by doping different compounds at their weight ratio as recorded.

TABLE 1
Device structures in Device Examples

| Device No. | HIL | HTL | EBL | EML | HBL | ETL |
|---|---|---|---|---|---|---|
| Example 1 | Compound | Compound | Compound | Compound | Compound | Compound |
| | HI | HT | EB1 | H2-4:Compound | HB | ET:Liq |
| | (100 Å) | (400 Å) | (50 Å) | 198 (98:2) | (50 Å) | (40:60) |
| | | | | (400 Å) | | (350 Å) |
| Example 2 | Compound | Compound | Compound | Compound | Compound | Compound |
| | HI | HT | EB1 | H4-17:Compound | HB | ET:Liq |
| | (100 Å) | (400 Å) | (50 Å) | 198 (98:2) | (50 Å) | (40:60) |
| | | | | (400 Å) | | (350 Å) |
| Example 3 | Compound | Compound | Compound | Compound | Compound | Compound |
| | HI | HT | EB1 | H5-1:Compound | HB | ET:Liq |
| | (100 Å) | (400 Å) | (50 Å) | 198 (98:2) | (50 Å) | (40:60) |
| | | | | (400 Å) | | (350 Å) |
| Example 4 | Compound | Compound | Compound | Compound | Compound | Compound |
| | HI | HT | EB1 | H2-4:Compound | HB | ET:Liq |
| | (100 Å) | (400 Å) | (50 Å) | 268 (97.5:2.5) | (50 Å) | (40:60) |
| | | | | (400 Å) | | (350 Å) |
| Example 5 | Compound | Compound | Compound | Compound | Compound | Compound |
| | HI | HT | EB1 | H4-17:Compound | HB | ET:Liq |
| | (100 Å) | (400 Å) | (50 Å) | 268 (98:2) | (50 Å) | (40:60) |
| | | | | (400 Å) | | (350 Å) |
| Example 6 | Compound | Compound | Compound | Compound | Compound | Compound |
| | HI | HT | EB1 | H2-4:Compound | HB | ET:Liq |
| | (100 Å) | (400 Å) | (50 Å) | 490 (97.5:2.5) | (50 Å) | (40:60) |
| | | | | (400 Å) | | (350 Å) |
| Example 7 | Compound | Compound | Compound | Compound | Compound | Compound |
| | HI | HT | EB1 | H4-17:Compound | HB | ET:Liq |
| | (100 Å) | (400 Å) | (50 Å) | 490 (98:2) | (50 Å) | (40:60) |
| | | | | (400 Å) | | (350 Å) |
| Comparative | Compound | Compound | Compound | Compound CBP: | Compound | Compound |
| Example 1 | HI | HT | EB1 | Compound 198 | HB | ET:Liq |
| | (100 Å) | (400 Å) | (50 Å) | (98:2) | (50 Å) | (40:60) |
| | | | | (400 Å) | | (350 Å) |

The structures of the materials used in the devices are shown as follows:

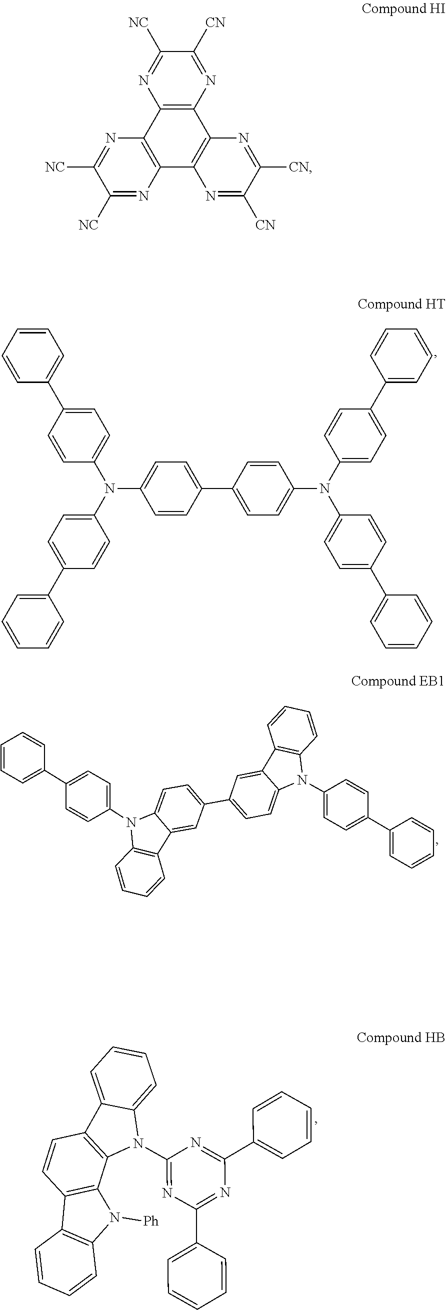 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccccc3)nc(-n3c4ccccc4c4ccc5c6ccccc6n(-c6ccccc6)c5c43)n2)cc1]

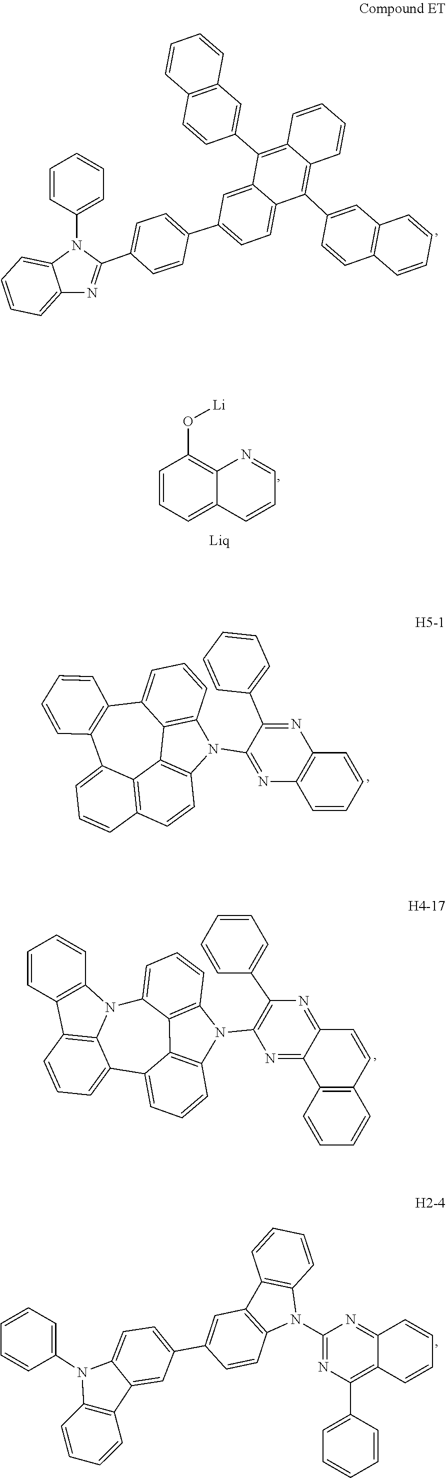

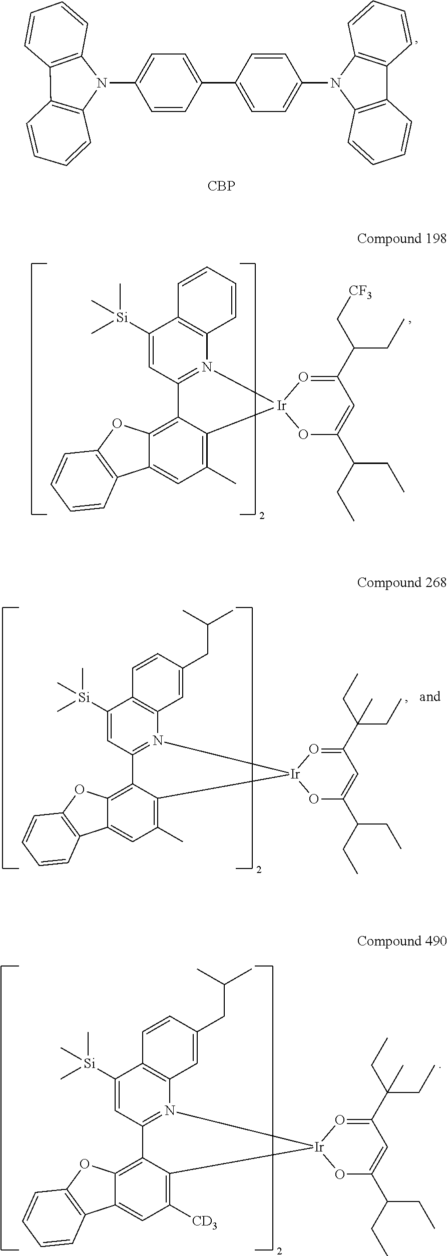

IVL and lifetime of the devices were measured. Table 2 shows the data of the devices, that is, CIE, voltage, external quantum efficiency (EQE), luminous efficiency (CE), power efficiency (PE), and lifetime LT97 measured at a current density of 15 mA/cm².

TABLE 2
Device data

| | | Voltage | EQE | CE | PE | LT97 |
|---|---|---|---|---|---|---|
| Device No. | CIE (x, y) | (V) | (%) | (cd/A) | (lm/W) | (h) |
| Example 1 | (0.672, 0.324) | 3.95 | 20.83 | 20 | 16 | 448.3 |
| Example 2 | (0.684, 0.315) | 3.60 | 24.74 | 22 | 19 | 499.7 |
| Example 3 | (0.684, 0.315) | 3.36 | 25.24 | 22 | 21 | 1232.6 |
| Example 4 | (0.679, 0.319) | 4.07 | 23.74 | 23 | 18 | 1447.6 |
| Example 5 | (0.683, 0.316) | 3.49 | 26.01 | 25 | 22 | 964.3 |
| Example 6 | (0.679, 0.319) | 4.08 | 23.81 | 23 | 18 | 1504.2 |
| Example 7 | (0.683, 0.316) | 3.54 | 26.09 | 25 | 22 | 1221.4 |
| Comparative | (0.668, 0.322) | 8.31 | 5.62 | 6 | 2 | 2.2 |
| Example 1 | | | | | | |

Discussion: As can be seen from Table 2, devices in Examples 1 to 7, which included the particular combination of the first compound and the first metal complex selected in the present disclosure, had redder colors, lower voltages, higher efficiencies, and longer lifetimes than the device in Comparative Example 1. In the prior art, Compound CBP is usually chosen to be used as the host material and cooperated with the quinolinyl dibenzofuran-Ir light-emitting material. Obviously, the performance of the preceding material combination in the device performance is far from the performance of the new material combination disclosed in the present disclosure. The special combination of the specific host material disclosed in the present disclosure and the quinolinyl dibenzofuran-Ir light-emitting material has an excellent performance in key parameters such as color, voltage, efficiency, and lifetime, and the performance of such a combination on the related device data is far superior to the performance of the emissive layer material combination used in the prior art. The present disclosure provides an emissive layer material combination that has excellent performance and deep red emitted color for the industry.

It is to be understood that various embodiments described herein are merely illustrated and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limitative.

What is claimed is:

1. An electroluminescent device, comprising:
an anode,
a cathode, and
an organic layer disposed between the anode and the cathode, wherein the organic layer comprises a first metal complex and a first compound;
wherein
the first metal complex comprises a ligand Lₐ coordinated with a metal, and the metal is selected from metals having a relative atomic mass greater than 40; Lₐ has a structure represented by Formula 1: 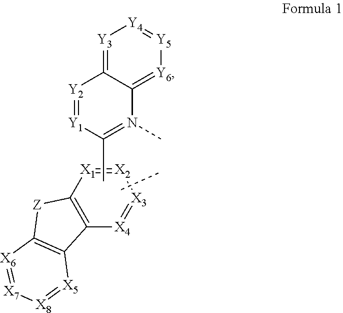
wherein X₁ to X₈ are, at each occurrence identically or differently, selected from C, CRₓ or N;
Y₁ to Y₆ are, at each occurrence identically or differently, selected from CR_{y1}, CR_{y2} or N; the R_{y2} has a structure of -L₁-SiRₛ₁Rₛ₂Rₛ₃;
Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y1}, Rₛ₁, Rₛ₂, Rₛ₃ can be optionally joined to form a ring;
Z is selected from O, S or Se;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof; and
wherein
the first compound has a structure represented by Formula 2: 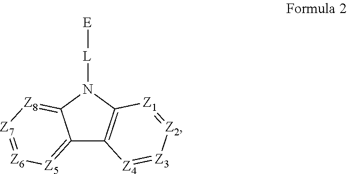
wherein Z₁ and Z₈ are, at each occurrence identically or differently, selected from CR_{z1} or N;
Z₂, Z₃, Z₆, and Z₇ are, at each occurrence identically or differently, selected from CR_{z2} or N;
Z₄ and Z₅ are, at each occurrence identically or differently, selected from CR_{z3} or N;
E has a structure represented by Formula 3-1 or Formula 3-2: 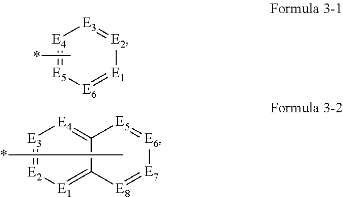
in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;
* represents a position where E is joined to L;
L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;
R_{z2}, R_{z3}, and Rₑ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{z1}, R_{z2}, R_{z3} can be optionally joined to form a ring;
adjacent substituents Rₑ can be optionally joined to form a ring.

2. The electroluminescent device according to claim 1, wherein in Formula 1, Y₁ to Y₆ are, at each occurrence identically or differently, selected from CR_{y1}, CR_{y2} or N, and when a plurality of substituents R_{y1} are present, adjacent substituents R_{y1} are not joined to form a ring.

3. The electroluminescent device according to claim 1, wherein in Formula 1, Y₁ to Y₆ are, at each occurrence identically or differently, selected from CR_{y1}, CR_{y2} or N, at least one of Y₁ to Y₆ is selected from CR_{y2}, and the R_{ye} has a structure of -L₁-SiRₛ₁Rₛ₂Rₛ₃;
Rₛ₁, Rₛ₂ and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
adjacent substituents Rₛ₁, Rₛ₂, Rₛ₃ can be optionally joined to form a ring.

4. The electroluminescent device according to claim 1, wherein two adjacent ones of X₁ to X₄ are C, and one of the two C is joined to the metal by a carbon-metal bond, the one of X₁ to X₄ at the ortho position of the carbon-metal bond is selected from CRₓ, and Rₓ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or combinations thereof.

5. The electroluminescent device according to claim 1, wherein at least one of X₁ to X₈ and Y₁ to Y₆ is selected from CRₓ or CR_{y1}, and Rₓ and R_{y1} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least two or three of X₁ to X₈ and Y₁ to Y₆ are selected from CRₓ and/or CR_{y1}, and the Rₓ and R_{y1} are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

6. The electroluminescent device according to claim 1, wherein the first metal complex has a structure of M(Lₐ)ₘ(L_{b})ₙ(L_{c})_{q};
wherein the metal M is selected from Ir, Rh, Re, Os, Pt, Au or Cu;
Lₐ, L_{b}, and L_{c} are a first ligand, a second ligand, and a third ligand of the complex, respectively; m is selected from 1, 2 or 3, n is selected from 0, 1 or 2, q is selected from 0, 1 or 2, and m+n+q is equal to the oxidation state of the metal M; when m is greater than 1, the plurality of Lₐ may be identical or different; when n is 2, two L_{b} may be identical or different; when q is 2, two L_{c} may be identical or different;
Lₐ, L_{b}, and L_{c} can be optionally joined to form a multi-dentate ligand;
L_{b} and L_{c} are, at each occurrence identically or differently, selected from the group consisting of the following structures: 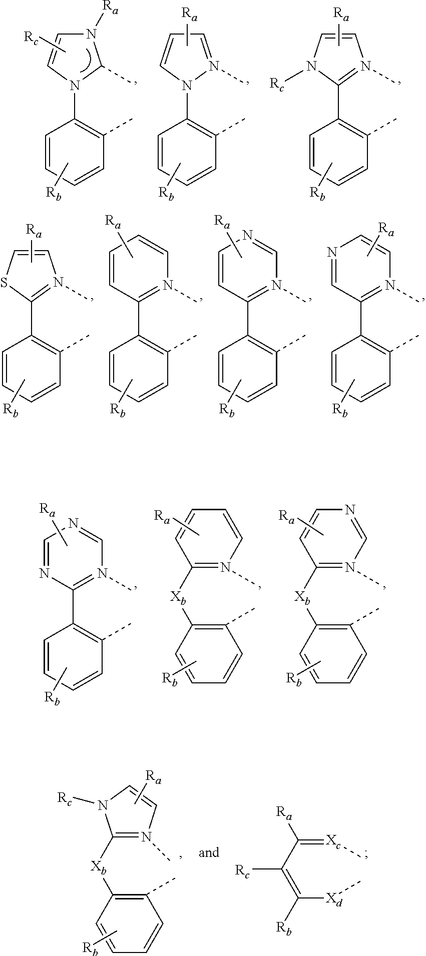
wherein Rₐ, R_{b}, and R_{c} represent, at each occurrence identically or differently, mono-substitution, multiple substitutions or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, Rₑ, R_{N1}, R_{N2}, R_{C1}, and R_{C2} can be optionally joined to form a ring.

7. The electroluminescent device according to claim 1, wherein the first metal complex has a structure of M(Lₐ)ₘ(L_{b})ₙ(L_{c})_{q};
wherein the metal M is selected from Ir, Rh, Re, Os, Pt, Au or Cu;
Lₐ, L_{b}, and L_{c} are a first ligand, a second ligand, and a third ligand of the metal complex, respectively; m is selected from 1, 2 or 3, n is selected from 0, 1 or 2, q is selected from 0, 1 or 2, and m+n+q is equal to the oxidation state of the metal M; when m is greater than 1, the plurality of Lₐ may be identical or different; when n is 2, two L_{b} may be identical or different; when q is 2, two L_{c} may be identical or different; Lₐ, L_{b}, and L_{c} can be optionally joined to form a multi-dentate ligand;
L_{b} is, at each occurrence identically or differently, selected from the following structure: 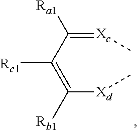
wherein X_{c} and X_{d} are, at each occurrence identically or differently, selected from the group consisting of: O, S, Se and NR_{N2};
Rₐ₁, R_{b1}, R_{c1}, and R_{N2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ₁, R_{b1}, R_{c1} can be optionally joined to form a ring;
L_{c} is, at each occurrence identically or differently, selected from the group consisting of the following structures: 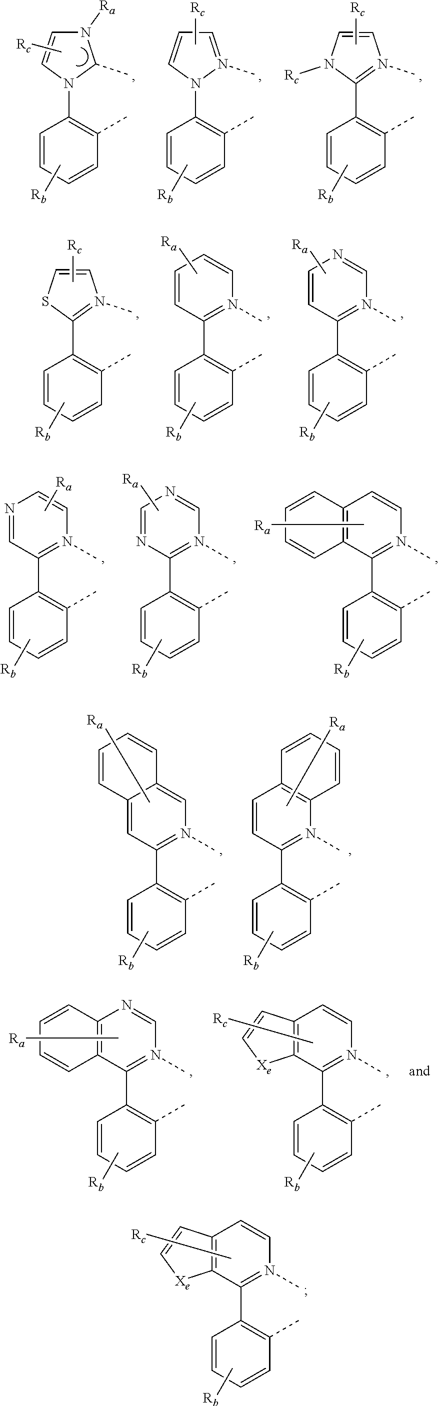
wherein Rₐ, R_{b}, and Rₑ represent, at each occurrence identically or differently, mono-substitution, multiple substitutions or non-substitution;
Xₑ is, at each occurrence identically or differently, selected from the group consisting of: O, S, Se, and NR_{N3};
Rₐ, R_{b}, R_{c}, and R_{N3} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{b}, R_{c} can be optionally joined to form a ring.

8. The electroluminescent device according to claim 1, wherein Lₐ has a structure represented by Formula 4: 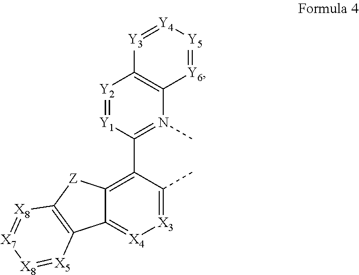
wherein
Z is selected from O or S;
X₃ to X₈ are, at each occurrence identically or differently, selected from CRₓ or N;
Y₁ to Y₆ are, at each occurrence identically or differently, selected from CR_{y1}, CR_{y2} or N;
wherein at least one of Y₁ to Y₆ is selected from CR_{y2}, and the R_{y2} has a structure of -L₁-SiRₛ₁Rₛ₂Rₛ₃;
Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
adjacent substituents Rₓ, Rₛ₁, Rₛ₂, Rₛ₃ can be optionally joined to form a ring.

9. The electroluminescent device according to claim 1, wherein the first metal complex has a structure represented by Formula 5: 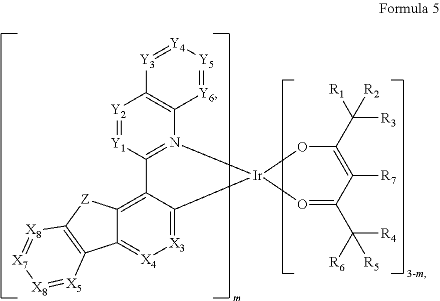
wherein
m is 1 or 2;
Z is, at each occurrence identically or differently, selected from O or S; preferably, Z is O;
X₃ to X₈ are, at each occurrence identically or differently, selected from CRₓ or N;
Y₁ to Y₆ are, at each occurrence identically or differently, selected from CR_{y1}, CR_{y2} or N;
wherein at least one of Y₁ to Y₆ is selected from CR_{y2}, and the R_{ye} has a structure of -L₁-SiRₛ₁Rₛ₂Rₛ₃;
Rₓ, R_{y1}, Rₛ₁, Rₛ₂, Rₛ₃, R₁, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
adjacent substituents Rₓ, Rₛ₁, Rₛ₂, Rₛ₃ can be optionally joined to form a ring;
adjacent substituents R₁, R₂, R₃, R₄, R₅, R₆, R₇ can be optionally joined to form a ring;
preferably, at least one or two of R₁ to R₃ are selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R₄ to R₆ is substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof;
more preferably, at least two of R₁ to R₃ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R₆ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

10. The electroluminescent device according to claim 1, wherein Y₁ and Y₂ are, at each occurrence identically or differently, selected from CR_{y1} or N; Y₃ to Y₆ are, at each occurrence identically or differently, selected from CR_{y1}, CR_{y2} or N, and at least one of Y₃ to Y₆ is selected from CR_{y2}, and the R_{ye} has a structure of -L₁-SiRₛ₁Rₛ₂Rₛ₃;
R_{y1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
adjacent substituents Rₛ₁, Rₛ₂, Rₛ₃ can be optionally joined to form a ring;
preferably, at least one of Y₃ to Y₆ is selected from CR_{y2}, and the R_{y2} has a structure of -L₁-SiRₛ₁Rₛ₂Rₛ₃;
Rₛ₁, Rₛ₂, and Rₛ₃ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, and combinations thereof.

11. The electroluminescent device according to claim 6, wherein Y₁ to Y₆ are each independently selected from CR_{y1} or CR_{y2}.

12. The electroluminescent device according to claim 6, wherein at least one of Y₁ to Y₆ is selected from N.

13. The electroluminescent device according to claim 6, wherein Z is O.

14. The electroluminescent device according to claim 8, wherein at least one of X₃ to X₈ is selected from N;
preferably, one of X₃ to X₈ is selected from N;
more preferably, X₈ is N.

15. The electroluminescent device according to claim 8, wherein X₃ to X₈ are each independently selected from CRₓ;
preferably, the Rₓ is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, a cyano group or combinations thereof;
more preferably, the Rₓ is selected from the group consisting of: hydrogen, deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, and combinations thereof.

16. The electroluminescent device according to claim 8, wherein X₃ is selected from CRₓ, and the Rₓ is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted arylsilyl having 6 to 20 carbon atoms, a cyano group or combinations thereof;
preferably, the Rₓ is selected from deuterium, halogen, substituted or unsubstituted alkyl having 1 to 20 carbon atoms, substituted or unsubstituted cycloalkyl having 3 to 20 ring carbon atoms, a cyano group or combinations thereof;
more preferably, the Rₓ is selected from methyl or deuterated methyl.

17. The electroluminescent device according to claim 1, wherein Y₂ is selected from CR_{y1} or CR_{y2}; the R_{y1} is selected from the group consisting of: substituted or unsubstituted alkyl having 1 to 20 carbon atoms, substituted or unsubstituted cycloalkyl having 3 to 20 ring carbon atoms, and combinations thereof; the R_{y2} has a structure of -L₁-SiRₛ₁Rₛ₂Rₛ₃;
wherein Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
adjacent substituents Rₛ₁, Rₛ₂, Rₛ₃ can be optionally joined to form a ring.

18. The electroluminescent device according to claim 6, wherein Y₁ to Y₆ are each independently selected from CR_{y1} or CR_{y2}, at least one of Y₁ to Y₆ is selected from CR_{y2}, and the R_{y2} has a structure of -L₁-SiRₛ₁Rₛ₂Rₛ₃, wherein L₁ is selected from a single bond, Rₛ₁, Rₛ₂, and Rₛ₃ are each independently selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, and combinations thereof, and at least one or two of Rₛ₁, Rₛ₂, and Rₛ₃ are independently selected from substituted or unsubstituted alkyl having 1 to 20 carbon atoms, substituted or unsubstituted cycloalkyl having 3 to 20 ring carbon atoms or combinations thereof;
preferably, at least one of Y₂ or Y₄ is selected from CR_{y2};
more preferably, Y₂ or Y₄ is selected from CR_{y2}.

19. The electroluminescent device according to claim 18, wherein Rₛ₁, Rₛ₂, and Rₛ₃ are each independently selected from the group consisting of: methyl, ethyl, isopropyl, isobutyl, t-butyl, neopentyl, cyclopentyl, cyclopentylmethyl, cyclohexyl, norbornyl, adamantyl, trifluoromethyl, phenyl, and combinations thereof.

20. The electroluminescent device according to claim 1, wherein Lₐ is, at each occurrence identically or differently, selected from the group consisting of the following structures:

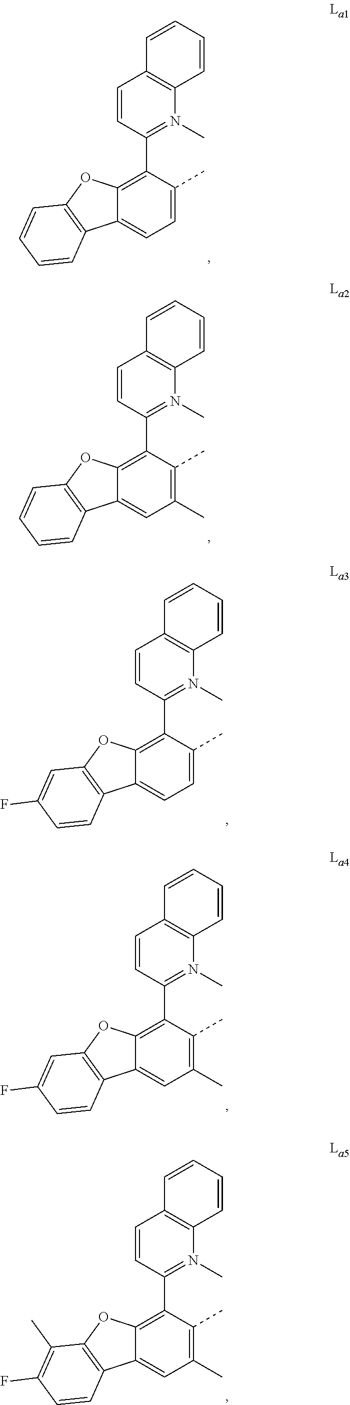

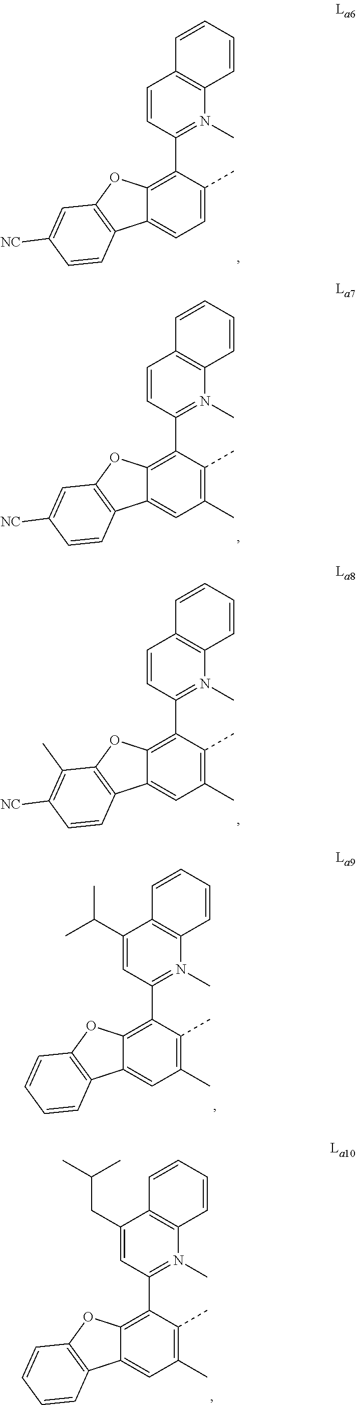

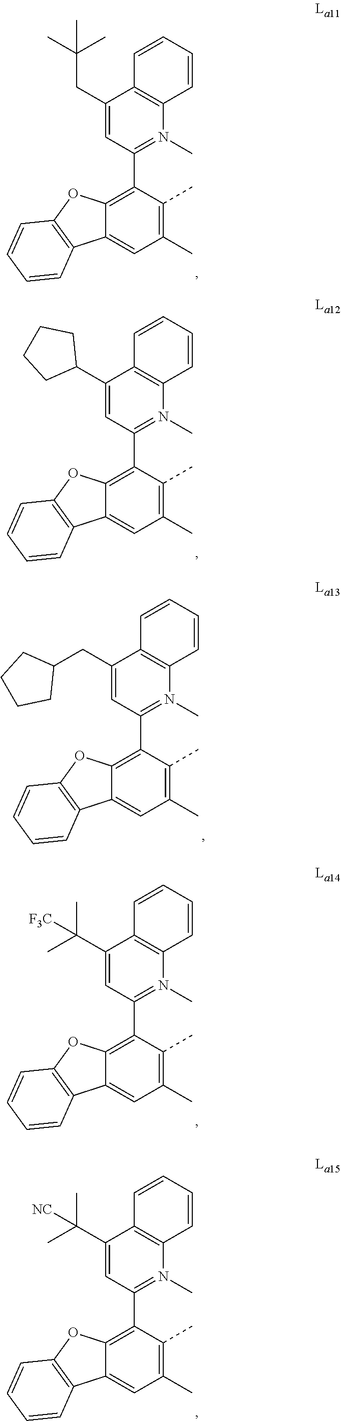

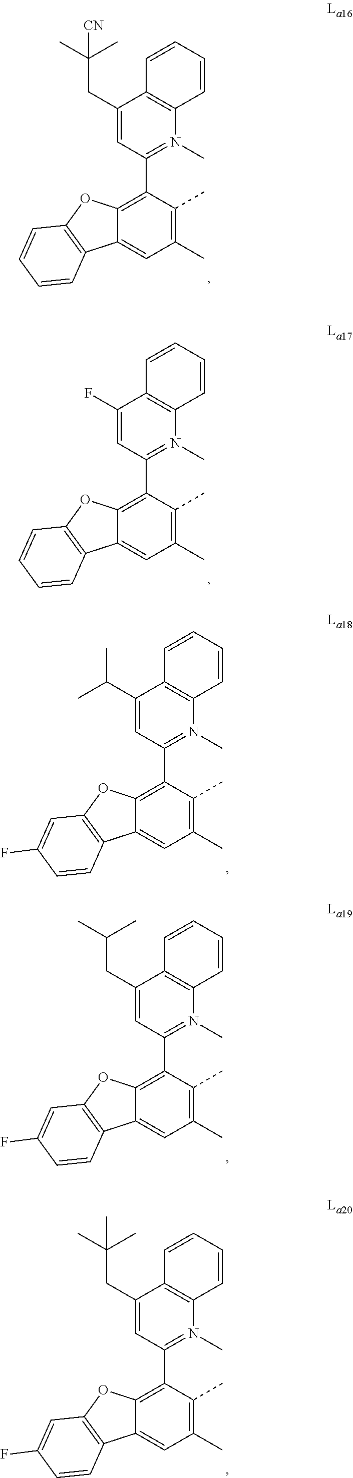

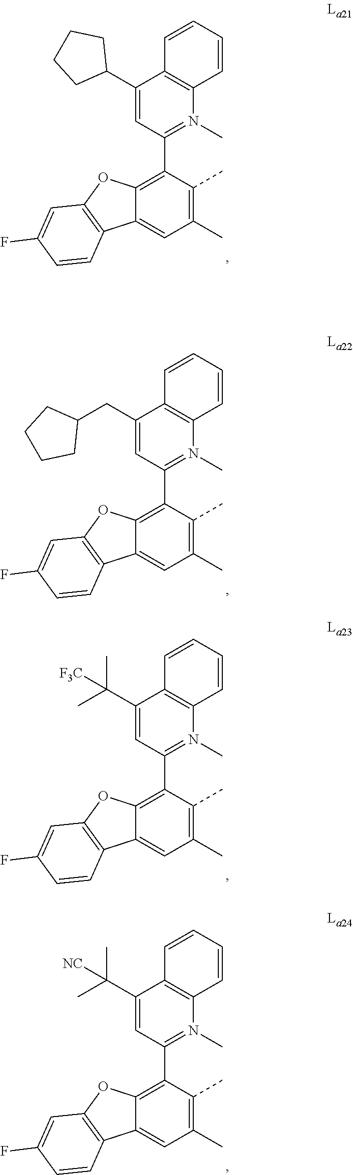

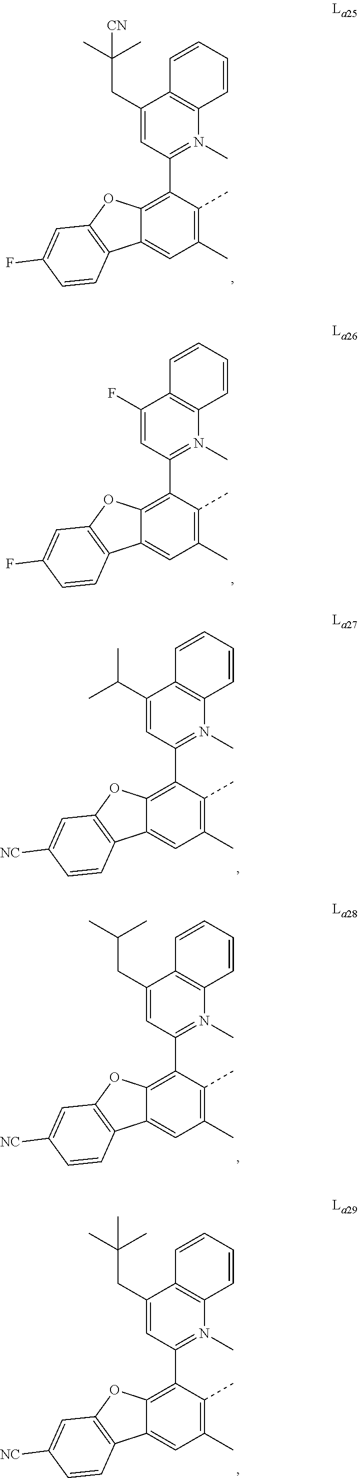

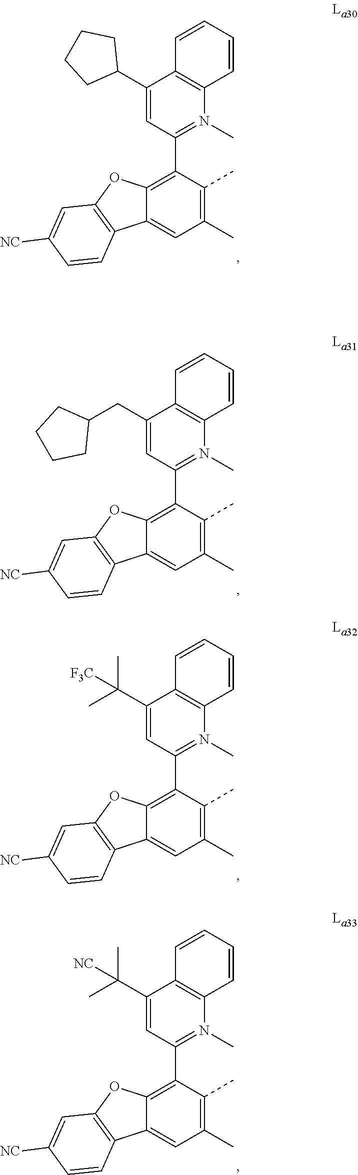

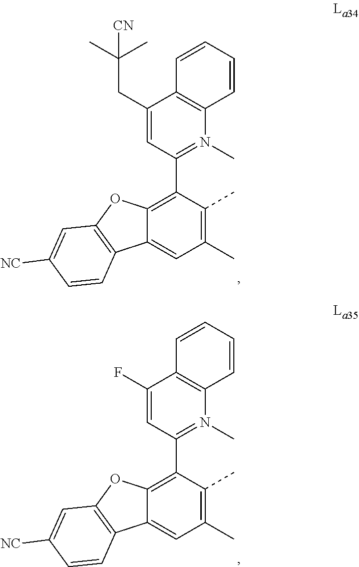

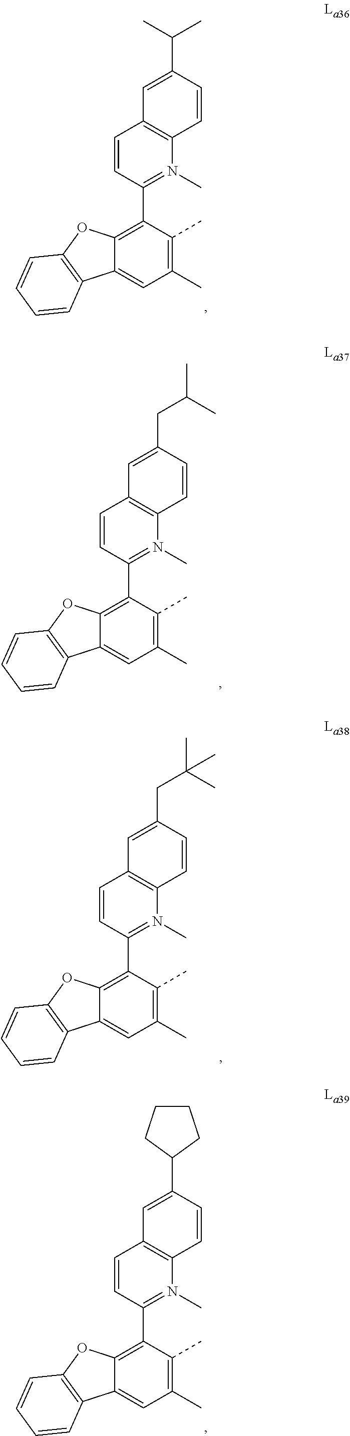

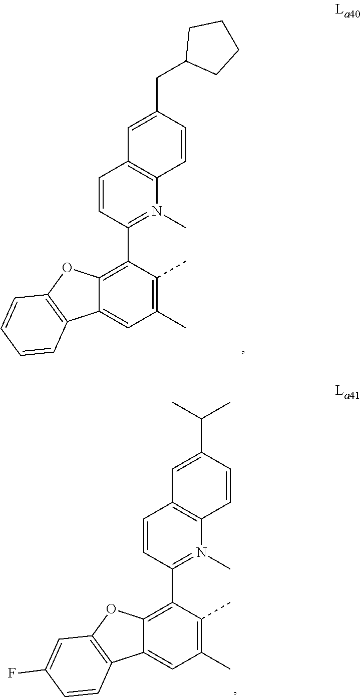

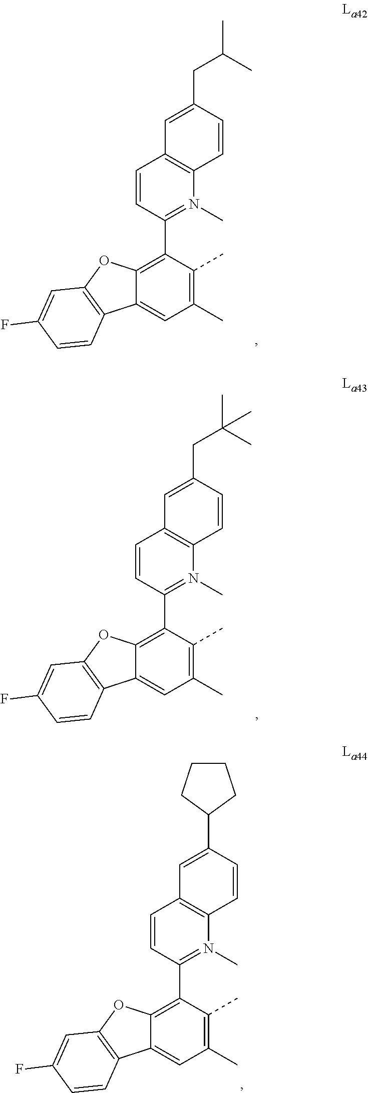

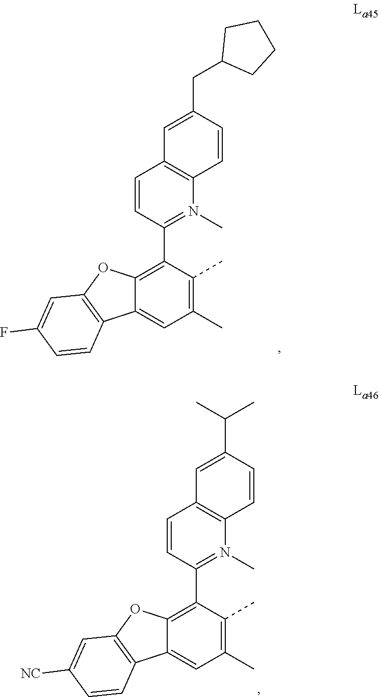

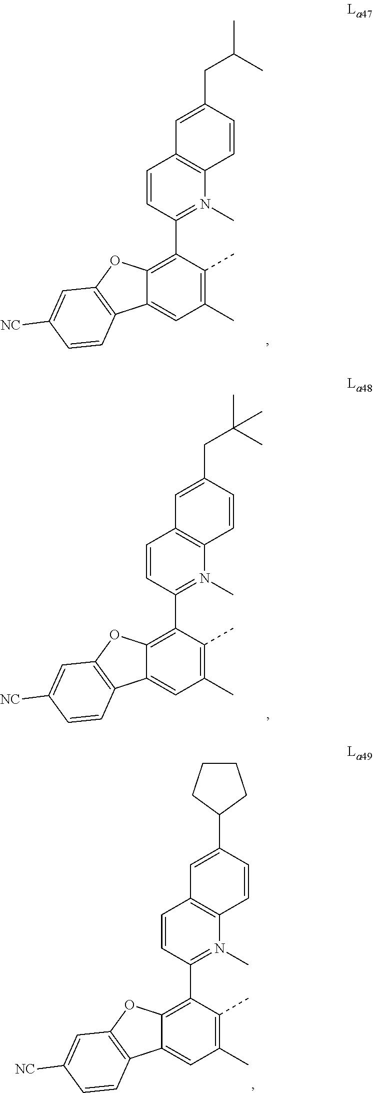

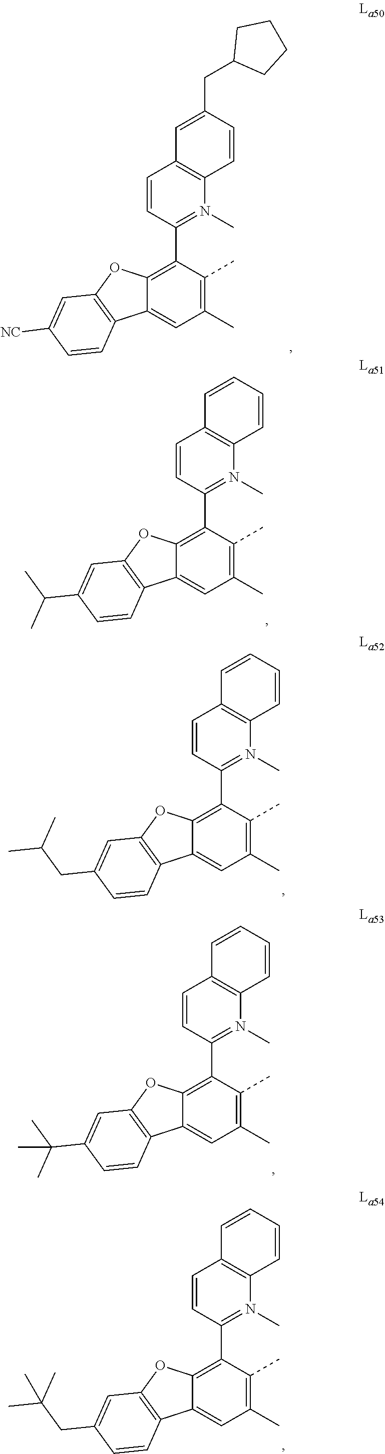

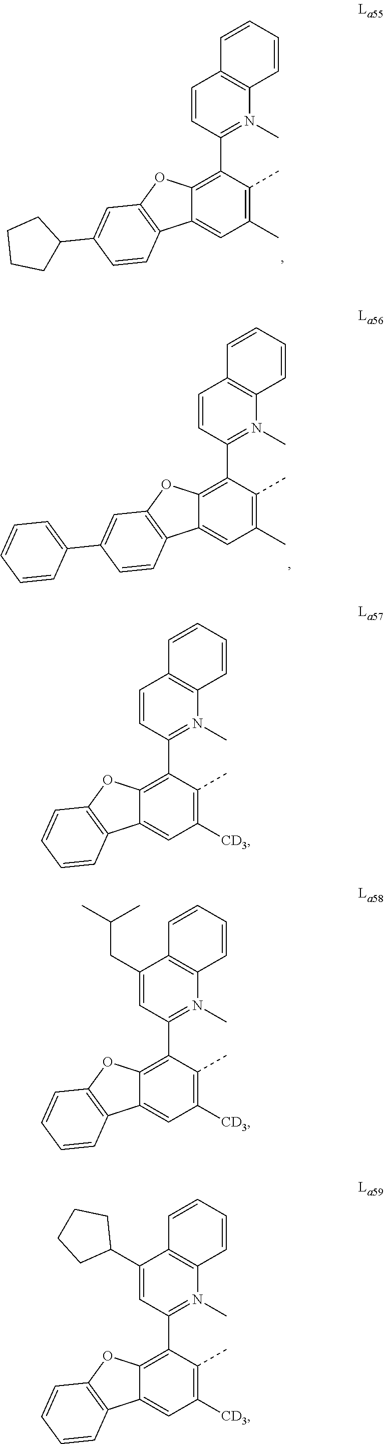

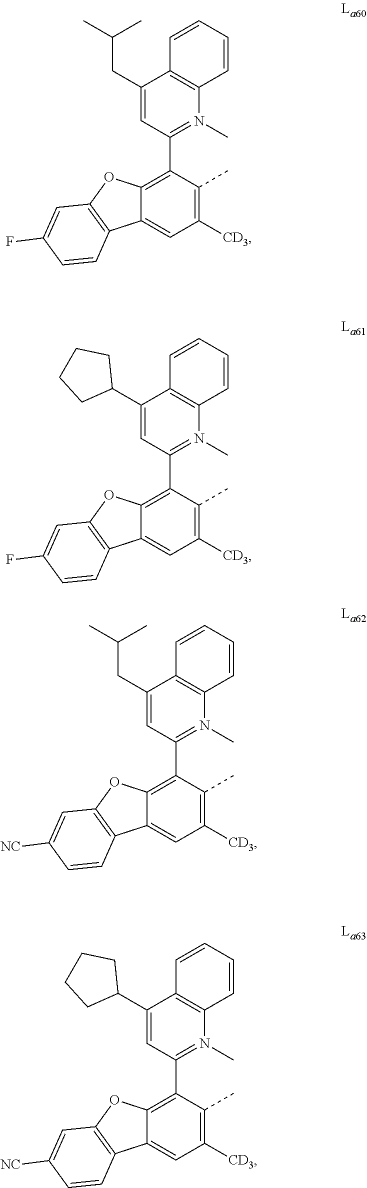

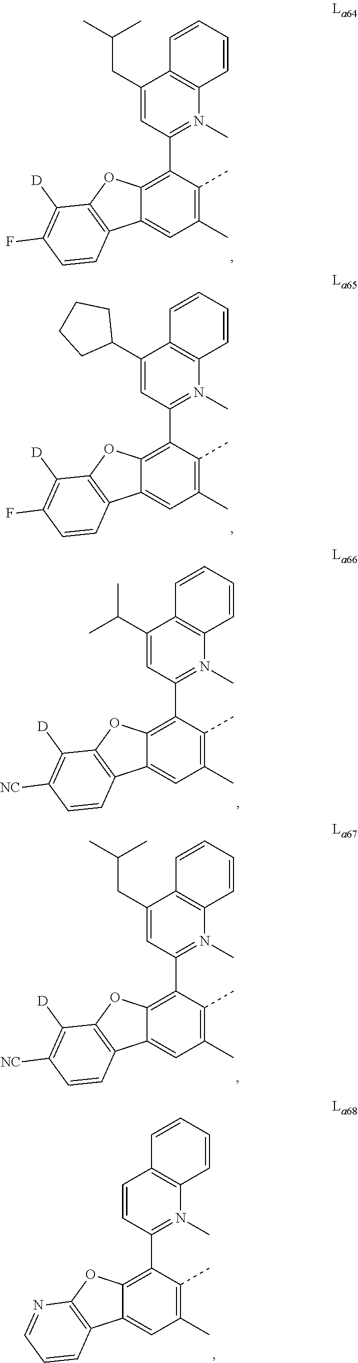

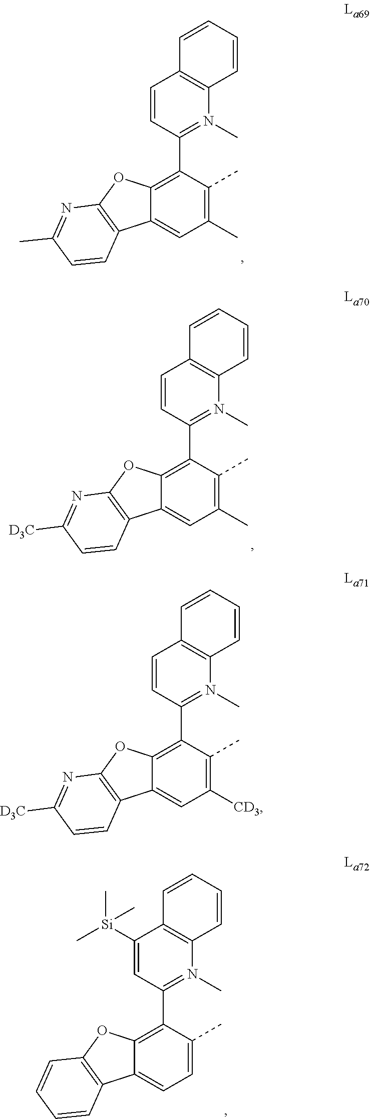

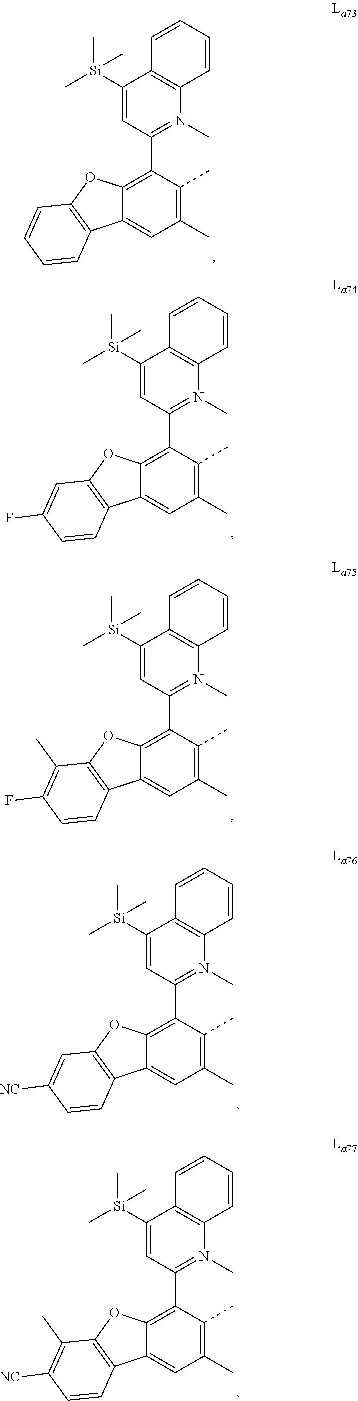

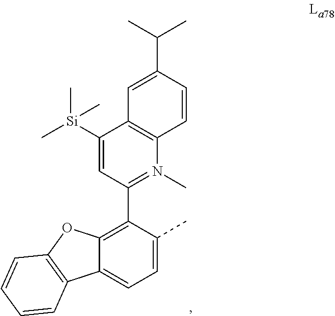

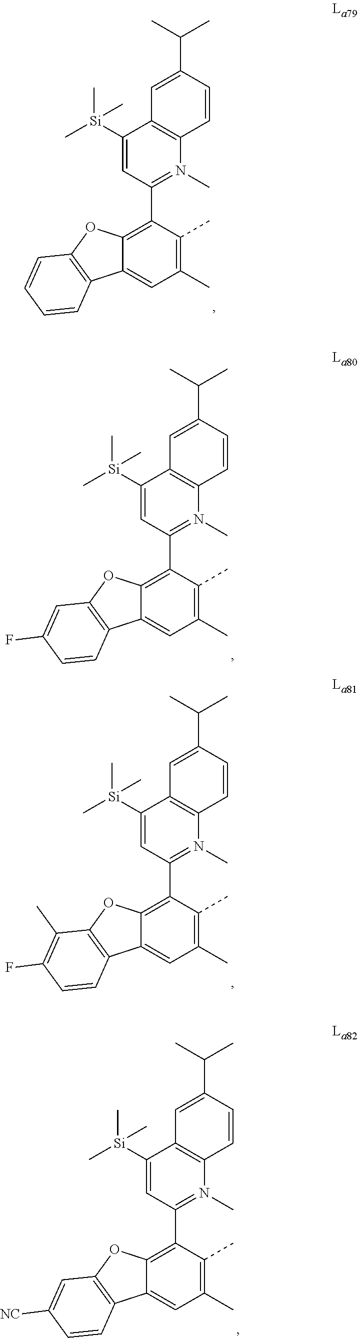

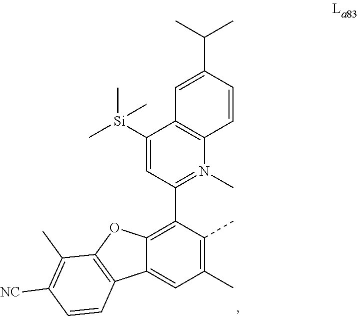

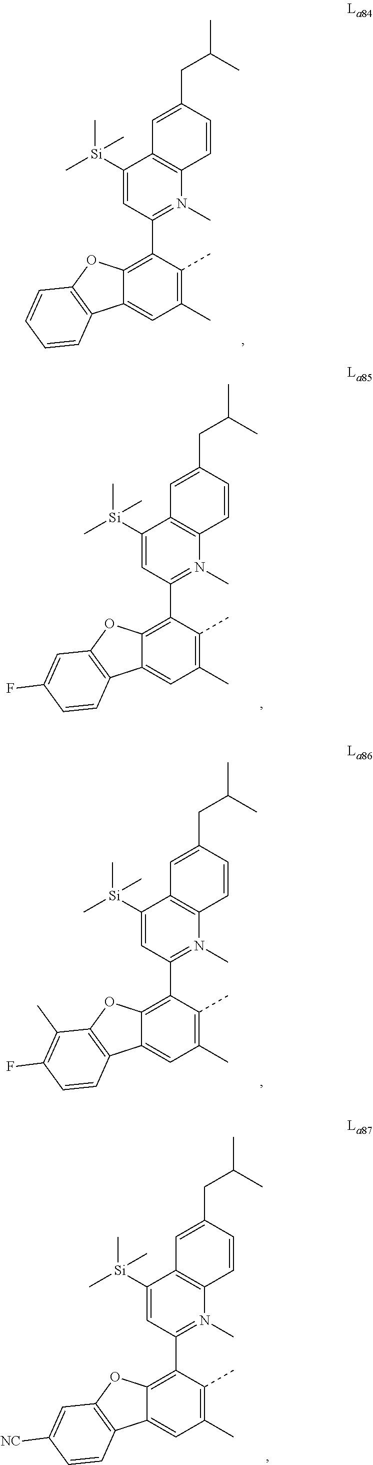

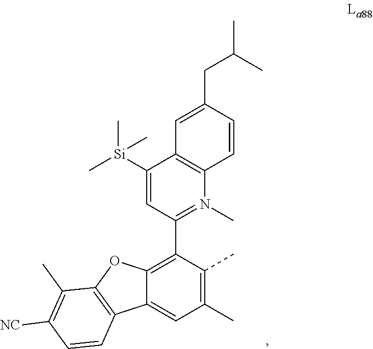

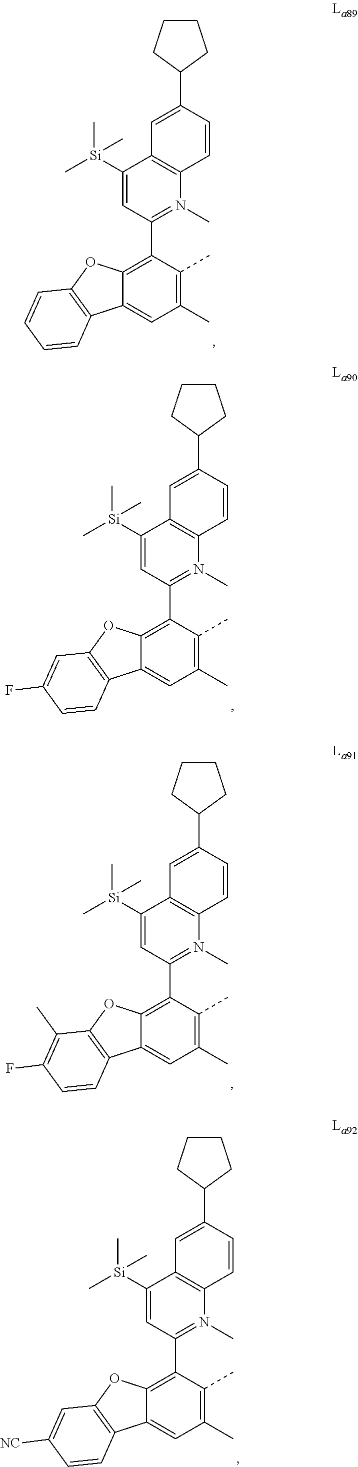

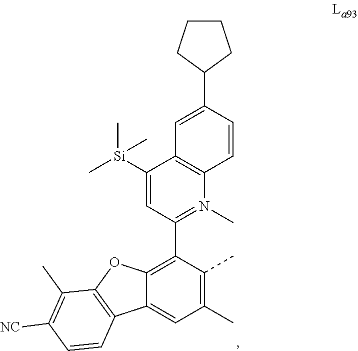

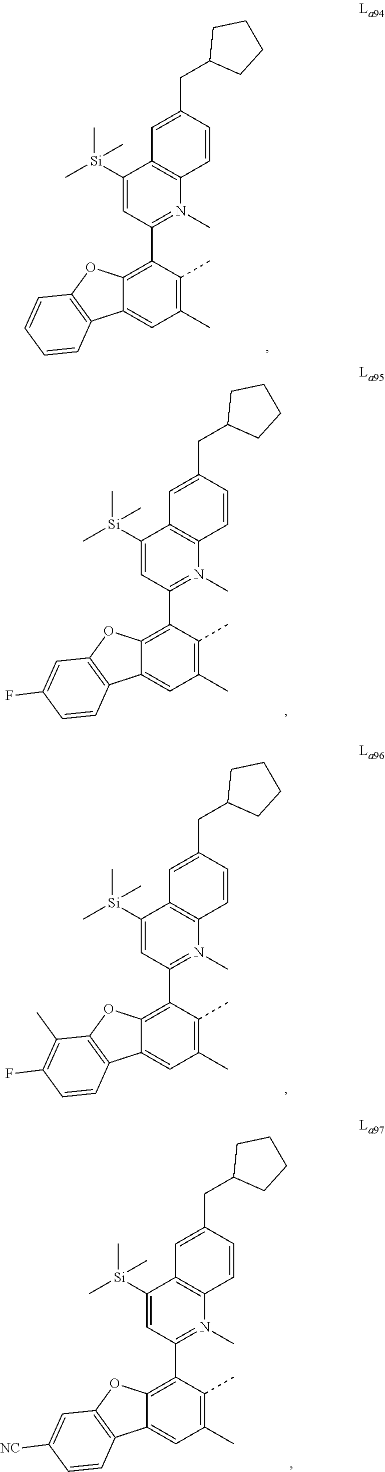

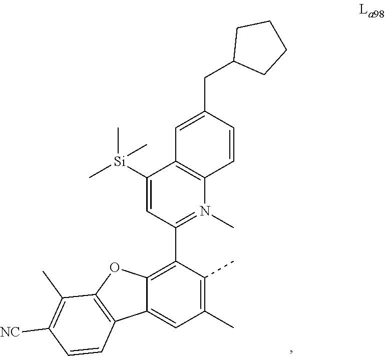

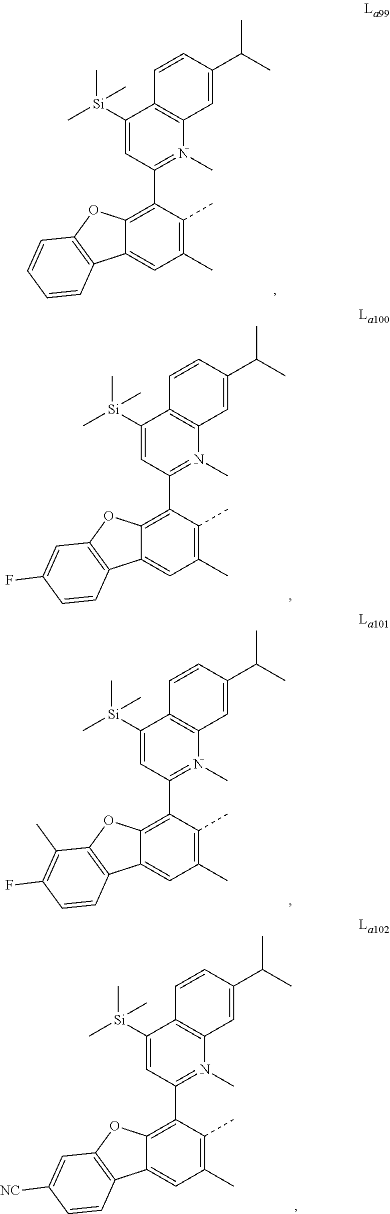

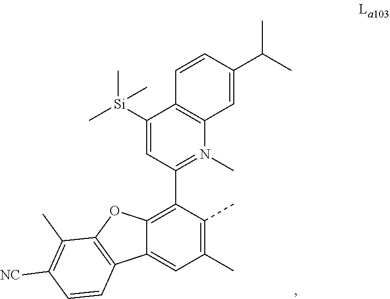

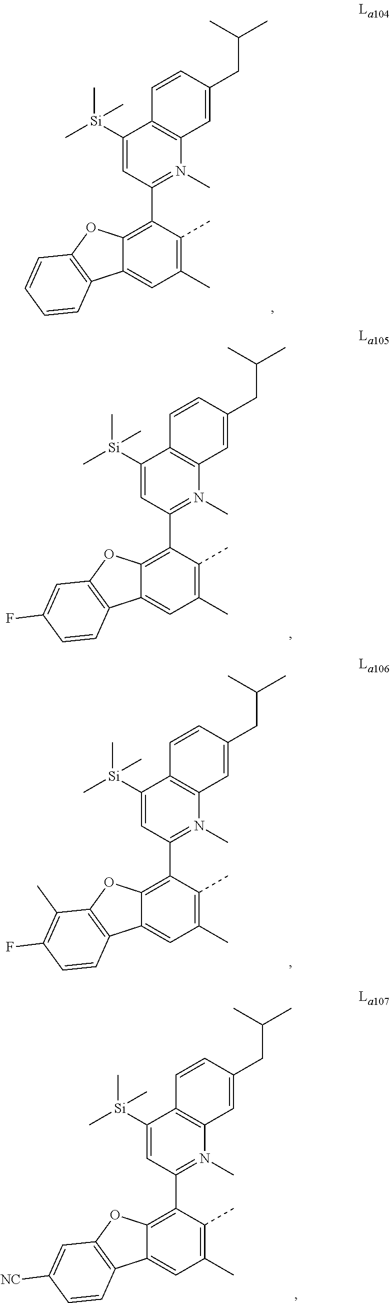

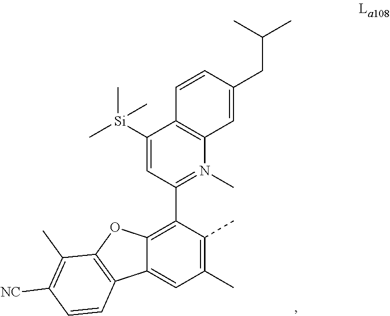

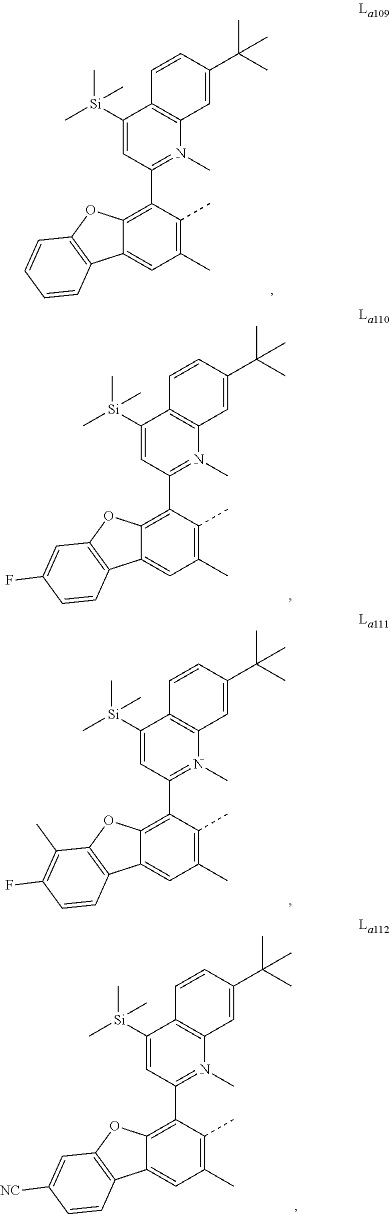

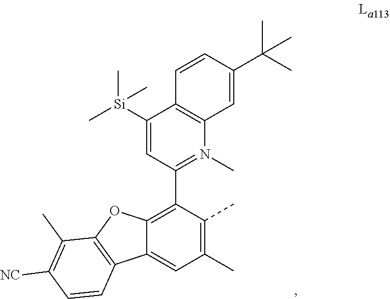

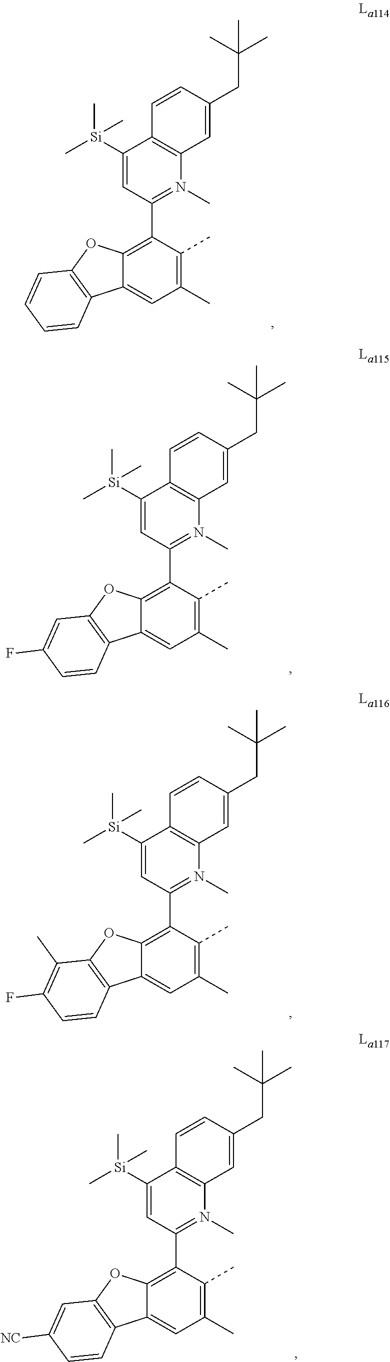

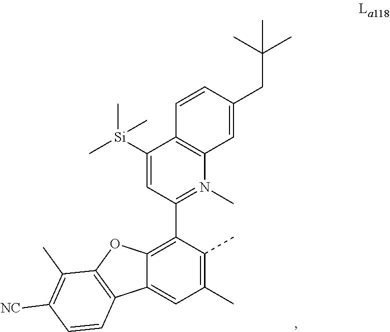

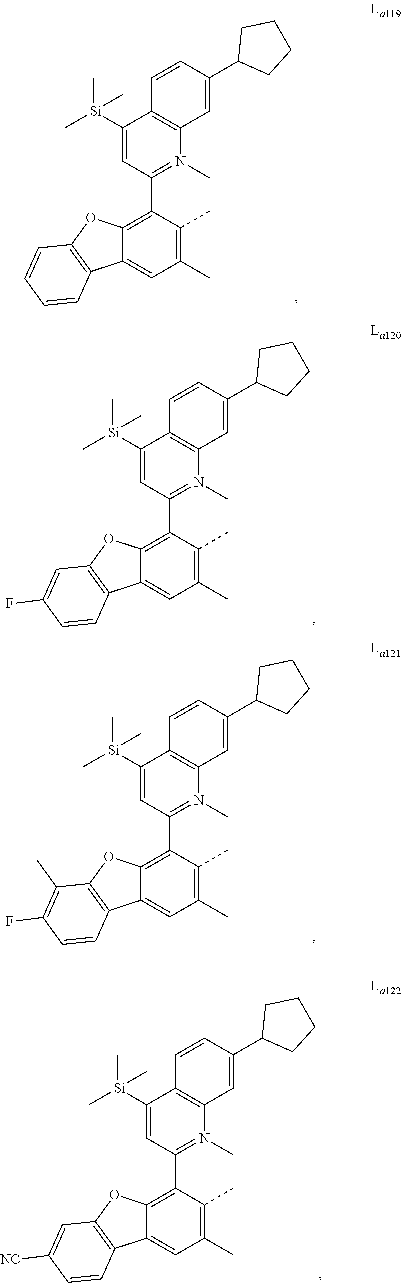

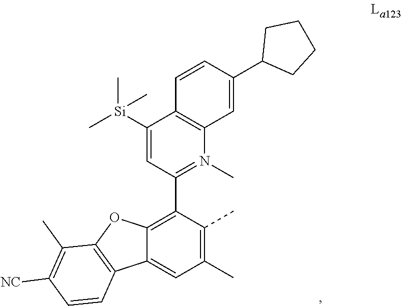

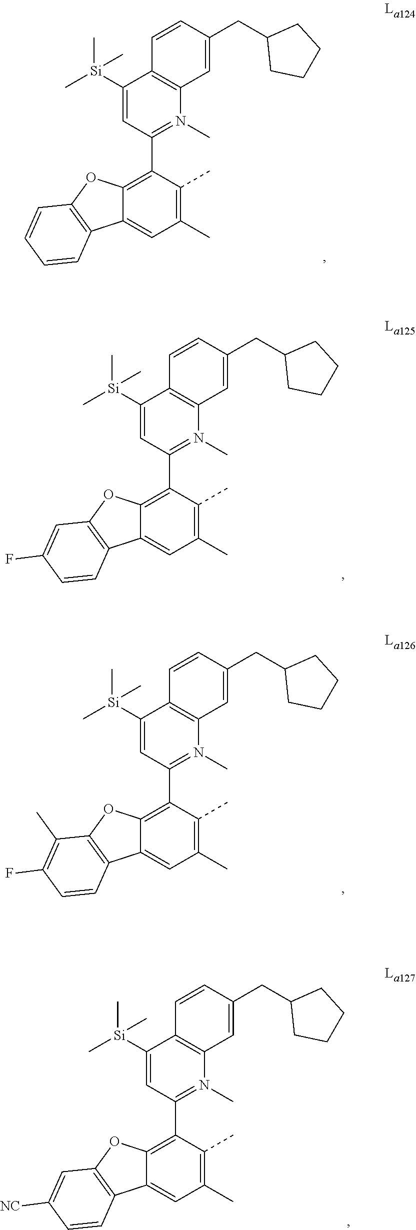

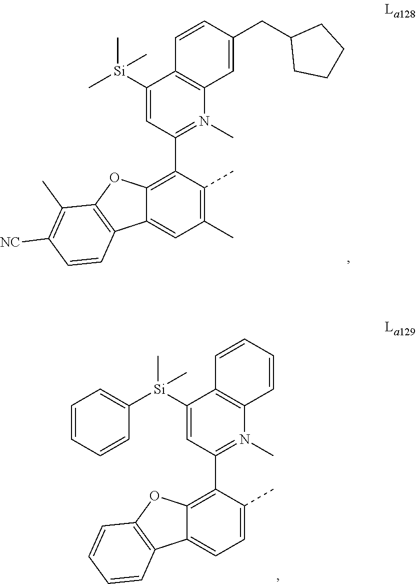

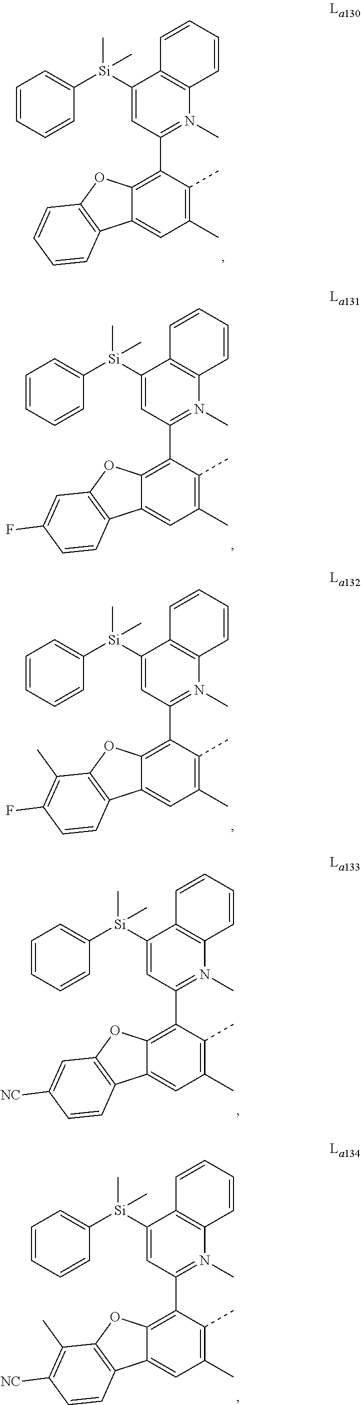

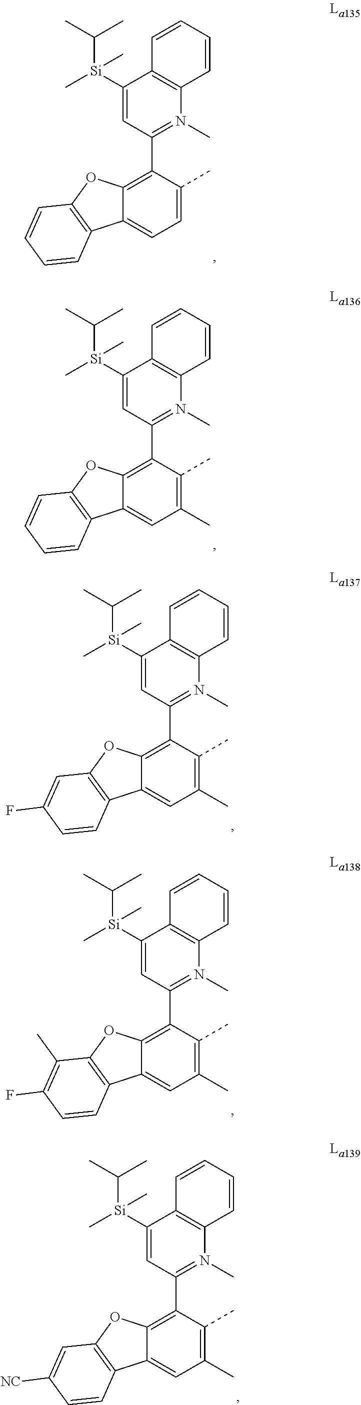

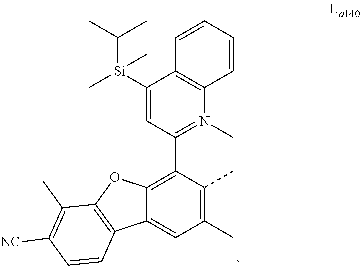

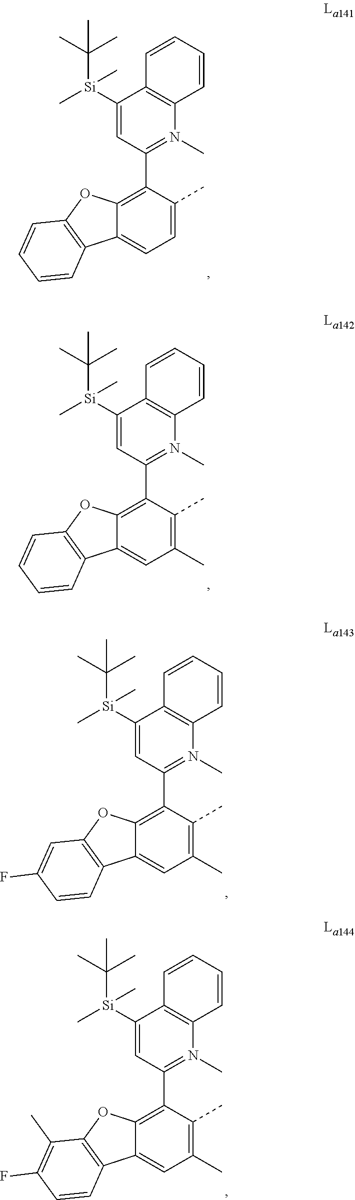

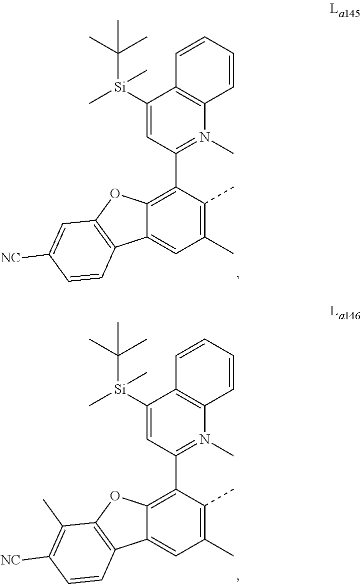

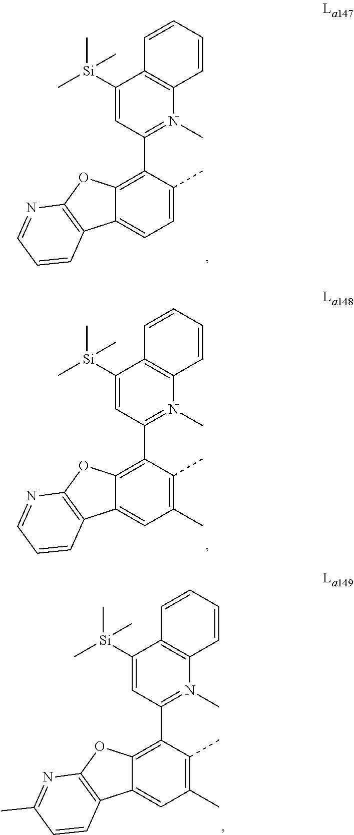

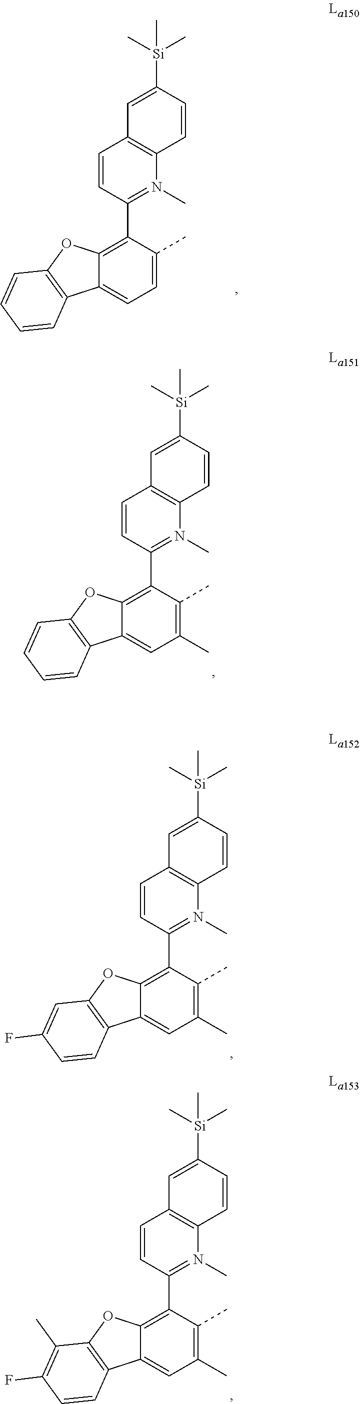

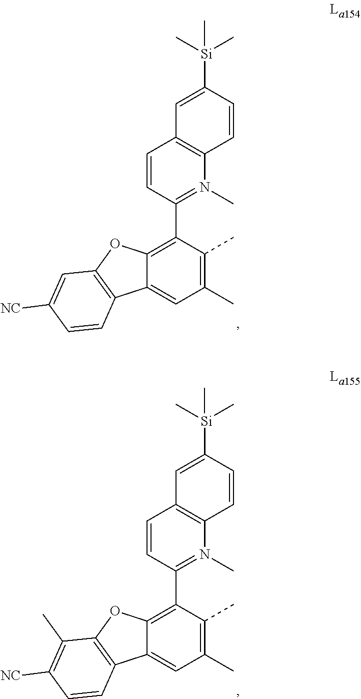

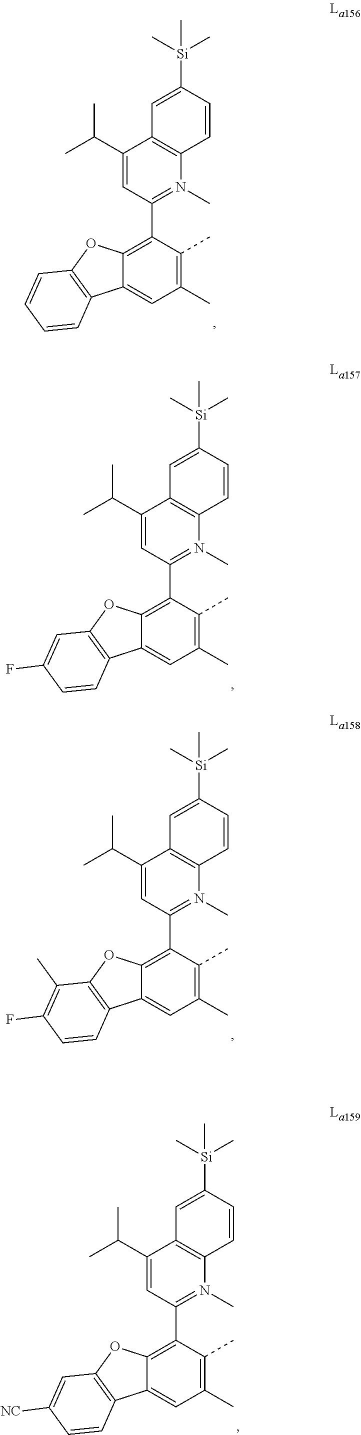

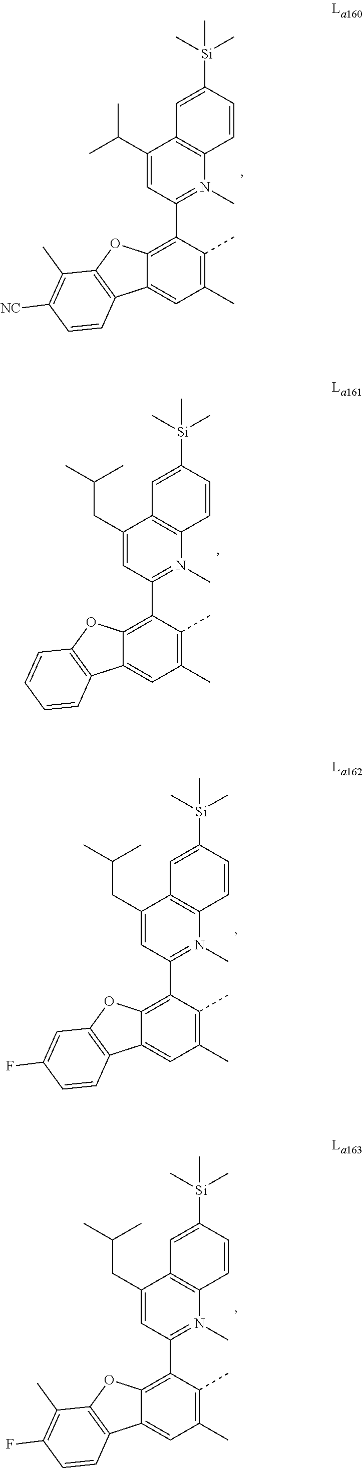

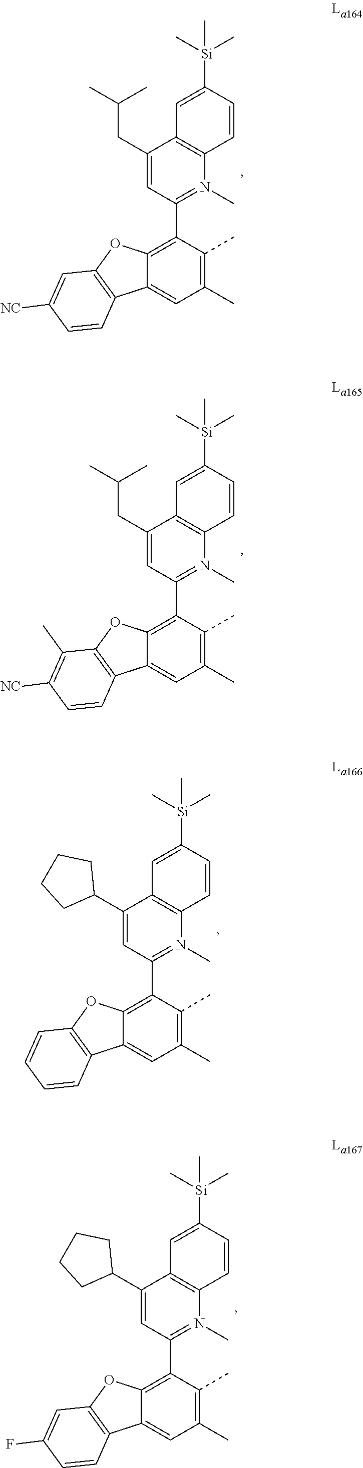

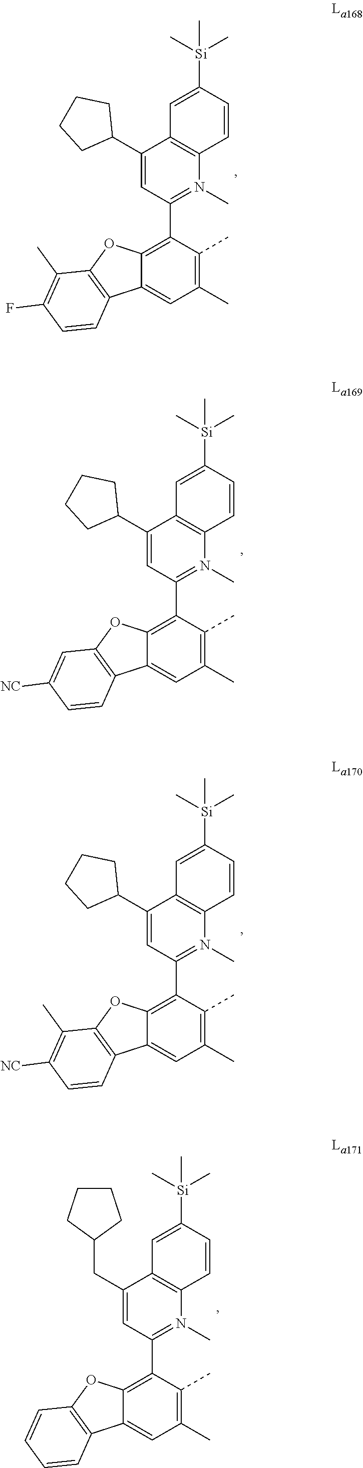

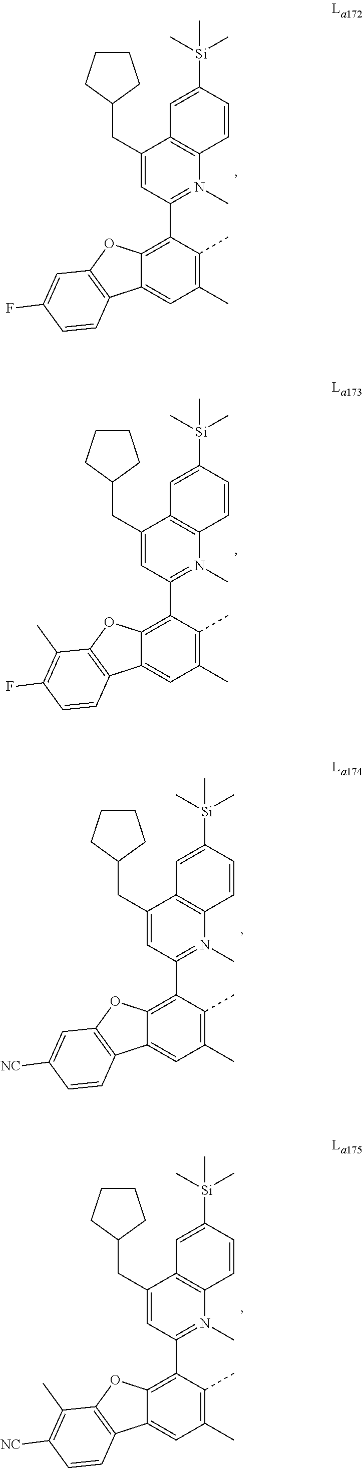

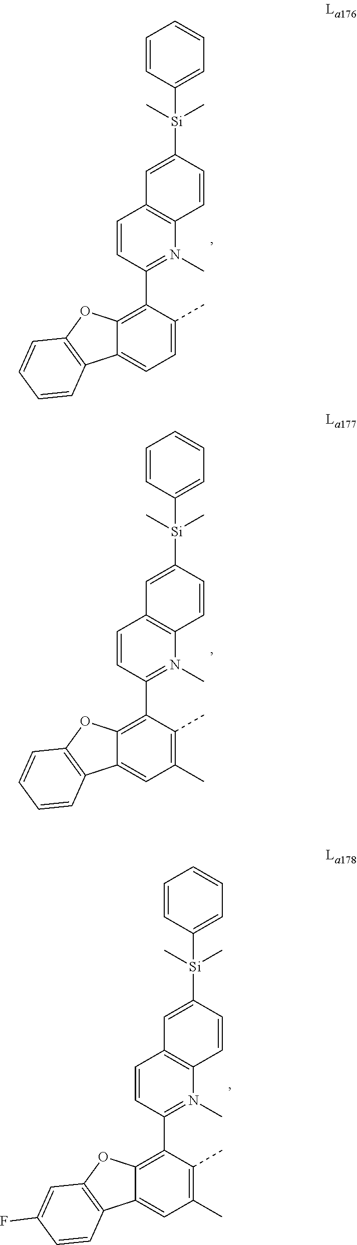

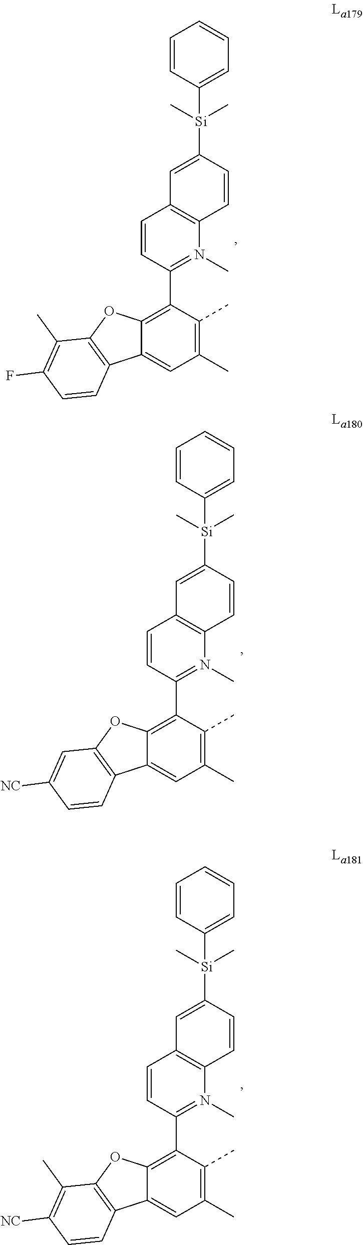

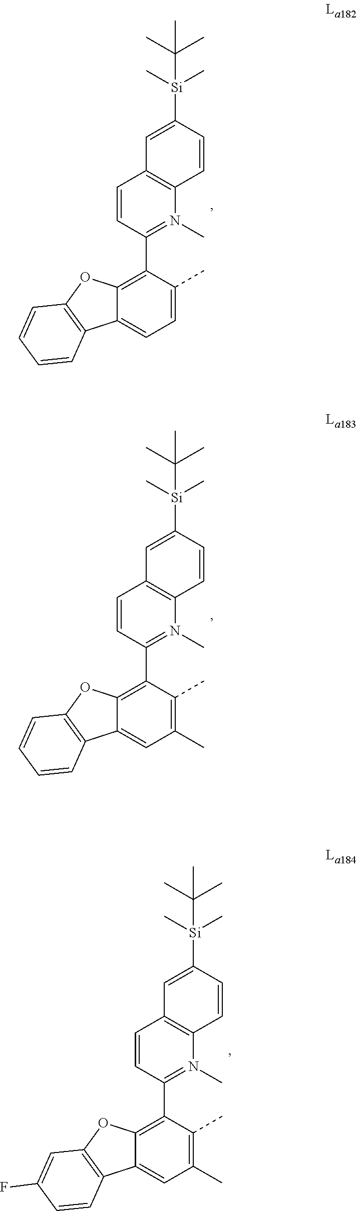

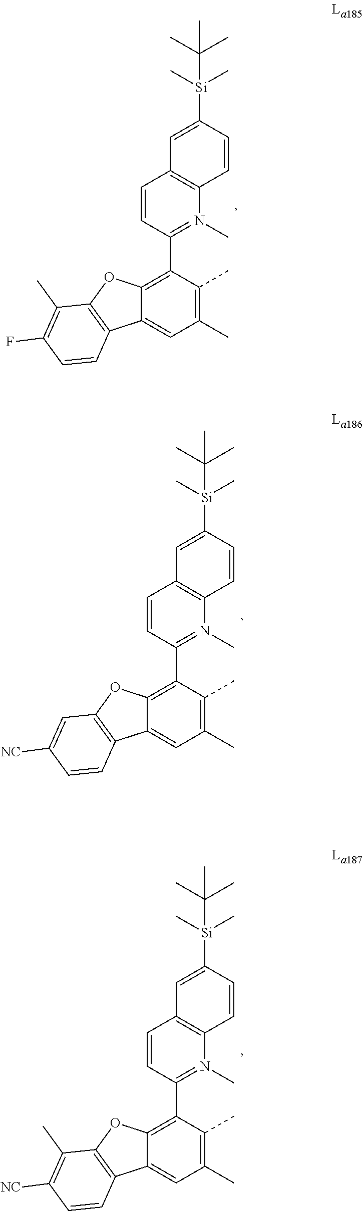

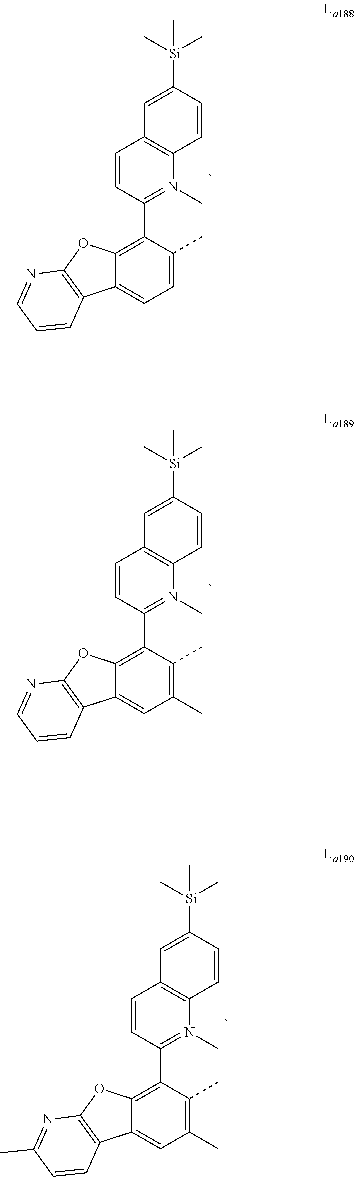

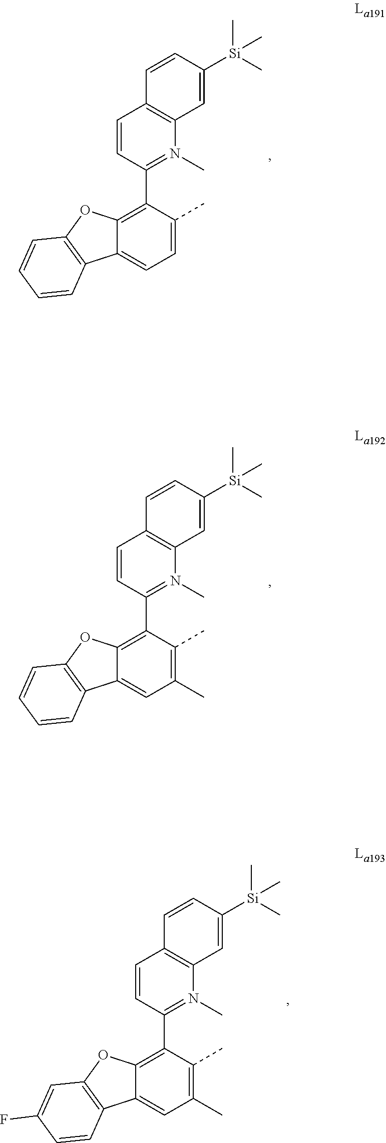

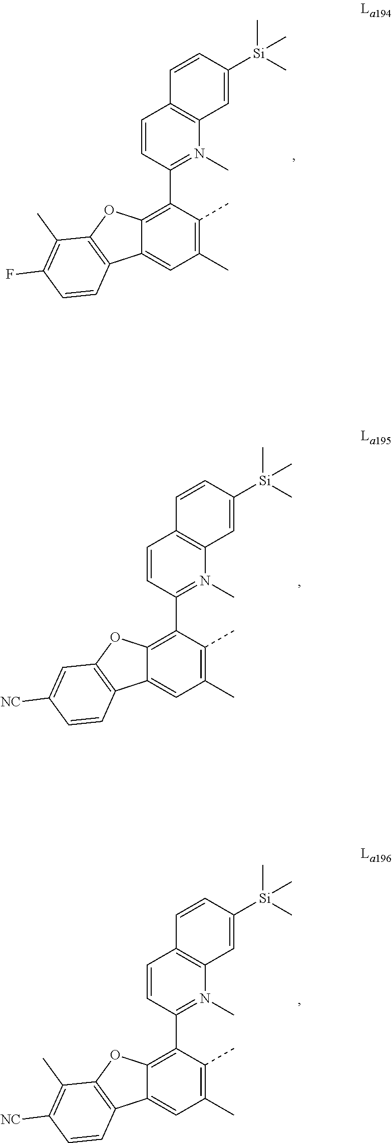

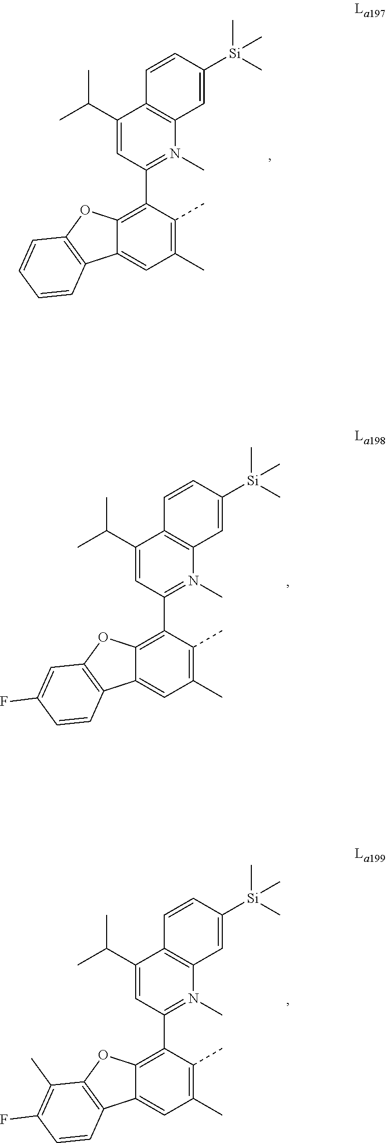

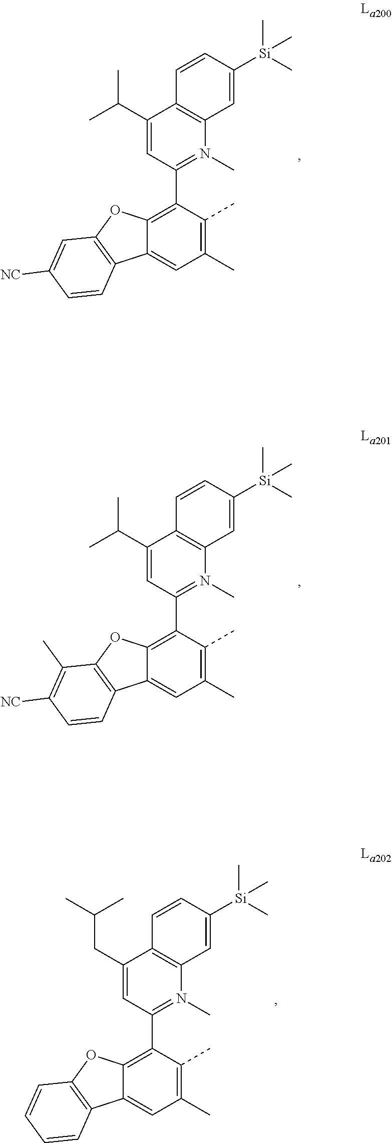

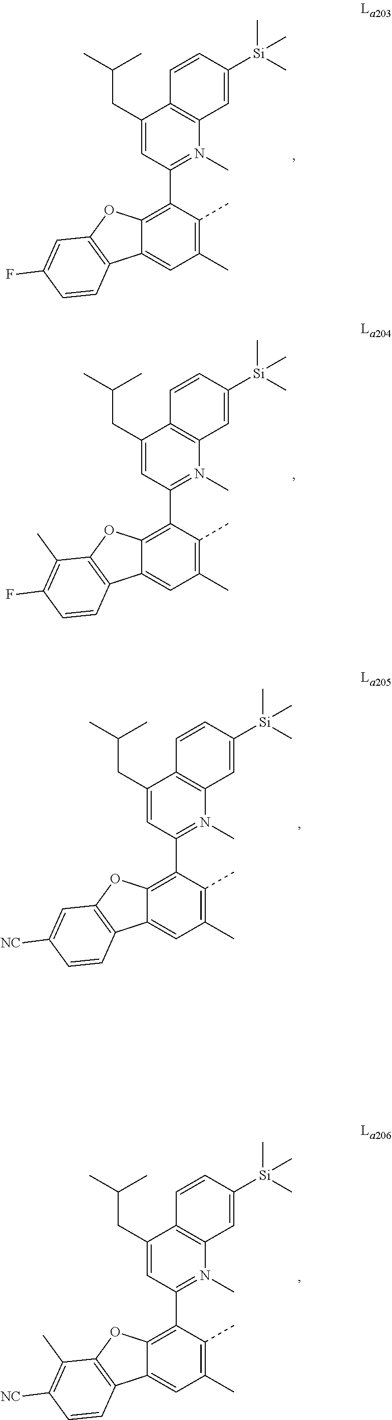

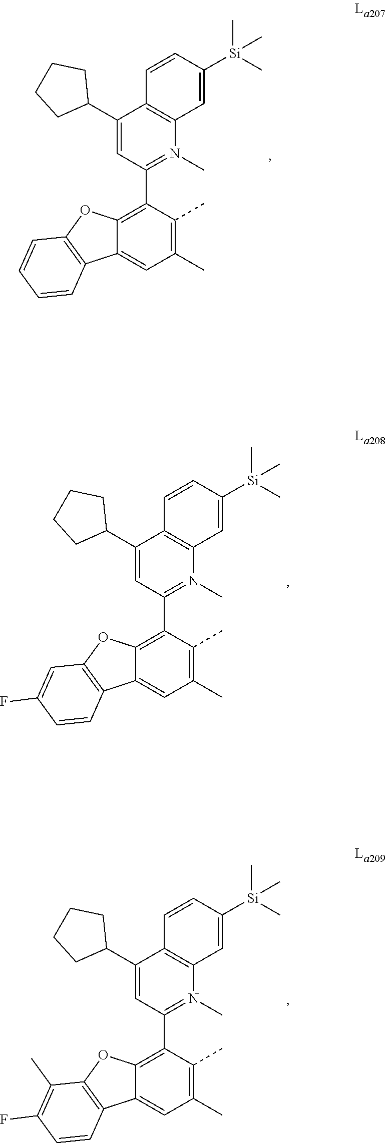

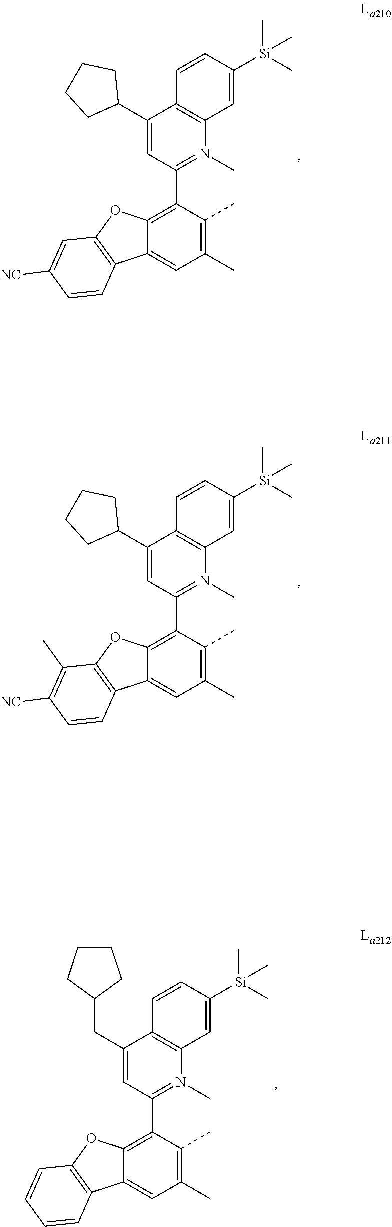

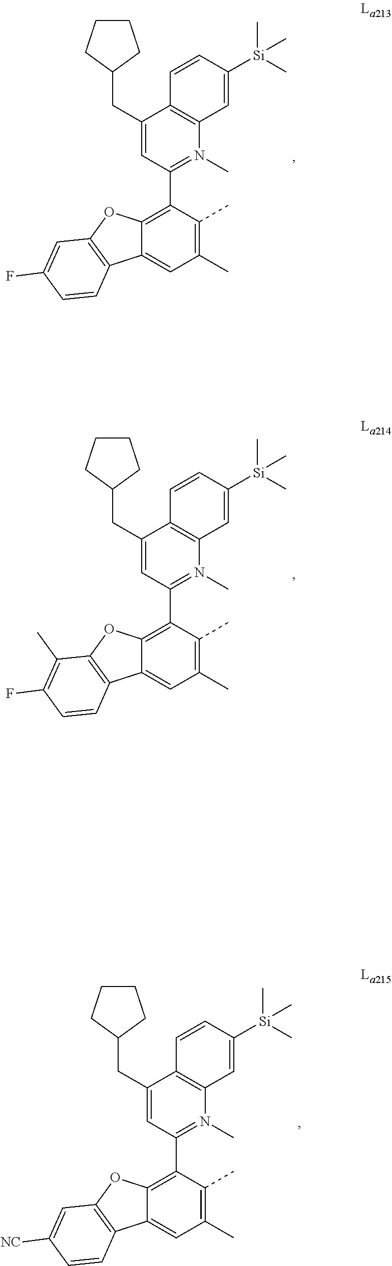

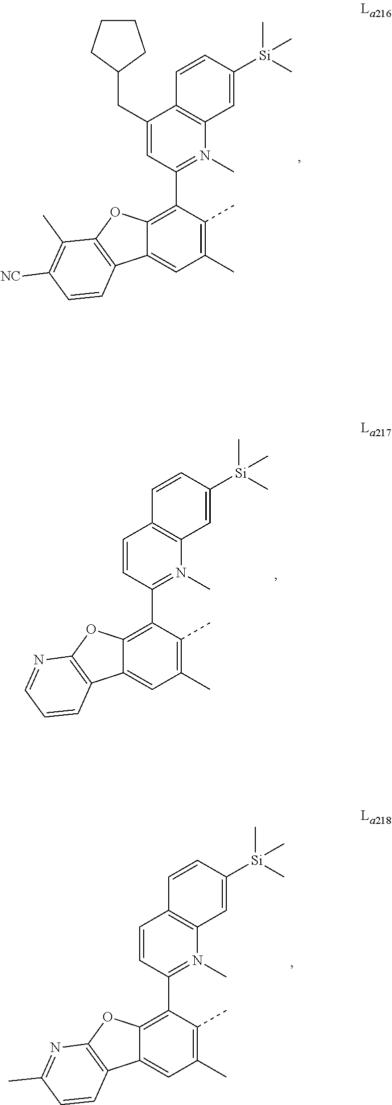

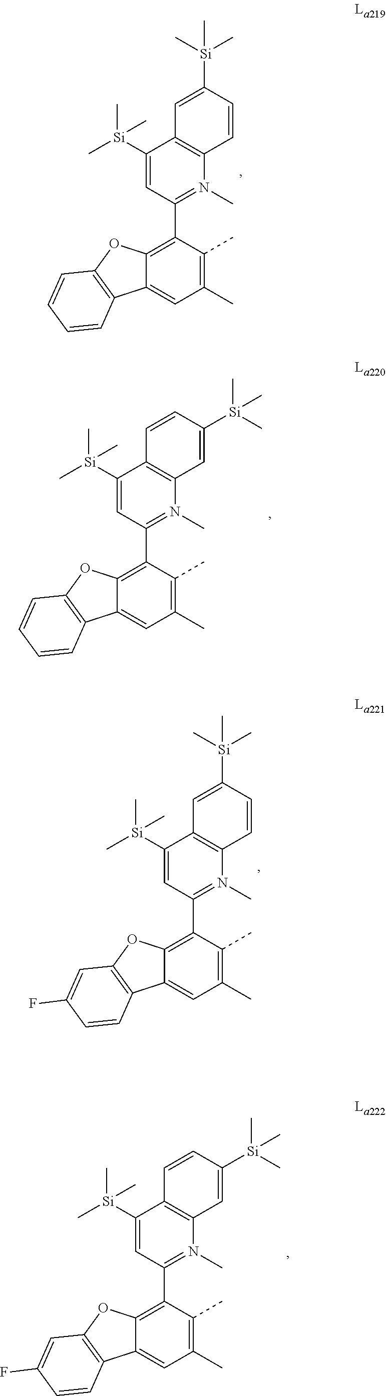

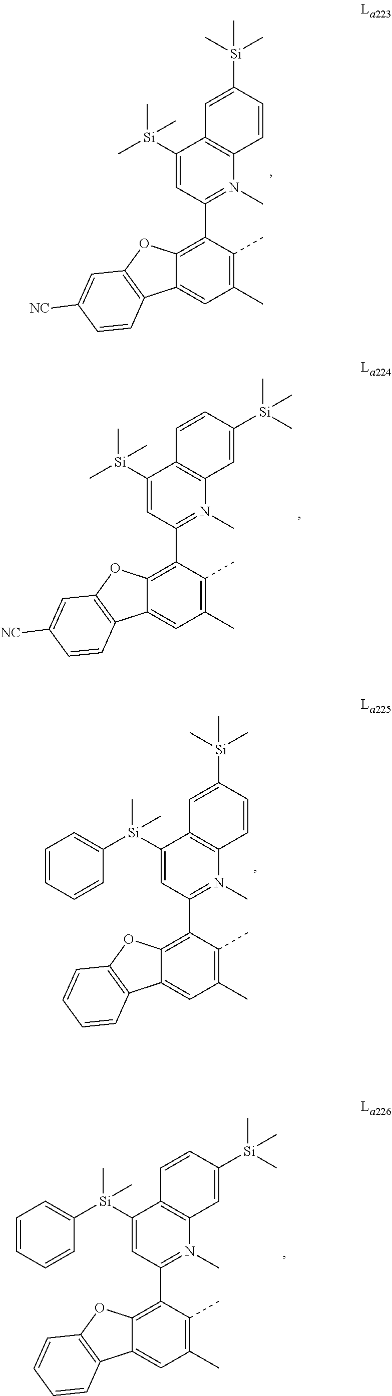

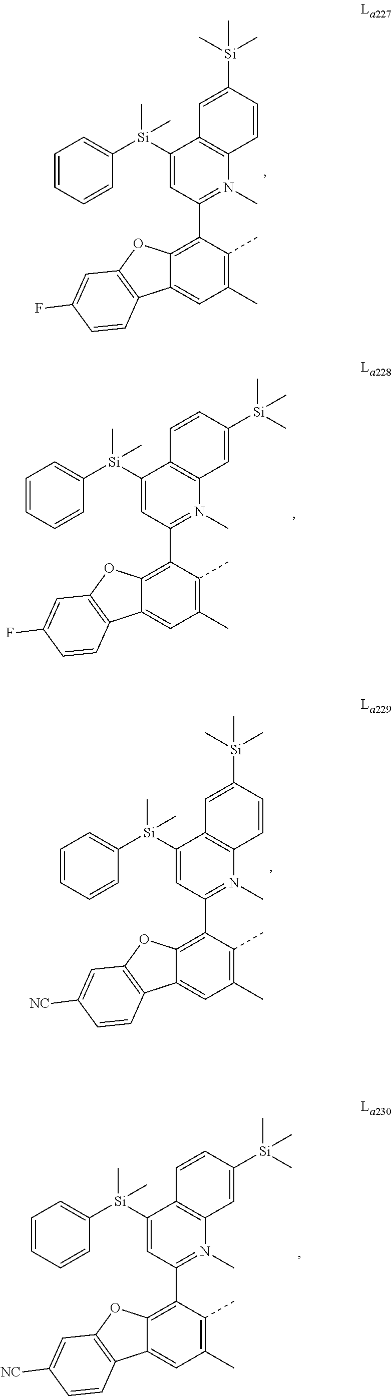

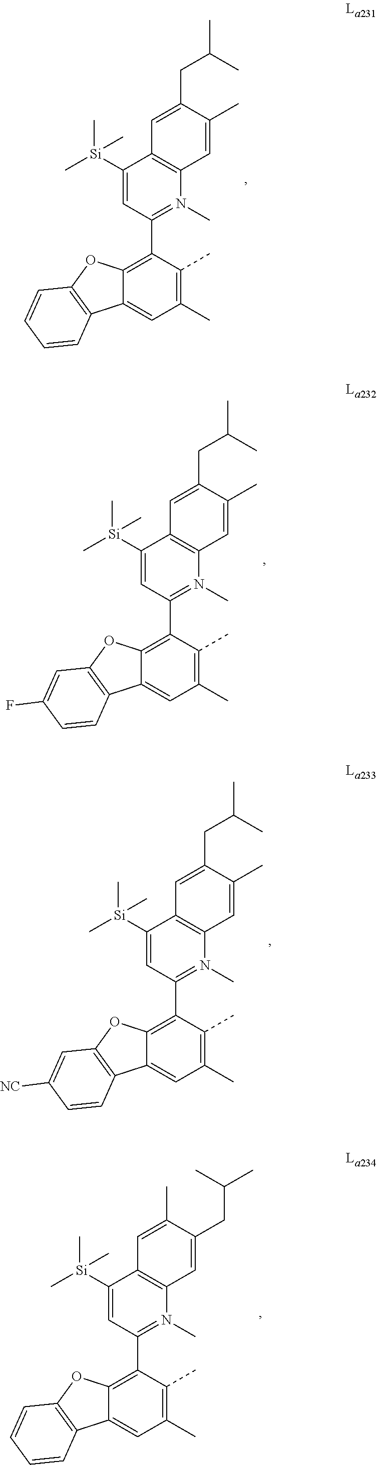

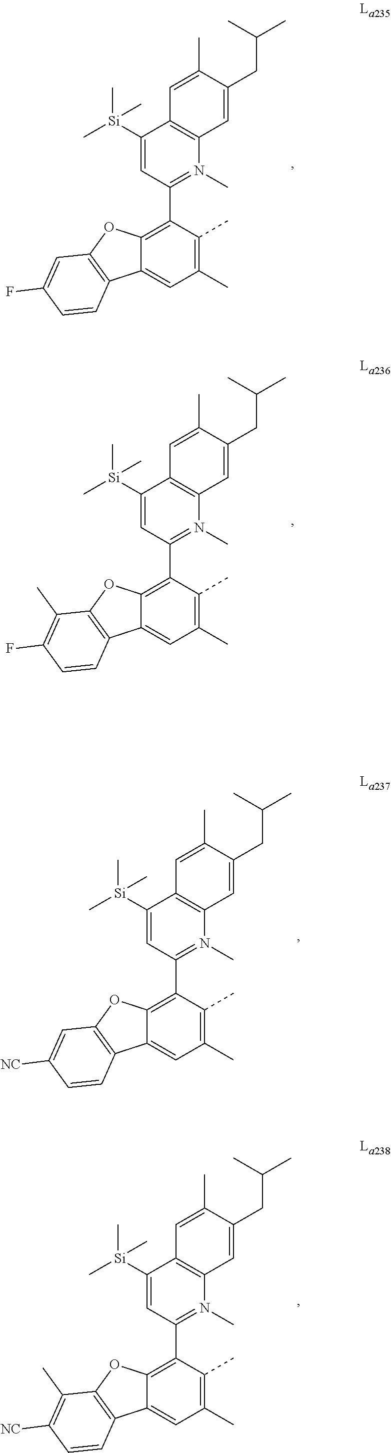

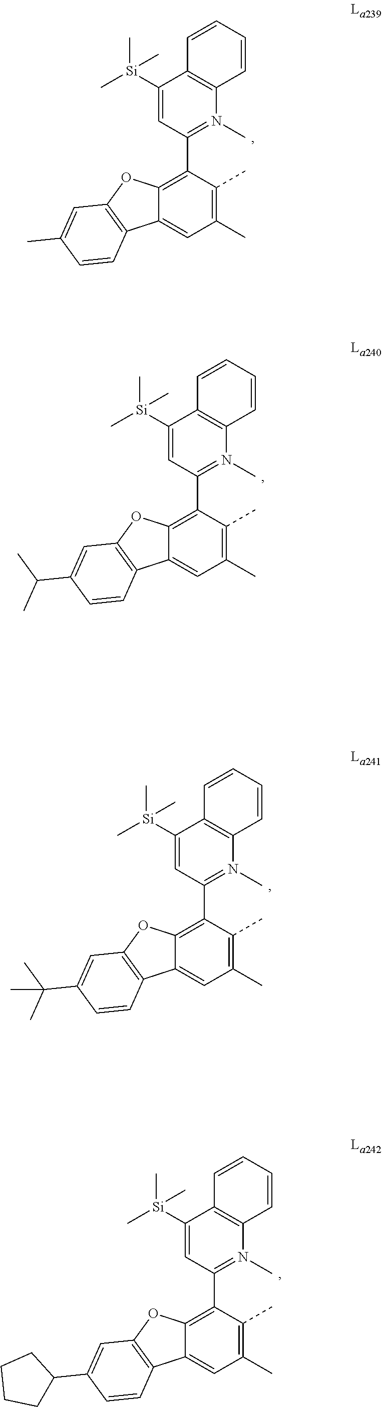

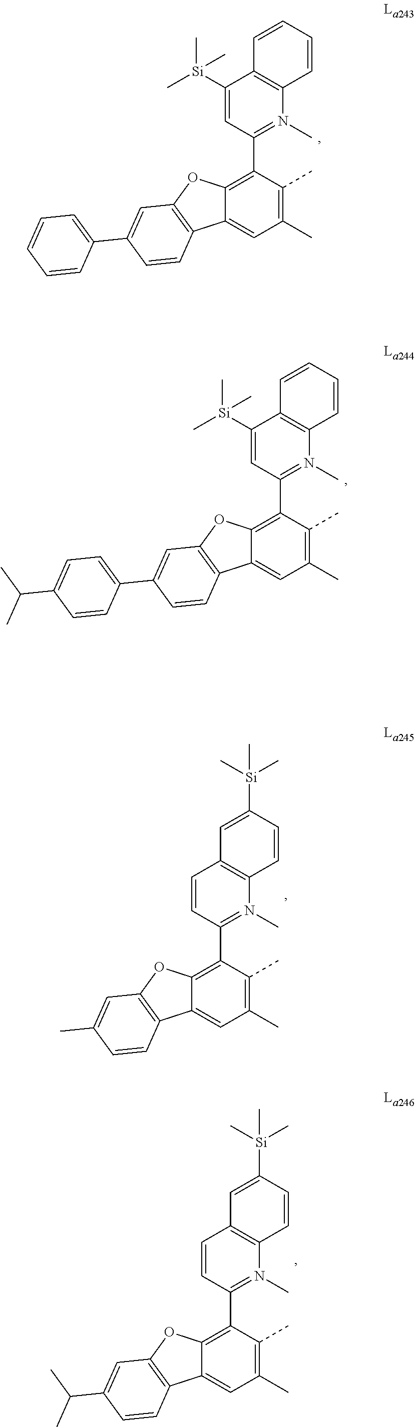

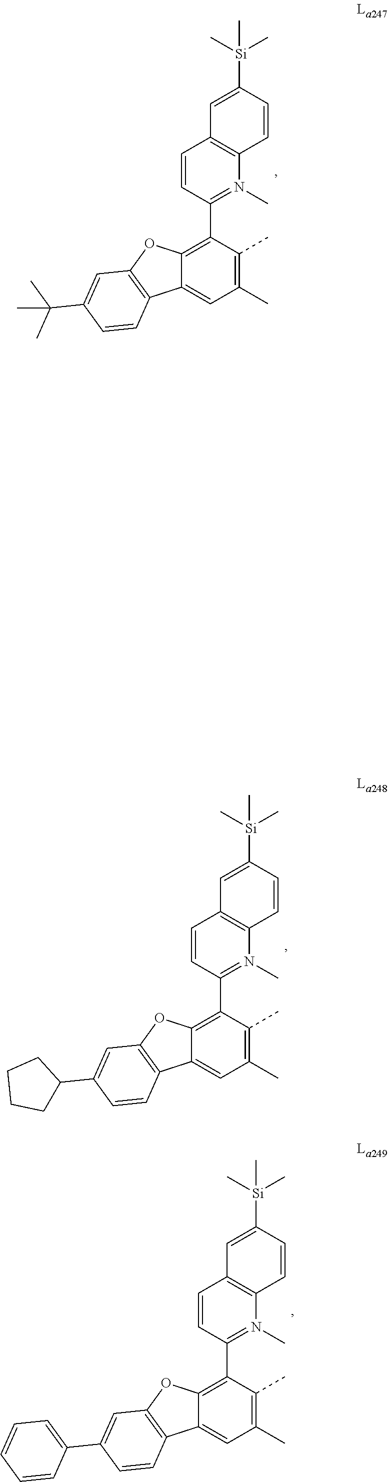

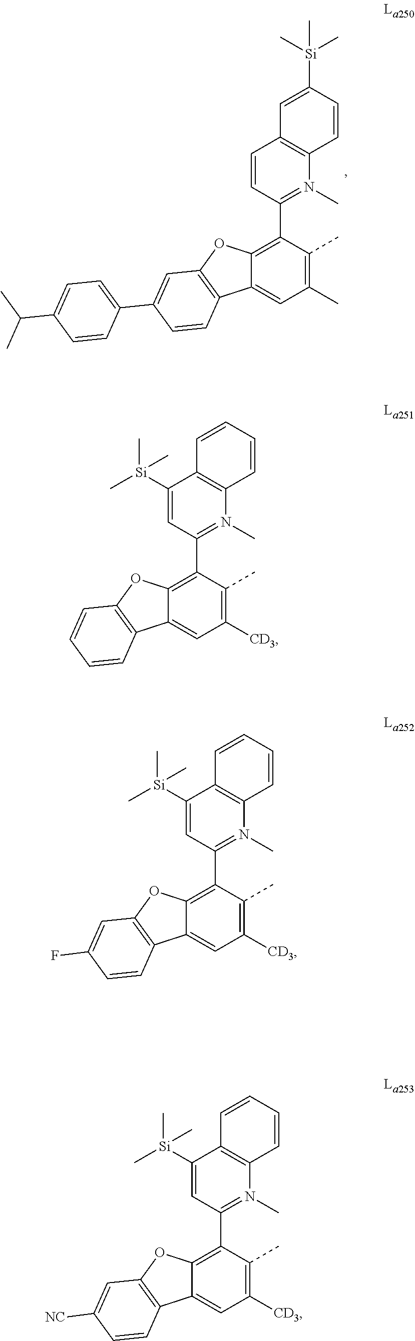

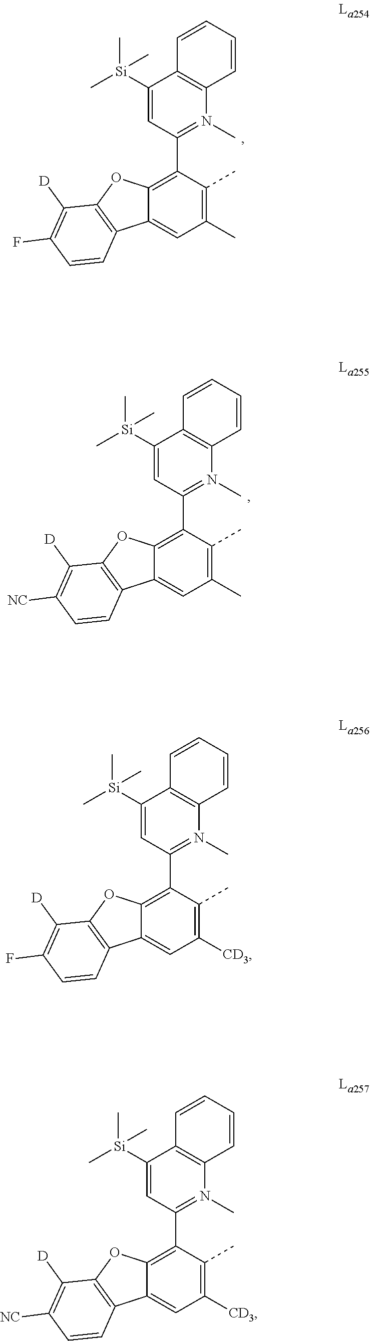

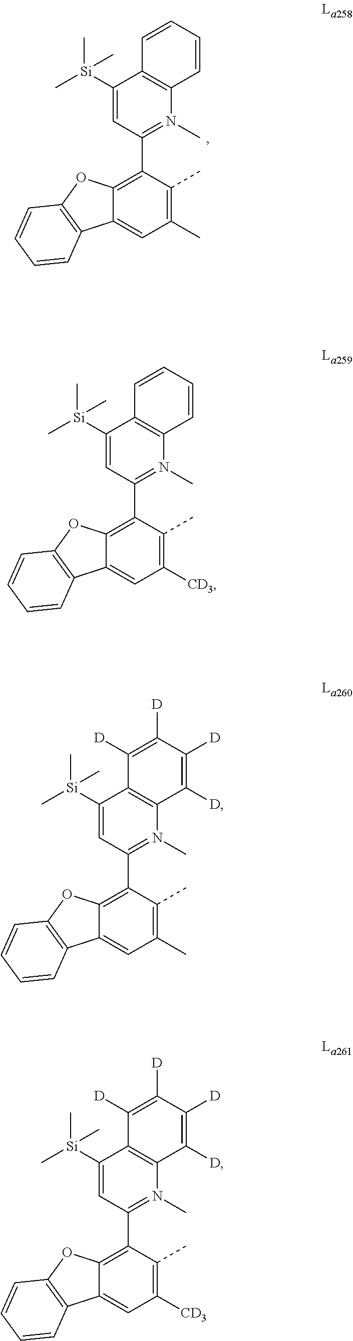

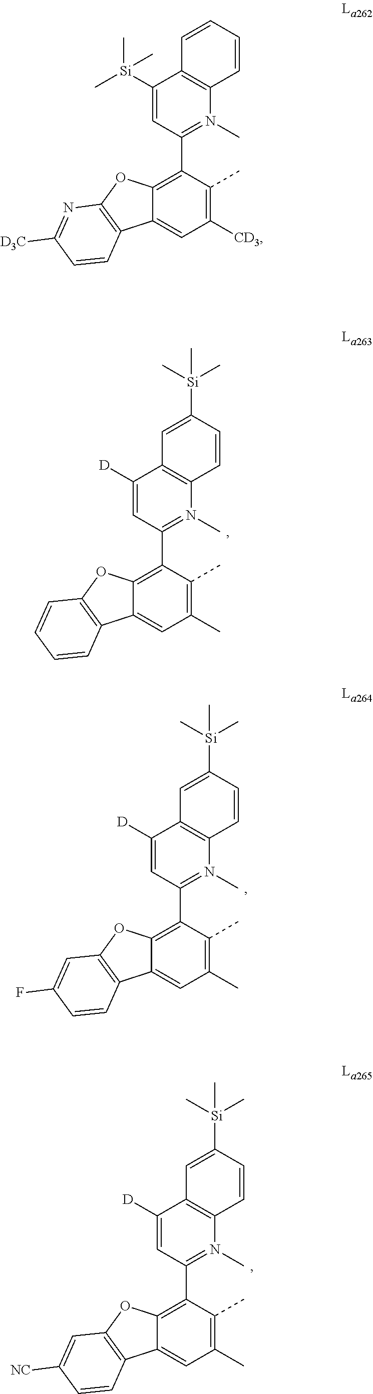

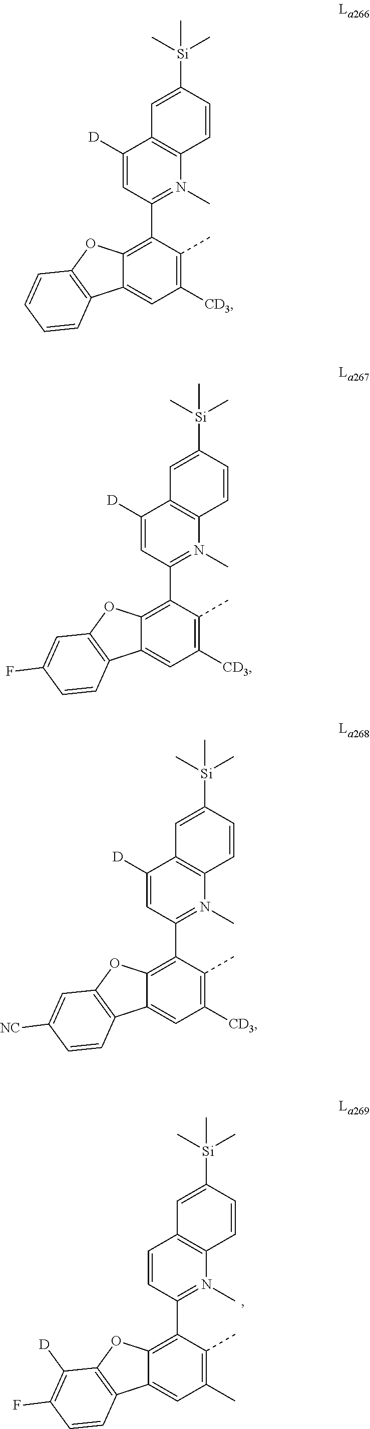

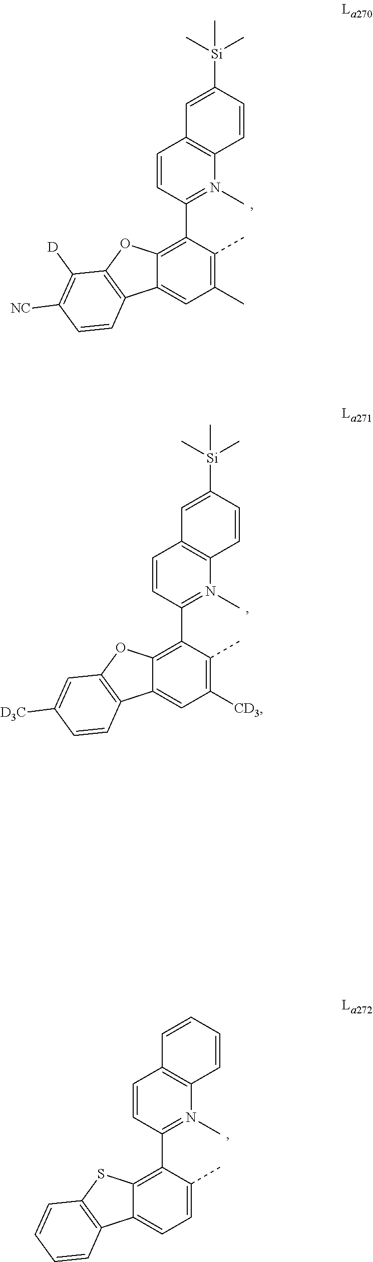

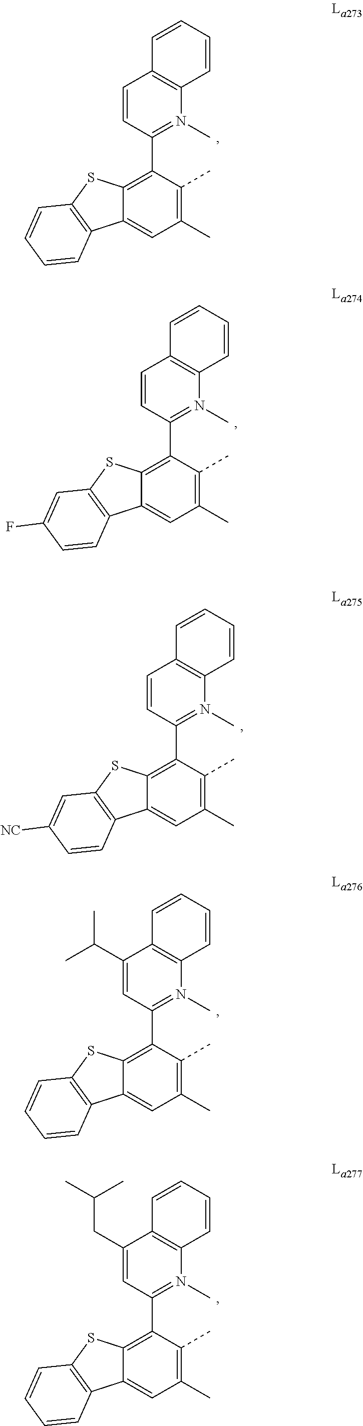

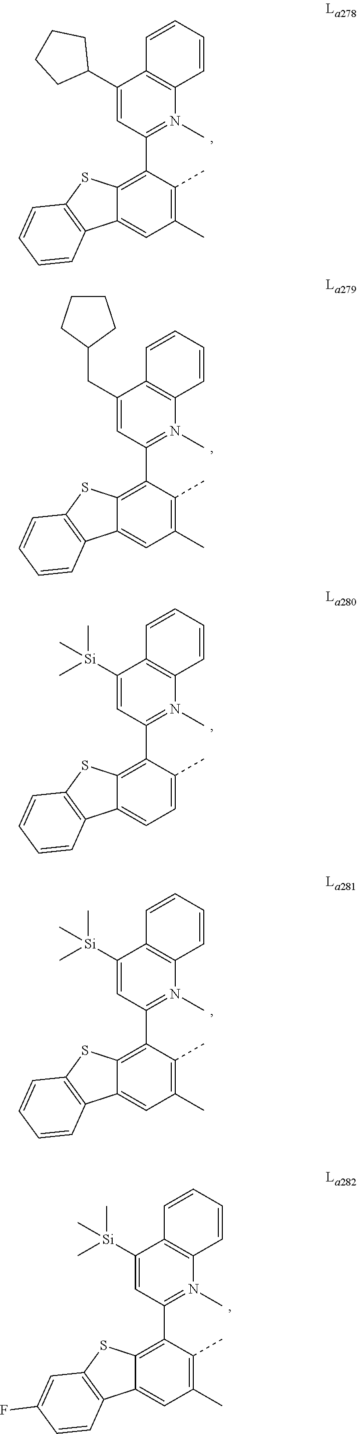

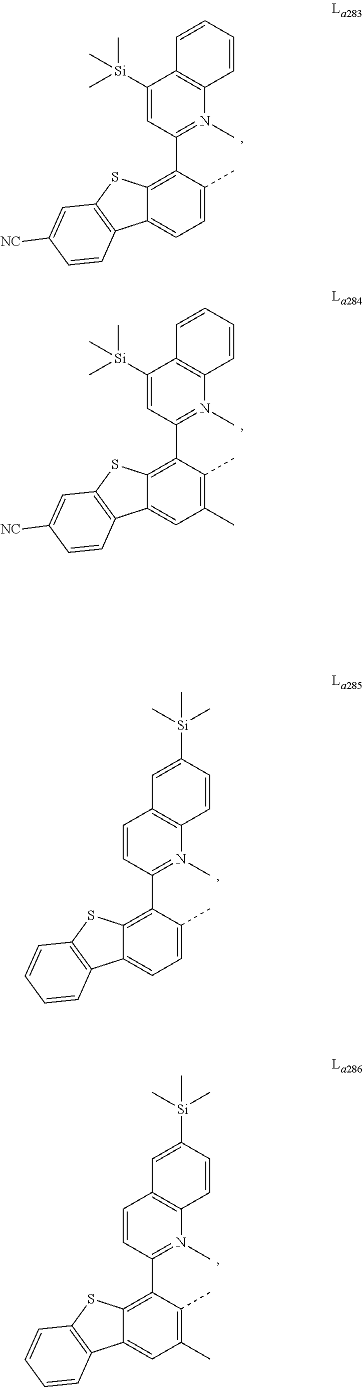

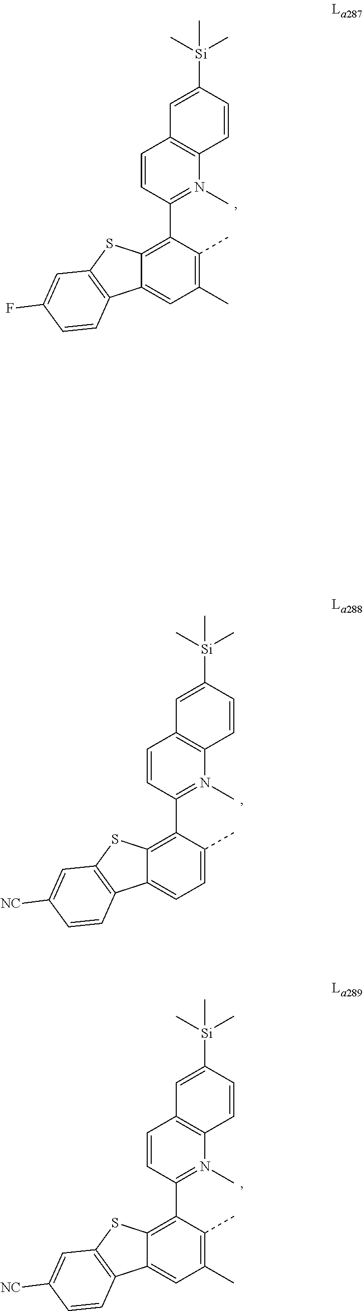

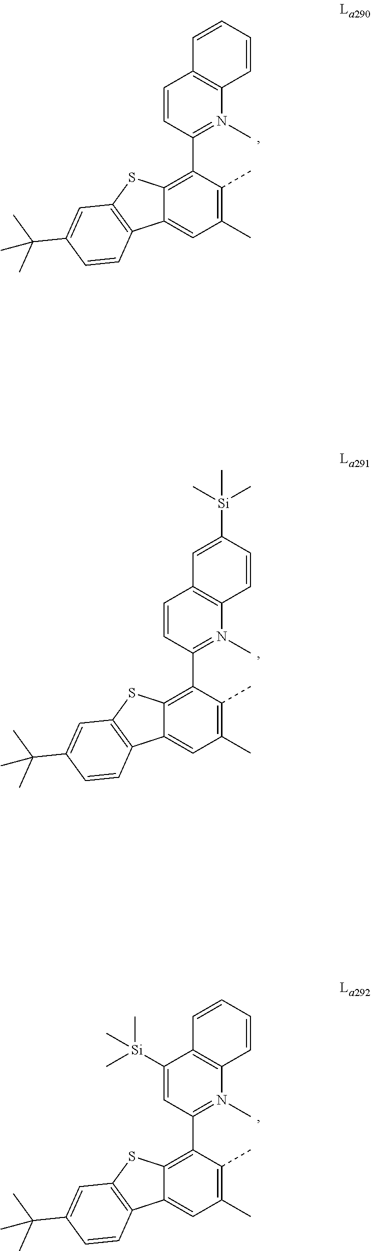

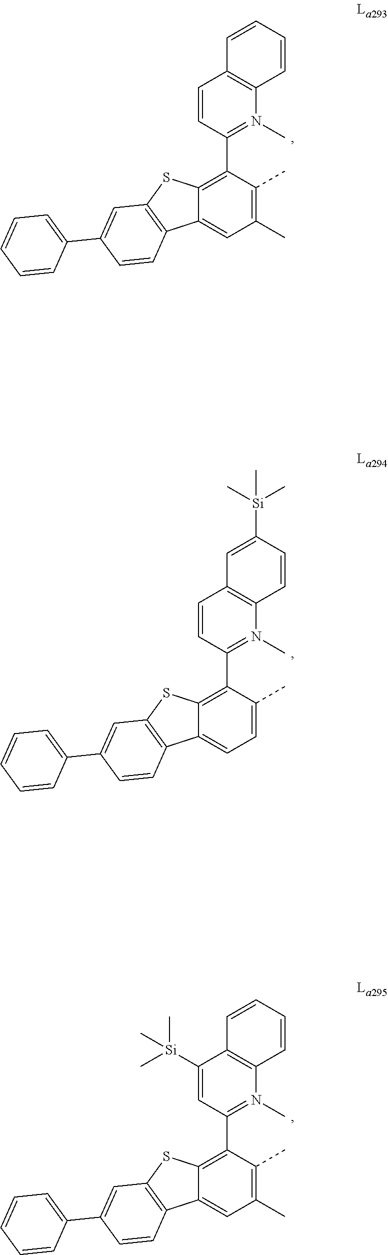

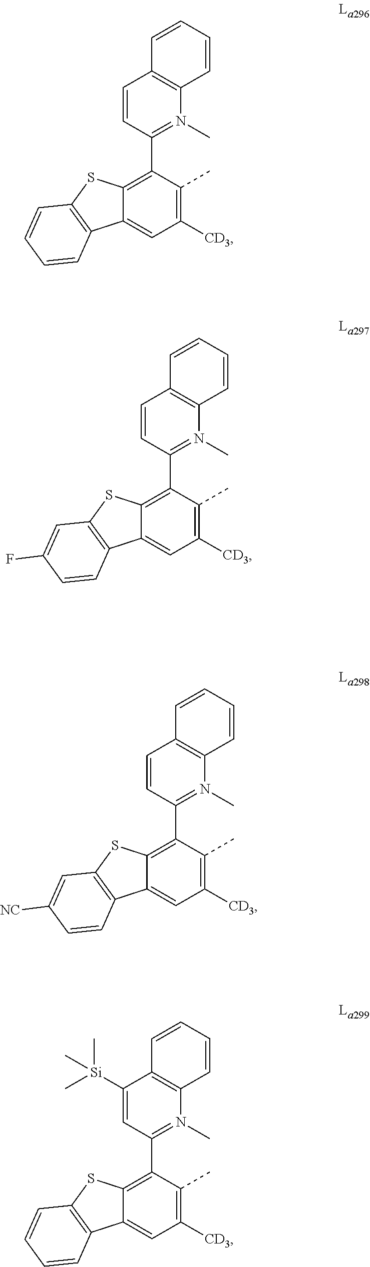

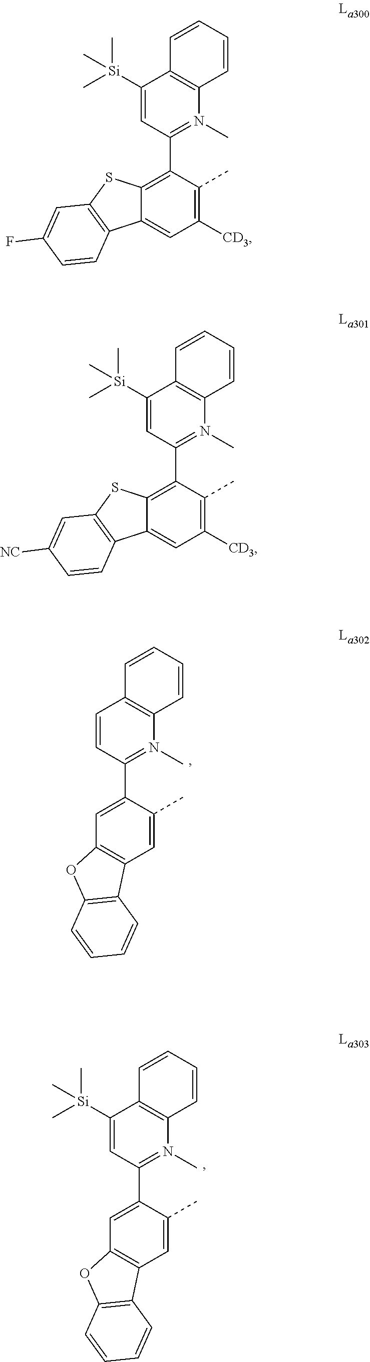

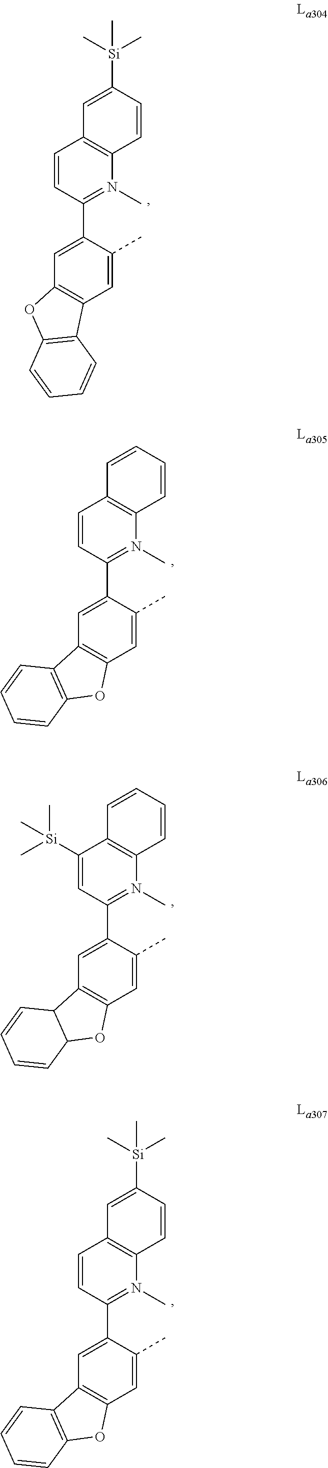

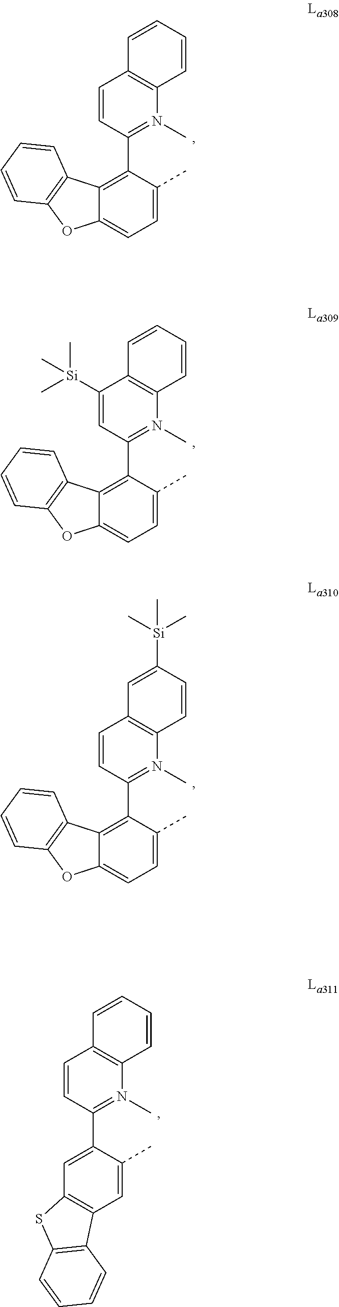

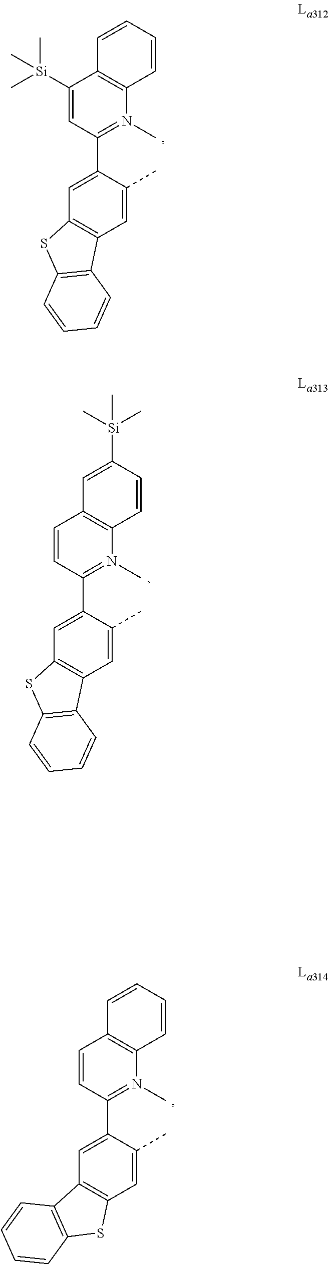

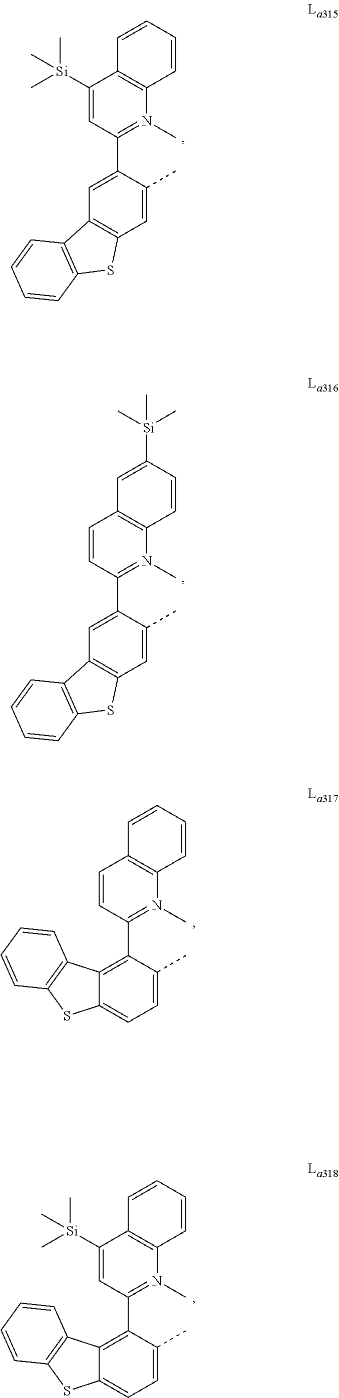

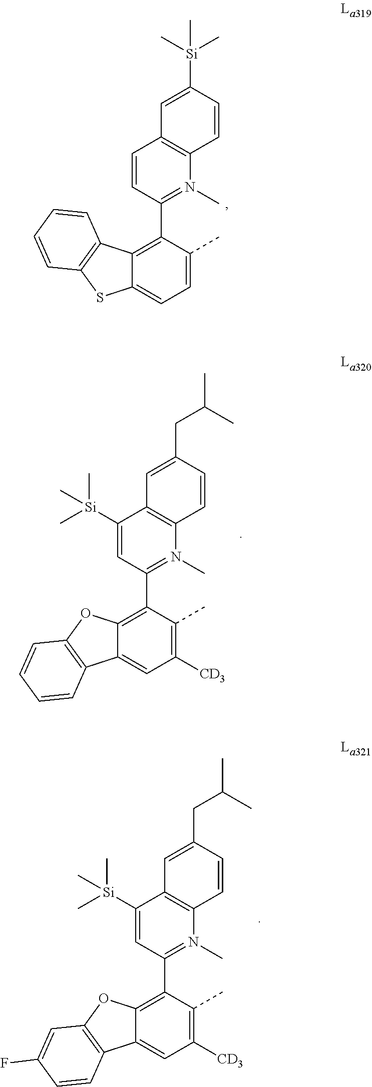

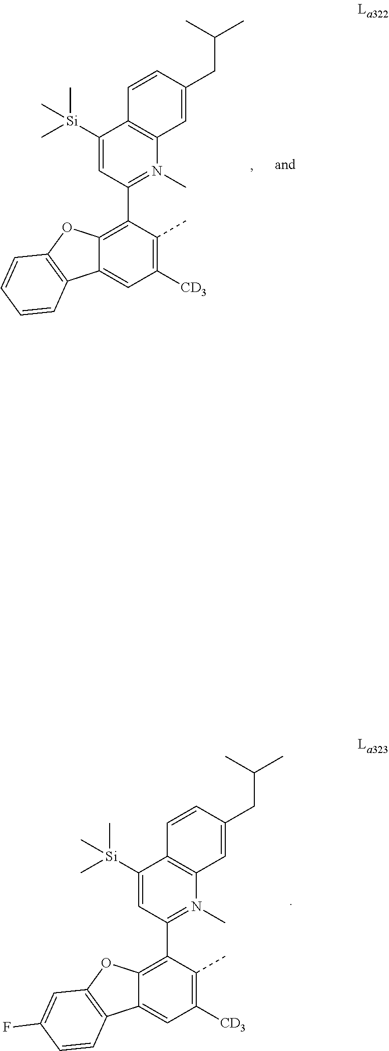

21. The electroluminescent device according to claim 20, wherein L_{b} is, at each occurrence identically or differently, selected from a group consisting of the following structures: 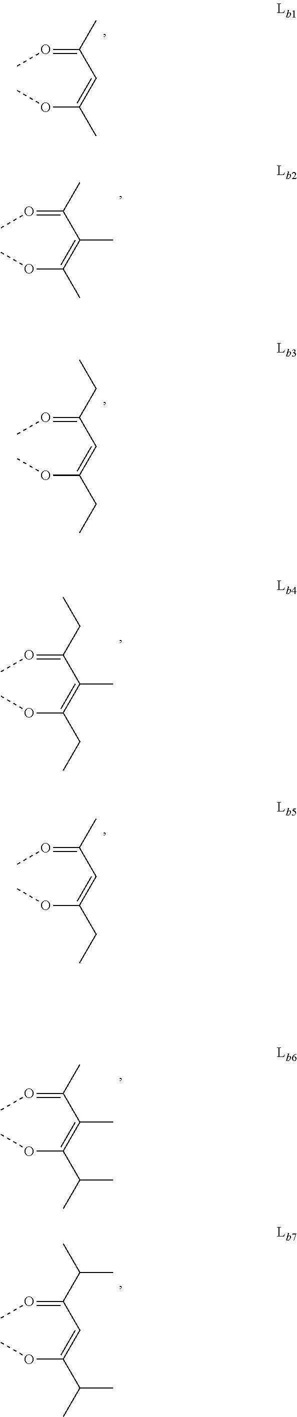 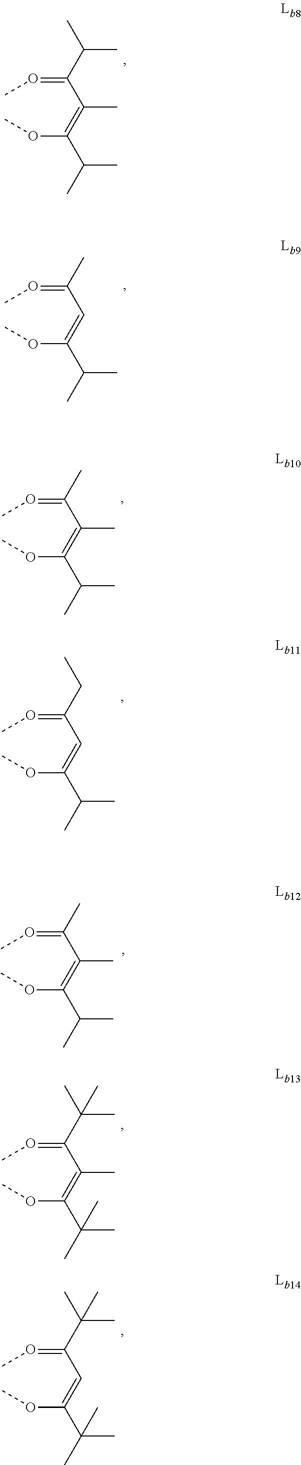 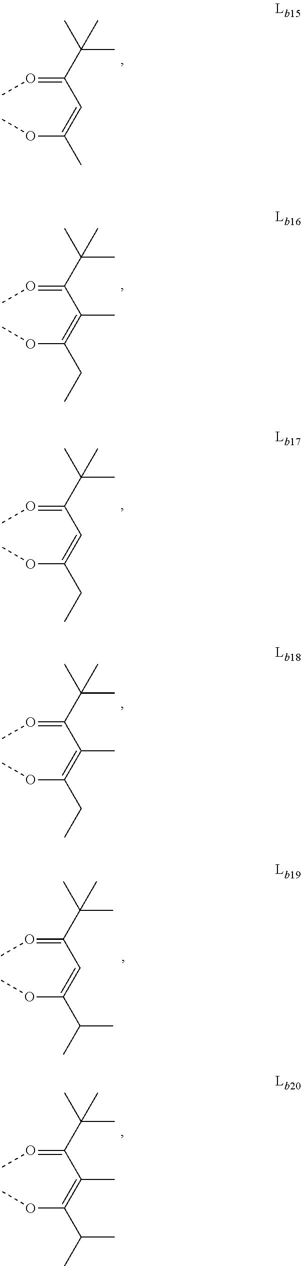 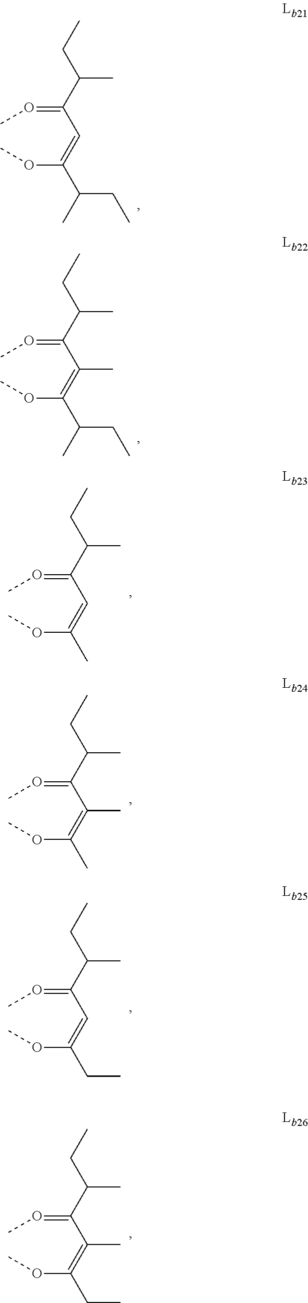 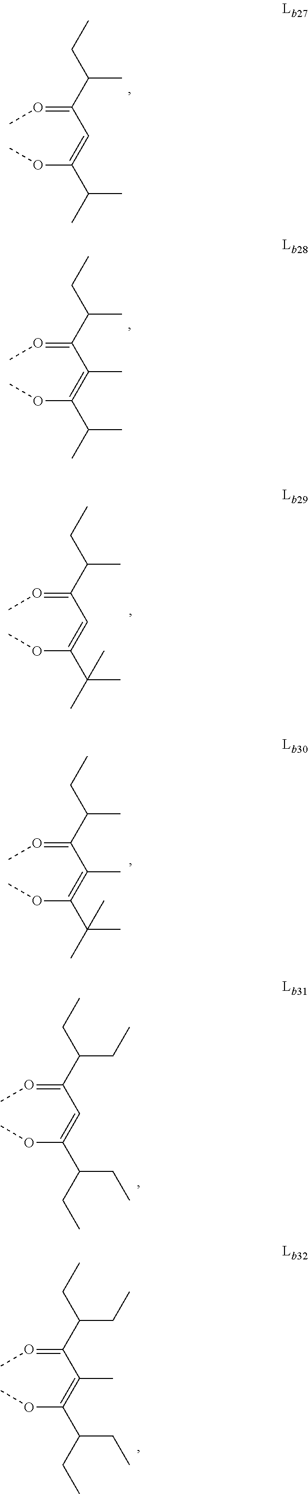 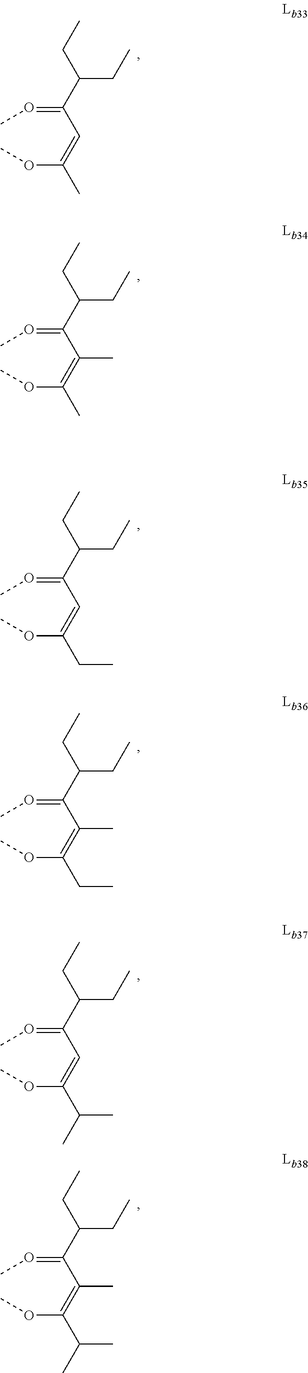 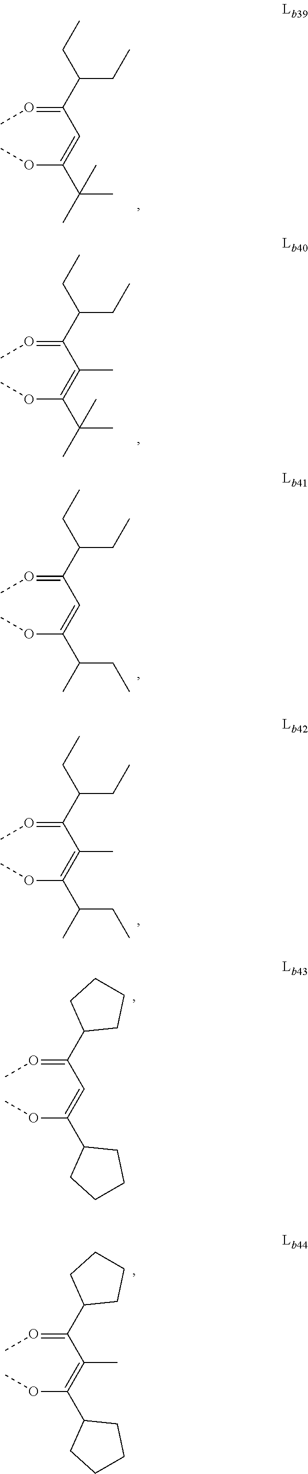 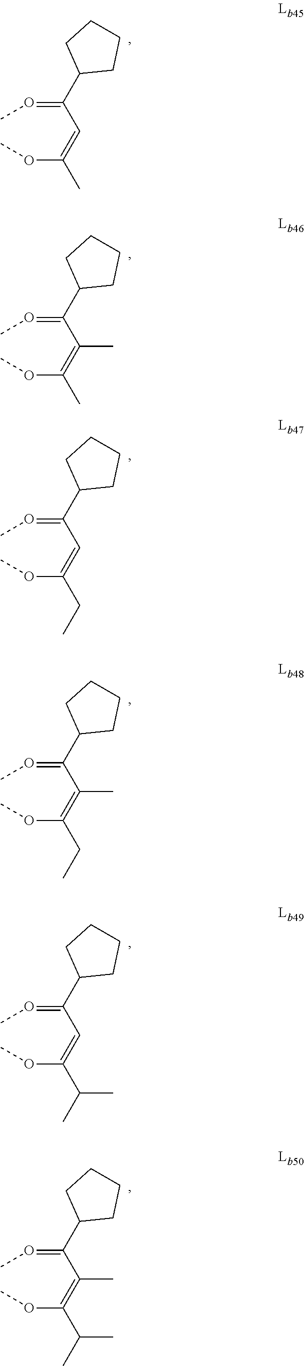 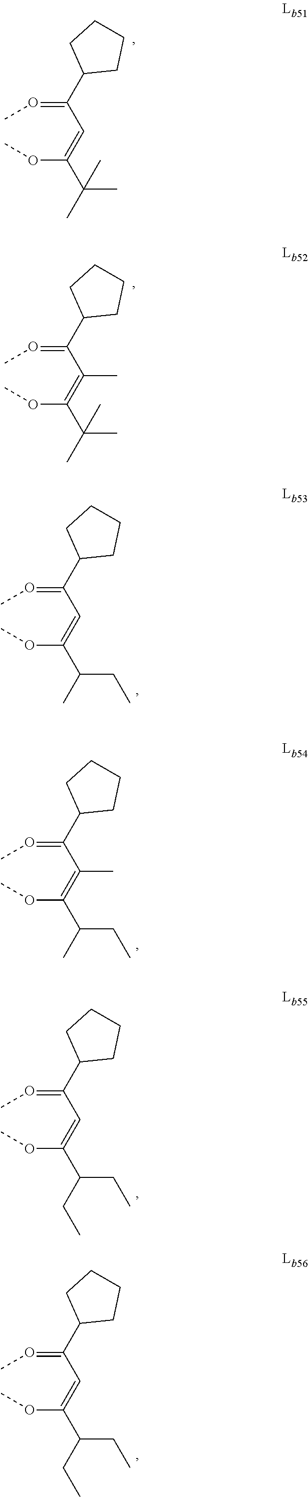 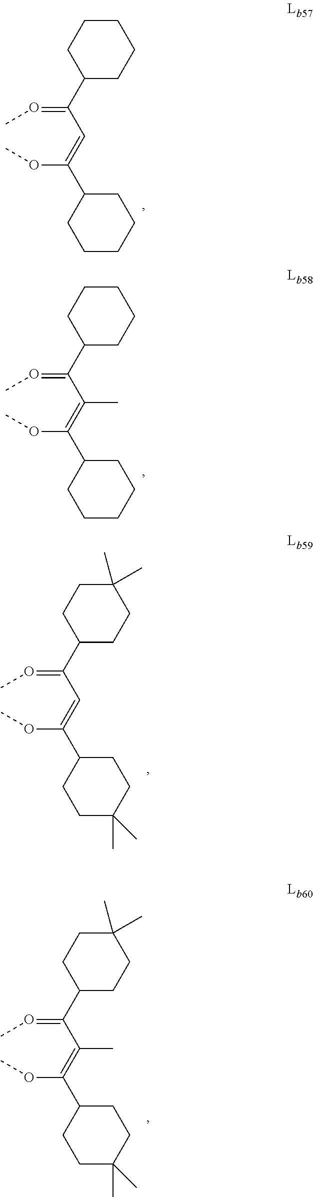 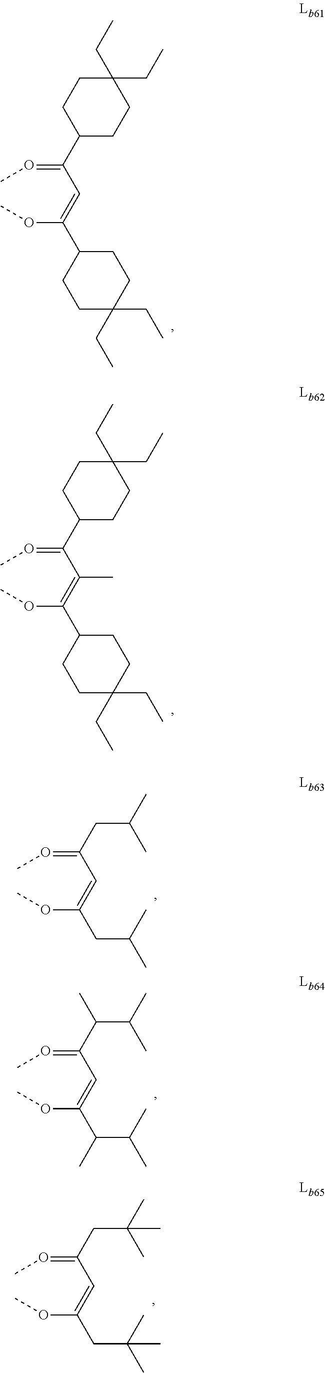 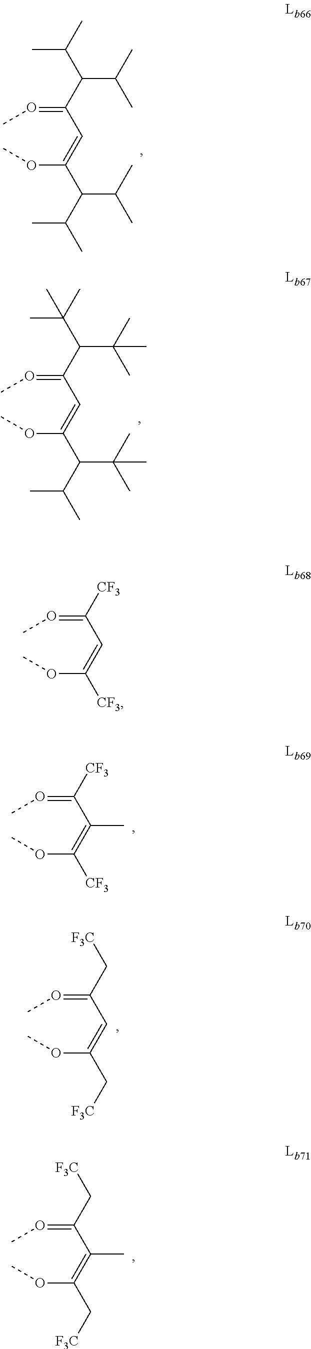 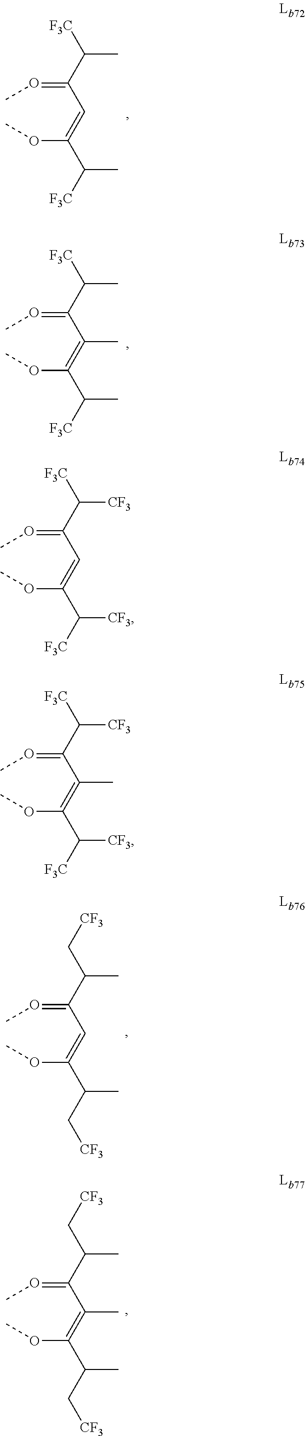 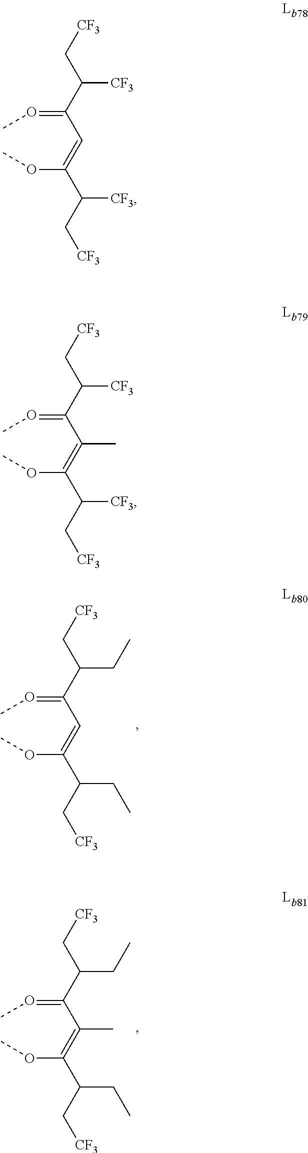 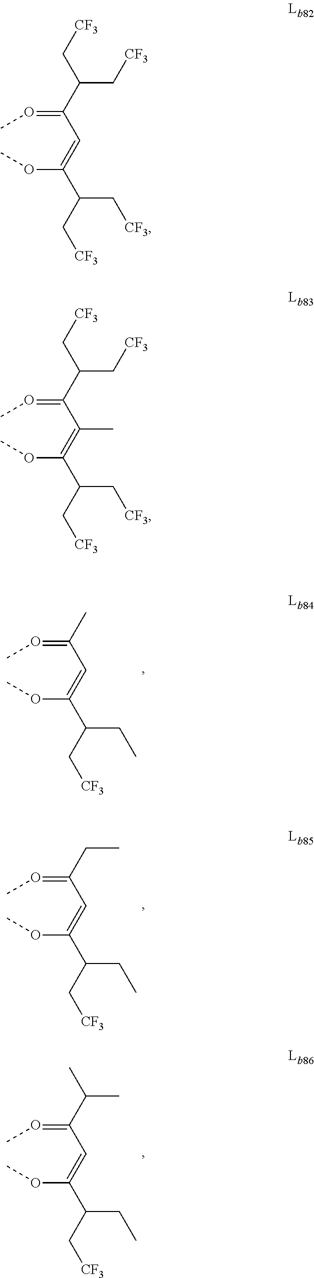 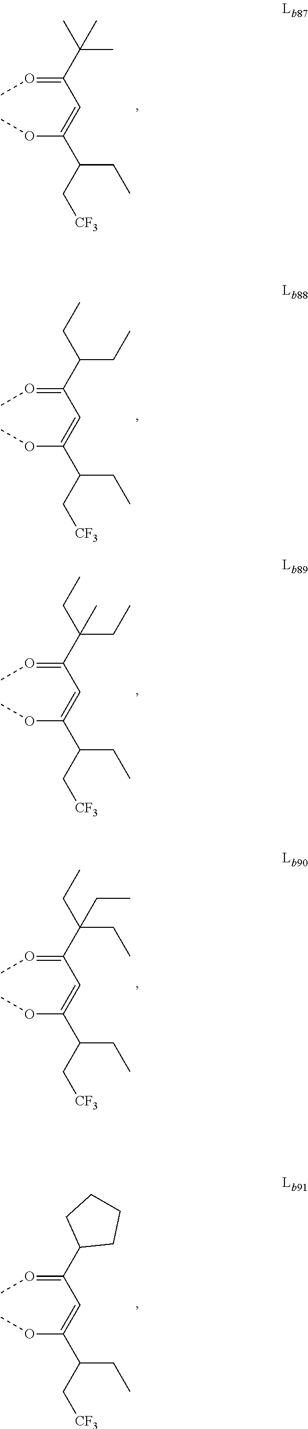 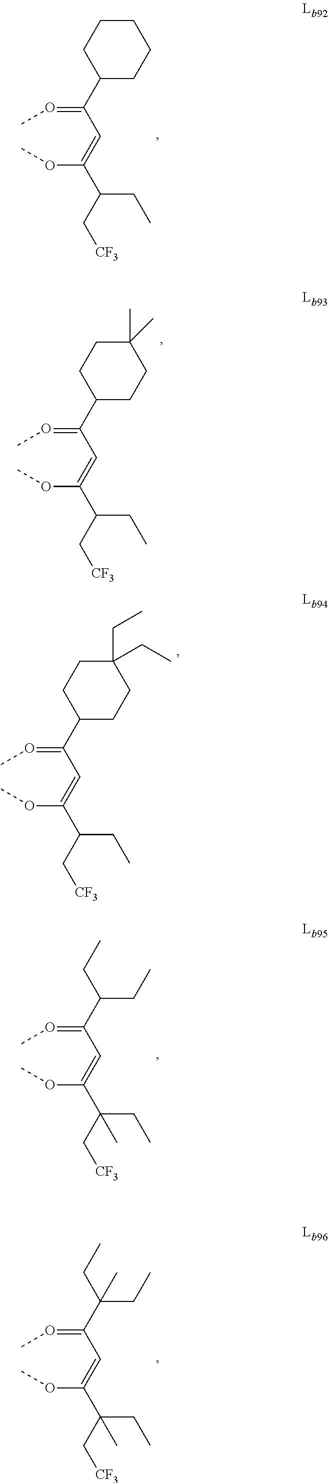 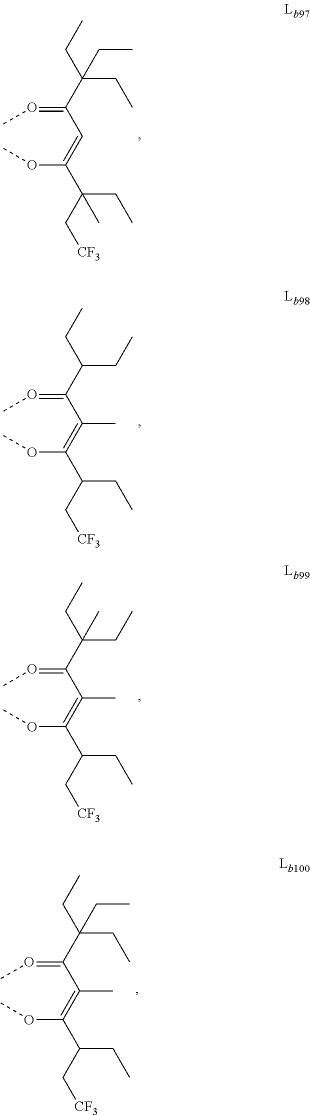 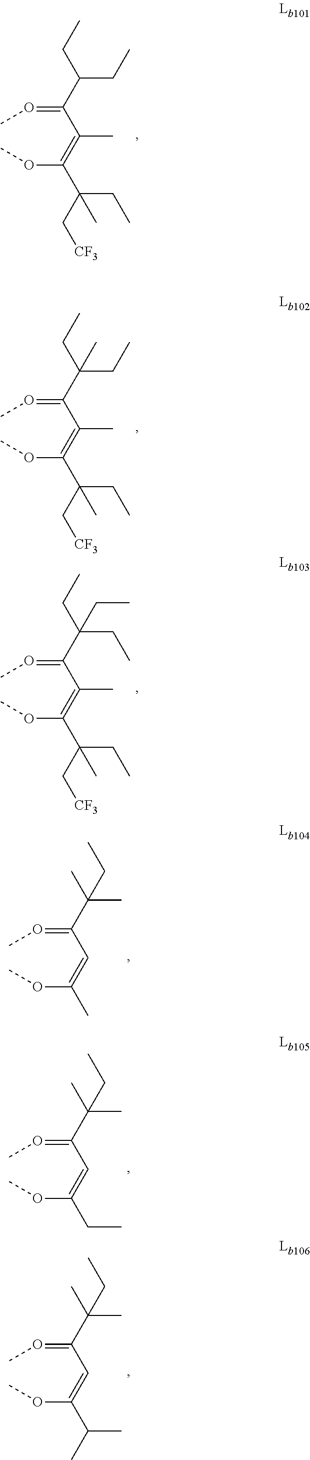 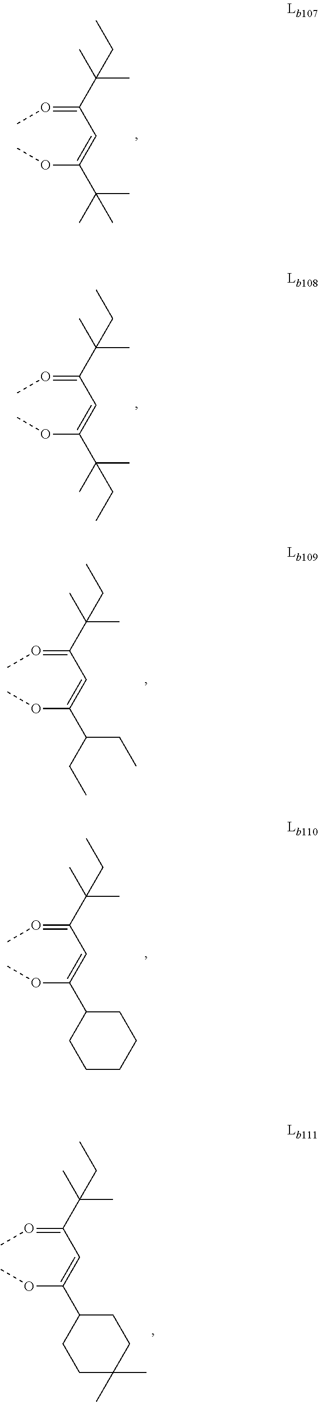 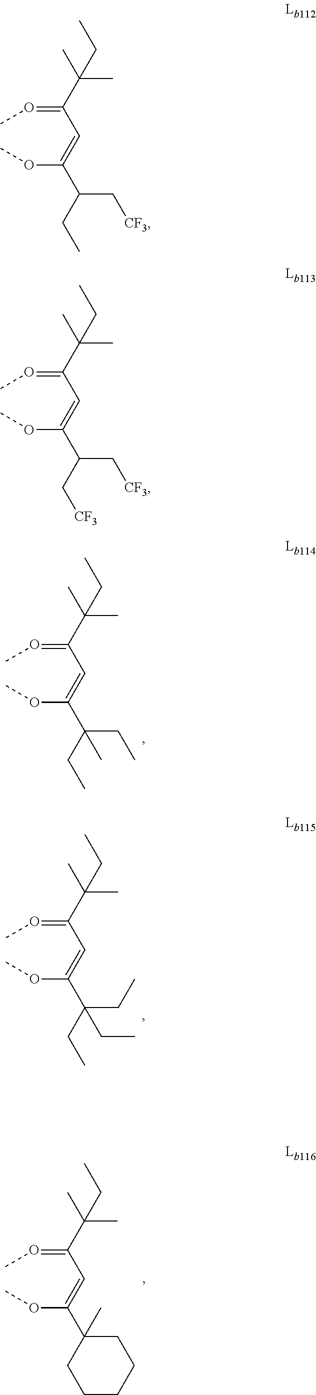 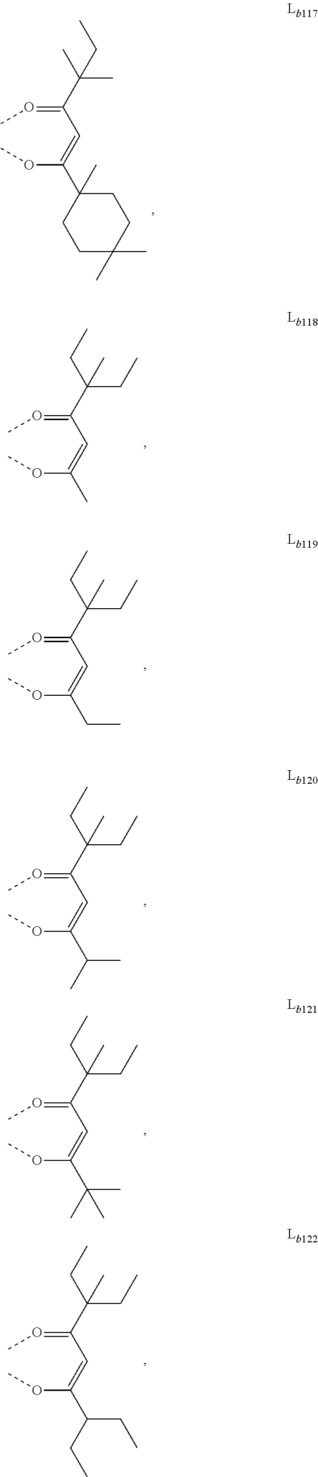 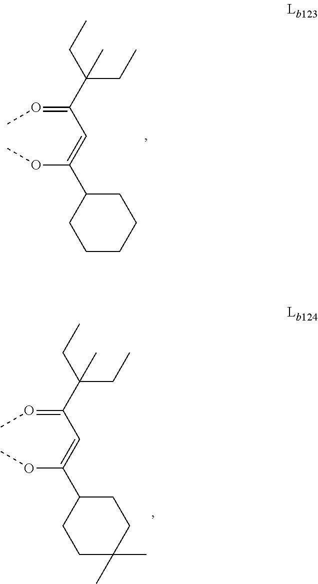 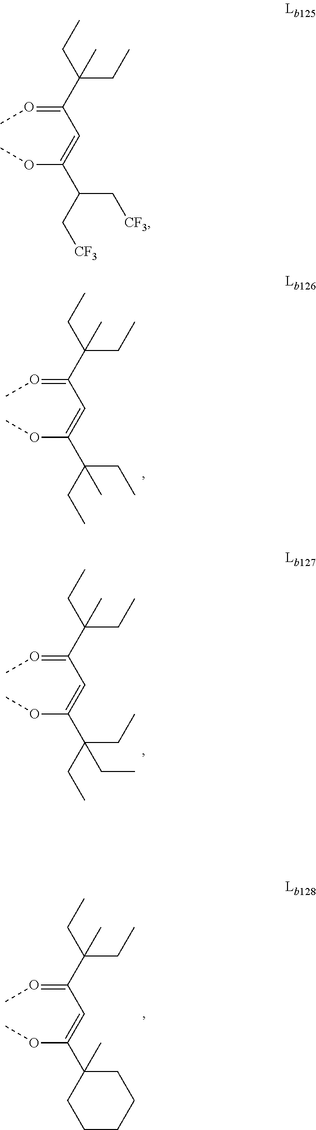 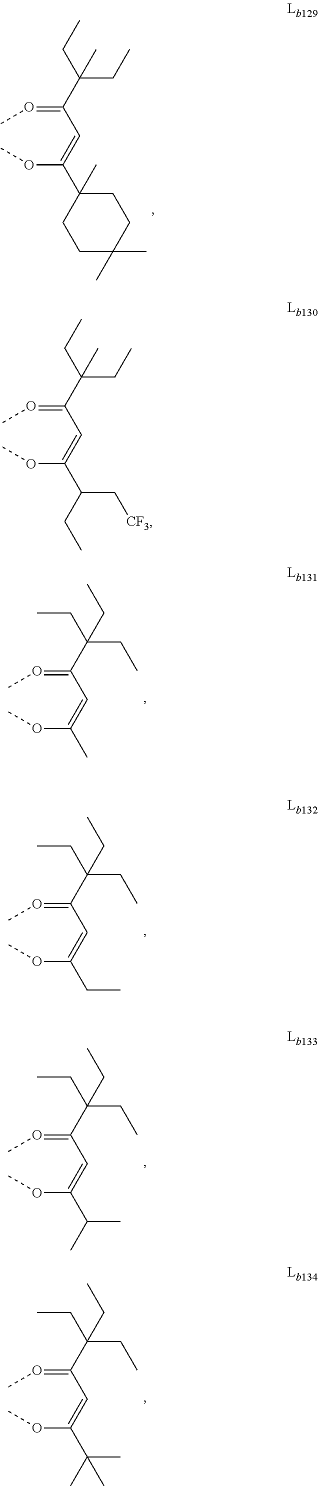 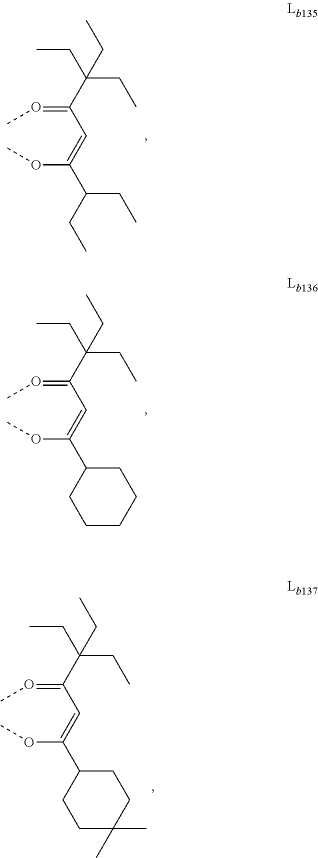 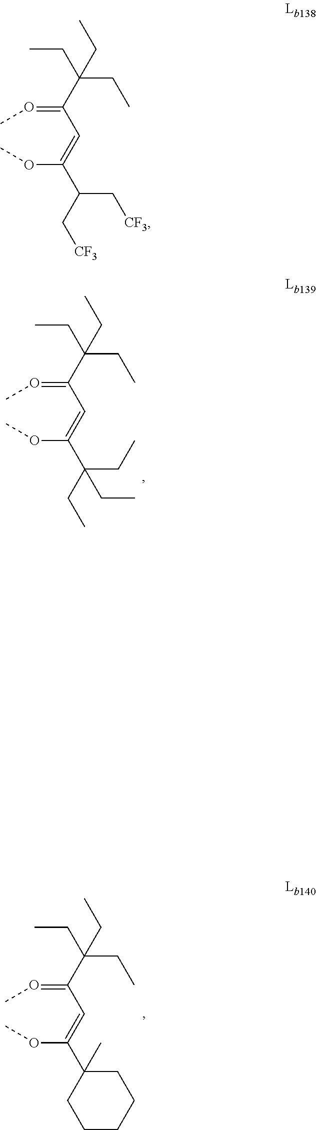 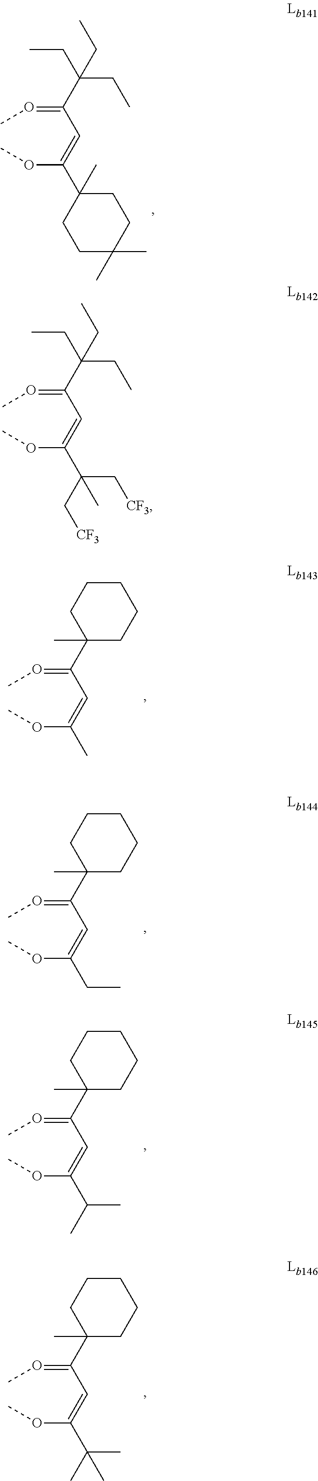 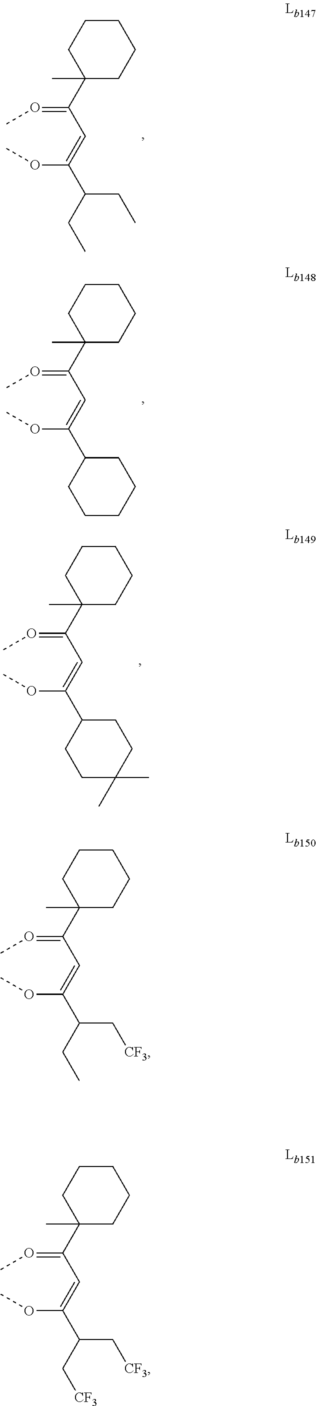 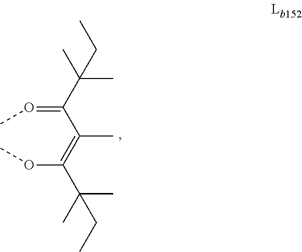 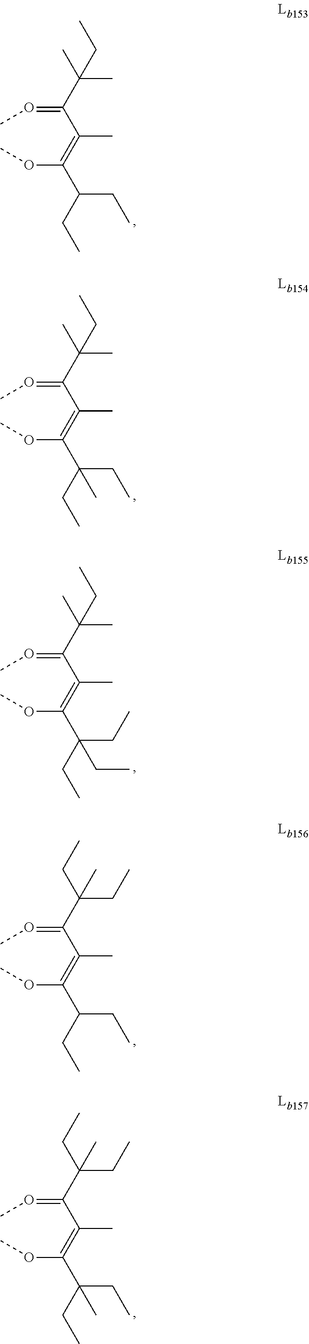 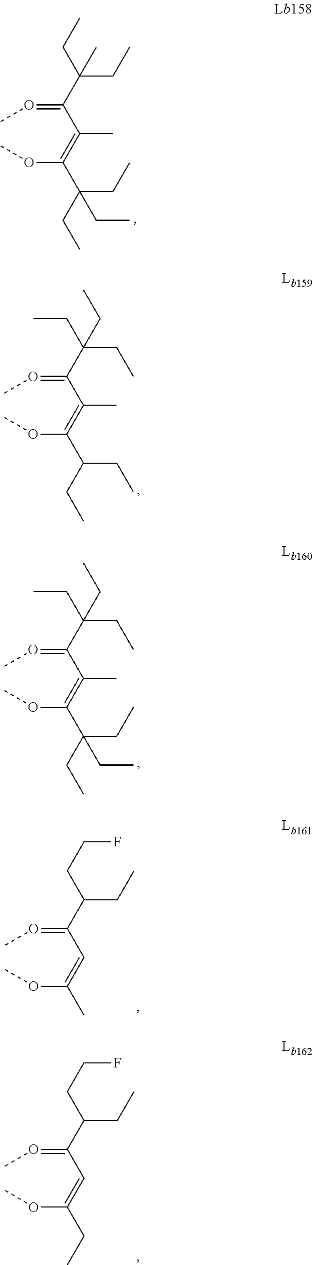 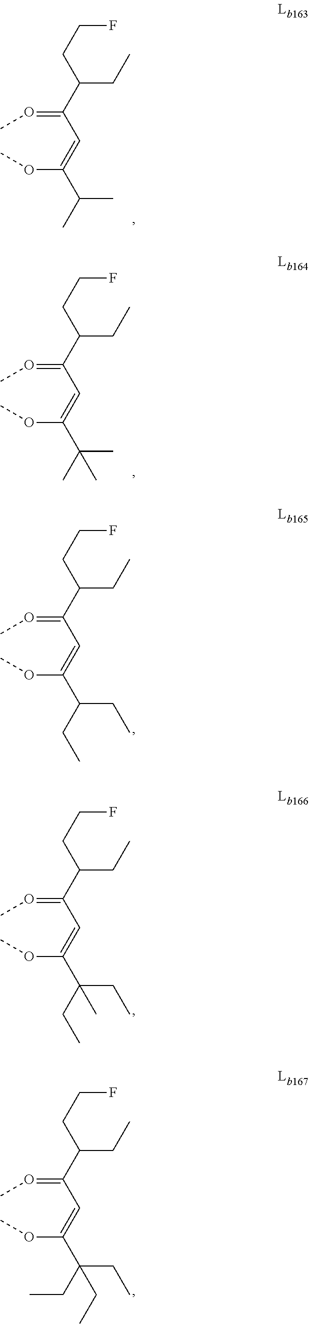 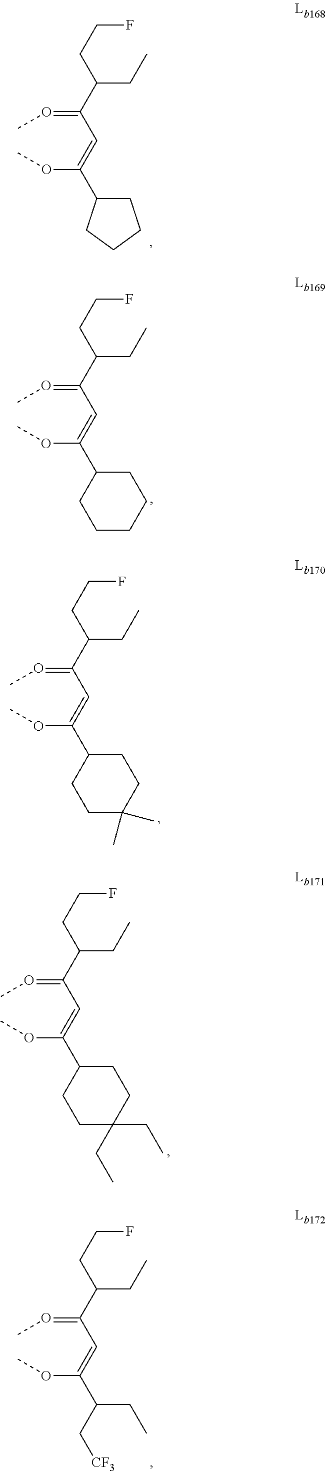 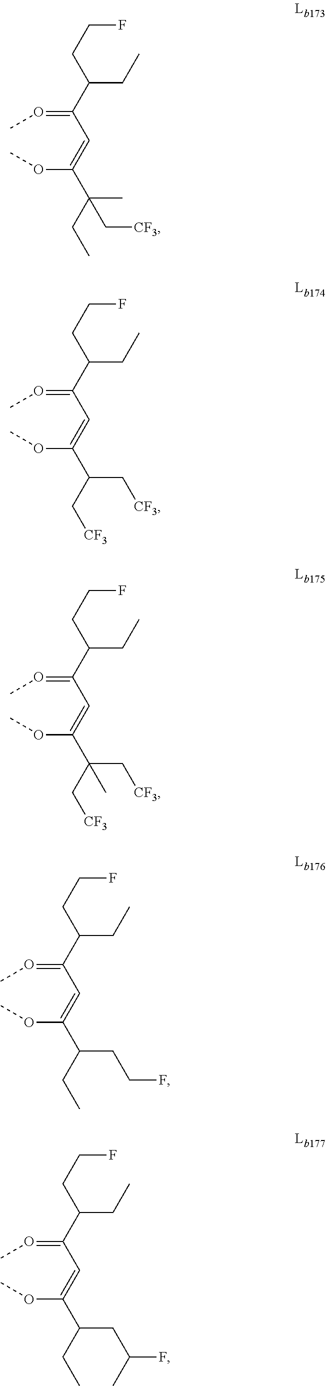 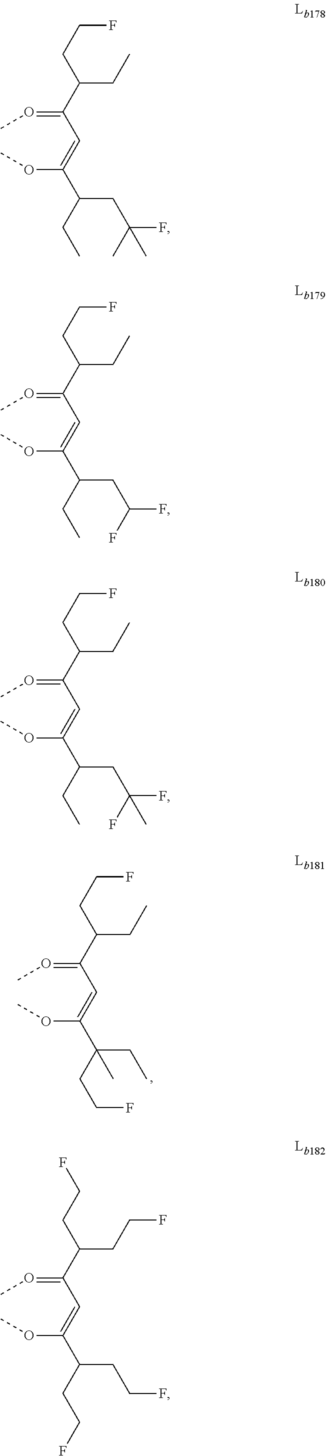 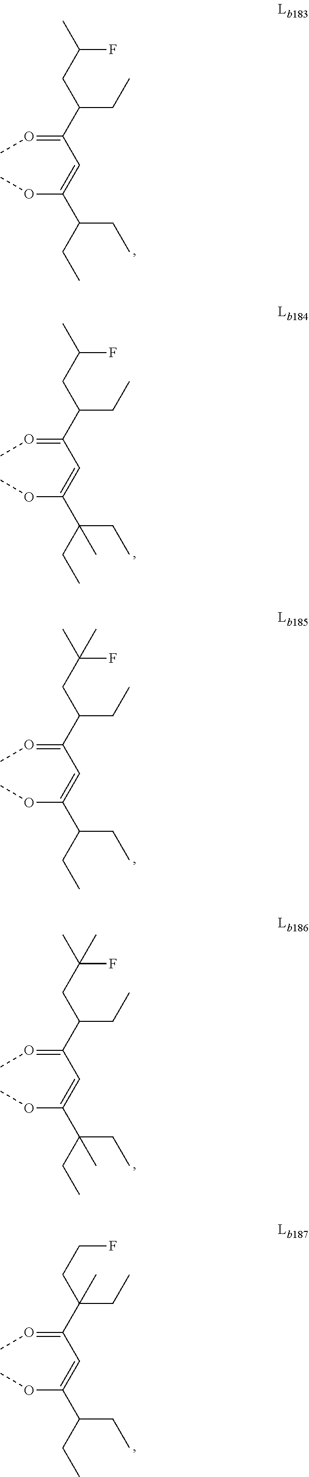 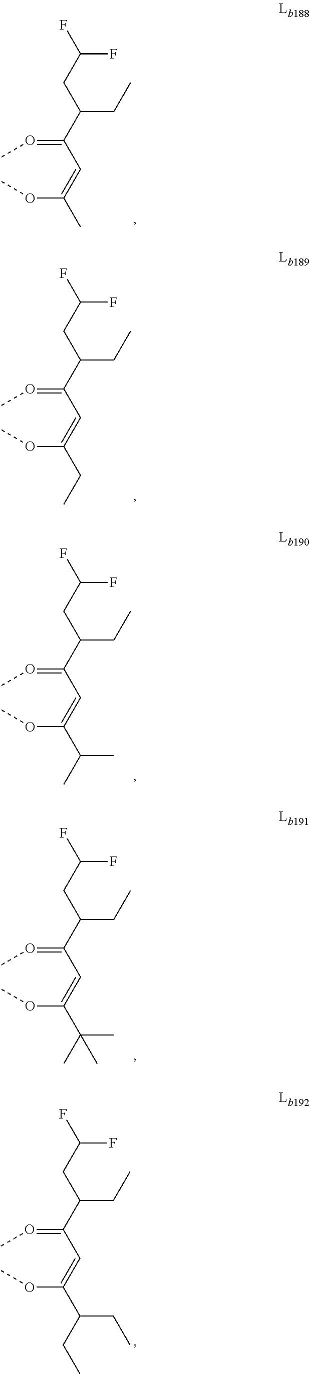 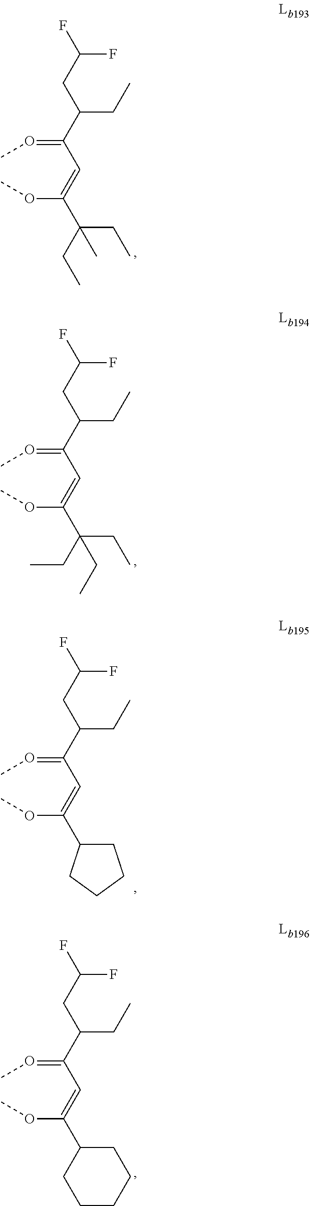 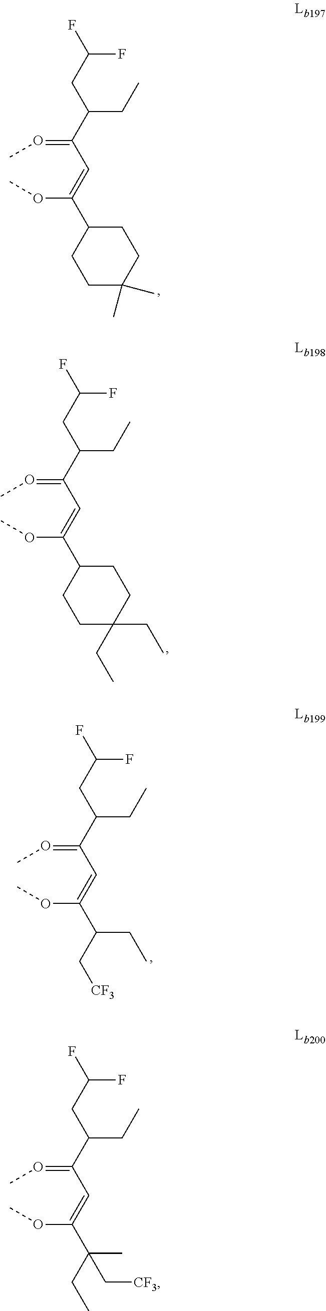 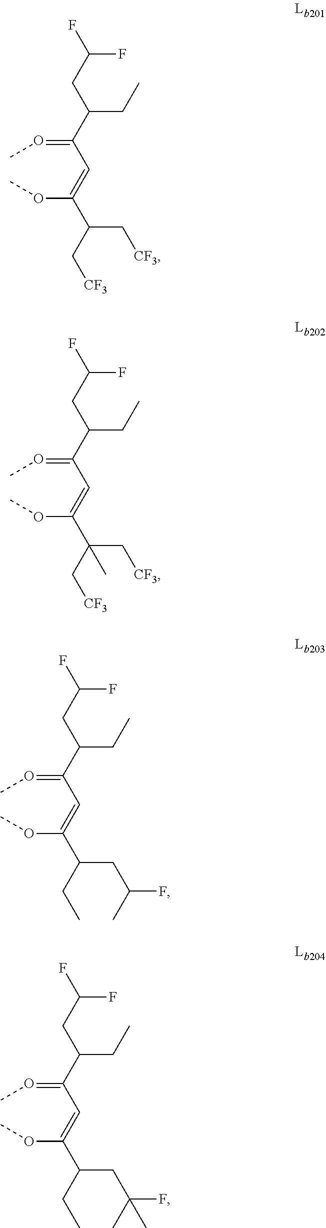 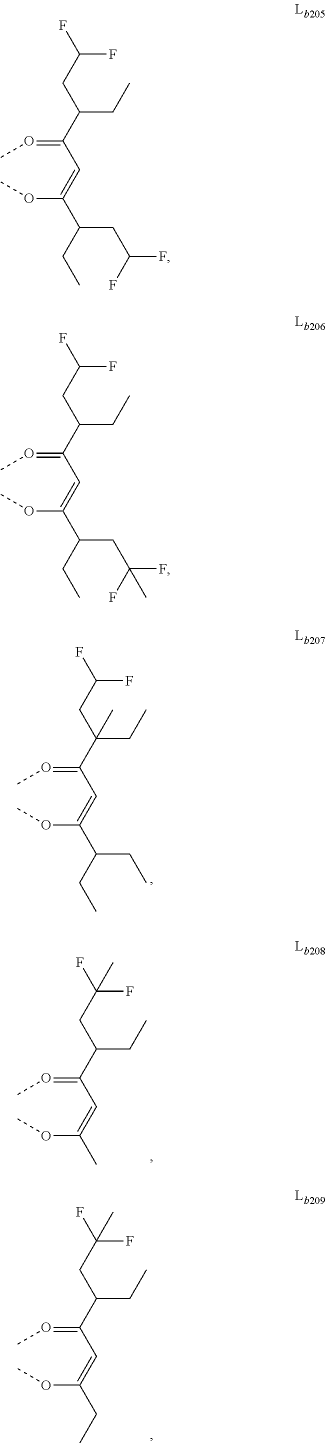 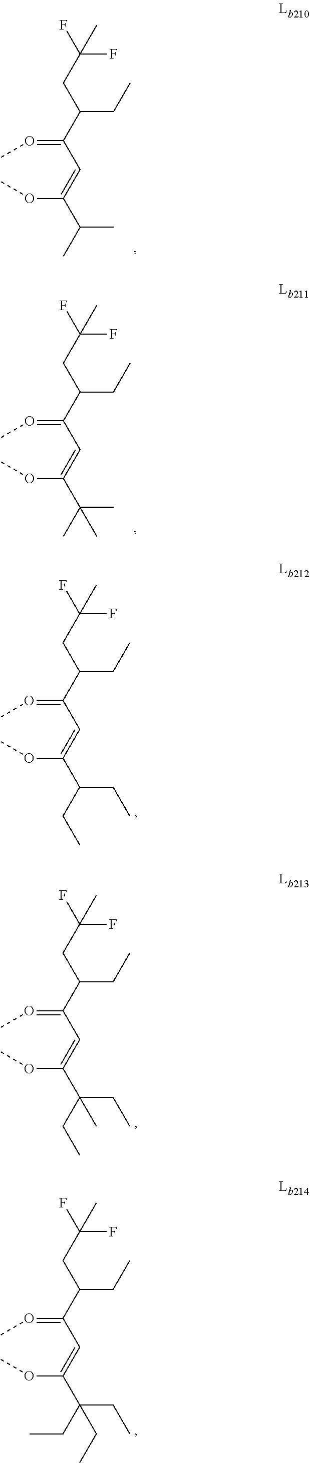 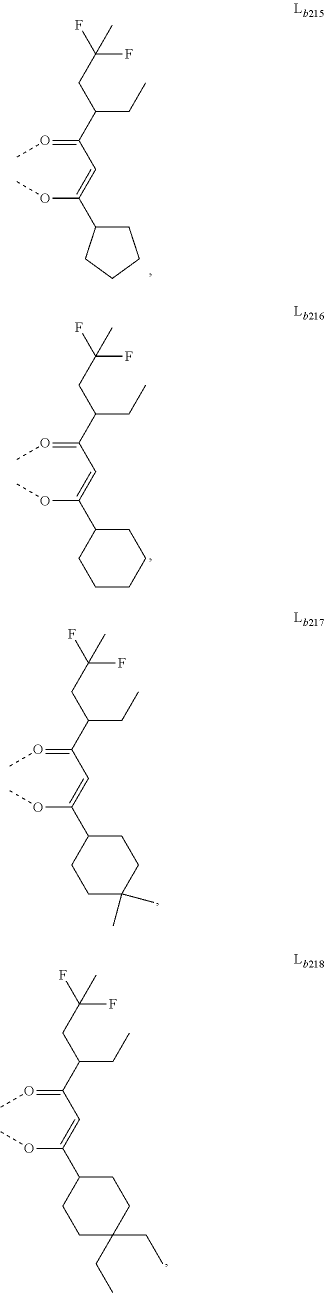 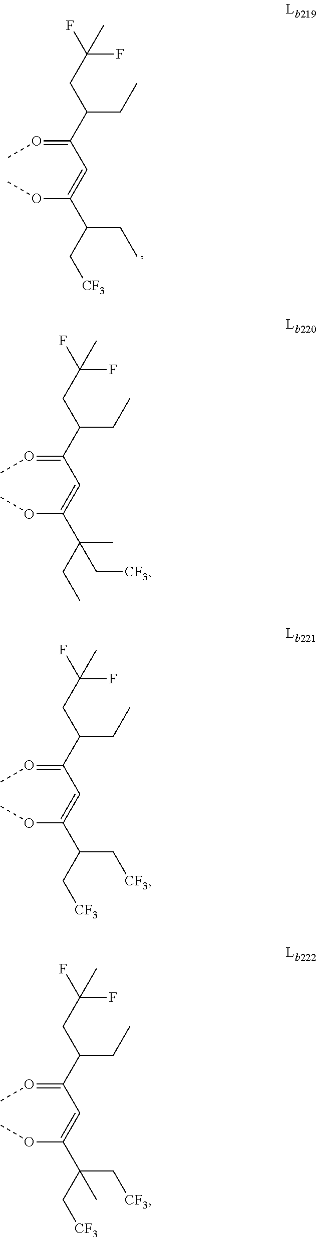 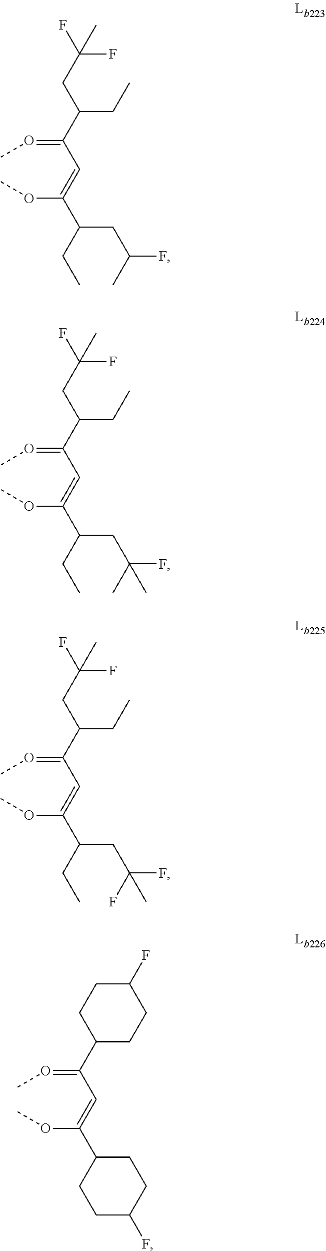 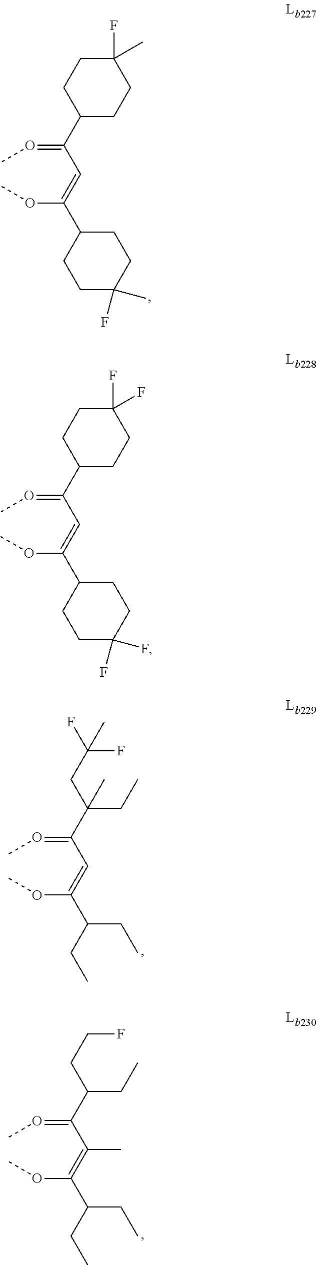 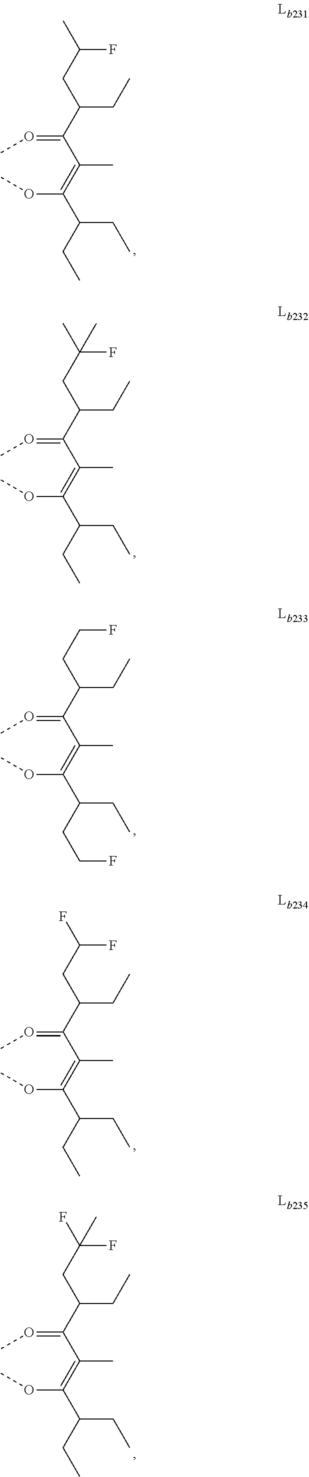 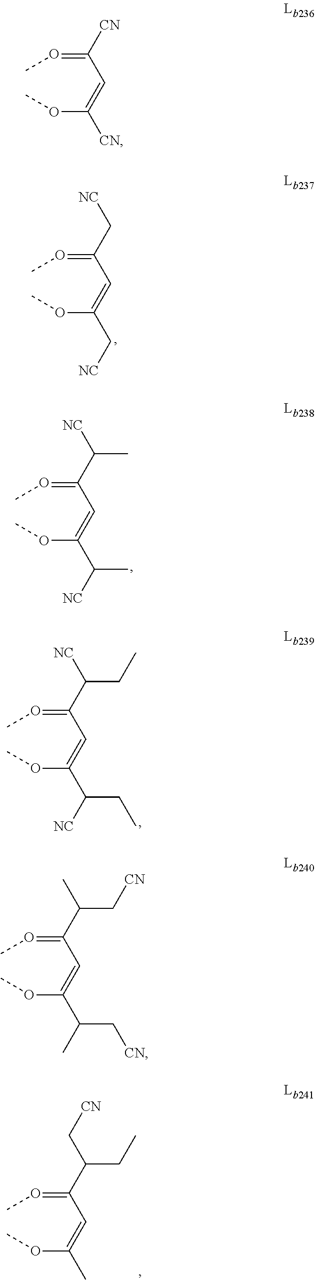 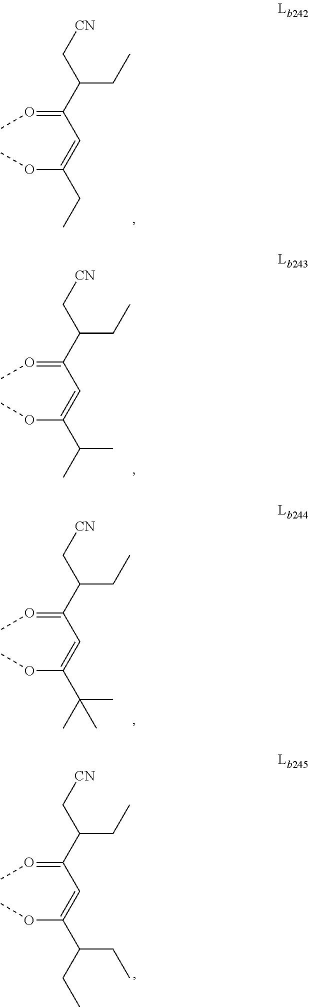 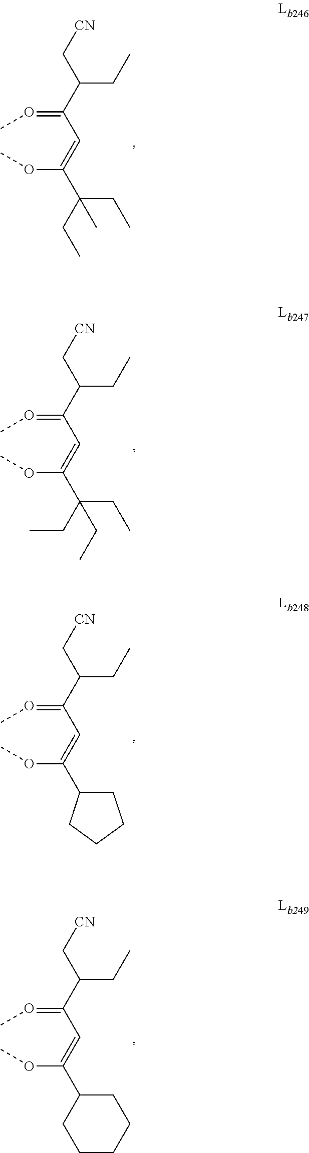 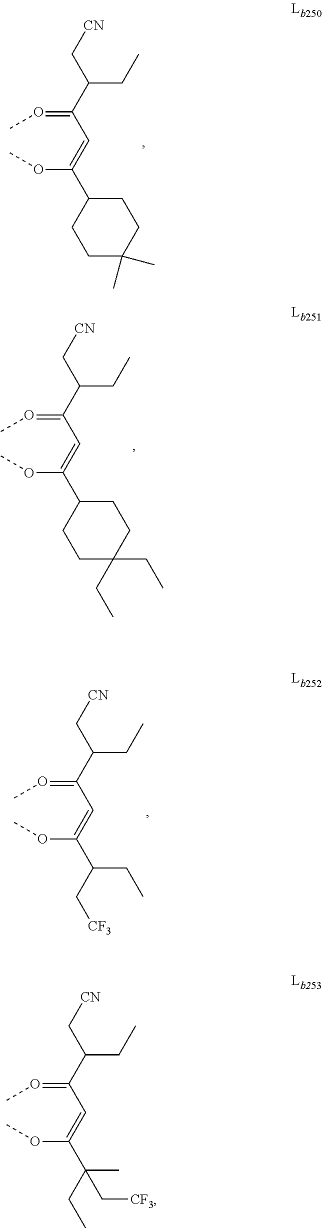 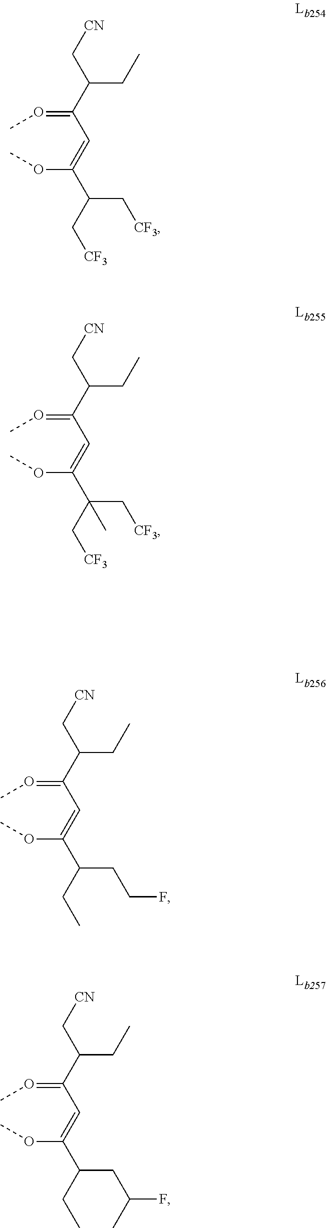 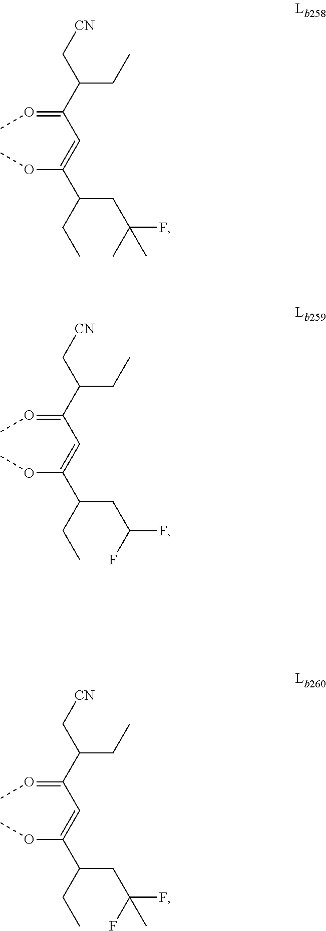 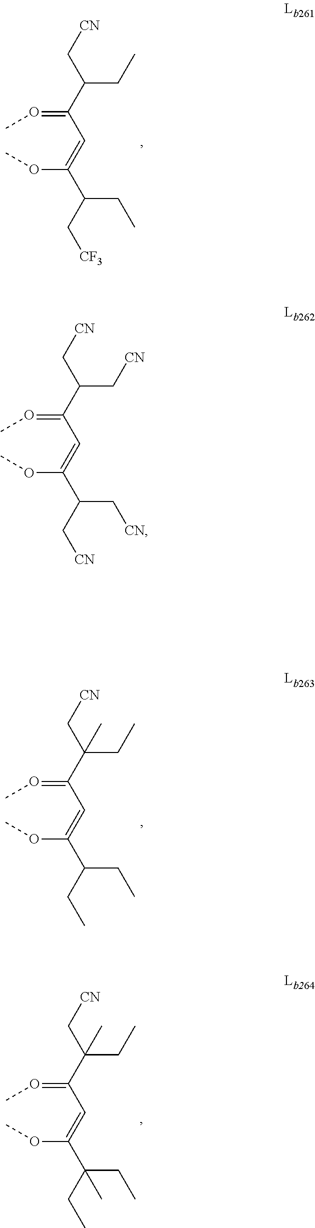 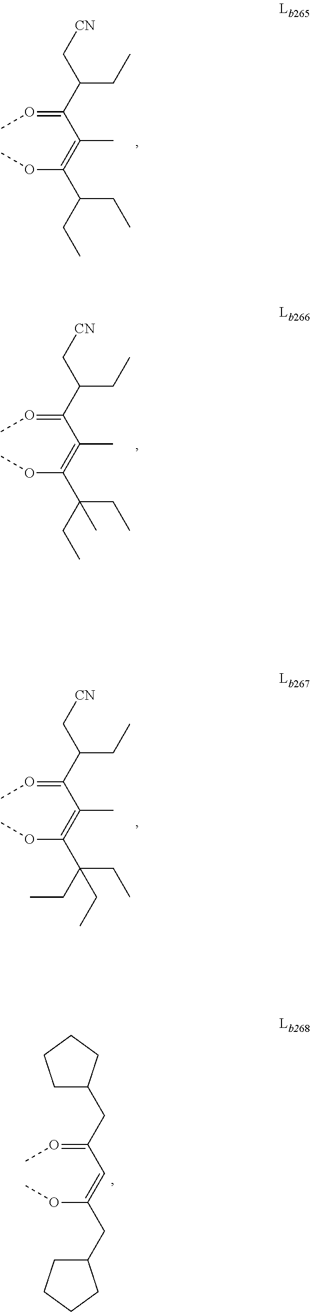 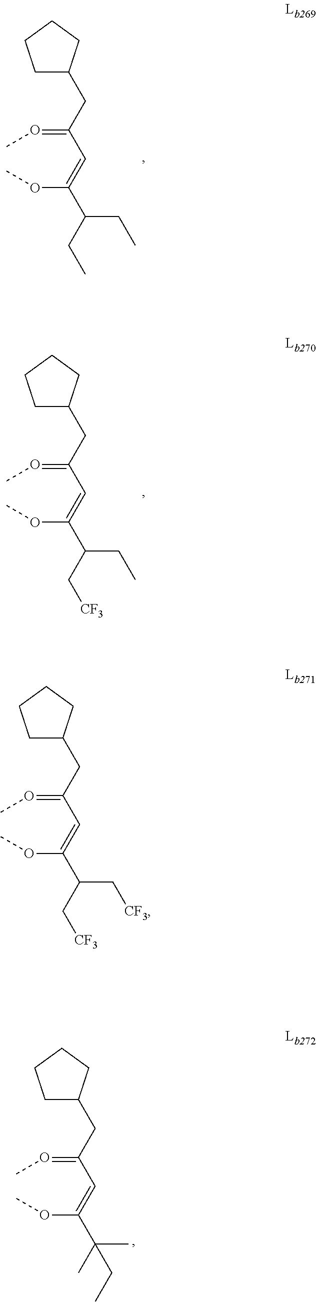 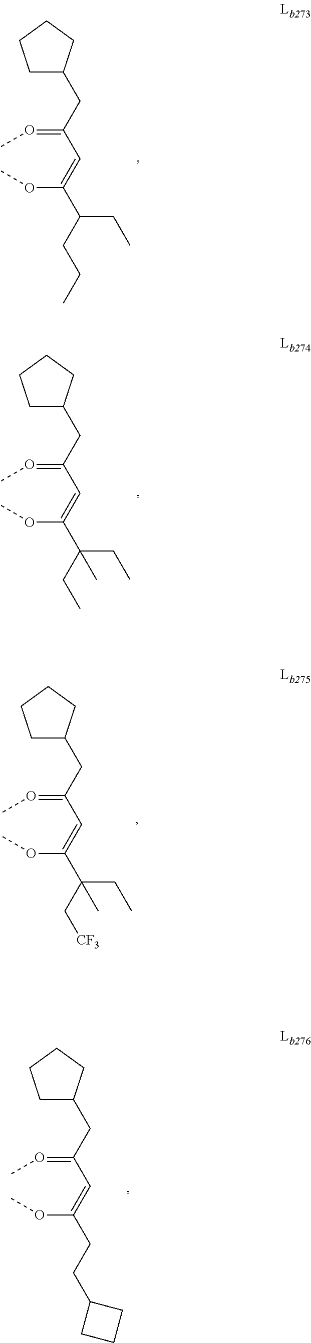 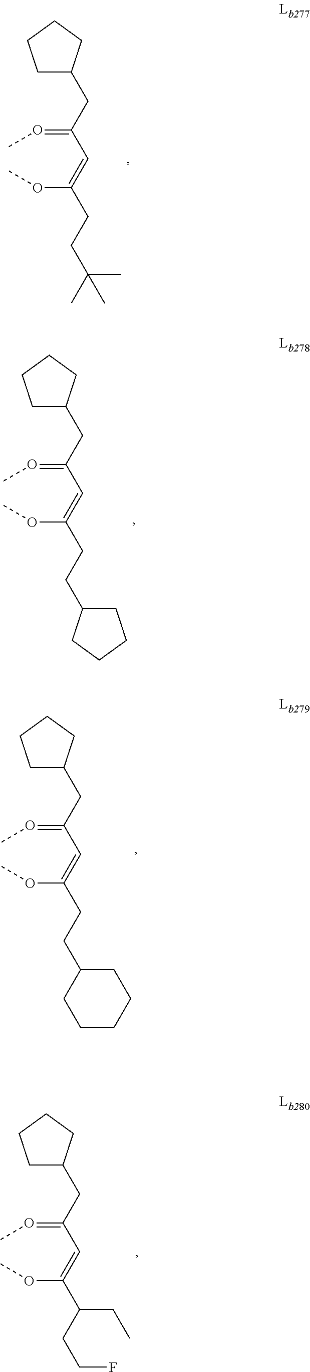 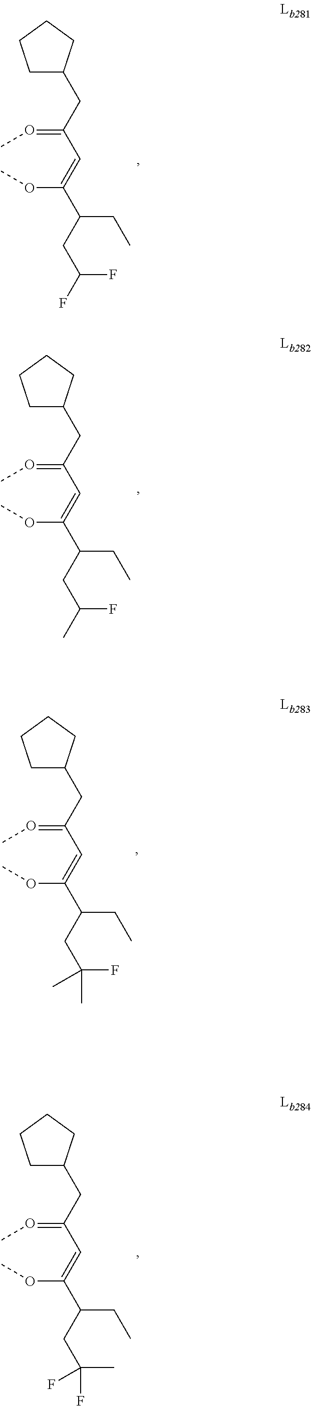 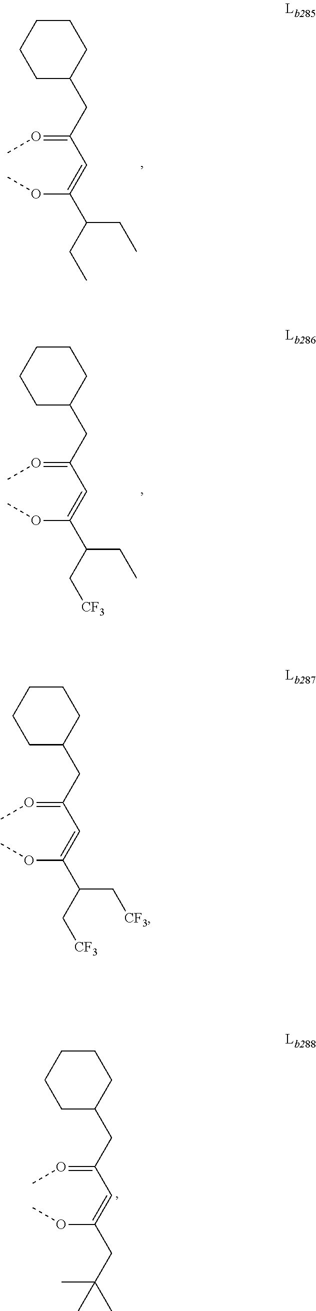 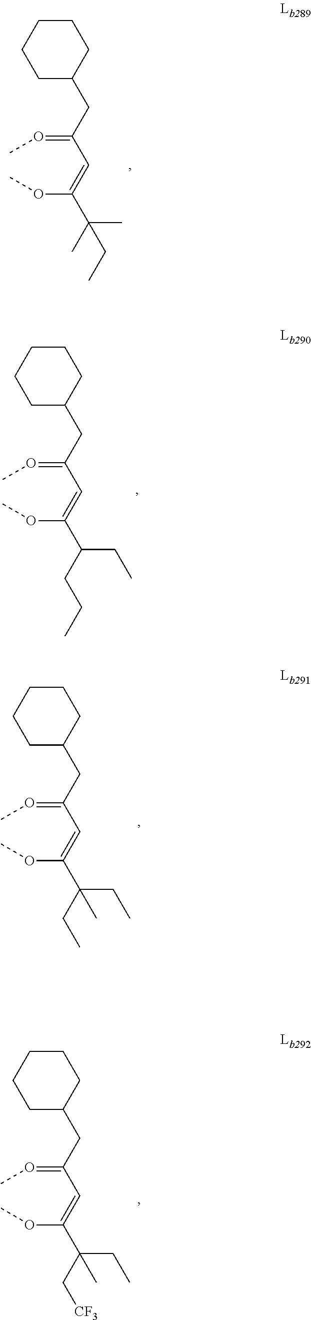 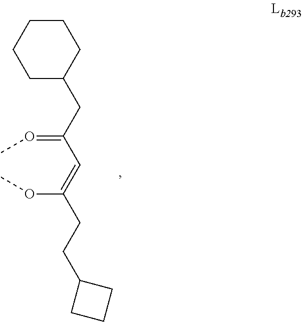 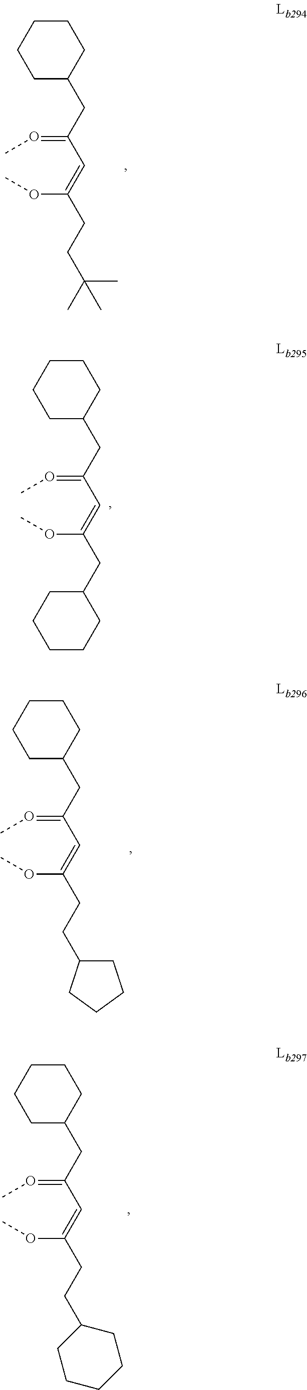 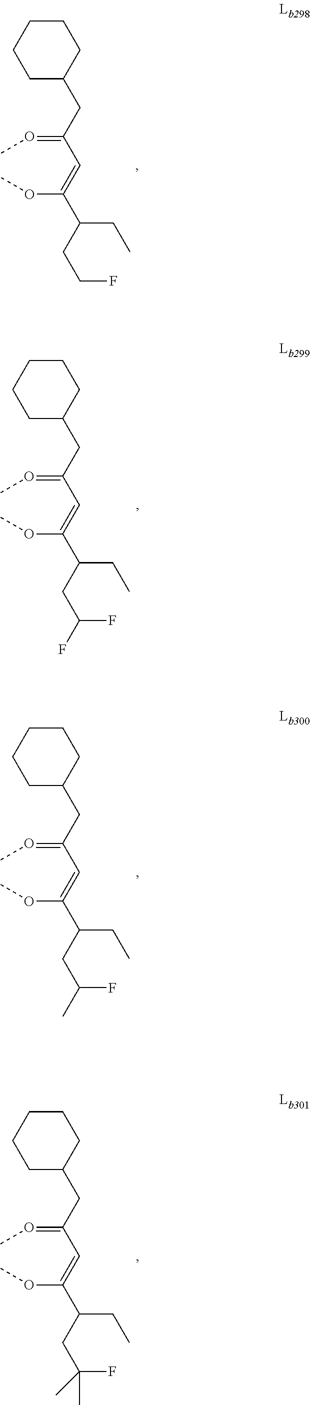 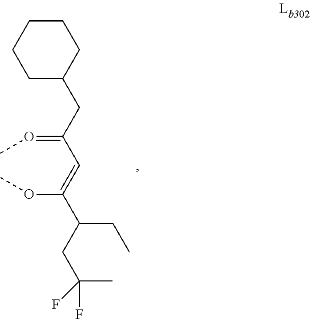 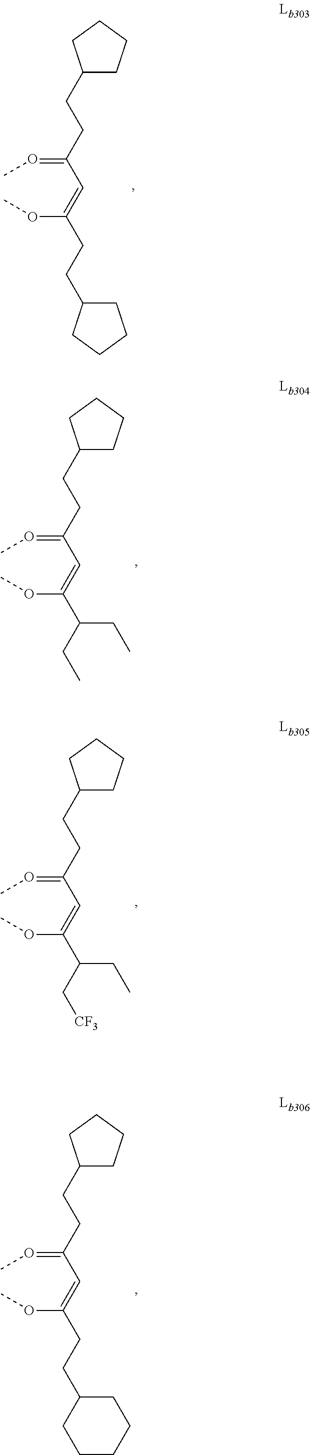 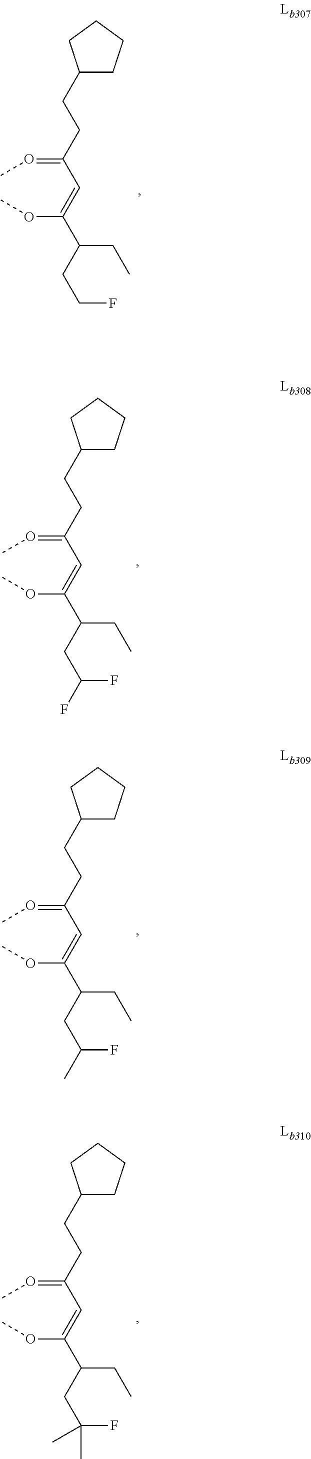 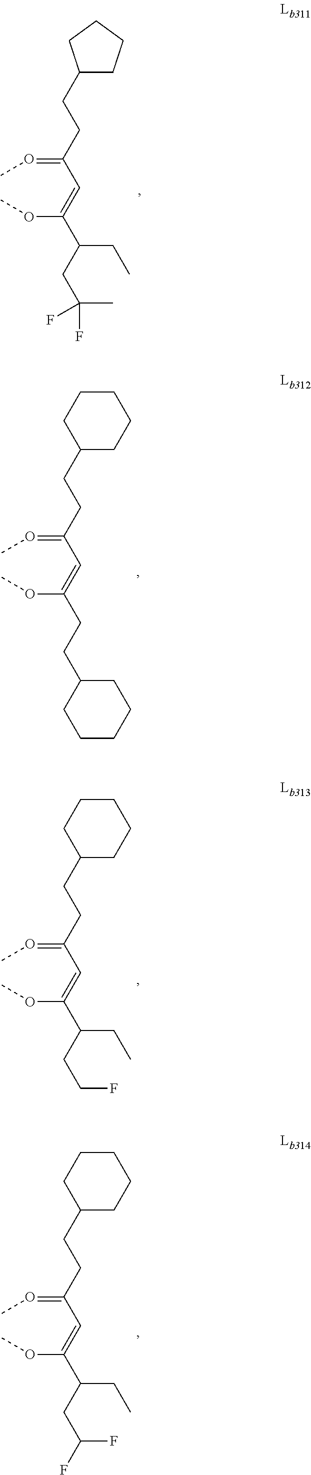 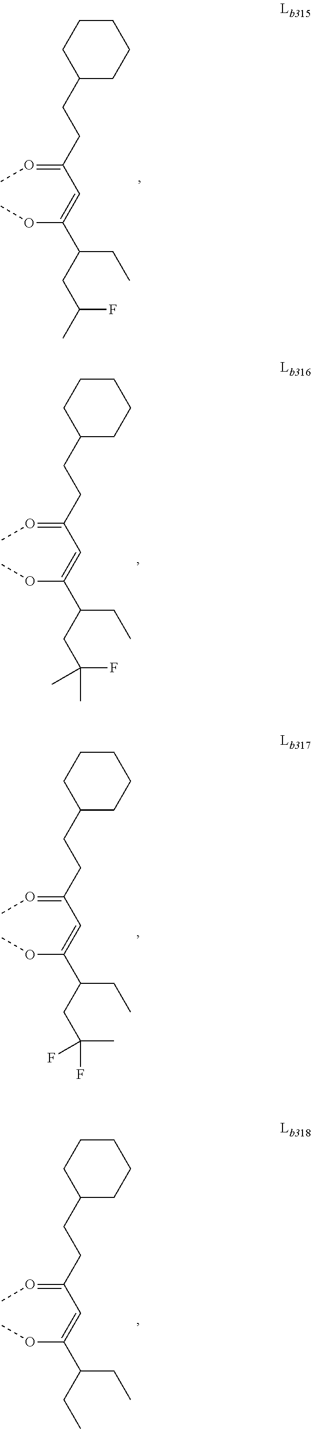 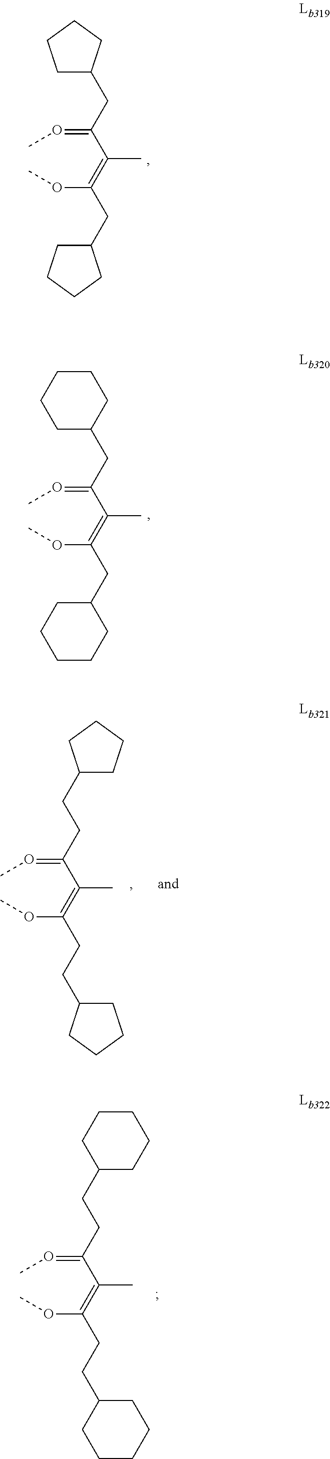
and
wherein L_{c} is, at each occurrence identically or differently, selected from the group consisting of the following structures:

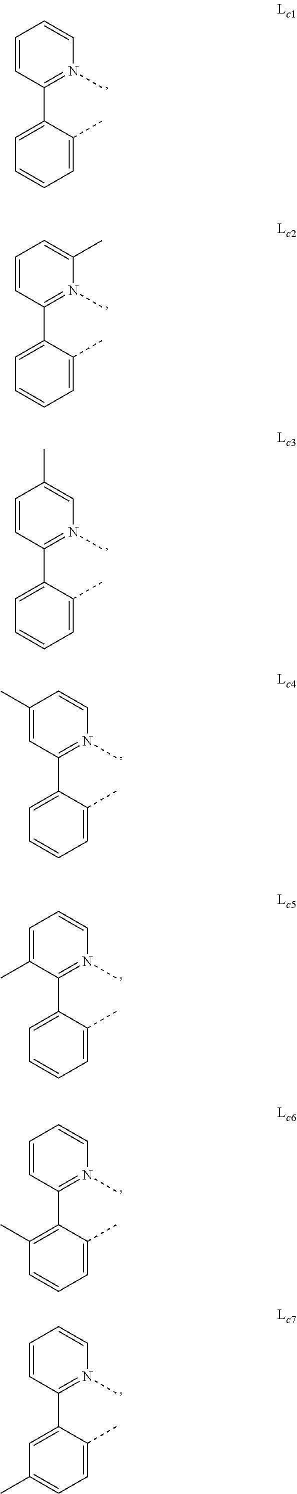

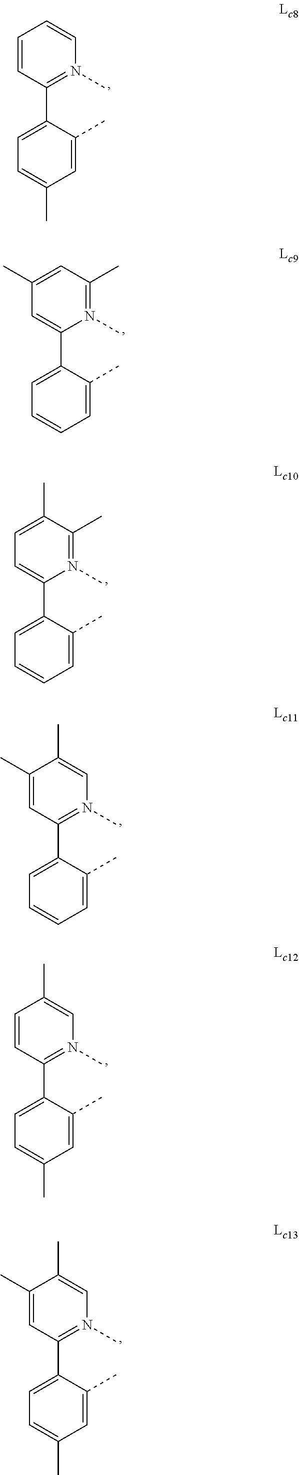

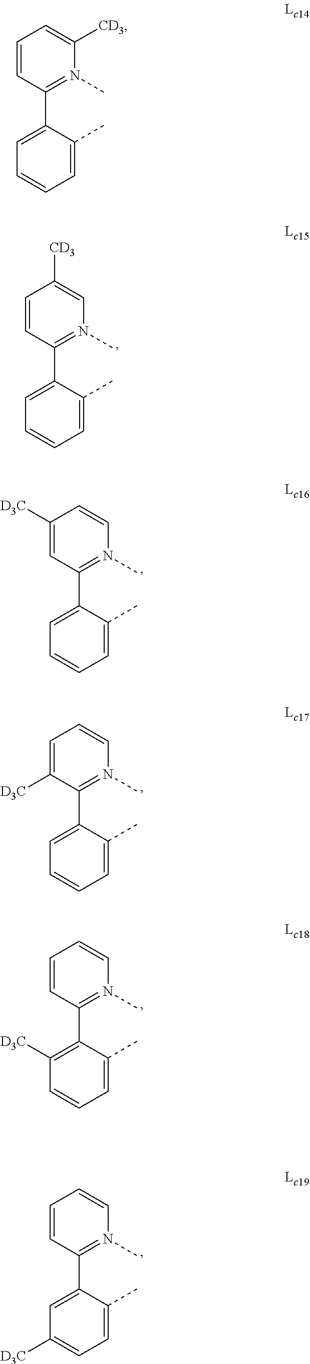

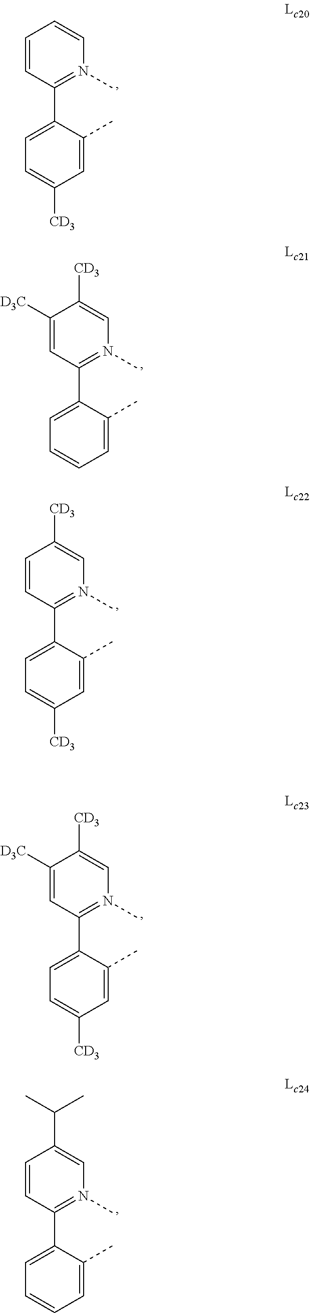

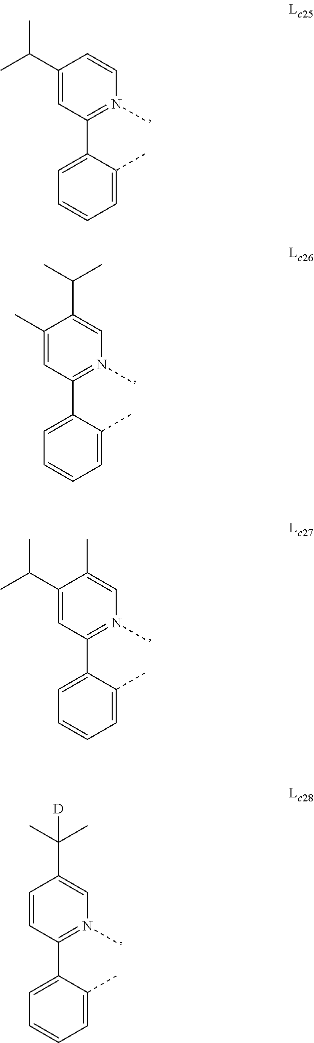

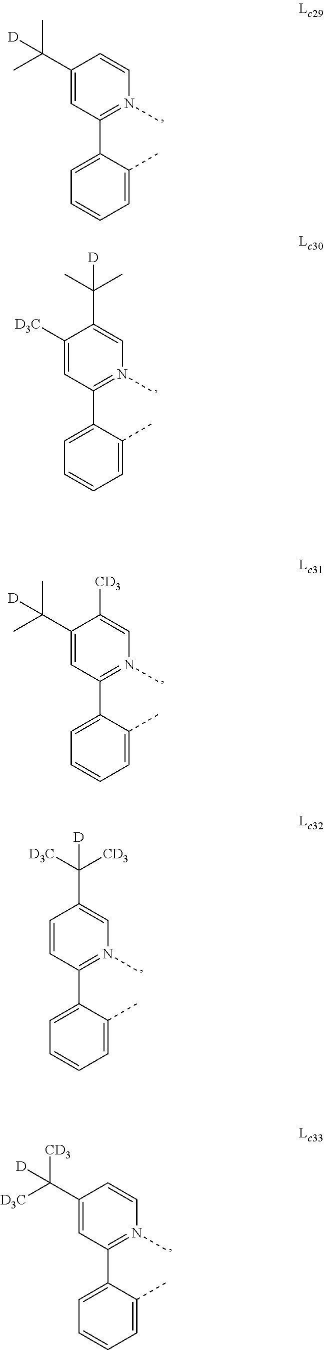

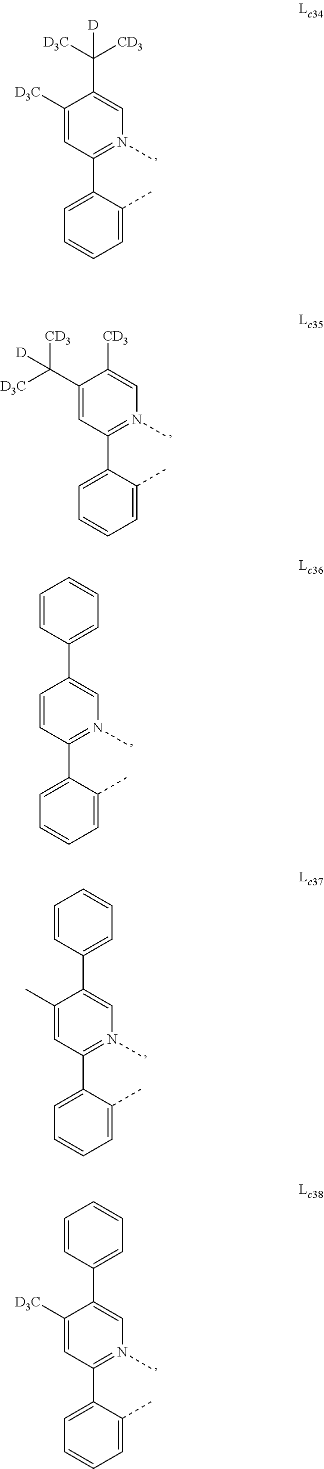

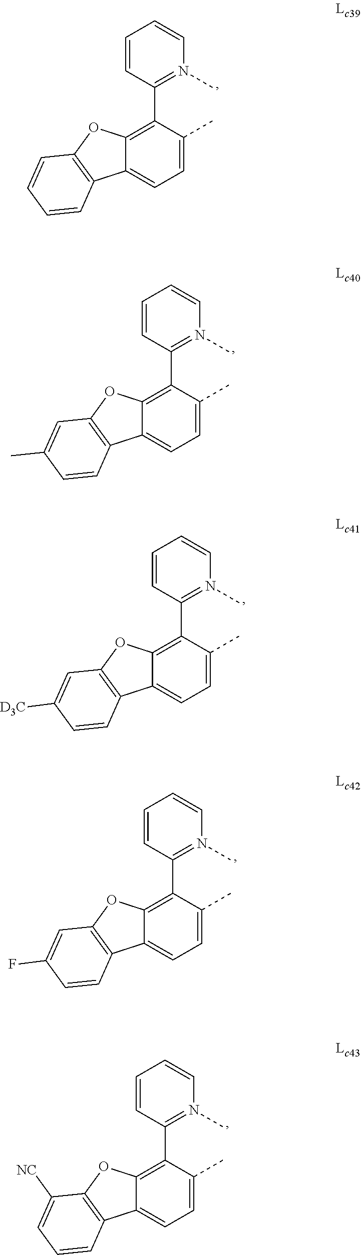

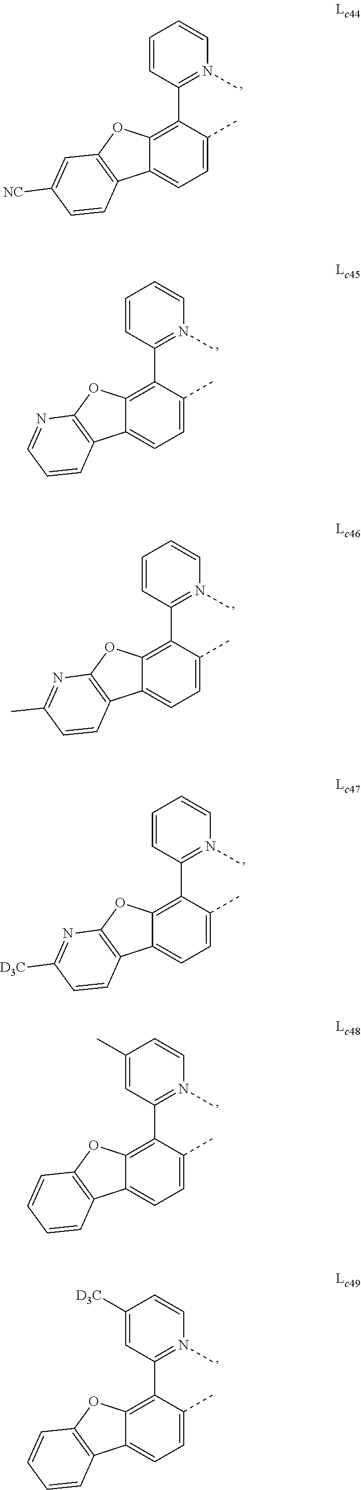

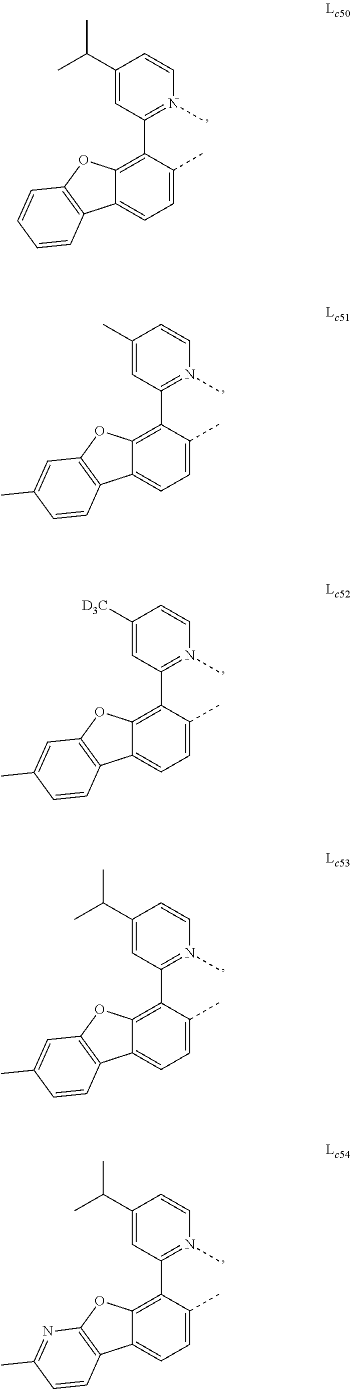

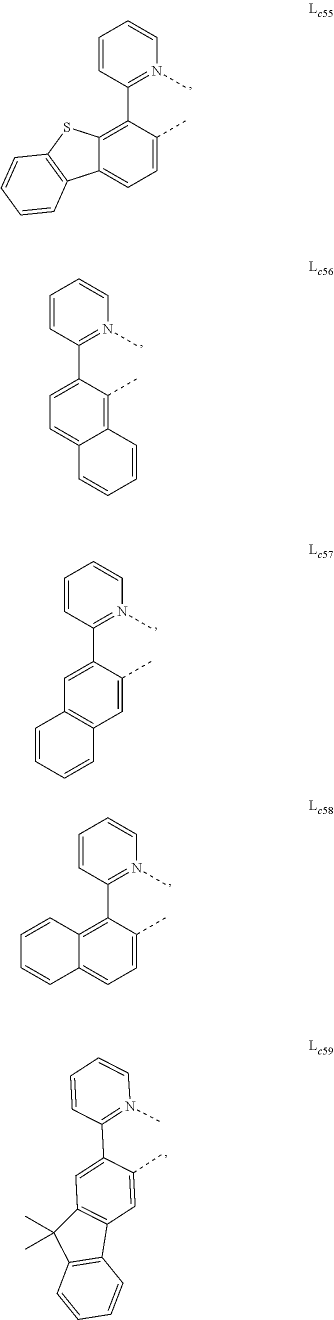

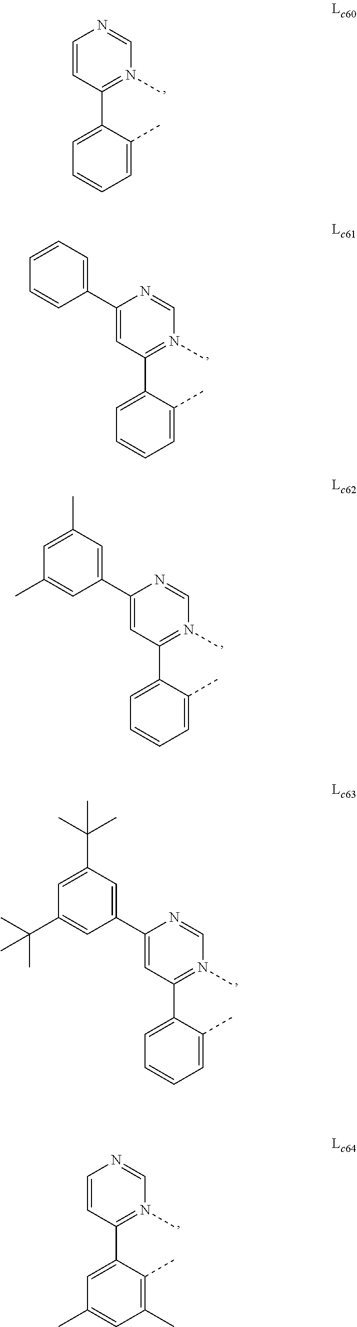

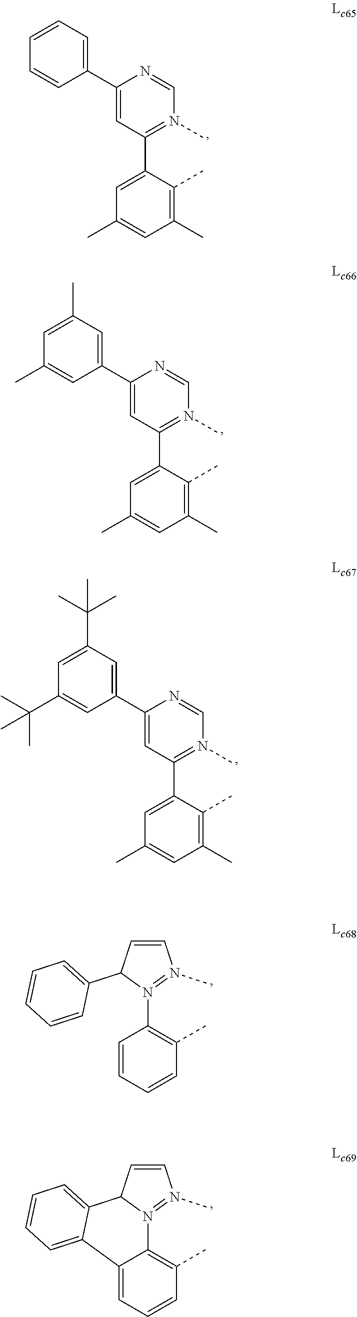

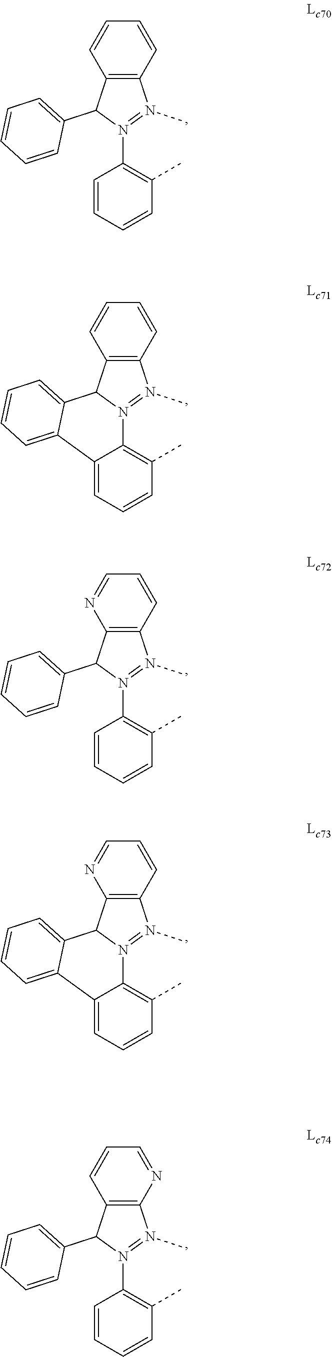

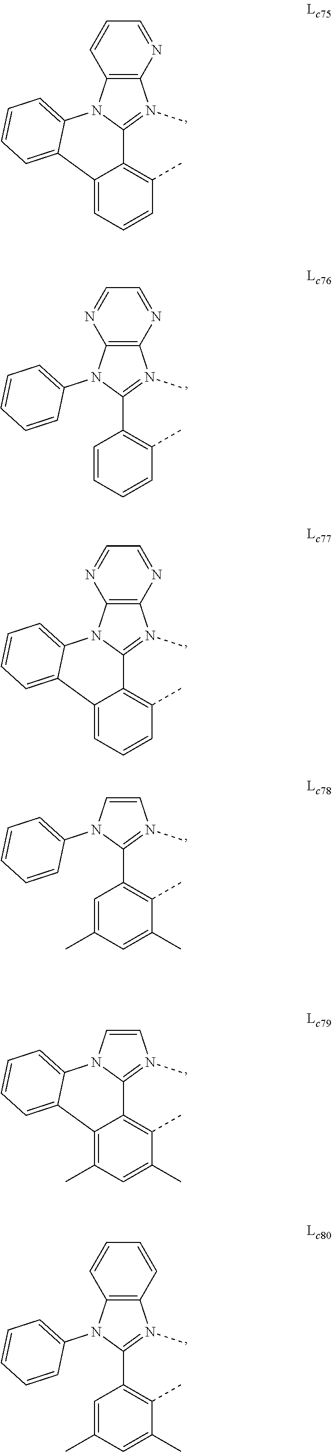

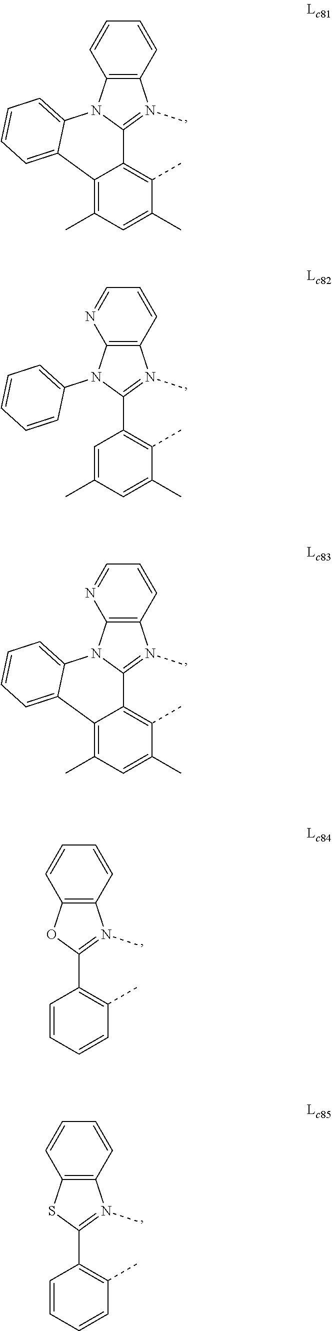

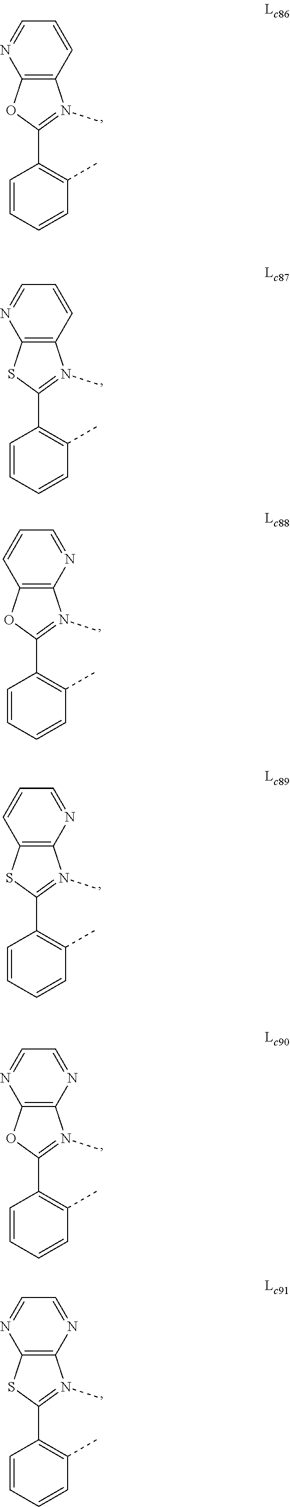

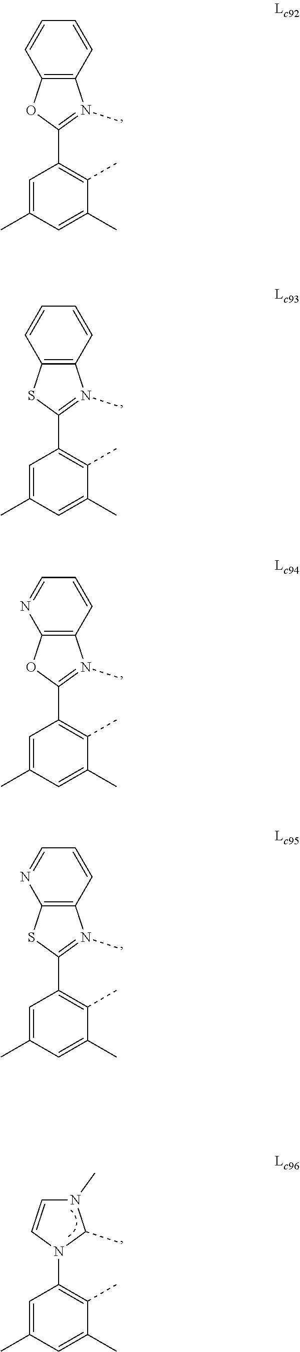

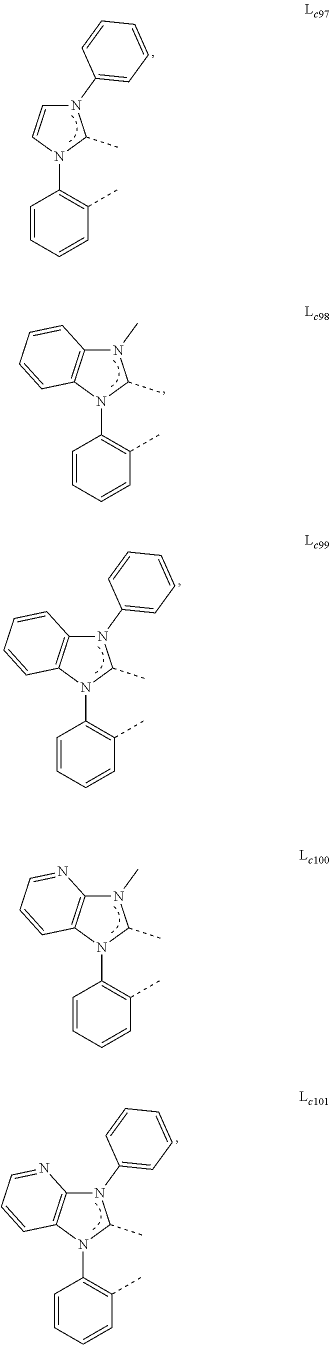

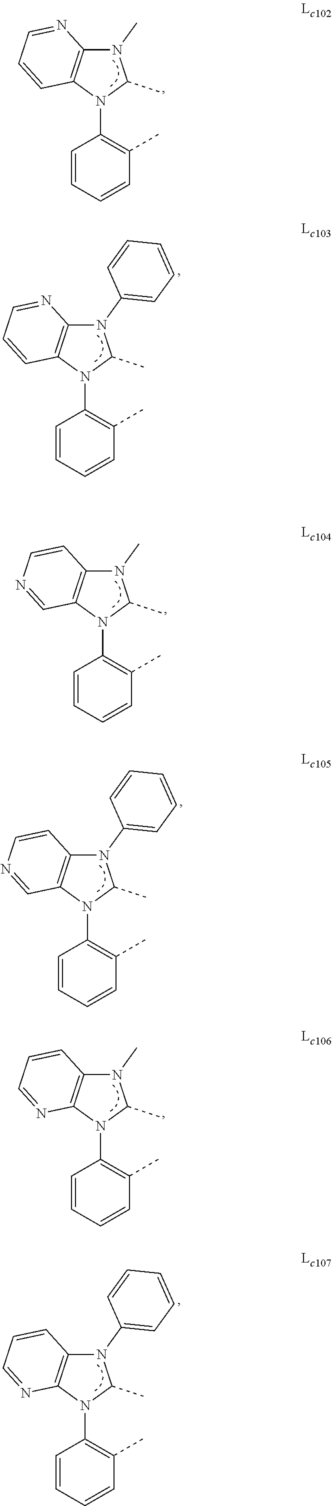

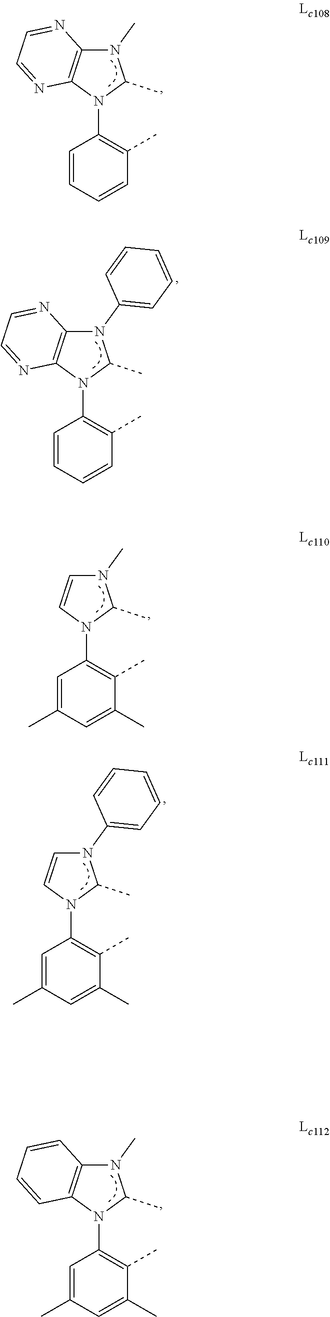

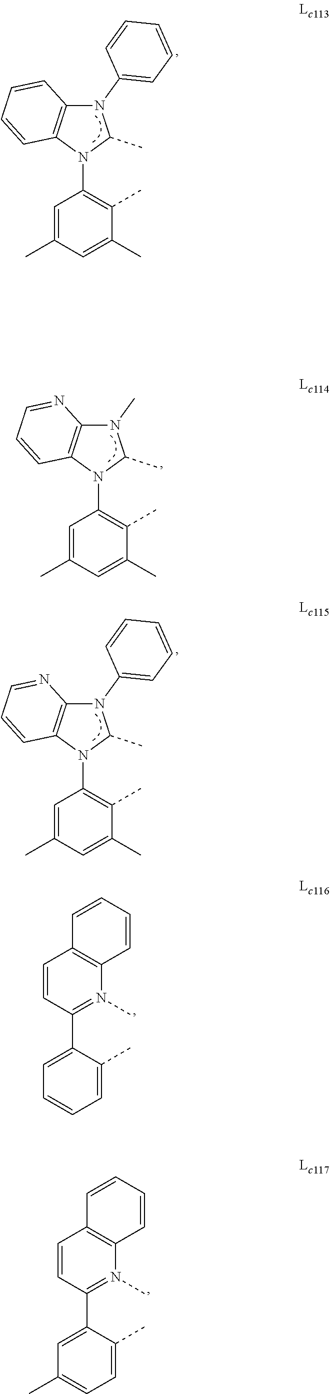

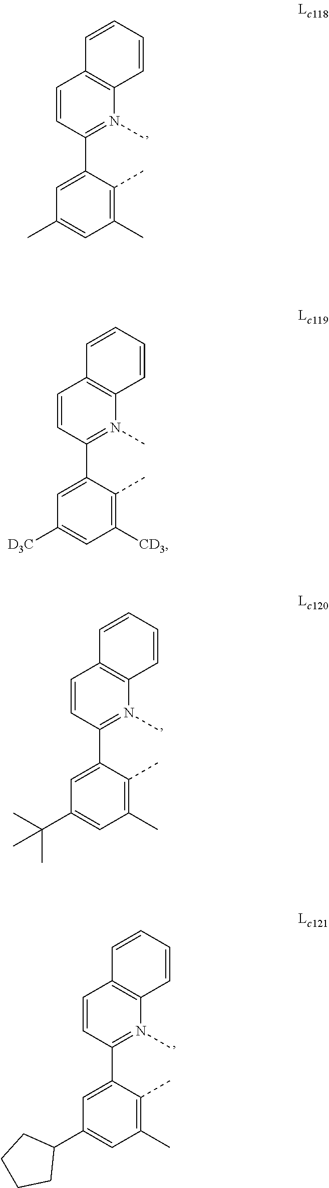

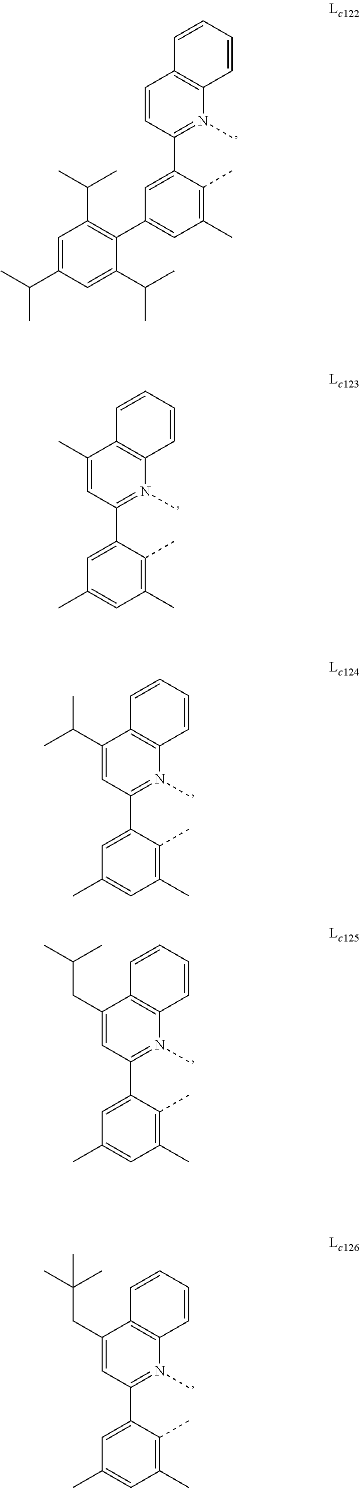

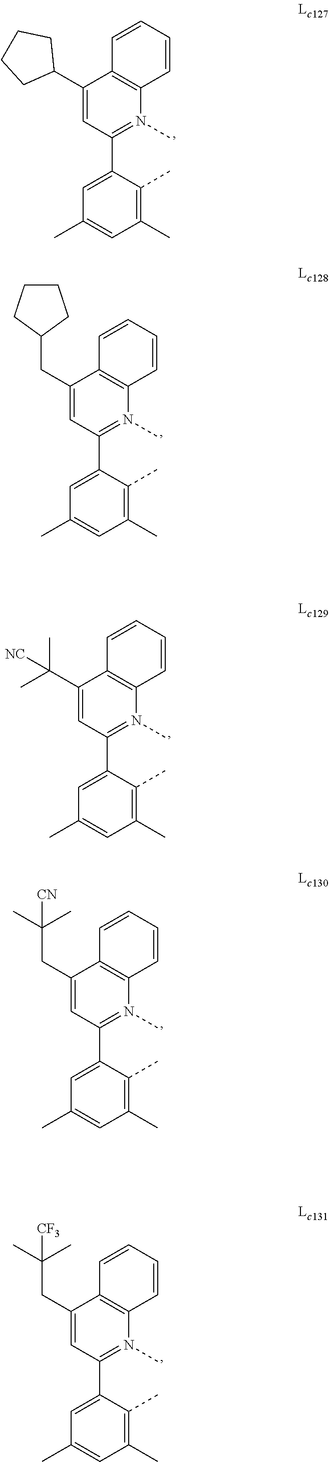

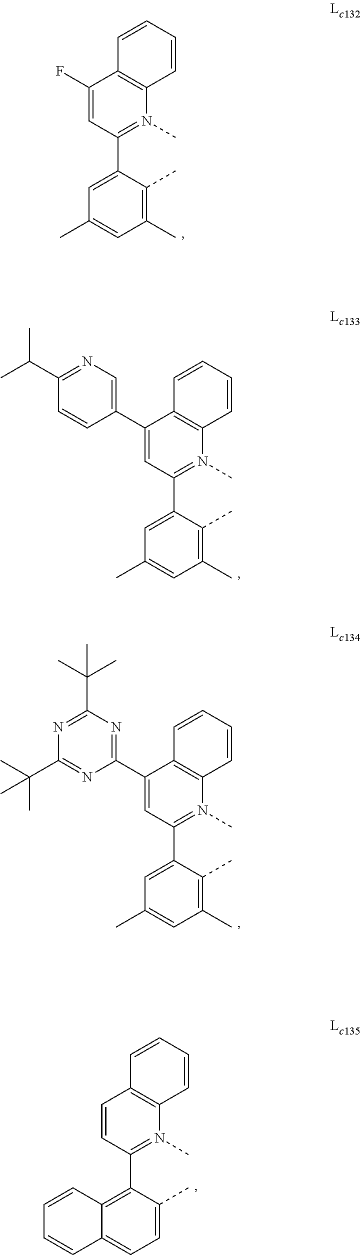

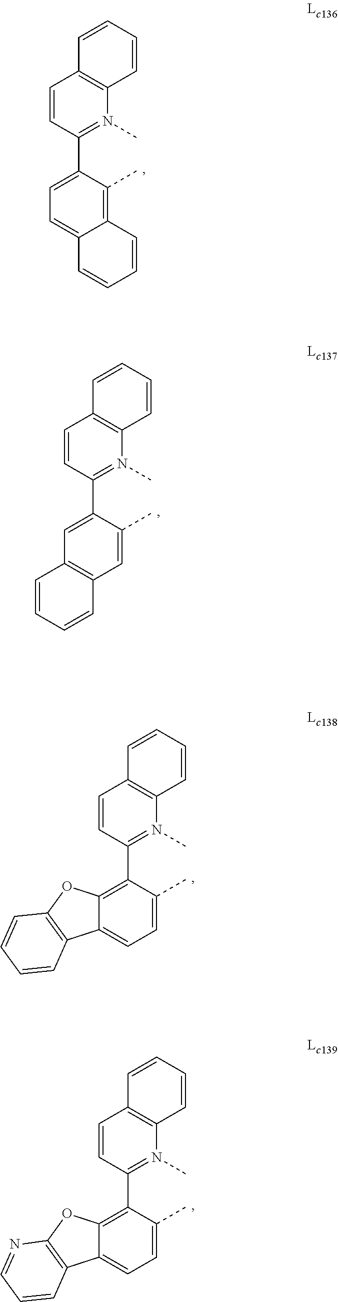

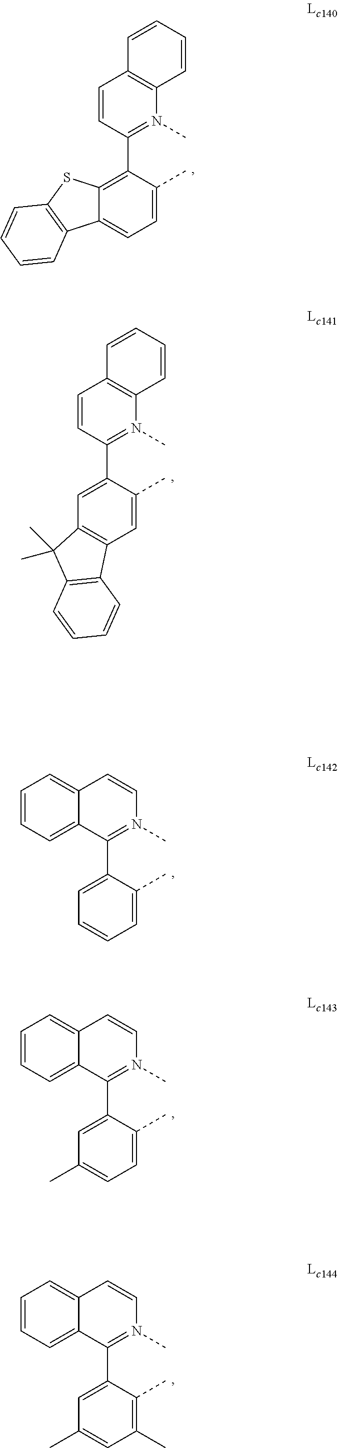

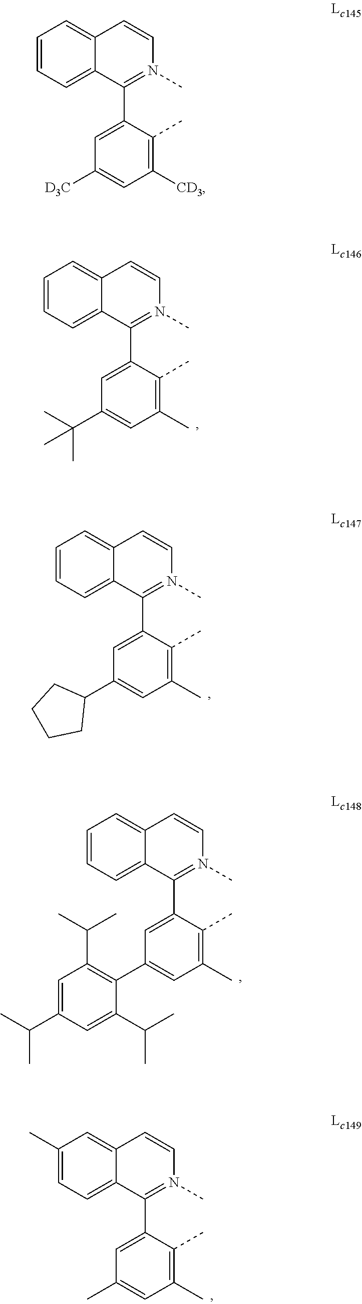

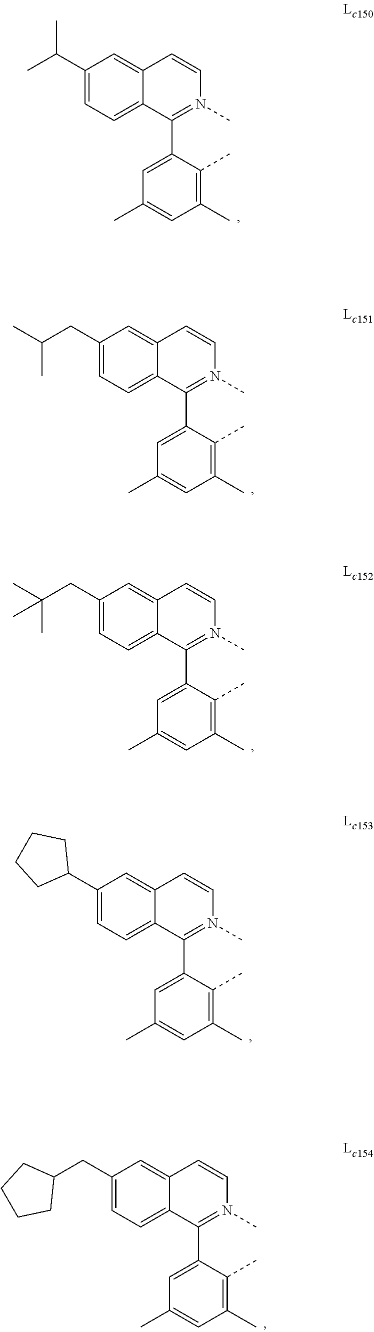

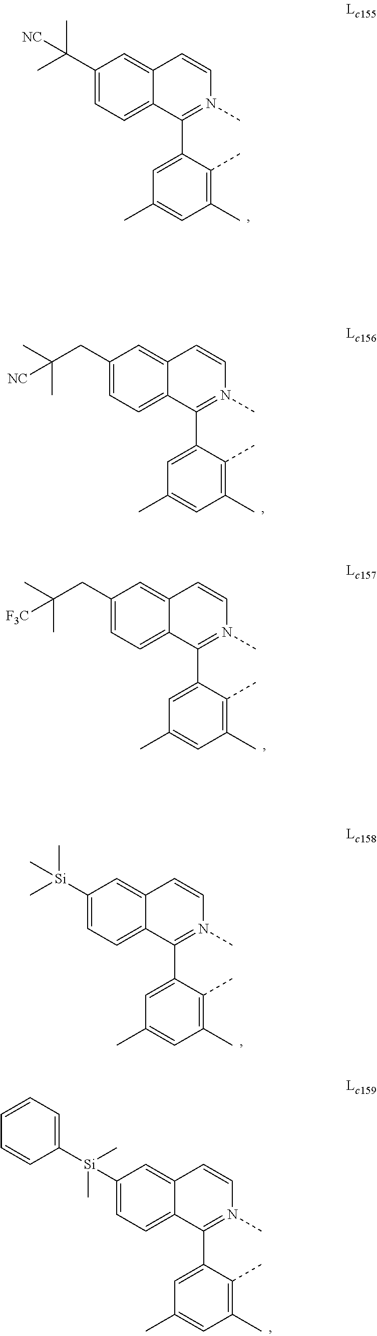

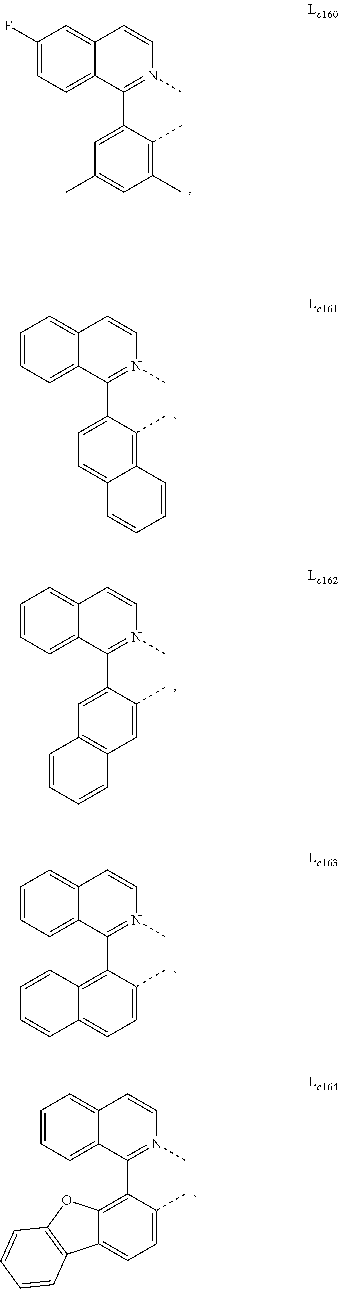

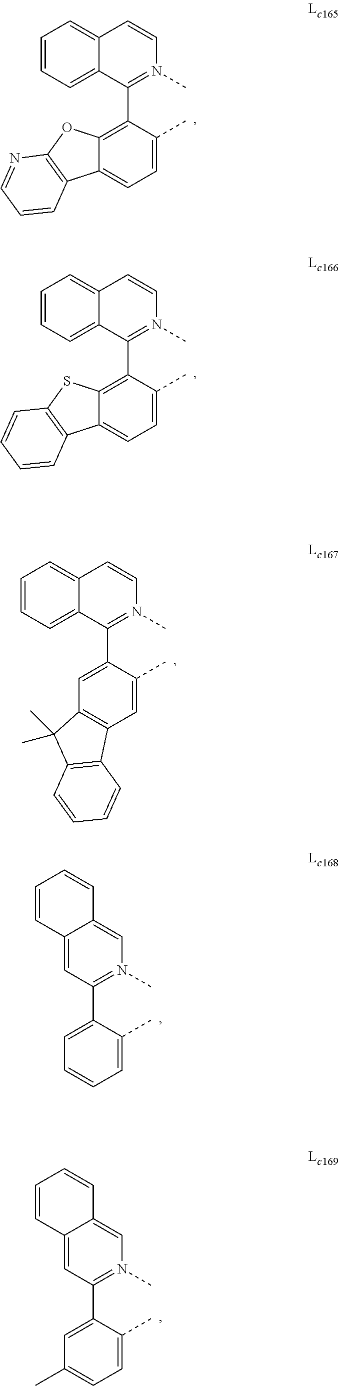

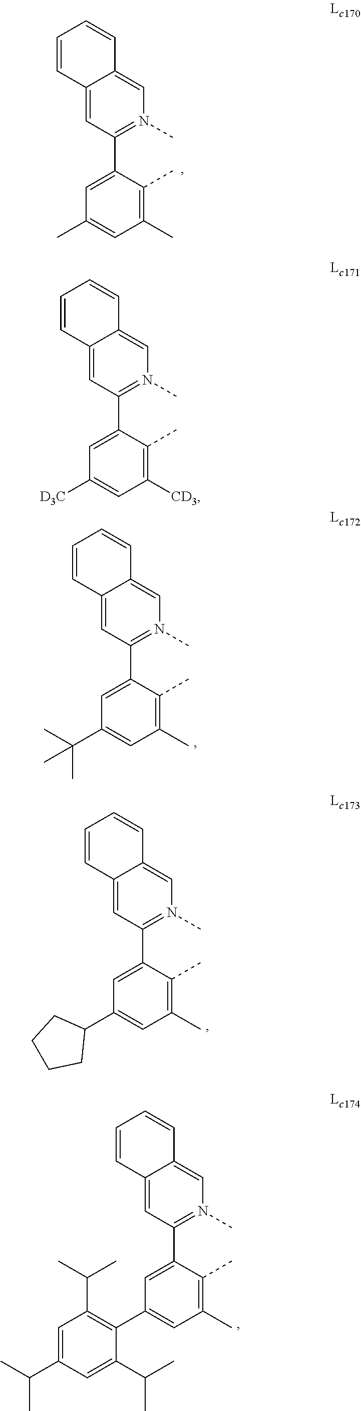

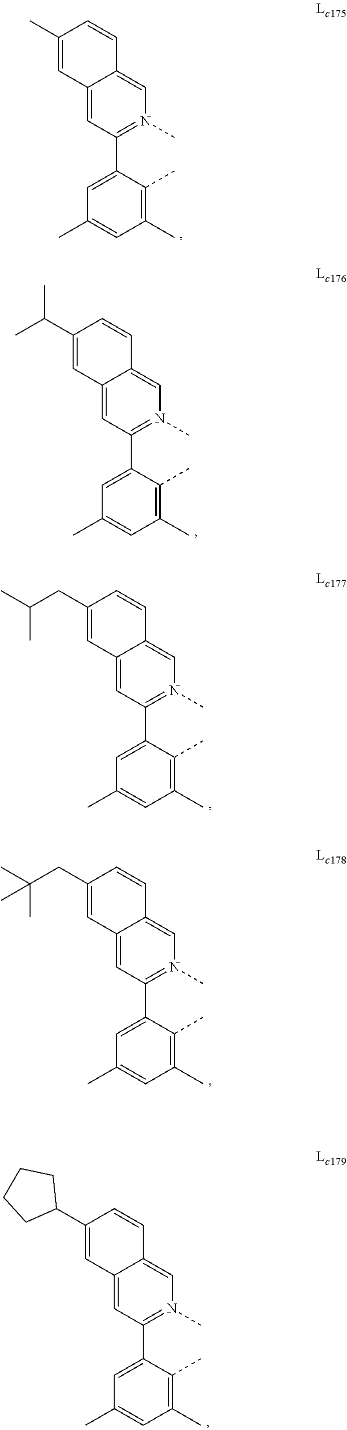

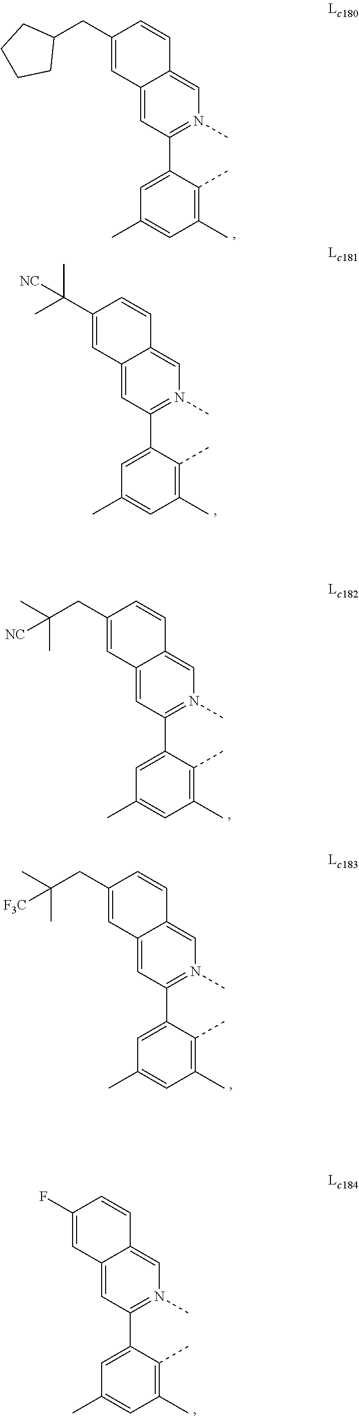

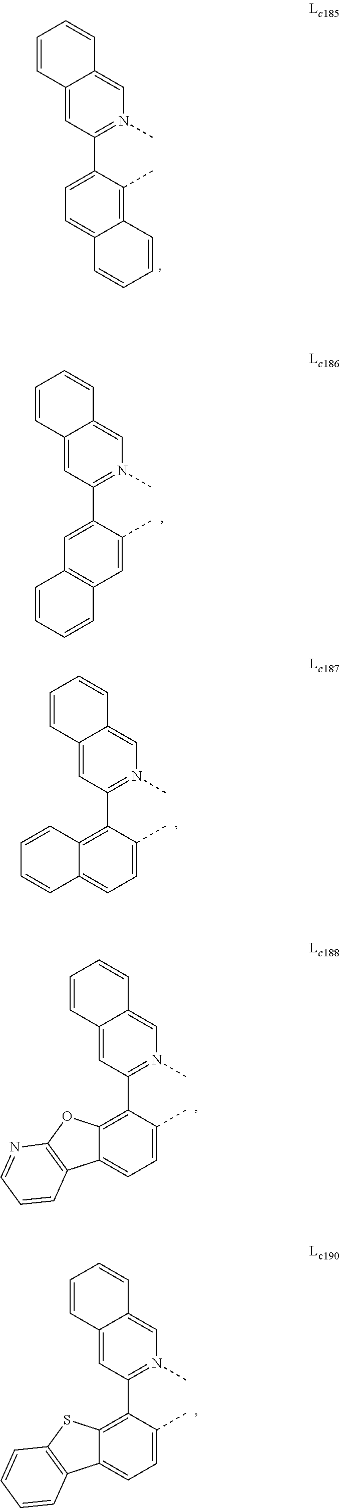

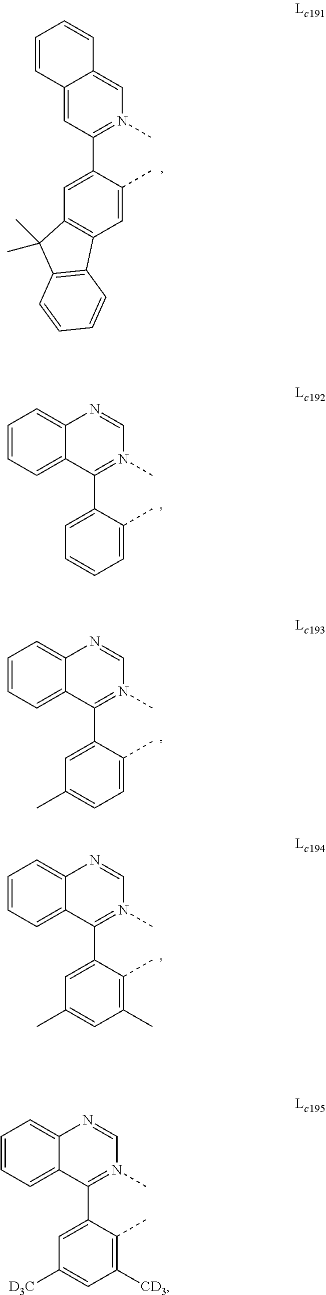

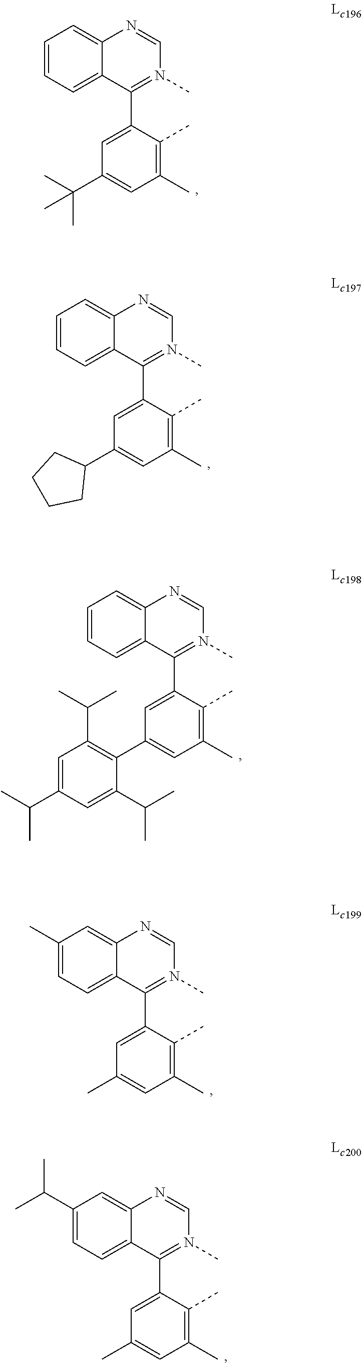

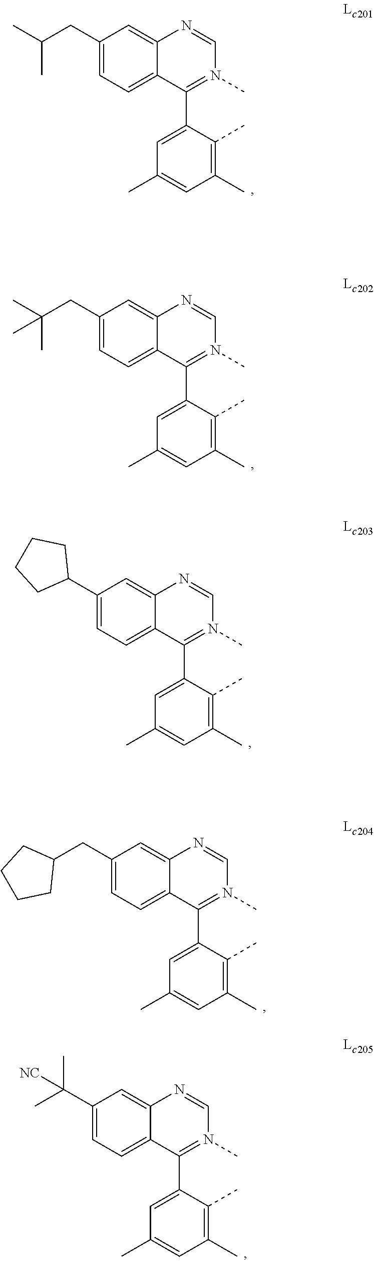

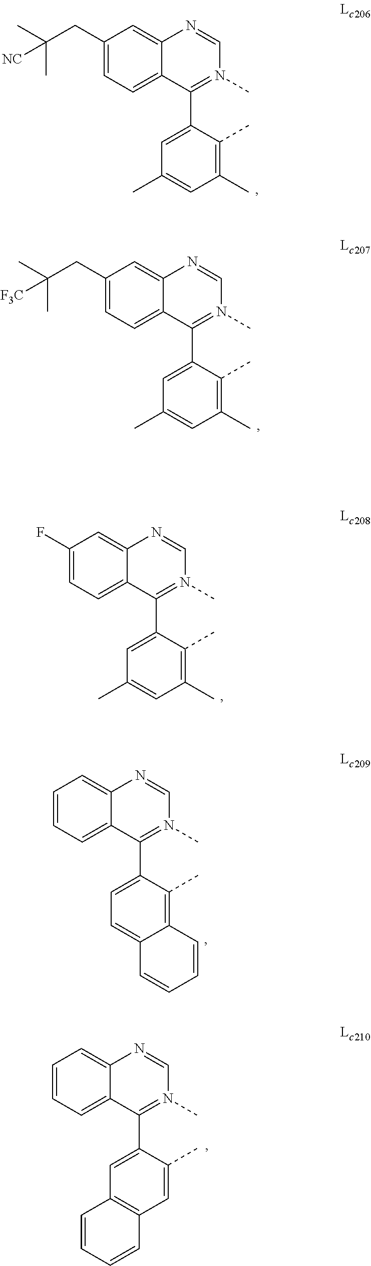

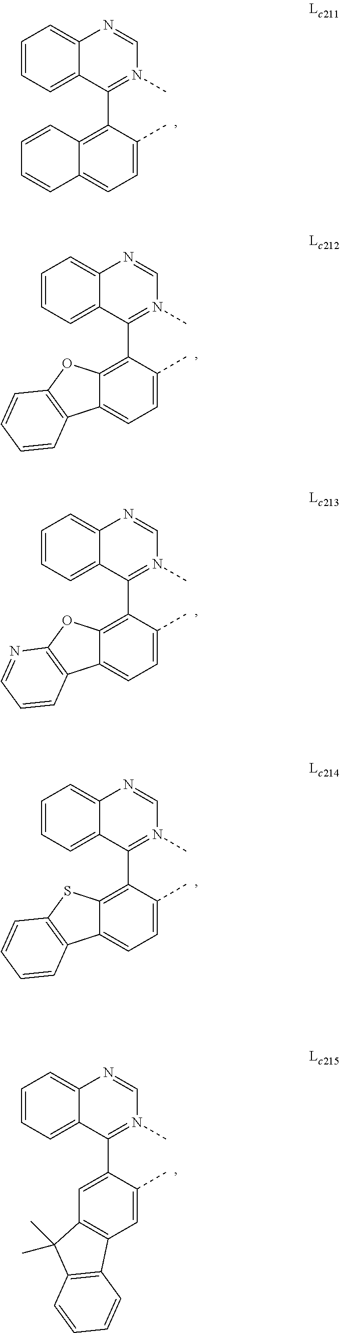

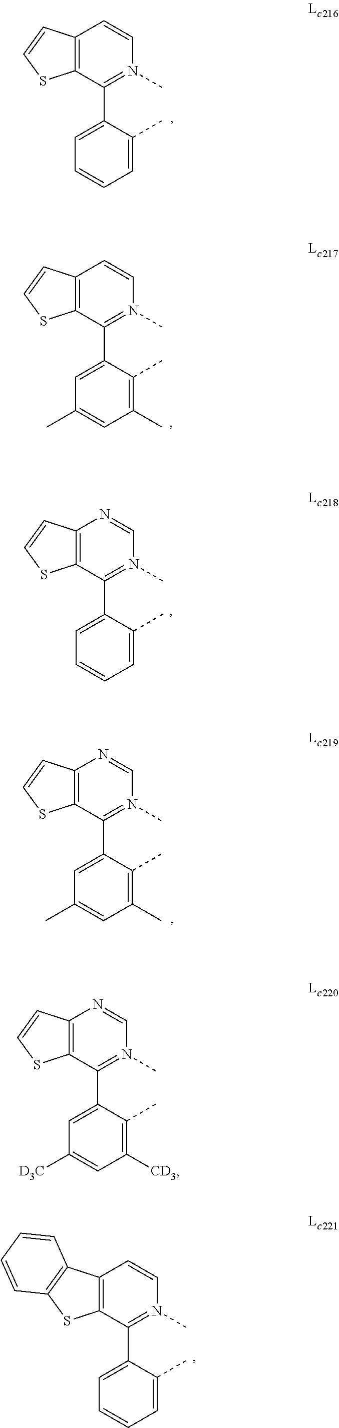

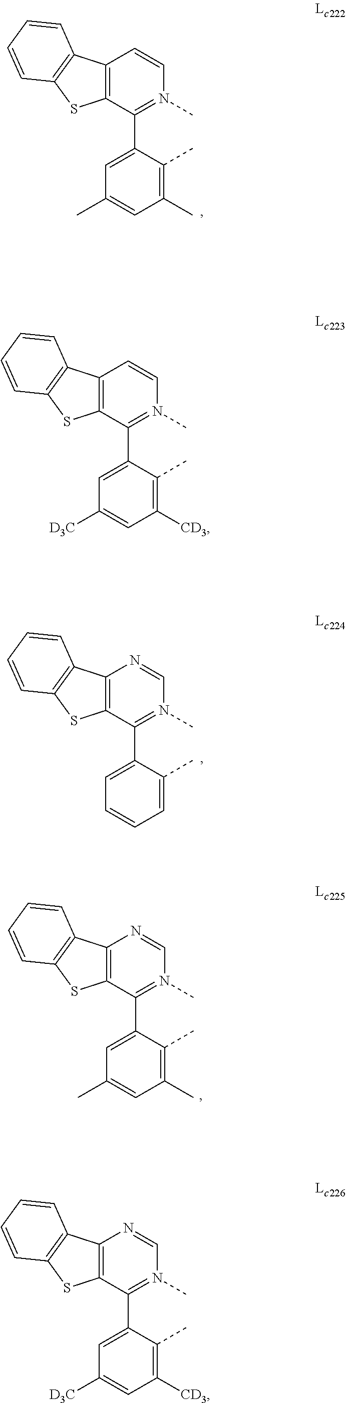

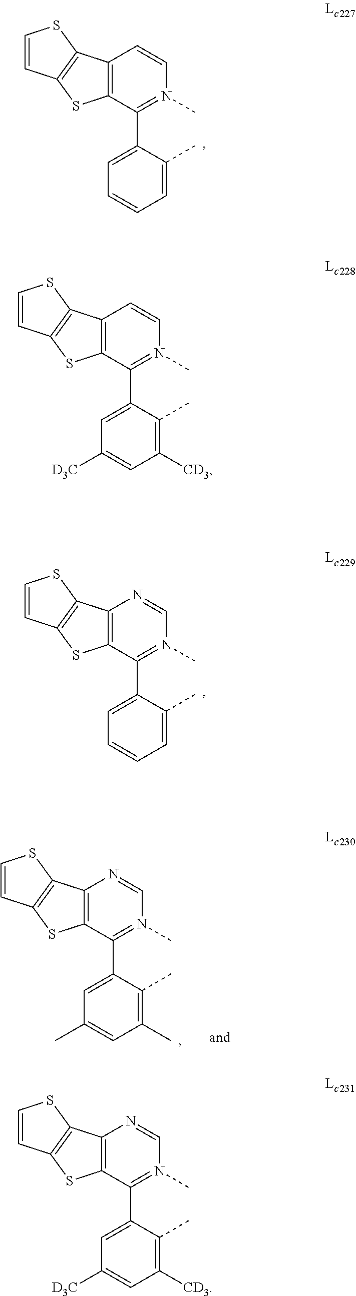

22. The electroluminescent device according to claim 21, wherein the first metal complex has a structure of Ir(Lₐ)₂(L_{b}) or Ir(Lₐ)₂(L_{c}) or Ir(Lₐ)(L_{c})₂;
wherein when the first metal complex has a structure of Ir(Lₐ)₂(L_{b}), Lₐ is, at each occurrence identically or differently, selected from any one or any two of the group consisting of Lₐ₁ to Lₐ₃₁₉, and L_{b} is selected from any one of the group consisting of L_{b1} to L_{b322}; when the first metal complex has a structure of Ir(Lₐ)₂(L_{c}), Lₐ is, at each occurrence identically or differently, selected from any one or any two of the group consisting of Lₐ₁ to Lₐ₃₁₉, and L_{c} is selected from any one of the group consisting of L_{c1} to L_{c231}; when the first metal complex has a structure of Ir(Lₐ)(L_{c})₂, Lₐ is selected from any one of the group consisting of Lₐ₁ to Lₐ₃₁₉, and L_{c} is, at each occurrence identically or differently, selected from any one or any two of the group consisting of L_{c1} to L_{c231};
preferably, the first metal complex is selected from the group consisting of Compound 1 to Compound 612;
wherein Compound 1 to Compound 492 have a structure of Ir(Lₐ)₂(L_{b}), wherein two Lₐ are identical and Lₐ and L_{b} are respectively selected from structures listed in the following table:

| Compound No. | Lₐ | L_{b} | Compound No. | Lₐ | L_{b} |
|---|---|---|---|---|---|
| 1 | Lₐ₁ | L_{b1} | 2 | Lₐ₂ | L_{b1} |
| 3 | Lₐ₄ | L_{b1} | 4 | Lₐ₇ | L_{b1} |
| 5 | Lₐ₁ | L_{b1} | 6 | Lₐ₁₉ | L_{b1} |
| 7 | Lₐ₂₈ | L_{b1} | 8 | Lₐ₃₇ | L_{b1} |
| 9 | Lₐ₄₂ | L_{b1} | 10 | Lₐ₄₇ | L_{b1} |
| 11 | Lₐ₅₃ | L_{b1} | 12 | Lₐ₅₈ | L_{b1} |
| 13 | Lₐ₆₀ | L_{b1} | 14 | Lₐ₆₂ | L_{b1} |
| 15 | Lₐ₆₄ | L_{b1} | 16 | Lₐ₆₇ | L_{b1} |
| 17 | Lₐ₇₁ | L_{b1} | 18 | Lₐ₇₃ | L_{b1} |
| 19 | Lₐ₇₄ | L_{b1} | 20 | Lₐ₇₅ | L_{b1} |
| 21 | Lₐ₇₆ | L_{b1} | 22 | Lₐ₇₇ | L_{b1} |
| 23 | Lₐ₈₄ | L_{b1} | 24 | Lₐ₈₅ | L_{b1} |
| 25 | Lₐ₈₆ | L_{b1} | 26 | Lₐ₈₇ | L_{b1} |
| 27 | Lₐ₈₈ | L_{b1} | 28 | Lₐ₁₀₄ | L_{b1} |
| 29 | Lₐ₁₀₅ | L_{b1} | 30 | Lₐ₁₀₆ | L_{b1} |
| 31 | Lₐ₁₀₇ | L_{b1} | 32 | Lₐ₁₀₈ | L_{b1} |
| 33 | Lₐ₁₃₀ | L_{b1} | 34 | Lₐ₁₅₁ | L_{b1} |
| 35 | Lₐ₁₅₂ | L_{b1} | 36 | Lₐ₁₅₄ | L_{b1} |
| 37 | Lₐ₁₆₁ | L_{b1} | 38 | Lₐ₁₆₂ | L_{b1} |
| 39 | Lₐ₁₆₄ | L_{b1} | 40 | Lₐ₁₉₂ | L_{b1} |
| 41 | Lₐ₁₉₃ | L_{b1} | 42 | Lₐ₁₉₅ | L_{b1} |
| 43 | Lₐ₂₁₉ | L_{b1} | 44 | Lₐ₂₃₁ | L_{b1} |
| 45 | Lₐ₂₄₁ | L_{b1} | 46 | Lₐ₂₄₇ | L_{b1} |
| 47 | Lₐ₂₅₁ | L_{b1} | 48 | Lₐ₂₅₄ | L_{b1} |
| 49 | Lₐ₂₅₅ | L_{b1} | 50 | Lₐ₂₆₂ | L_{b1} |
| 51 | Lₐ₂₆₉ | L_{b1} | 52 | Lₐ₂₇₀ | L_{b1} |
| 53 | Lₐ₂₇₃ | L_{b1} | 54 | Lₐ₂₇₇ | L_{b1} |
| 55 | Lₐ₂₈₁ | L_{b1} | 56 | Lₐ₂₈₂ | L_{b1} |
| 57 | Lₐ₂₈₃ | L_{b1} | 58 | Lₐ₂₈₇ | L_{b1} |
| 59 | Lₐ₂₉₆ | L_{b1} | 60 | Lₐ₂₉₉ | L_{b1} |
| 61 | Lₐ₁ | L_{b31} | 62 | Lₐ₂ | L_{b31} |
| 63 | Lₐ₄ | L_{b31} | 64 | Lₐ₇ | L_{b31} |
| 65 | Lₐ₁ | L_{b31} | 66 | Lₐ₁₉ | L_{b31} |
| 67 | Lₐ₂₈ | L_{b31} | 68 | Lₐ₃₇ | L_{b31} |
| 69 | Lₐ₄₂ | L_{b31} | 70 | Lₐ₄₇ | L_{b31} |
| 71 | Lₐ₅₃ | L_{b31} | 72 | Lₐ₅₈ | L_{b31} |
| 73 | Lₐ₆₀ | L_{b31} | 74 | Lₐ₆₂ | L_{b31} |
| 75 | Lₐ₆₄ | L_{b31} | 76 | Lₐ₆₇ | L_{b31} |
| 77 | Lₐ₇₁ | L_{b31} | 78 | Lₐ₇₃ | L_{b31} |
| 79 | Lₐ₇₄ | L_{b31} | 80 | Lₐ₇₅ | L_{b31} |
| 81 | Lₐ₇₆ | L_{b31} | 82 | Lₐ₇₇ | L_{b31} |
| 83 | Lₐ₈₄ | L_{b31} | 84 | Lₐ₈₅ | L_{b31} |
| 85 | Lₐ₈₆ | L_{b31} | 86 | Lₐ₈₇ | L_{b31} |
| 87 | Lₐ₈₈ | L_{b31} | 88 | Lₐ₁₀₄ | L_{b31} |
| 89 | Lₐ₁₀₅ | L_{b31} | 90 | Lₐ₁₀₆ | L_{b31} |
| 91 | Lₐ₁₀₇ | L_{b31} | 92 | Lₐ₁₀₈ | L_{b31} |
| 93 | Lₐ₁₃₀ | L_{b31} | 94 | Lₐ₁₅₁ | L_{b31} |
| 95 | Lₐ₁₅₂ | L_{b31} | 96 | Lₐ₁₅₄ | L_{b31} |
| 97 | Lₐ₁₆₁ | L_{b31} | 98 | Lₐ₁₆₂ | L_{b31} |
| 99 | Lₐ₁₆₄ | L_{b31} | 100 | Lₐ₁₉₂ | L_{b31} |
| 101 | Lₐ₁₉₃ | L_{b31} | 102 | Lₐ₁₉₅ | L_{b31} |
| 103 | Lₐ₂₁₉ | L_{b31} | 104 | Lₐ₂₃₁ | L_{b31} |
| 105 | Lₐ₂₄₁ | L_{b31} | 106 | Lₐ₂₄₇ | L_{b31} |
| 107 | Lₐ₂₅₁ | L_{b31} | 108 | Lₐ₂₅₄ | L_{b31} |
| 109 | Lₐ₂₅₅ | L_{b31} | 110 | Lₐ₂₆₂ | L_{b31} |
| 111 | Lₐ₂₆₉ | L_{b31} | 112 | Lₐ₂₇₀ | L_{b31} |
| 113 | Lₐ₂₇₃ | L_{b31} | 114 | Lₐ₂₇₇ | L_{b31} |
| 115 | Lₐ₂₈₁ | L_{b31} | 116 | Lₐ₂₈₂ | L_{b31} |
| 117 | Lₐ₂₈₃ | L_{b31} | 118 | Lₐ₂₈₇ | L_{b31} |
| 119 | Lₐ₂₉₆ | L_{b31} | 120 | Lₐ₂₉₉ | L_{b31} |
| 121 | Lₐ₁ | L_{b57} | 122 | Lₐ₂ | L_{b57} |
| 123 | Lₐ₄ | L_{b57} | 124 | Lₐ₇ | L_{b57} |
| 125 | Lₐ₁₀ | L_{b57} | 126 | Lₐ₁₉ | L_{b57} |
| 127 | Lₐ₂₈ | L_{b57} | 128 | Lₐ₃₇ | L_{b57} |
| 129 | Lₐ₄₂ | L_{b57} | 130 | Lₐ₄₇ | L_{b57} |
| 131 | Lₐ₅₃ | L_{b57} | 132 | Lₐ₅₈ | L_{b57} |
| 133 | Lₐ₆₀ | L_{b57} | 134 | Lₐ₆₂ | L_{b57} |
| 135 | Lₐ₆₄ | L_{b57} | 136 | Lₐ₆₇ | L_{b57} |
| 137 | Lₐ₇₁ | L_{b57} | 138 | Lₐ₇₃ | L_{b57} |
| 139 | Lₐ₇₄ | L_{b57} | 140 | Lₐ₇₅ | L_{b57} |
| 141 | Lₐ₇₆ | L_{b57} | 142 | Lₐ₇₇ | L_{b57} |
| 143 | Lₐ₈₄ | L_{b57} | 144 | Lₐ₈₅ | L_{b57} |
| 145 | Lₐ₈₆ | L_{b57} | 146 | Lₐ₈₇ | L_{b57} |
| 147 | Lₐ₈₈ | L_{b57} | 148 | Lₐ₁₀₄ | L_{b57} |
| 149 | Lₐ₁₀₅ | L_{b57} | 150 | Lₐ₁₀₆ | L_{b57} |
| 151 | Lₐ₁₀₇ | L_{b57} | 152 | Lₐ₁₀₈ | L_{b57} |
| 153 | Lₐ₁₃₀ | L_{b57} | 154 | Lₐ₁₅₁ | L_{b57} |
| 155 | Lₐ₁₅₂ | L_{b57} | 156 | Lₐ₁₅₄ | L_{b57} |
| 157 | Lₐ₁₆₁ | L_{b57} | 158 | Lₐ₁₆₂ | L_{b57} |
| 159 | Lₐ₁₆₄ | L_{b57} | 160 | Lₐ₁₉₂ | L_{b57} |
| 161 | Lₐ₁₉₃ | L_{b57} | 162 | Lₐ₁₉₅ | L_{b57} |
| 163 | Lₐ₂₁₉ | L_{b57} | 164 | Lₐ₂₃₁ | L_{b57} |
| 165 | Lₐ₂₄₁ | L_{b57} | 166 | Lₐ₂₄₇ | L_{b57} |
| 167 | Lₐ₂₅₁ | L_{b57} | 168 | Lₐ₂₅₄ | L_{b57} |
| 169 | Lₐ₂₅₅ | L_{b57} | 170 | Lₐ₂₆₂ | L_{b57} |
| 171 | Lₐ₂₆₉ | L_{b57} | 172 | Lₐ₂₇₀ | L_{b57} |
| 173 | Lₐ₂₇₃ | L_{b57} | 174 | Lₐ₂₇₇ | L_{b57} |
| 175 | Lₐ₂₈₁ | L_{b57} | 176 | Lₐ₂₈₂ | L_{b57} |
| 177 | Lₐ₂₈₃ | L_{b57} | 178 | Lₐ₂₈₇ | L_{b57} |
| 179 | Lₐ₂₉₆ | L_{b57} | 180 | Lₐ₂₉₉ | L_{b57} |
| 181 | Lₐ₁ | L_{b88} | 182 | Lₐ₂ | L_{b88} |
| 183 | Lₐ₄ | L_{b88} | 184 | Lₐ₇ | L_{b88} |
| 185 | Lₐ₁₀ | L_{b88} | 186 | Lₐ₁₉ | L_{b88} |
| 187 | Lₐ₂₈ | L_{b88} | 188 | Lₐ₃₇ | L_{b88} |
| 189 | Lₐ₄₂ | L_{b88} | 190 | Lₐ₄₇ | L_{b88} |
| 191 | Lₐ₅₃ | L_{b88} | 192 | Lₐ₅₈ | L_{b88} |
| 193 | Lₐ₆₀ | L_{b88} | 194 | Lₐ₆₂ | L_{b88} |
| 195 | Lₐ₆₄ | L_{b88} | 196 | Lₐ₆₇ | L_{b88} |
| 197 | Lₐ₇₁ | L_{b88} | 198 | Lₐ₇₃ | L_{b88} |
| 199 | Lₐ₇₄ | L_{b88} | 200 | Lₐ₇₅ | L_{b88} |
| 201 | Lₐ₇₆ | L_{b88} | 202 | Lₐ₇₇ | L_{b88} |
| 203 | Lₐ₈₄ | L_{b88} | 204 | Lₐ₈₅ | L_{b88} |
| 205 | Lₐ₈₆ | L_{b88} | 206 | Lₐ₈₇ | L_{b88} |
| 207 | Lₐ₈₈ | L_{b88} | 208 | Lₐ₁₀₄ | L_{b88} |
| 209 | Lₐ₁₀₅ | L_{b88} | 210 | Lₐ₁₀₆ | L_{b88} |
| 211 | Lₐ₁₀₇ | L_{b88} | 212 | Lₐ₁₀₈ | L_{b88} |
| 213 | Lₐ₁₃₀ | L_{b88} | 214 | Lₐ₁₅₁ | L_{b88} |
| 215 | Lₐ₁₅₂ | L_{b88} | 216 | Lₐ₁₅₄ | L_{b88} |
| 217 | Lₐ₁₆₁ | L_{b88} | 218 | Lₐ₁₆₂ | L_{b88} |
| 219 | Lₐ₁₆₄ | L_{b88} | 220 | Lₐ₁₉₂ | L_{b88} |
| 221 | Lₐ₁₉₃ | L_{b88} | 222 | Lₐ₁₉₅ | L_{b88} |
| 223 | Lₐ₂₁₉ | L_{b88} | 224 | Lₐ₂₃₁ | L_{b88} |
| 225 | Lₐ₂₄₁ | L_{b88} | 226 | Lₐ₂₄₇ | L_{b88} |
| 227 | Lₐ₂₅₁ | L_{b88} | 228 | Lₐ₂₅₄ | L_{b88} |
| 229 | Lₐ₂₅₅ | L_{b88} | 230 | Lₐ₂₆₂ | L_{b88} |
| 231 | Lₐ₂₆₉ | L_{b88} | 232 | Lₐ₂₇₀ | L_{b88} |
| 233 | Lₐ₂₇₃ | L_{b88} | 234 | Lₐ₂₇₇ | L_{b88} |
| 235 | Lₐ₂₈₁ | L_{b88} | 236 | Lₐ₂₈₂ | L_{b88} |
| 237 | Lₐ₂₈₃ | L_{b88} | 238 | Lₐ₂₈₇ | L_{b88} |
| 239 | Lₐ₂₉₆ | L_{b88} | 240 | Lₐ₂₉₉ | L_{b88} |
| 241 | Lₐ₁ | L_{b122} | 242 | Lₐ₂ | L_{b122} |
| 243 | Lₐ₄ | L_{b122} | 244 | Lₐ₇ | L_{b122} |
| 245 | Lₐ₁₀ | L_{b122} | 246 | Lₐ₁₉ | L_{b122} |
| 247 | Lₐ₂₈ | L_{b122} | 248 | Lₐ₃₇ | L_{b122} |
| 249 | Lₐ₄₂ | L_{b122} | 250 | Lₐ₄₇ | L_{b122} |
| 251 | Lₐ₅₃ | L_{b122} | 252 | Lₐ₅₈ | L_{b122} |
| 253 | Lₐ₆₀ | L_{b122} | 254 | Lₐ₆₂ | L_{b122} |
| 255 | Lₐ₆₄ | L_{b122} | 256 | Lₐ₆₇ | L_{b122} |
| 257 | Lₐ₇₁ | L_{b122} | 258 | Lₐ₇₃ | L_{b122} |
| 259 | Lₐ₇₄ | L_{b122} | 260 | Lₐ₇₅ | L_{b122} |
| 261 | Lₐ₇₆ | L_{b122} | 262 | Lₐ₇₇ | L_{b122} |
| 263 | Lₐ₈₄ | L_{b122} | 264 | Lₐ₈₅ | L_{b122} |
| 265 | Lₐ₈₆ | L_{b122} | 266 | Lₐ₈₇ | L_{b122} |
| 267 | Lₐ₈₈ | L_{b122} | 268 | Lₐ₁₀₄ | L_{b122} |
| 269 | Lₐ₁₀₅ | L_{b122} | 270 | Lₐ₁₀₆ | L_{b122} |
| 271 | Lₐ₁₀₇ | L_{b122} | 272 | Lₐ₁₀₈ | L_{b122} |
| 273 | Lₐ₁₃₀ | L_{b122} | 274 | Lₐ₁₅₁ | L_{b122} |
| 275 | Lₐ₁₅₂ | L_{b122} | 276 | Lₐ₁₅₄ | L_{b122} |
| 277 | Lₐ₁₆₁ | L_{b122} | 278 | Lₐ₁₆₂ | L_{b122} |
| 279 | Lₐ₁₆₄ | L_{b122} | 280 | Lₐ₁₉₂ | L_{b122} |
| 281 | Lₐ₁₉₃ | L_{b122} | 282 | Lₐ₁₉₅ | L_{b122} |
| 283 | Lₐ₂₁₉ | L_{b122} | 284 | Lₐ₂₃₁ | L_{b122} |
| 285 | Lₐ₂₄₁ | L_{b122} | 286 | Lₐ₂₄₇ | L_{b122} |
| 287 | Lₐ₂₅₁ | L_{b122} | 288 | Lₐ₂₅₄ | L_{b122} |
| 289 | Lₐ₂₅₅ | L_{b122} | 290 | Lₐ₂₆₂ | L_{b122} |
| 291 | Lₐ₂₆₉ | L_{b122} | 292 | Lₐ₂₇₀ | L_{b122} |
| 293 | Lₐ₂₇₃ | L_{b122} | 294 | Lₐ₂₇₇ | L_{b122} |
| 295 | Lₐ₂₈₁ | L_{b122} | 296 | Lₐ₂₈₂ | L_{b122} |
| 297 | Lₐ₂₈₃ | L_{b122} | 298 | Lₐ₂₈₇ | L_{b122} |
| 299 | Lₐ₂₉₆ | L_{b122} | 300 | Lₐ₂₉₉ | L_{b122} |
| 301 | Lₐ₁ | L_{b126} | 302 | Lₐ₂ | L_{b126} |
| 303 | Lₐ₄ | L_{b126} | 304 | Lₐ₇ | L_{b126} |
| 305 | Lₐ₁₀ | L_{b126} | 306 | Lₐ₁₉ | L_{b126} |
| 307 | Lₐ₂₈ | L_{b126} | 308 | Lₐ₃₇ | L_{b126} |
| 309 | Lₐ₄₂ | L_{b126} | 310 | Lₐ₄₇ | L_{b126} |
| 311 | Lₐ₅₃ | L_{b126} | 312 | Lₐ₅₈ | L_{b126} |
| 313 | Lₐ₆₀ | L_{b126} | 314 | Lₐ₆₂ | L_{b126} |
| 315 | Lₐ₆₄ | L_{b126} | 316 | Lₐ₆₇ | L_{b126} |
| 317 | Lₐ₇₁ | L_{b126} | 318 | Lₐ₇₃ | L_{b126} |
| 319 | Lₐ₇₄ | L_{b126} | 320 | Lₐ₇₅ | L_{b126} |
| 321 | Lₐ₇₆ | L_{b126} | 322 | Lₐ₇₇ | L_{b126} |
| 323 | Lₐ₈₄ | L_{b126} | 324 | Lₐ₈₅ | L_{b126} |
| 325 | Lₐ₈₆ | L_{b126} | 326 | Lₐ₈₇ | L_{b126} |
| 327 | Lₐ₈₈ | L_{b126} | 328 | Lₐ₁₀₄ | L_{b126} |
| 329 | Lₐ₁₀₅ | L_{b126} | 330 | Lₐ₁₀₆ | L_{b126} |
| 331 | Lₐ₁₀₇ | L_{b126} | 332 | Lₐ₁₀₈ | L_{b126} |
| 333 | Lₐ₁₃₀ | L_{b126} | 334 | Lₐ₁₅₁ | L_{b126} |
| 335 | Lₐ₁₅₂ | L_{b126} | 336 | Lₐ₁₅₄ | L_{b126} |
| 337 | Lₐ₁₆₁ | L_{b126} | 338 | Lₐ₁₆₂ | L_{b126} |
| 339 | Lₐ₁₆₄ | L_{b126} | 340 | Lₐ₁₉₂ | L_{b126} |
| 341 | Lₐ₁₉₃ | L_{b126} | 342 | Lₐ₁₉₅ | L_{b126} |
| 343 | Lₐ₂₁₉ | L_{b126} | 344 | Lₐ₂₃₁ | L_{b126} |
| 345 | Lₐ₂₄₁ | L_{b126} | 346 | Lₐ₂₄₇ | L_{b126} |
| 347 | Lₐ₂₅₁ | L_{b126} | 348 | Lₐ₂₅₄ | L_{b126} |
| 349 | Lₐ₂₅₅ | L_{b126} | 350 | Lₐ₂₆₂ | L_{b126} |
| 351 | Lₐ₂₆₉ | L_{b126} | 352 | Lₐ₂₇₀ | L_{b126} |
| 353 | Lₐ₂₇₃ | L_{b126} | 354 | Lₐ₂₇₇ | L_{b126} |
| 355 | Lₐ₂₈₁ | L_{b126} | 356 | Lₐ₂₈₂ | L_{b126} |
| 357 | Lₐ₂₈₃ | L_{b126} | 358 | Lₐ₂₈₇ | L_{b126} |
| 359 | Lₐ₂₉₆ | L_{b126} | 360 | Lₐ₂₉₉ | L_{b126} |
| 361 | Lₐ₁ | L_{b212} | 362 | Lₐ₂ | L_{b212} |
| 363 | Lₐ₄ | L_{b212} | 364 | Lₐ₇ | L_{b212} |
| 365 | Lₐ₁₀ | L_{b212} | 366 | Lₐ₁₉ | L_{b212} |
| 367 | Lₐ₂₈ | L_{b212} | 368 | Lₐ₃₇ | L_{b212} |
| 369 | Lₐ₄₂ | L_{b212} | 370 | Lₐ₄₇ | L_{b212} |
| 371 | Lₐ₅₃ | L_{b212} | 372 | Lₐ₅₈ | L_{b212} |
| 373 | Lₐ₆₀ | L_{b212} | 374 | Lₐ₆₂ | L_{b212} |
| 375 | Lₐ₆₄ | L_{b212} | 376 | Lₐ₆₇ | L_{b212} |
| 377 | Lₐ₇₁ | L_{b212} | 378 | Lₐ₇₃ | L_{b212} |
| 379 | Lₐ₇₄ | L_{b212} | 380 | Lₐ₇₅ | L_{b212} |
| 381 | Lₐ₇₆ | L_{b212} | 382 | Lₐ₇₇ | L_{b212} |
| 383 | Lₐ₈₄ | L_{b212} | 384 | Lₐ₈₅ | L_{b212} |
| 385 | Lₐ₈₆ | L_{b212} | 386 | Lₐ₈₇ | L_{b212} |
| 387 | Lₐ₈₈ | L_{b212} | 388 | Lₐ₁₀₄ | L_{b212} |
| 389 | Lₐ₁₀₅ | L_{b212} | 390 | Lₐ₁₀₆ | L_{b212} |
| 391 | Lₐ₁₀₇ | L_{b212} | 392 | Lₐ₁₀₈ | L_{b212} |
| 393 | Lₐ₁₃₀ | L_{b212} | 394 | Lₐ₁₅₁ | L_{b212} |
| 395 | Lₐ₁₅₂ | L_{b212} | 396 | Lₐ₁₅₄ | L_{b212} |
| 397 | Lₐ₁₆₁ | L_{b212} | 398 | Lₐ₁₆₂ | L_{b212} |
| 399 | Lₐ₁₆₄ | L_{b212} | 400 | Lₐ₁₉₂ | L_{b212} |
| 401 | Lₐ₁₉₃ | L_{b212} | 402 | Lₐ₁₉₅ | L_{b212} |
| 403 | Lₐ₂₁₉ | L_{b212} | 404 | Lₐ₂₃₁ | L_{b212} |
| 405 | Lₐ₂₄₁ | L_{b212} | 406 | Lₐ₂₄₇ | L_{b212} |
| 407 | Lₐ₂₅₁ | L_{b212} | 408 | Lₐ₂₅₄ | L_{b212} |
| 409 | Lₐ₂₅₅ | L_{b212} | 410 | Lₐ₂₆₂ | L_{b212} |
| 411 | Lₐ₂₆₉ | L_{b212} | 412 | Lₐ₂₇₀ | L_{b212} |
| 413 | Lₐ₂₇₃ | L_{b212} | 414 | Lₐ₂₇₇ | L_{b212} |
| 415 | Lₐ₂₈₁ | L_{b212} | 416 | Lₐ₂₈₂ | L_{b212} |
| 417 | Lₐ₂₈₃ | L_{b212} | 418 | Lₐ₂₈₇ | L_{b212} |
| 419 | Lₐ₂₉₆ | L_{b212} | 420 | Lₐ₂₉₉ | L_{b212} |
| 421 | Lₐ₁ | L_{b245} | 422 | Lₐ₂ | L_{b245} |
| 423 | Lₐ₄ | L_{b245} | 424 | Lₐ₇ | L_{b245} |
| 425 | Lₐ₁₀ | L_{b245} | 426 | Lₐ₁₉ | L_{b245} |
| 427 | Lₐ₂₈ | L_{b245} | 428 | Lₐ₃₇ | L_{b245} |
| 429 | Lₐ₄₂ | L_{b245} | 430 | Lₐ₄₇ | L_{b245} |
| 431 | Lₐ₅₃ | L_{b245} | 432 | Lₐ₅₈ | L_{b245} |
| 433 | Lₐ₆₀ | L_{b245} | 434 | Lₐ₆₂ | L_{b245} |
| 435 | Lₐ₆₄ | L_{b245} | 436 | Lₐ₆₇ | L_{b245} |
| 437 | Lₐ₇₁ | L_{b245} | 438 | Lₐ₇₃ | L_{b245} |
| 439 | Lₐ₇₄ | L_{b245} | 440 | Lₐ₇₅ | L_{b245} |
| 441 | Lₐ₇₆ | L_{b245} | 442 | Lₐ₇₇ | L_{b245} |
| 443 | Lₐ₈₄ | L_{b245} | 444 | Lₐ₈₅ | L_{b245} |
| 445 | Lₐ₈₆ | L_{b245} | 446 | Lₐ₈₇ | L_{b245} |
| 447 | Lₐ₈₈ | L_{b245} | 448 | Lₐ₁₀₄ | L_{b245} |
| 449 | Lₐ₁₀₅ | L_{b245} | 450 | Lₐ₁₀₆ | L_{b245} |
| 451 | Lₐ₁₀₇ | L_{b245} | 452 | Lₐ₁₀₈ | L_{b245} |
| 453 | Lₐ₁₃₀ | L_{b245} | 454 | Lₐ₁₅₁ | L_{b245} |
| 455 | Lₐ₁₅₂ | L_{b245} | 456 | Lₐ₁₅₄ | L_{b245} |
| 457 | Lₐ₁₆₁ | L_{b245} | 458 | Lₐ₁₆₂ | L_{b245} |
| 459 | Lₐ₁₆₄ | L_{b245} | 460 | Lₐ₁₉₂ | L_{b245} |
| 461 | Lₐ₁₉₃ | L_{b245} | 462 | Lₐ₁₉₅ | L_{b245} |
| 463 | Lₐ₂₁₉ | L_{b245} | 464 | Lₐ₂₃₁ | L_{b245} |
| 465 | Lₐ₂₄₁ | L_{b245} | 466 | Lₐ₂₄₇ | L_{b245} |
| 467 | Lₐ₂₅₁ | L_{b245} | 468 | Lₐ₂₅₄ | L_{b245} |
| 469 | Lₐ₂₅₅ | L_{b245} | 470 | Lₐ₂₆₂ | L_{b245} |
| 471 | Lₐ₂₆₉ | L_{b245} | 472 | Lₐ₂₇₀ | L_{b245} |
| 473 | Lₐ₂₇₃ | L_{b245} | 474 | Lₐ₂₇₇ | L_{b245} |
| 475 | Lₐ₂₈₁ | L_{b245} | 476 | Lₐ₂₈₂ | L_{b245} |
| 477 | Lₐ₂₈₃ | L_{b245} | 478 | Lₐ₂₈₇ | L_{b245} |
| 479 | Lₐ₂₉₆ | L_{b245} | 480 | Lₐ₂₉₉ | L_{b245} |
| 481 | Lₐ₃₂₀ | L_{b31} | 482 | Lₐ₃₂₀ | L_{b57} |
| 483 | Lₐ₃₂₀ | L_{b88} | 484 | Lₐ₃₂₀ | L_{b122} |
| 485 | Lₐ₃₂₀ | L_{b126} | 486 | Lₐ₃₂₀ | L_{b212} |
| 487 | Lₐ₃₂₂ | L_{b31} | 488 | Lₐ₃₂₂ | L_{b57} |
| 489 | Lₐ₃₂₂ | L_{b88} | 490 | Lₐ₃₂₂ | L_{b122} |
| 491 | Lₐ₃₂₂ | L_{b126} | 492 | Lₐ₃₂₂ | L_{b212} |

Compound 493 to Compound 612 have a structure of Ir(Lₐ)₂(L_{b}), wherein two Lₐ are different and Lₐ and L_{b} are respectively selected from structures listed in the following table:

| Compound No. | Lₐ | Lₐ | L_{b} | Compound No. | Lₐ | Lₐ | L_{b} |
|---|---|---|---|---|---|---|---|
| 493 | Lₐ₁₉ | Lₐ₇₃ | L_{b31} | 494 | Lₐ₁₉ | Lₐ₇₅ | L_{b31} |
| 495 | Lₐ₁₉ | Lₐ₇₇ | L_{b31} | 496 | Lₐ₁₉ | Lₐ₈₄ | L_{b31} |
| 497 | Lₐ₁₉ | Lₐ₁₀₄ | L_{b31} | 498 | Lₐ₇₃ | Lₐ₇₅ | L_{b31} |
| 499 | Lₐ₇₃ | Lₐ₇₇ | L_{b31} | 500 | Lₐ₇₃ | Lₐ₈₄ | L_{b31} |
| 501 | Lₐ₇₃ | Lₐ₁₀₄ | L_{b31} | 502 | Lₐ₇₃ | Lₐ₁₅₁ | L_{b31} |
| 503 | Lₐ₇₃ | Lₐ₁₅₂ | L_{b31} | 504 | Lₐ₇₃ | Lₐ₁₅₄ | L_{b31} |
| 505 | Lₐ₇₃ | Lₐ₂₉₉ | L_{b31} | 506 | Lₐ₇₅ | Lₐ₇₇ | L_{b31} |
| 507 | Lₐ₇₅ | Lₐ₈₄ | L_{b31} | 508 | Lₐ₇₅ | Lₐ₁₀₄ | L_{b31} |
| 509 | Lₐ₇₅ | Lₐ₁₅₁ | L_{b31} | 510 | Lₐ₇₅ | Lₐ₁₅₂ | L_{b31} |
| 511 | Lₐ₈₄ | Lₐ₁₀₄ | L_{b31} | 512 | Lₐ₈₄ | Lₐ₁₅₁ | L_{b31} |
| 513 | Lₐ₁₉ | Lₐ₇₃ | L_{b57} | 514 | Lₐ₁₉ | Lₐ₇₅ | L_{b57} |
| 515 | Lₐ₁₉ | Lₐ₇₇ | L_{b57} | 516 | Lₐ₁₉ | Lₐ₈₄ | L_{b57} |
| 517 | Lₐ₁₉ | Lₐ₁₀₄ | L_{b57} | 518 | Lₐ₇₃ | Lₐ₇₅ | L_{b57} |
| 519 | Lₐ₇₃ | Lₐ₇₇ | L_{b57} | 520 | Lₐ₇₃ | Lₐ₈₄ | L_{b57} |
| 521 | Lₐ₇₃ | Lₐ₁₀₄ | L_{b57} | 522 | Lₐ₇₃ | Lₐ₁₅₁ | L_{b57} |
| 523 | Lₐ₇₃ | Lₐ₁₅₂ | L_{b57} | 524 | Lₐ₇₃ | Lₐ₁₅₄ | L_{b57} |
| 525 | Lₐ₇₃ | Lₐ₂₉₉ | L_{b57} | 526 | Lₐ₇₅ | Lₐ₇₇ | L_{b57} |
| 527 | Lₐ₇₅ | Lₐ₈₄ | L_{b57} | 528 | Lₐ₇₅ | Lₐ₁₀₄ | L_{b57} |
| 529 | Lₐ₇₅ | Lₐ₁₅₁ | L_{b57} | 530 | Lₐ₇₅ | Lₐ₁₅₂ | L_{b57} |
| 531 | Lₐ₈₄ | Lₐ₁₀₄ | L_{b57} | 532 | Lₐ₈₄ | Lₐ₁₅₁ | L_{b57} |
| 533 | Lₐ₁₉ | Lₐ₇₃ | L_{b88} | 534 | Lₐ₁₉ | Lₐ₇₅ | L_{b88} |
| 535 | Lₐ₁₉ | Lₐ₇₇ | L_{b88} | 536 | Lₐ₁₉ | Lₐ₈₄ | L_{b88} |
| 537 | Lₐ₁₉ | Lₐ₁₀₄ | L_{b88} | 538 | Lₐ₇₃ | Lₐ₇₅ | L_{b88} |
| 539 | Lₐ₇₃ | Lₐ₇₇ | L_{b88} | 540 | Lₐ₇₃ | Lₐ₈₄ | L_{b88} |
| 541 | Lₐ₇₃ | Lₐ₁₀₄ | L_{b88} | 542 | Lₐ₇₃ | Lₐ₁₅₁ | L_{b88} |
| 543 | Lₐ₇₃ | Lₐ₁₅₂ | L_{b88} | 544 | Lₐ₇₃ | Lₐ₁₅₄ | L_{b88} |
| 545 | Lₐ₇₃ | Lₐ₂₉₉ | L_{b88} | 546 | Lₐ₇₅ | Lₐ₇₇ | L_{b88} |
| 547 | Lₐ₇₅ | Lₐ₈₄ | L_{b88} | 548 | Lₐ₇₅ | Lₐ₁₀₄ | L_{b88} |
| 549 | Lₐ₇₅ | Lₐ₁₅₁ | L_{b88} | 550 | Lₐ₇₅ | Lₐ₁₅₂ | L_{b88} |
| 551 | Lₐ₈₄ | Lₐ₁₀₄ | L_{b88} | 552 | Lₐ₈₄ | Lₐ₁₅₁ | L_{b88} |
| 553 | Lₐ₁₉ | Lₐ₇₃ | L_{b122} | 554 | Lₐ₁₉ | Lₐ₇₅ | L_{b122} |
| 555 | Lₐ₁₉ | Lₐ₇₇ | L_{b122} | 556 | Lₐ₁₉ | Lₐ₈₄ | L_{b122} |
| 557 | Lₐ₁₉ | Lₐ₁₀₄ | L_{b122} | 558 | Lₐ₇₃ | Lₐ₇₅ | L_{b122} |
| 559 | Lₐ₇₃ | Lₐ₇₇ | L_{b122} | 560 | Lₐ₇₃ | Lₐ₈₄ | L_{b122} |
| 561 | Lₐ₇₃ | Lₐ₁₀₄ | L_{b122} | 562 | Lₐ₇₃ | Lₐ₁₅₁ | L_{b122} |
| 563 | Lₐ₇₃ | Lₐ₁₅₂ | L_{b122} | 564 | Lₐ₇₃ | Lₐ₁₅₄ | L_{b122} |
| 565 | Lₐ₇₃ | Lₐ₂₉₉ | L_{b122} | 566 | Lₐ₇₅ | Lₐ₇₇ | L_{b122} |
| 567 | Lₐ₇₅ | Lₐ₈₄ | L_{b122} | 568 | Lₐ₇₅ | Lₐ₁₀₄ | L_{b122} |
| 569 | Lₐ₇₅ | Lₐ₁₅₁ | L_{b122} | 570 | Lₐ₇₅ | Lₐ₁₅₂ | L_{b122} |
| 571 | Lₐ₈₄ | Lₐ₁₀₄ | L_{b122} | 572 | Lₐ₈₄ | Lₐ₁₅₁ | L_{b122} |
| 573 | Lₐ₁₉ | Lₐ₇₃ | L_{b126} | 574 | Lₐ₁₉ | Lₐ₇₅ | L_{b126} |
| 575 | Lₐ₁₉ | Lₐ₇₇ | L_{b126} | 576 | Lₐ₁₉ | Lₐ₈₄ | L_{b126} |
| 577 | Lₐ₁₉ | Lₐ₁₀₄ | L_{b126} | 578 | Lₐ₇₃ | Lₐ₇₅ | L_{b126} |
| 579 | Lₐ₇₃ | Lₐ₇₇ | L_{b126} | 580 | Lₐ₇₃ | Lₐ₈₄ | L_{b126} |
| 581 | Lₐ₇₃ | Lₐ₁₀₄ | L_{b126} | 582 | Lₐ₇₃ | Lₐ₁₅₁ | L_{b126} |
| 583 | Lₐ₇₃ | Lₐ₁₅₂ | L_{b126} | 584 | Lₐ₇₃ | Lₐ₁₅₄ | L_{b126} |
| 585 | Lₐ₇₃ | Lₐ₂₉₉ | L_{b126} | 586 | Lₐ₇₅ | Lₐ₇₇ | L_{b126} |
| 587 | Lₐ₇₅ | Lₐ₈₄ | L_{b126} | 588 | Lₐ₇₅ | Lₐ₁₀₄ | L_{b126} |
| 589 | Lₐ₇₅ | Lₐ₁₅₁ | L_{b126} | 590 | Lₐ₇₅ | Lₐ₁₅₂ | L_{b126} |
| 591 | Lₐ₈₄ | Lₐ₁₀₄ | L_{b126} | 592 | Lₐ₈₄ | Lₐ₁₅₁ | L_{b126} |
| 593 | Lₐ₁₉ | Lₐ₇₃ | L_{b212} | 594 | Lₐ₁₉ | Lₐ₇₅ | L_{b212} |
| 595 | Lₐ₁₉ | Lₐ₇₇ | L_{b212} | 596 | Lₐ₁₉ | Lₐ₈₄ | L_{b212} |
| 597 | Lₐ₁₉ | Lₐ₁₀₄ | L_{b212} | 598 | Lₐ₇₃ | Lₐ₇₅ | L_{b212} |
| 599 | Lₐ₇₃ | Lₐ₇₇ | L_{b212} | 600 | Lₐ₇₃ | Lₐ₈₄ | L_{b212} |
| 601 | Lₐ₇₃ | Lₐ₁₀₄ | L_{b212} | 602 | Lₐ₇₃ | Lₐ₁₅₁ | L_{b212} |
| 603 | Lₐ₇₃ | Lₐ₁₅₂ | L_{b212} | 604 | Lₐ₇₃ | Lₐ₁₅₄ | L_{b212} |
| 605 | Lₐ₇₃ | Lₐ₂₉₉ | L_{b212} | 606 | Lₐ₇₅ | Lₐ₇₇ | L_{b212} |
| 607 | Lₐ₇₅ | Lₐ₈₄ | L_{b212} | 608 | Lₐ₇₅ | Lₐ₁₀₄ | L_{b212} |
| 609 | Lₐ₇₅ | Lₐ₁₅₁ | L_{b212} | 610 | Lₐ₇₅ | Lₐ₁₅₂ | L_{b212} |
| 611 | Lₐ₈₄ | Lₐ₁₀₄ | L_{b212} | 612 | Lₐ₈₄ | Lₐ₁₅₁ | L_{b212} |

23. The electroluminescent device according to claim 1, wherein the first compound has a structure represented by any one of Formula 6, Formula 7 or Formula 8: 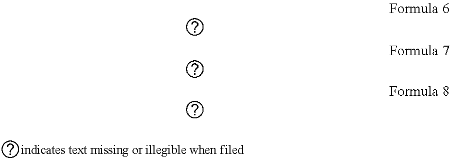
wherein Zₕ₁ and Zₕ₈ are, at each occurrence identically or differently, selected from CR_{z1} or N; Zₕ₂, Zₕ₃, Zₕ₆, and Zₕ₇ are, at each occurrence identically or differently, selected from C, CR_{z2} or N; Zₕ₄ and Zₕ₅ are, at each occurrence identically or differently, selected from CR_{z3} or N; Zₕ₉ to Zₕ₂₃ are, at each occurrence identically or differently, selected from C, CR_{zh} or N; R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;
R_{z2}, R_{z3}, and R_{zh}, are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
in Formula 6, Formula 7 or Formula 8, adjacent substituents R_{z2} and R_{z3} can be optionally joined to form a 6- to 10-membered ring; adjacent substituents R_{zh} on the same 6-membered ring can be optionally joined to form a ring;
E has a structure represented by Formula 3-1 or Formula 3-2: 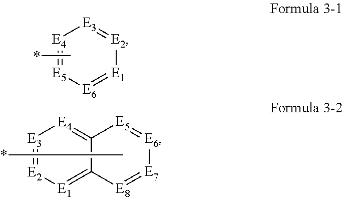
in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;
* represents a position where E is joined to L;
L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
Rₑ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₑ can be optionally joined to form a ring.

24. The electroluminescent device according to claim 1, wherein the first compound has a structure represented by Formula 9: 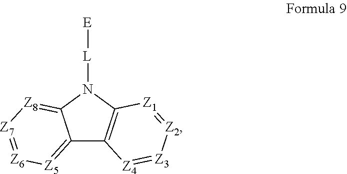
wherein
Z₁ and Z₈ are, at each occurrence identically or differently, selected from CR_{z1} or N; Z₂, Z₃, Z₆, and Z₇ are, at each occurrence identically or differently, selected from CR_{z2} or N; Z₄ and Z₅ are, at each occurrence identically or differently, selected from CR_{z3}, and two substituents R_{z3} in Z₄ and Z₅ are joined to form a ring;
R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;
R_{z2} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R_{z3} is, at each occurrence identically or differently, selected from the group consisting of: hydrogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof;
adjacent substituents R_{z2}, R_{z3} can be optionally joined to form a ring;
preferably, a ring formed by joining two substituents R_{z3} in Z₄ and Z₅ has at least 7 ring atoms;
E has a structure represented by Formula 3-1 or Formula 3-2: 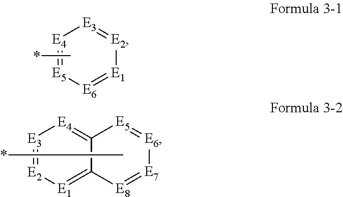
in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;
* represents a position where E is joined to L;
L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
Rₑ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₑ can be optionally joined to form a ring.

25. The electroluminescent device according to claim 24, wherein the first compound has a structure represented by any one of Formula 10, Formula 11, Formula 12, Formula 13, Formula 14 or Formula 15: 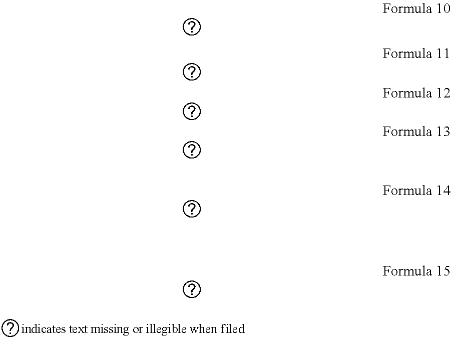
wherein
Z₁ and Z₈ are, at each occurrence identically or differently, selected from CR_{z1} or N; Z₂, Z₃, Z₆, and Z₇ are, at each occurrence identically or differently, selected from CR_{z2} or N; Zₕ₁ to Zₕ₉ are, at each occurrence identically or differently, selected from CR_{zh} or N;
R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;
R_{z2} and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{z1}, R_{z2}, R_{zh} can be optionally joined to form a ring;
preferably, R_{z2} and R_{zh} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted amino having 0 to 20 carbon atoms, a cyano group, an isocyano group, a hydroxyl group, a sulfanyl group, and combinations thereof;
E has a structure represented by Formula 3-1 or Formula 3-2: 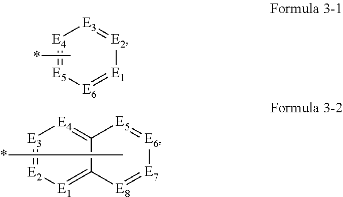
in Formula 3-1 and Formula 3-2, E₁ to E₈ are, at each occurrence identically or differently, selected from C, CRₑ or N; and in Formula 3-1, at least two of E₁ to E₆ are N, and in Formula 3-2, at least two of E₁ to E₈ are N;
* represents a position where E is joined to L;
L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
Rₑ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₑ can be optionally joined to form a ring.

26. The electroluminescent device according to claim 23, wherein Zₕ₁, Zₕ₈, Z₁, and Z₈ are, at each occurrence identically or differently, selected from CR_{z1}.

27. The electroluminescent device according to claim 1, wherein E is selected from the group consisting of: substituted or unsubstituted pyrimidyl, substituted or unsubstituted triazinyl, substituted or unsubstituted quinazolinyl, substituted or unsubstituted quinoxalinyl, substituted or unsubstituted benzoquinazolinyl, and substituted or unsubstituted benzoquinoxalinyl; optionally, hydrogens in the above groups can be partially or completely substituted by deuterium.

28. The electroluminescent device according to claim 27, wherein E is selected from the group consisting of the following structures:

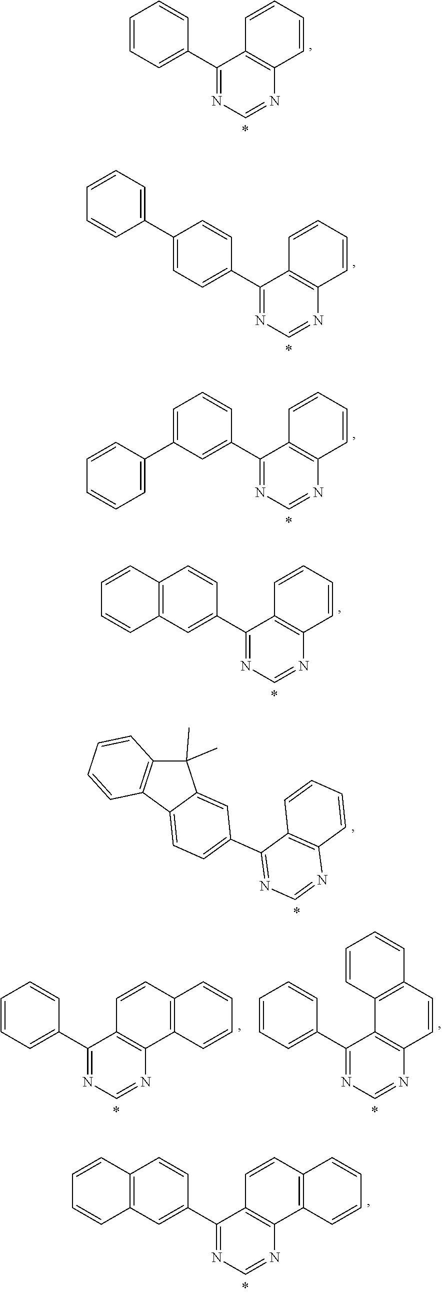

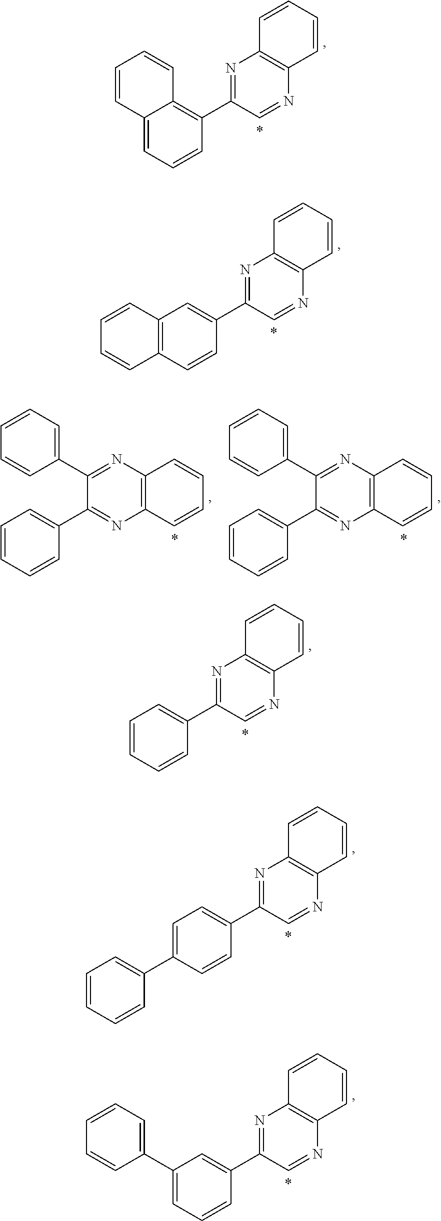

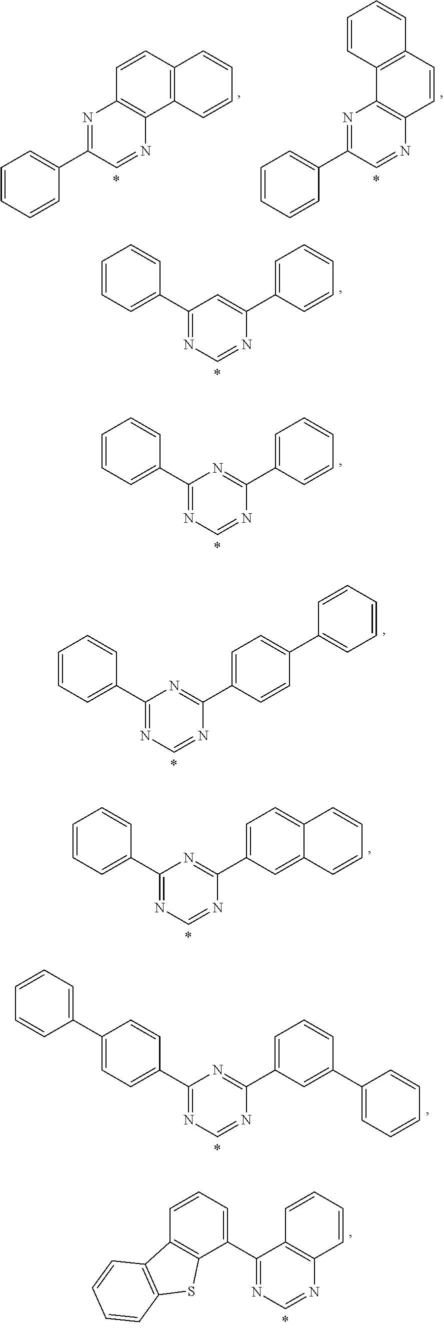

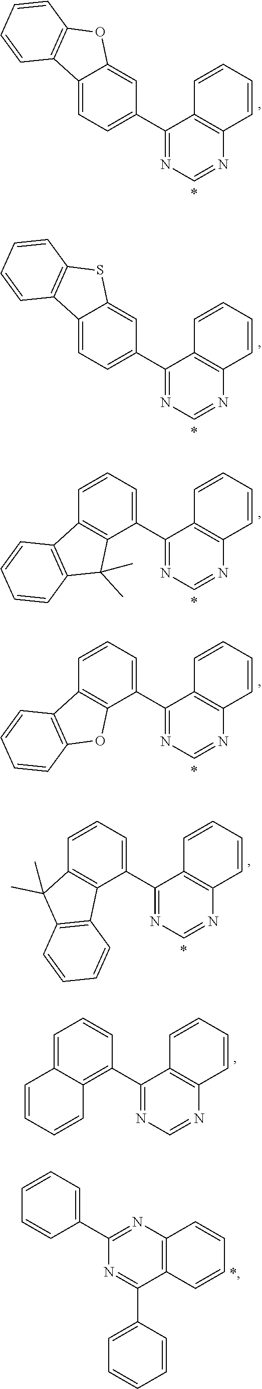

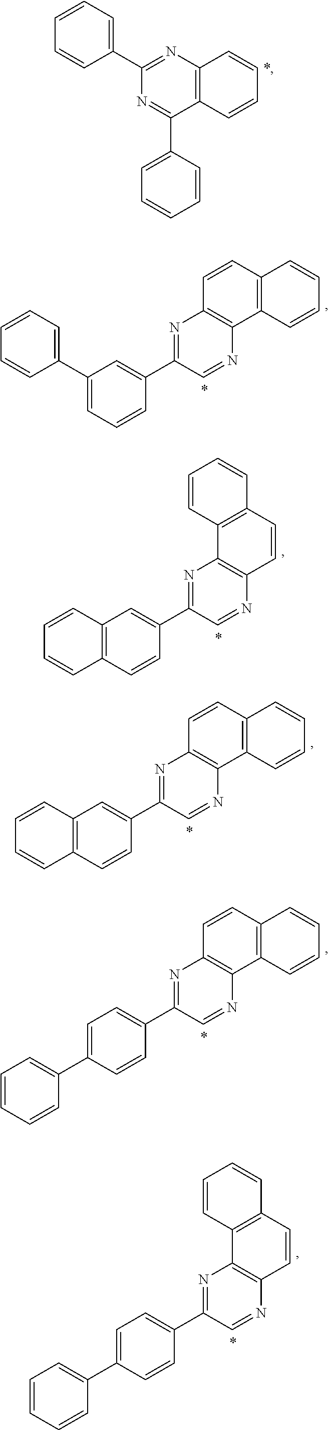 [SMILES: c1ccc(-c2nc(-c3ccccc3)c3ccccc3n2)cc1 ; c1ccc(-c2cccc(-c3cnc4c(ccc5ccccc54)n3)c2)cc1 ; c1ccc2cc(-c3cnc4ccc5ccccc5c4n3)ccc2c1 ; c1ccc2cc(-c3cnc4c(ccc5ccccc54)n3)ccc2c1 ; c1ccc(-c2ccc(-c3cnc4c(ccc5ccccc54)n3)cc2)cc1 ; c1ccc(-c2ccc(-c3cnc4ccc5ccccc5c4n3)cc2)cc1]

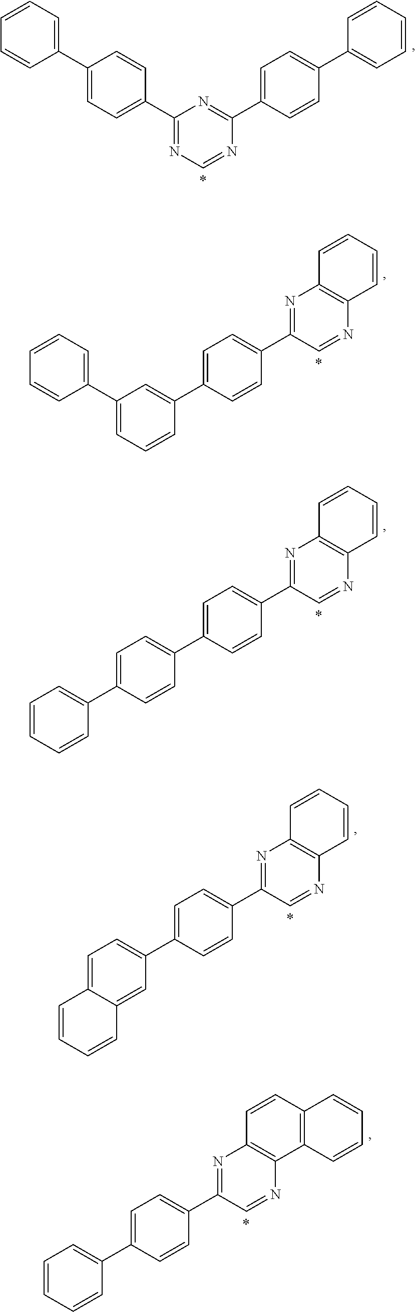 [SMILES: c1ccc(-c2ccc(-c3ncnc(-c4ccc(-c5ccccc5)cc4)n3)cc2)cc1 ; c1ccc(-c2cccc(-c3ccc(-c4cnc5ccccc5n4)cc3)c2)cc1 ; c1ccc(-c2ccc(-c3ccc(-c4cnc5ccccc5n4)cc3)cc2)cc1 ; c1ccc2cc(-c3ccc(-c4cnc5ccccc5n4)cc3)ccc2c1 ; c1ccc(-c2ccc(-c3cnc4c(ccc5ccccc54)n3)cc2)cc1]

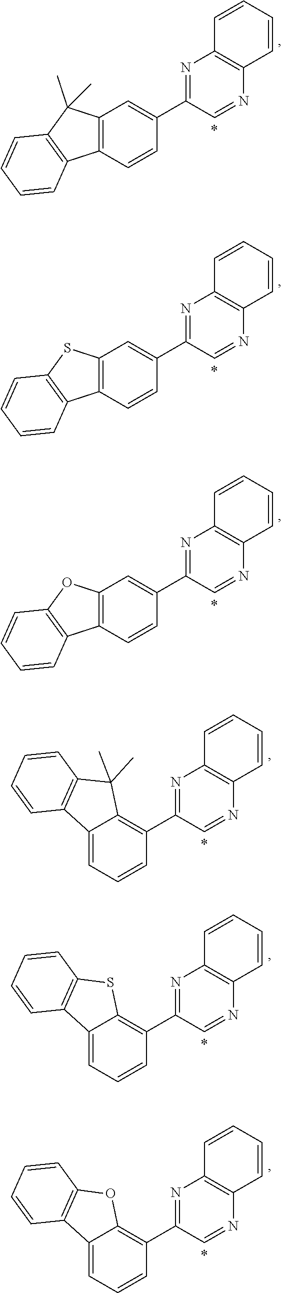 [SMILES: CC1(C)c2ccccc2-c2ccc(-c3cnc4ccccc4n3)cc21 ; c1ccc2nc(-c3ccc4c(c3)sc3ccccc34)cnc2c1 ; c1ccc2nc(-c3ccc4c(c3)oc3ccccc34)cnc2c1 ; CC1(C)c2ccccc2-c2cccc(-c3cnc4ccccc4n3)c21 ; c1ccc2nc(-c3cccc4c3sc3ccccc34)cnc2c1 ; c1ccc2nc(-c3cccc4c3oc3ccccc34)cnc2c1]

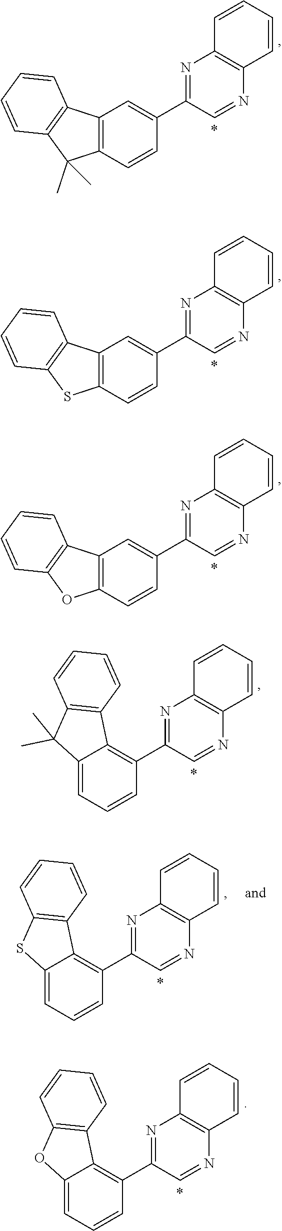 [SMILES: CC1(C)c2ccccc2-c2cc(-c3cnc4ccccc4n3)ccc21 ; c1ccc2nc(-c3ccc4sc5ccccc5c4c3)cnc2c1 ; c1ccc2nc(-c3ccc4oc5ccccc5c4c3)cnc2c1 ; CC1(C)c2ccccc2-c2c(-c3cnc4ccccc4n3)cccc21 ; c1ccc2nc(-c3cccc4sc5ccccc5c34)cnc2c1 ; c1ccc2nc(-c3cccc4oc5ccccc5c34)cnc2c1]

29. The electroluminescent device according to claim 1, wherein L is selected from the group consisting of: a single bond, phenylene, naphthylene, biphenylene, terphenylene, triphenylenylene, pyridylene, furylene, thienylene, dibenzofurylene, dibenzothienylene, and combinations thereof; optionally, hydrogens in the above groups can be partially or completely substituted by deuterium;
preferably, L is selected from a single bond or phenylene.

30. The electroluminescent device according to claim 1, wherein the first compound is selected from the group consisting of the following structures:

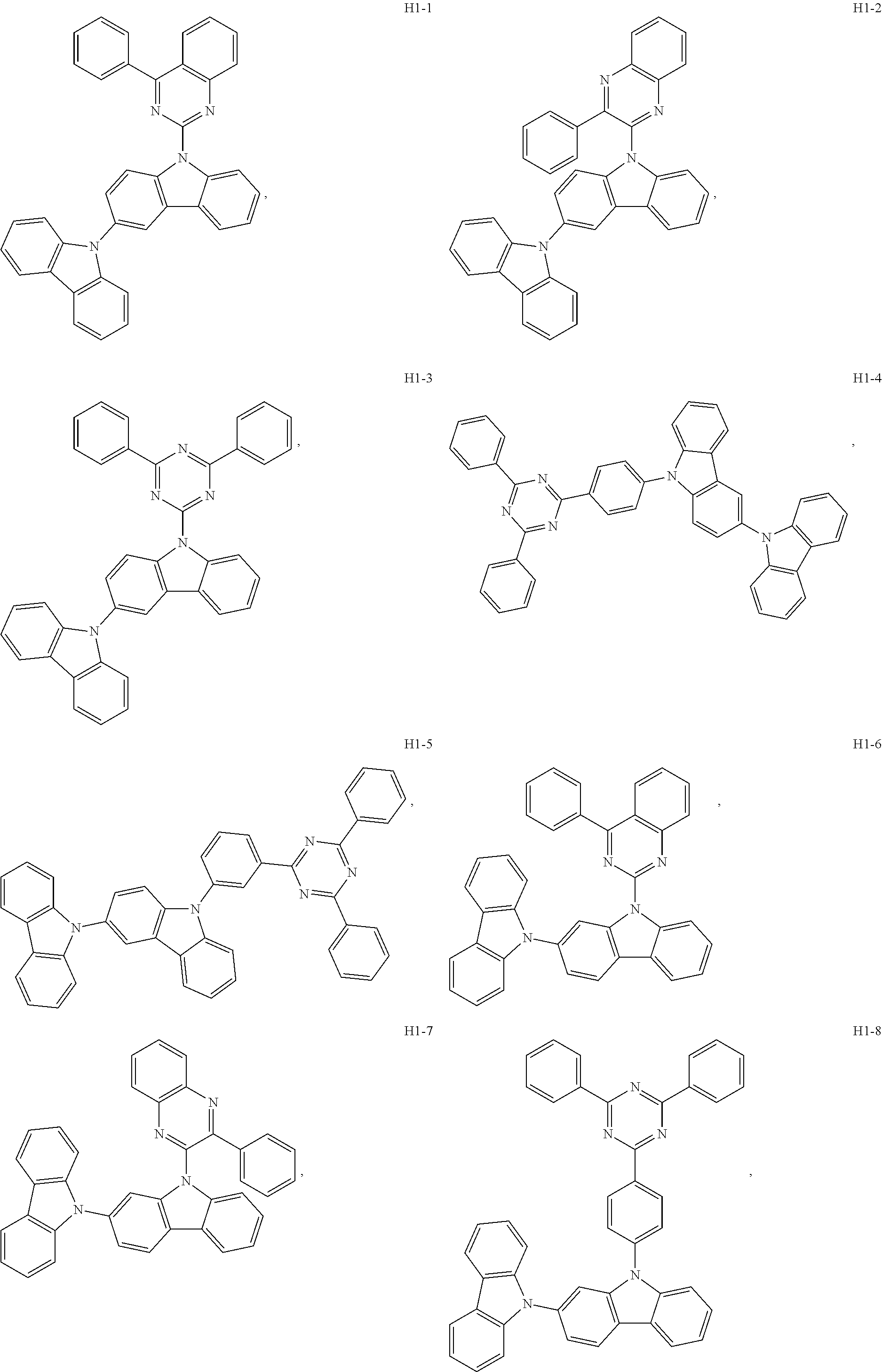

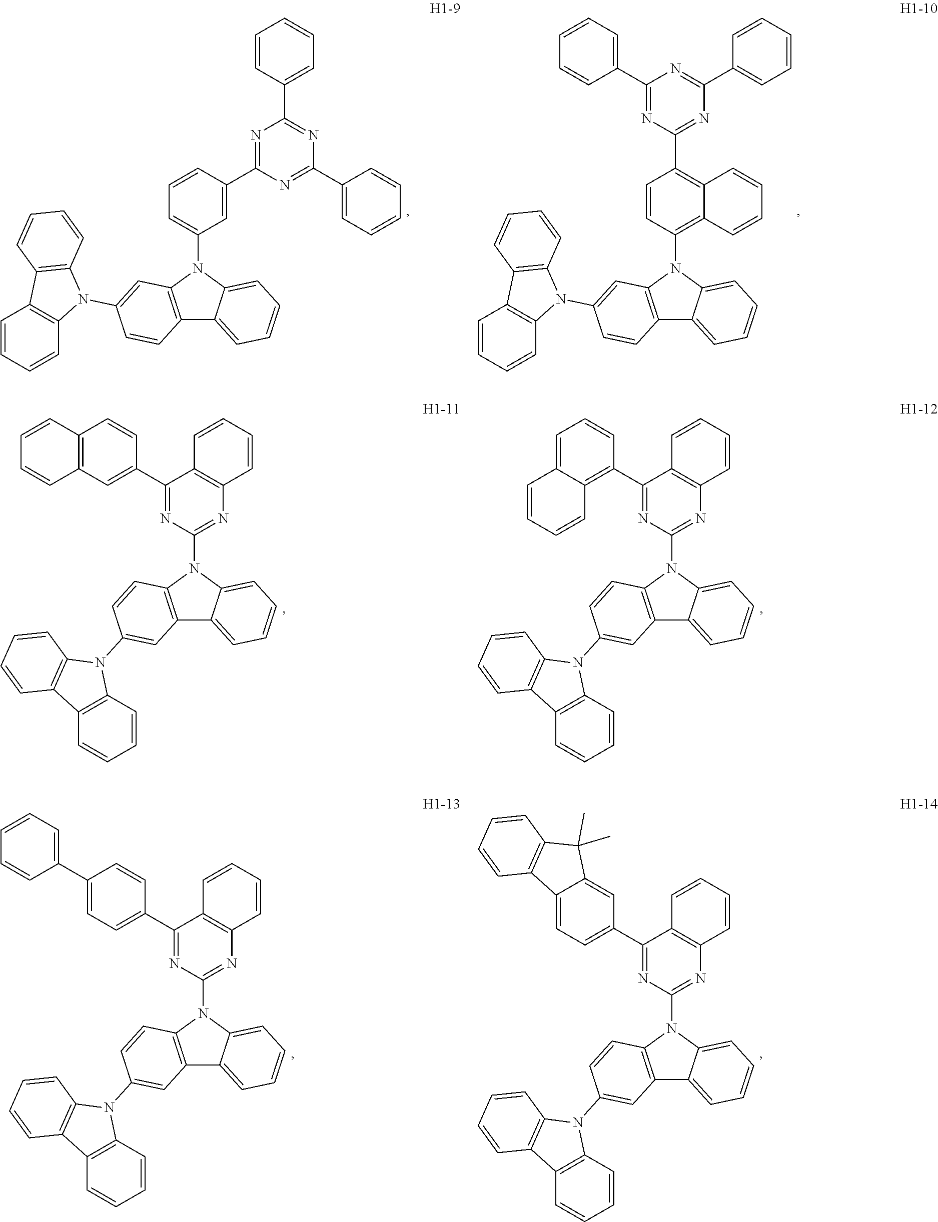

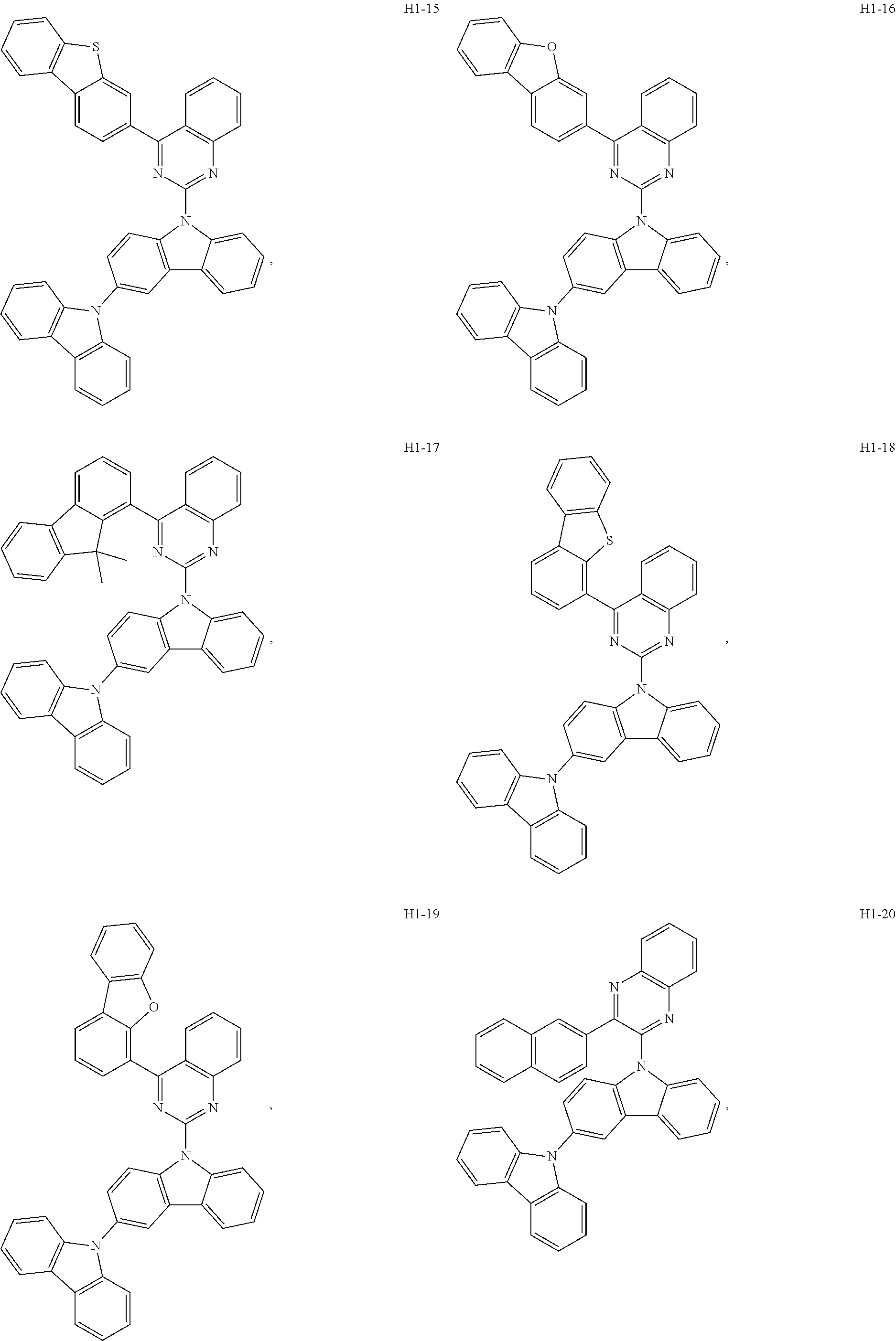 [SMILES: c1ccc2c(-c3ccc4c(c3)sc3ccccc34)nc(-n3c4ccccc4c4cc(-n5c6ccccc6c6ccccc65)ccc43)nc2c1 ; c1ccc2c(-c3ccc4c(c3)oc3ccccc34)nc(-n3c4ccccc4c4cc(-n5c6ccccc6c6ccccc65)ccc43)nc2c1 ; CC1(C)c2ccccc2-c2cccc(-c3nc(-n4c5ccccc5c5cc(-n6c7ccccc7c7ccccc76)ccc54)nc4ccccc34)c21 ; c1ccc2c(-c3cccc4c3sc3ccccc34)nc(-n3c4ccccc4c4cc(-n5c6ccccc6c6ccccc65)ccc43)nc2c1 ; c1ccc2c(-c3cccc4c3oc3ccccc34)nc(-n3c4ccccc4c4cc(-n5c6ccccc6c6ccccc65)ccc43)nc2c1 ; c1ccc2cc(-c3nc4ccccc4nc3-n3c4ccccc4c4cc(-n5c6ccccc6c6ccccc65)ccc43)ccc2c1]

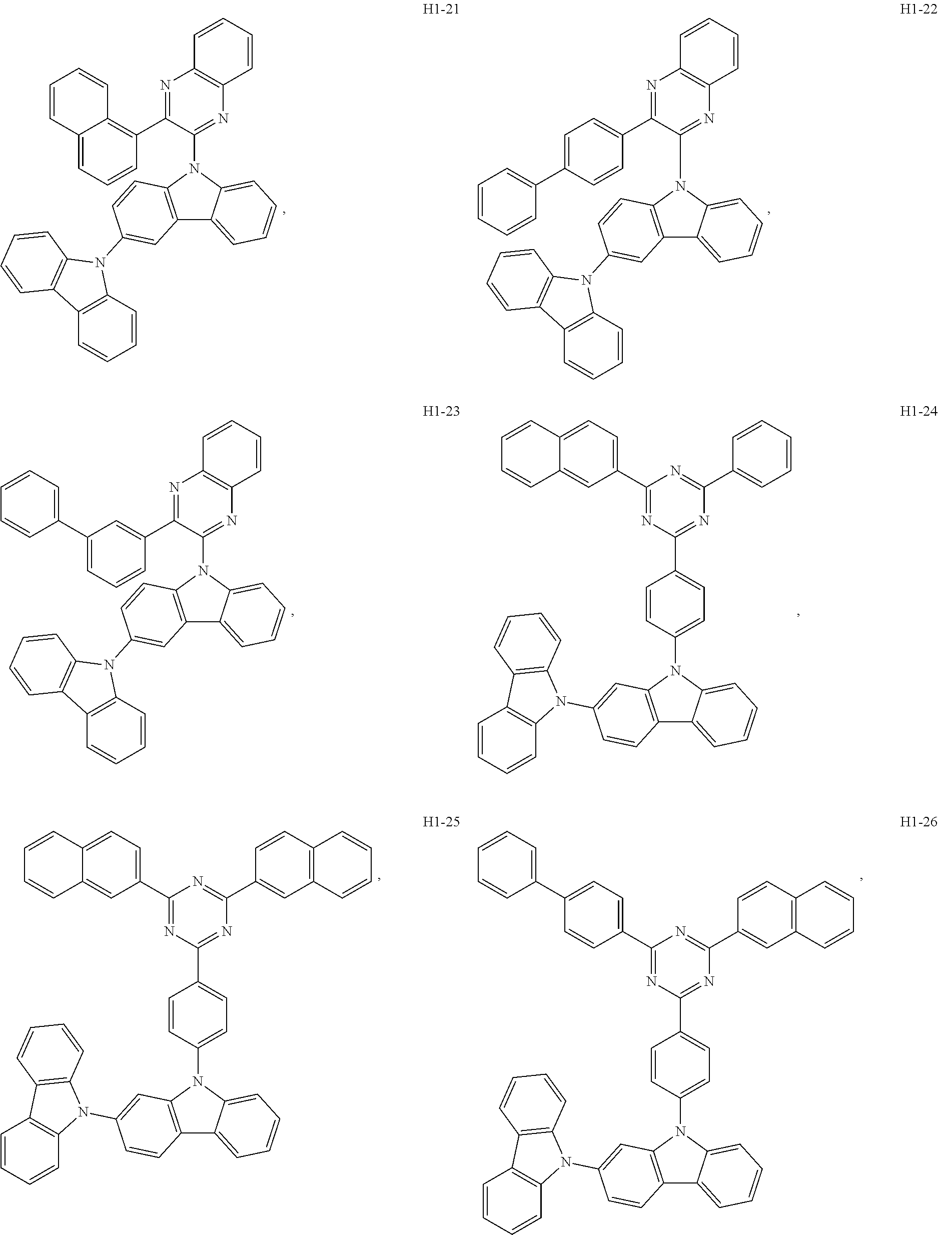

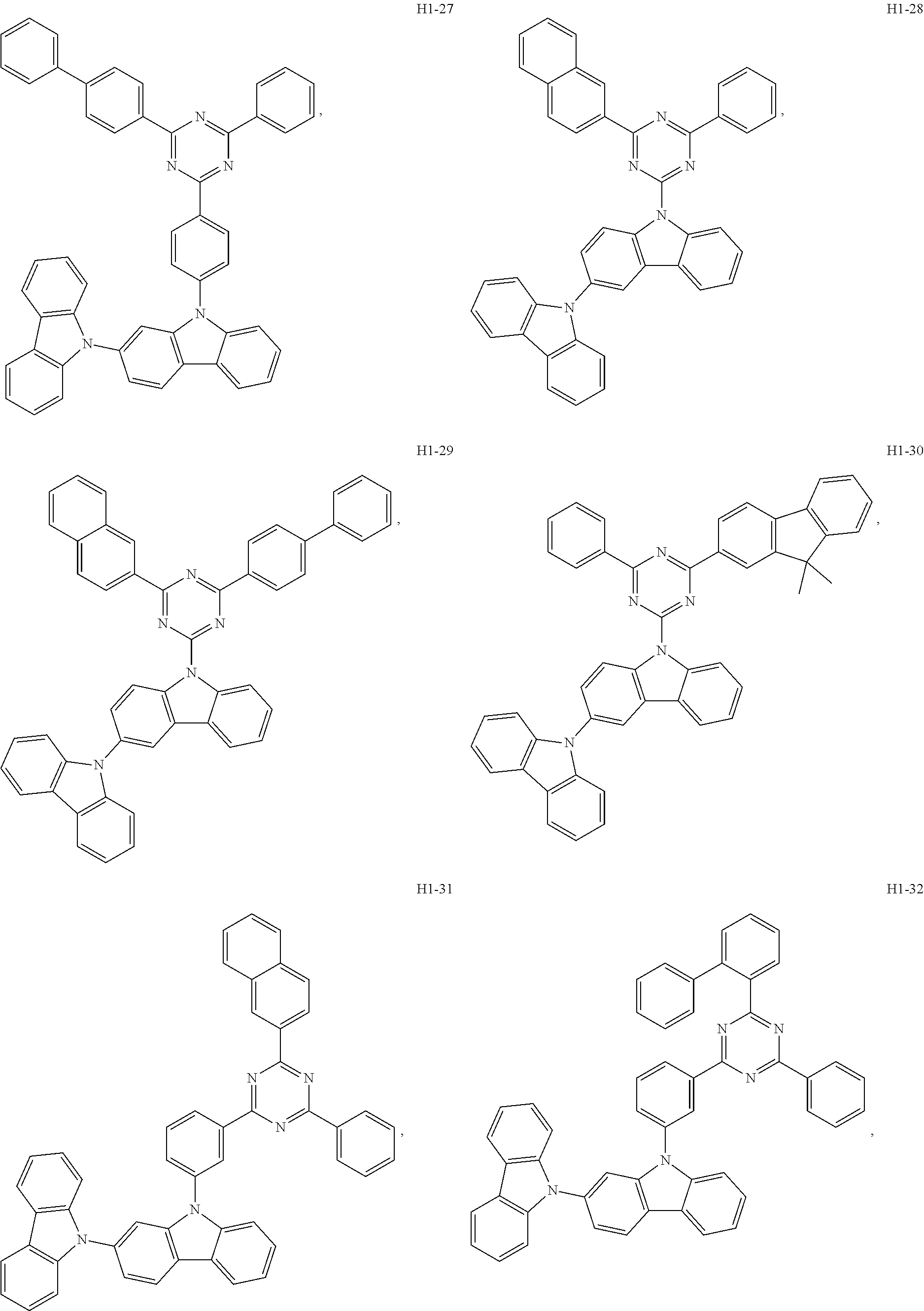

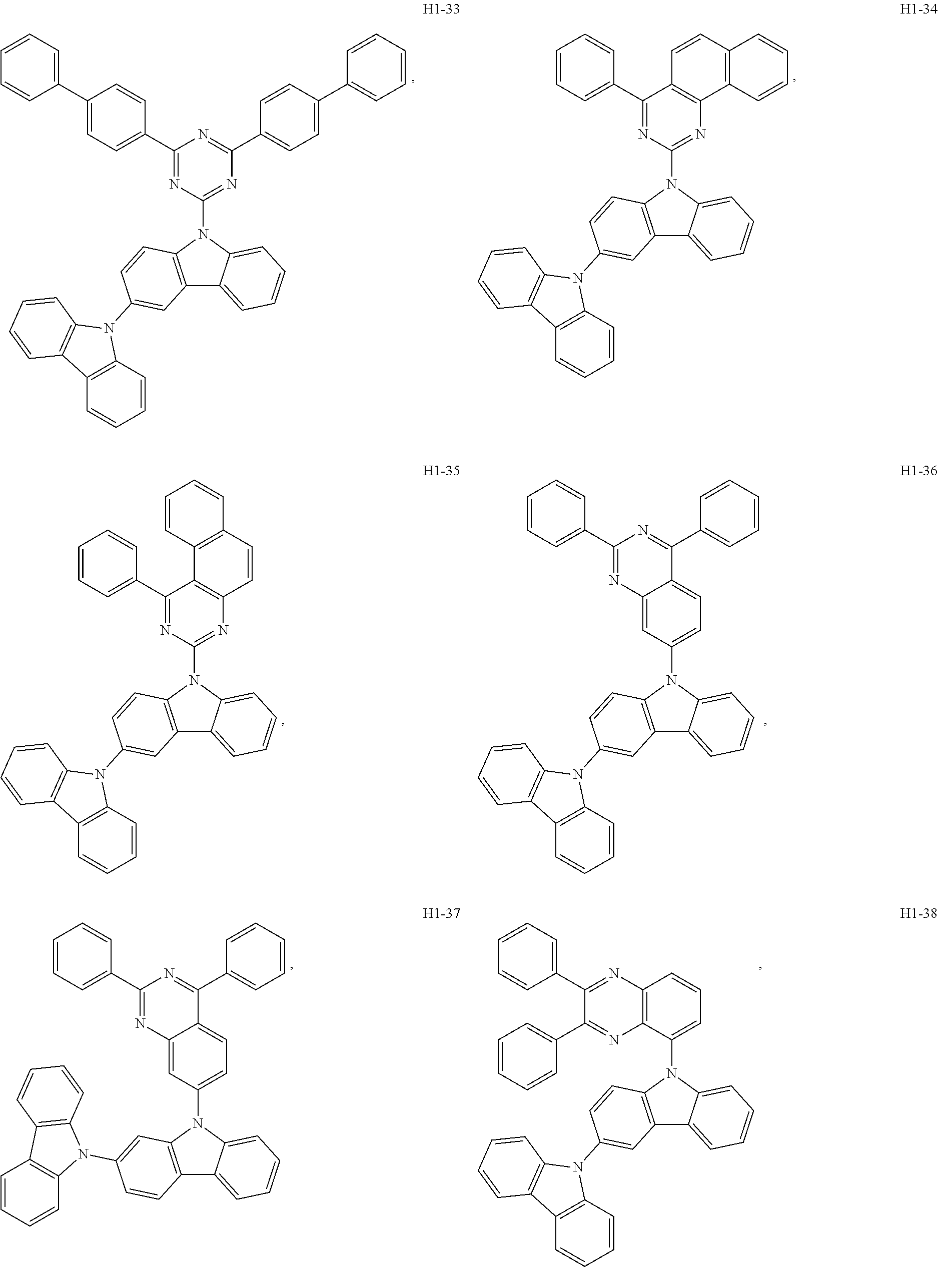 [SMILES: c1ccc(-c2ccc(-c3nc(-c4ccc(-c5ccccc5)cc4)nc(-n4c5ccccc5c5cc(-n6c7ccccc7c7ccccc76)ccc54)n3)cc2)cc1 ; c1ccc(-c2nc(-n3c4ccccc4c4cc(-n5c6ccccc6c6ccccc65)ccc43)nc3c2ccc2ccccc23)cc1 ; c1ccc(-c2nc(-n3c4ccccc4c4cc(-n5c6ccccc6c6ccccc65)ccc43)nc3ccc4ccccc4c23)cc1 ; c1ccc(-c2nc(-c3ccccc3)c3ccc(-n4c5ccccc5c5cc(-n6c7ccccc7c7ccccc76)ccc54)cc3n2)cc1 ; c1ccc(-c2nc(-c3ccccc3)c3ccc(-n4c5ccccc5c5ccc(-n6c7ccccc7c7ccccc76)cc54)cc3n2)cc1 ; c1ccc(-c2nc3cccc(-n4c5ccccc5c5cc(-n6c7ccccc7c7ccccc76)ccc54)c3nc2-c2ccccc2)cc1]

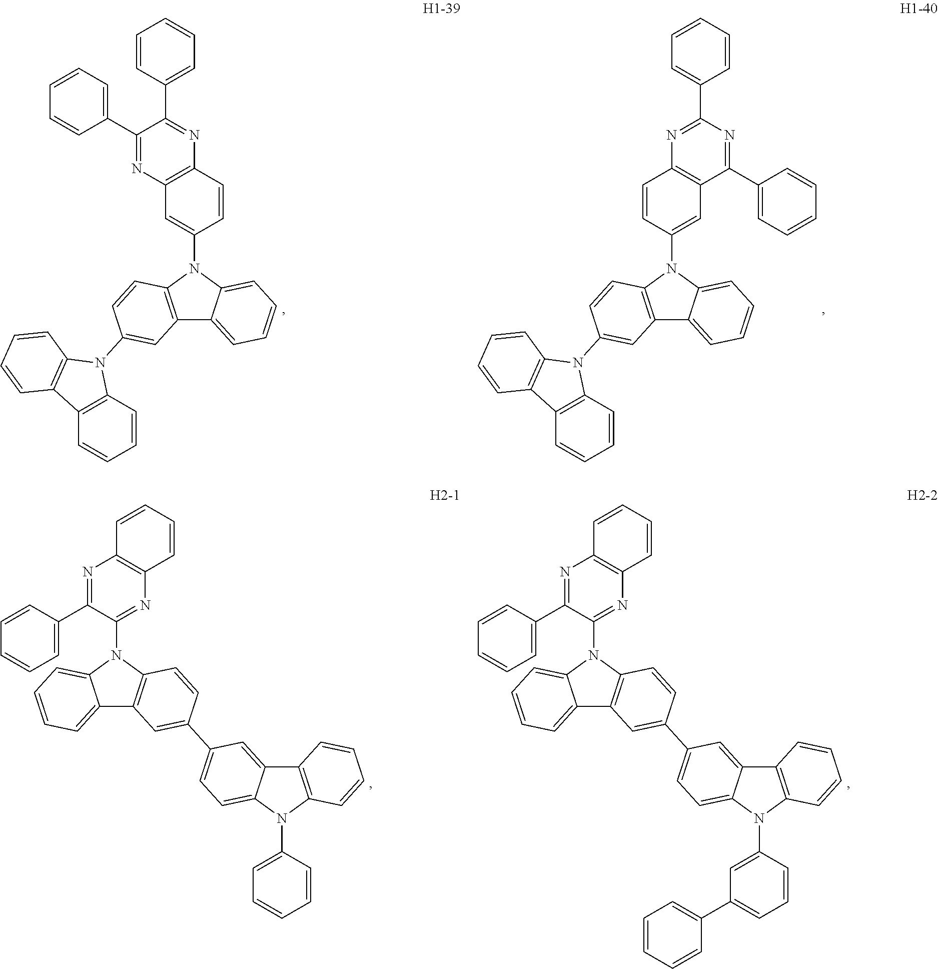 [SMILES: c1ccc(-c2nc3ccc(-n4c5ccccc5c5cc(-n6c7ccccc7c7ccccc76)ccc54)cc3nc2-c2ccccc2)cc1 ; c1ccc(-c2nc(-c3ccccc3)c3cc(-n4c5ccccc5c5cc(-n6c7ccccc7c7ccccc76)ccc54)ccc3n2)cc1 ; c1ccc(-c2nc3ccccc3nc2-n2c3ccccc3c3cc(-c4ccc5c(c4)c4ccccc4n5-c4ccccc4)ccc32)cc1 ; c1ccc(-c2cccc(-n3c4ccccc4c4cc(-c5ccc6c(c5)c5ccccc5n6-c5nc6ccccc6nc5-c5ccccc5)ccc43)c2)cc1]

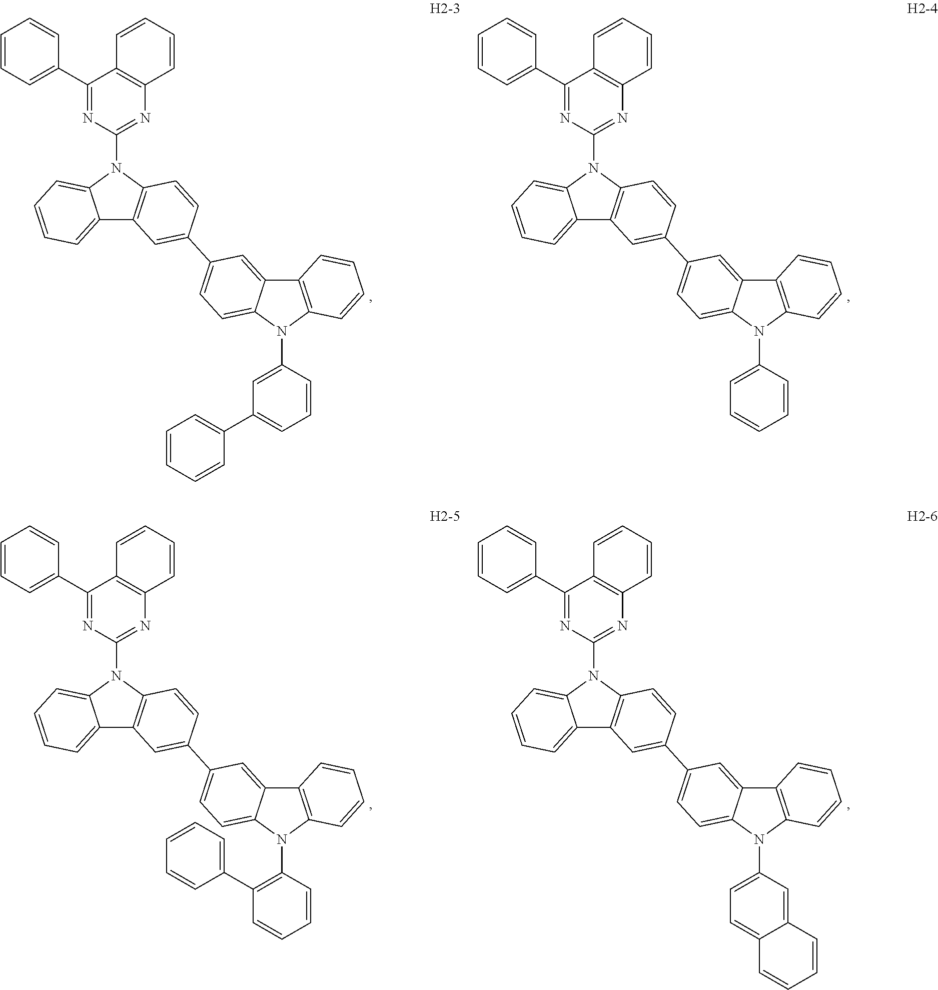 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2ccccc2-n2c3ccccc3c3cc(-c4ccc5c(c4)c4ccccc4n5-c4nc(-c5ccccc5)c5ccccc5n4)ccc32)cc1 ; c1ccc(-c2nc(-n3c4ccccc4c4cc(-c5ccc6c(c5)c5ccccc5n6-c5ccc6ccccc6c5)ccc43)nc3ccccc23)cc1]

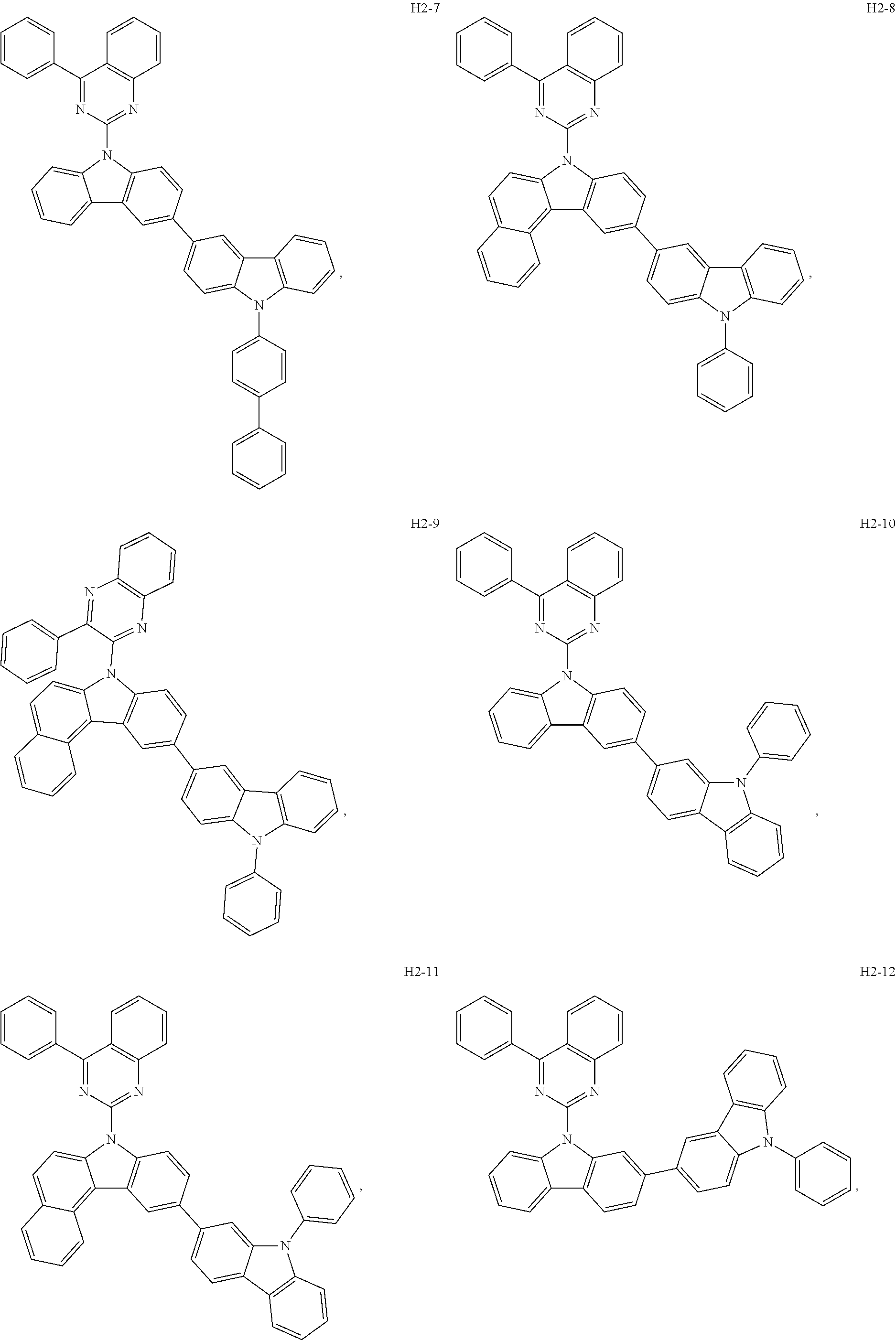

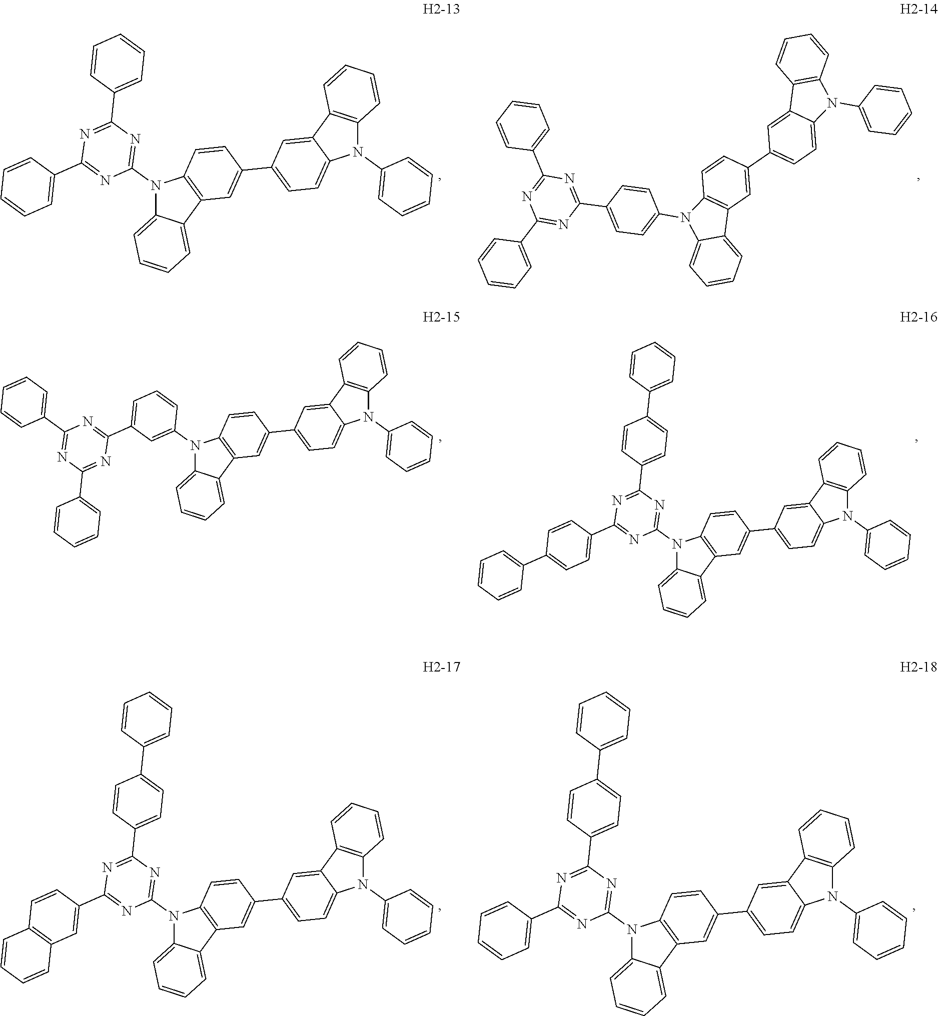

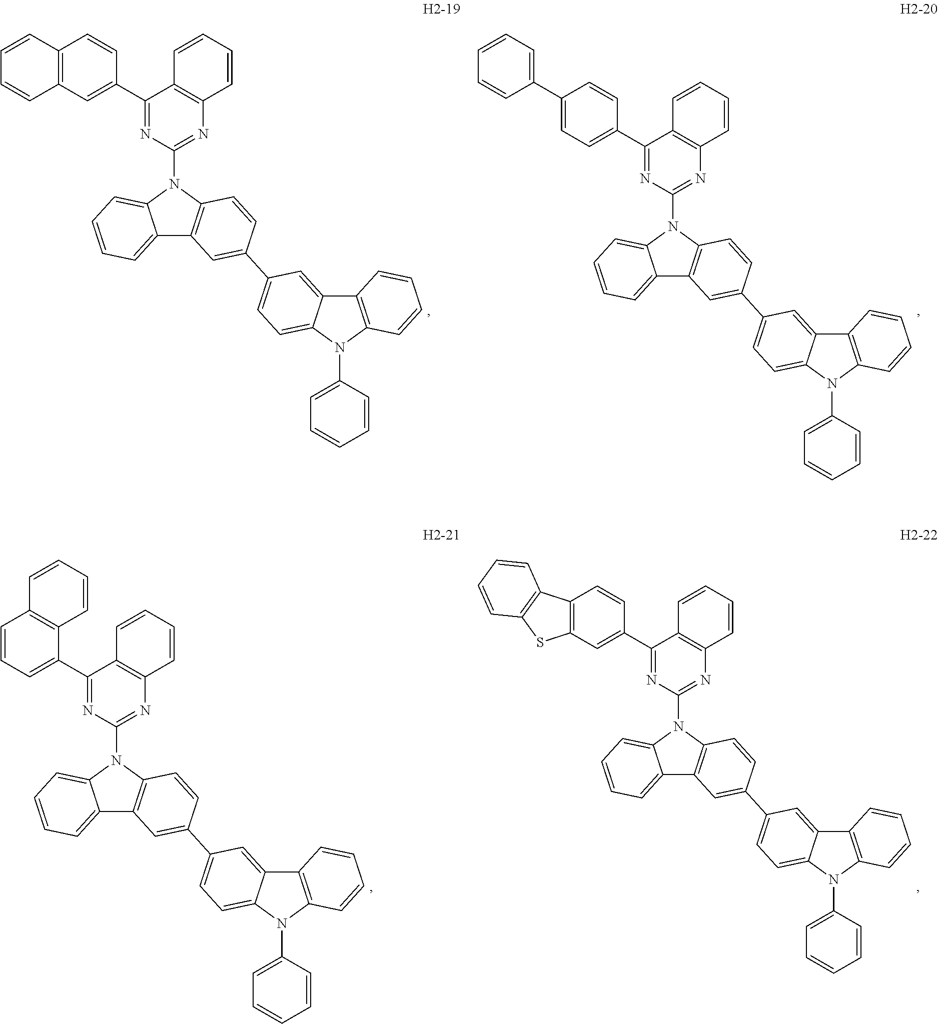 [SMILES: c1ccc(-n2c3ccccc3c3cc(-c4ccc5c(c4)c4ccccc4n5-c4nc(-c5ccc6ccccc6c5)c5ccccc5n4)ccc32)cc1 ; c1ccc(-c2ccc(-c3nc(-n4c5ccccc5c5cc(-c6ccc7c(c6)c6ccccc6n7-c6ccccc6)ccc54)nc4ccccc34)cc2)cc1 ; c1ccc(-n2c3ccccc3c3cc(-c4ccc5c(c4)c4ccccc4n5-c4nc(-c5cccc6ccccc56)c5ccccc5n4)ccc32)cc1 ; c1ccc(-n2c3ccccc3c3cc(-c4ccc5c(c4)c4ccccc4n5-c4nc(-c5ccc6c(c5)sc5ccccc56)c5ccccc5n4)ccc32)cc1]

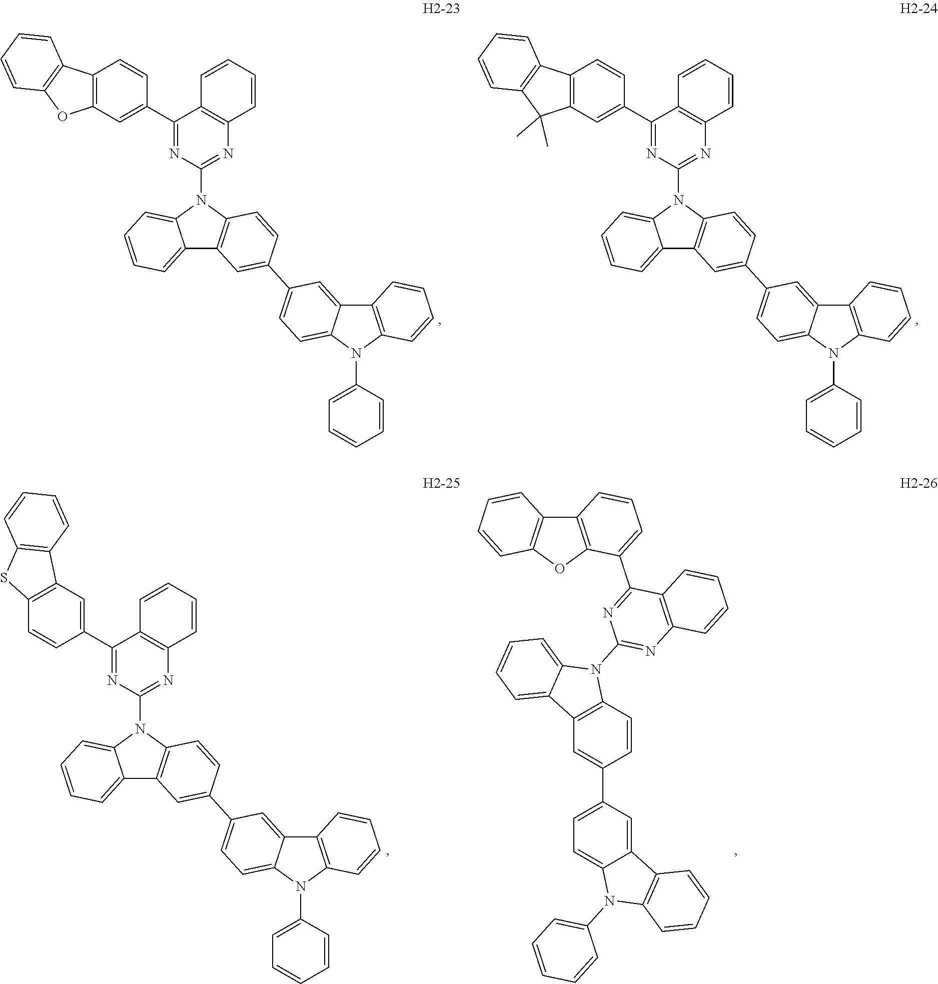 [SMILES: c1ccc(-n2c3ccccc3c3cc(-c4ccc5c(c4)c4ccccc4n5-c4nc(-c5ccc6c(c5)oc5ccccc56)c5ccccc5n4)ccc32)cc1 ; CC1(C)c2ccccc2-c2ccc(-c3nc(-n4c5ccccc5c5cc(-c6ccc7c(c6)c6ccccc6n7-c6ccccc6)ccc54)nc4ccccc34)cc21 ; c1ccc(-n2c3ccccc3c3cc(-c4ccc5c(c4)c4ccccc4n5-c4nc(-c5ccc6sc7ccccc7c6c5)c5ccccc5n4)ccc32)cc1 ; c1ccc(-n2c3ccccc3c3cc(-c4ccc5c(c4)c4ccccc4n5-c4nc(-c5cccc6c5oc5ccccc56)c5ccccc5n4)ccc32)cc1]

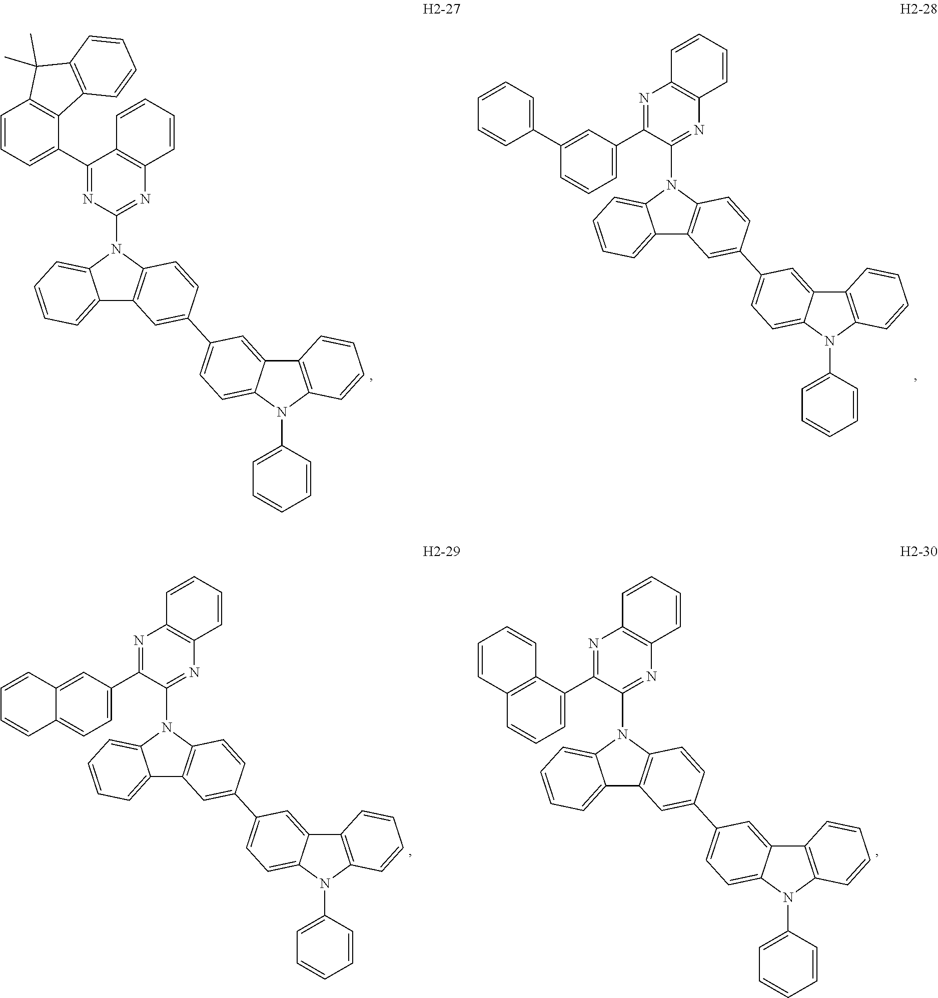 [SMILES: CC1(C)c2ccccc2-c2c(-c3nc(-n4c5ccccc5c5cc(-c6ccc7c(c6)c6ccccc6n7-c6ccccc6)ccc54)nc4ccccc34)cccc21 ; c1ccc(-c2cccc(-c3nc4ccccc4nc3-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4nc5ccccc5nc4-c4ccc5ccccc5c4)ccc32)cc1 ; c1ccc(-n2c3ccccc3c3cc(-c4ccc5c(c4)c4ccccc4n5-c4nc5ccccc5nc4-c4cccc5ccccc45)ccc32)cc1]

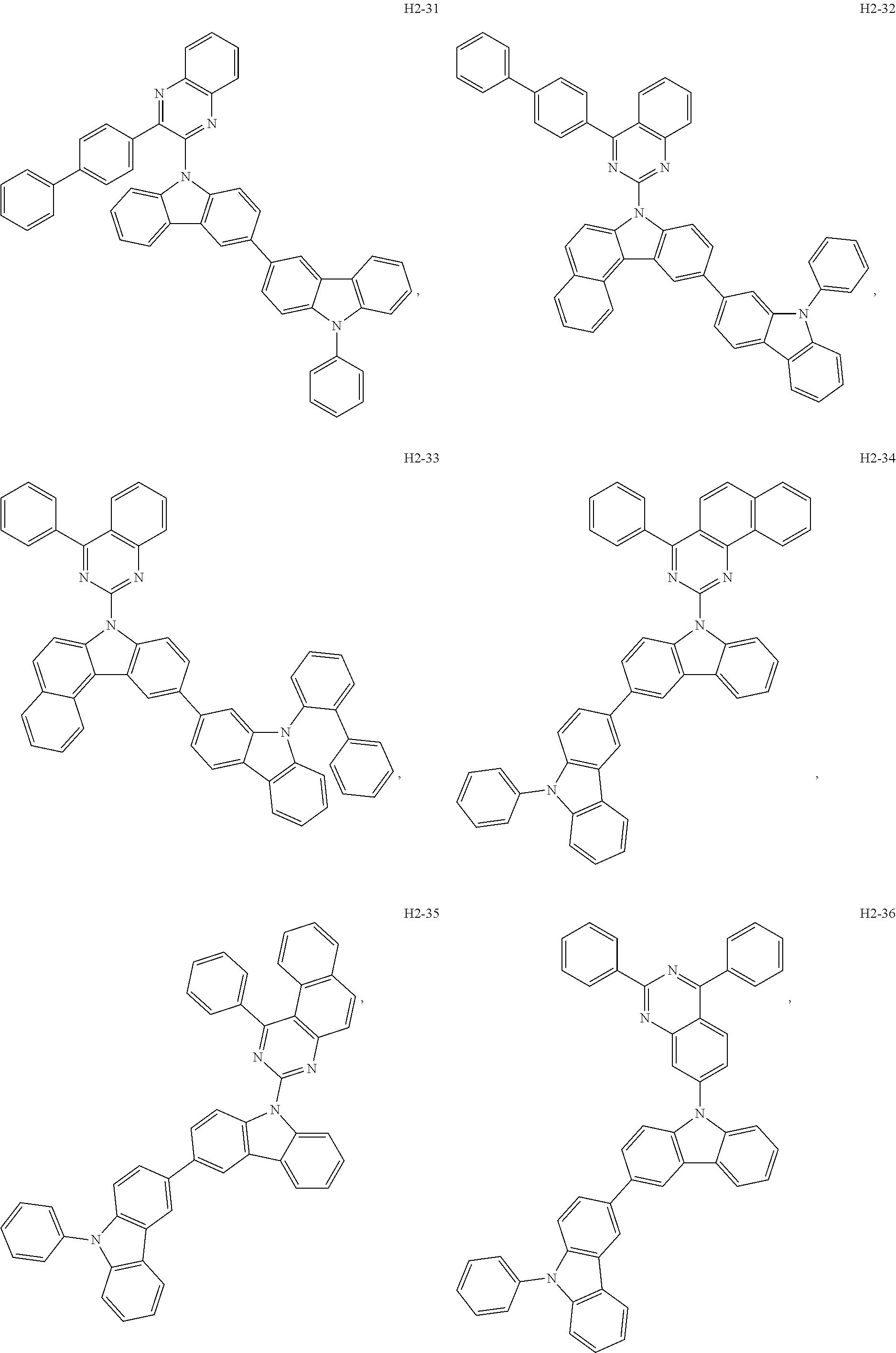

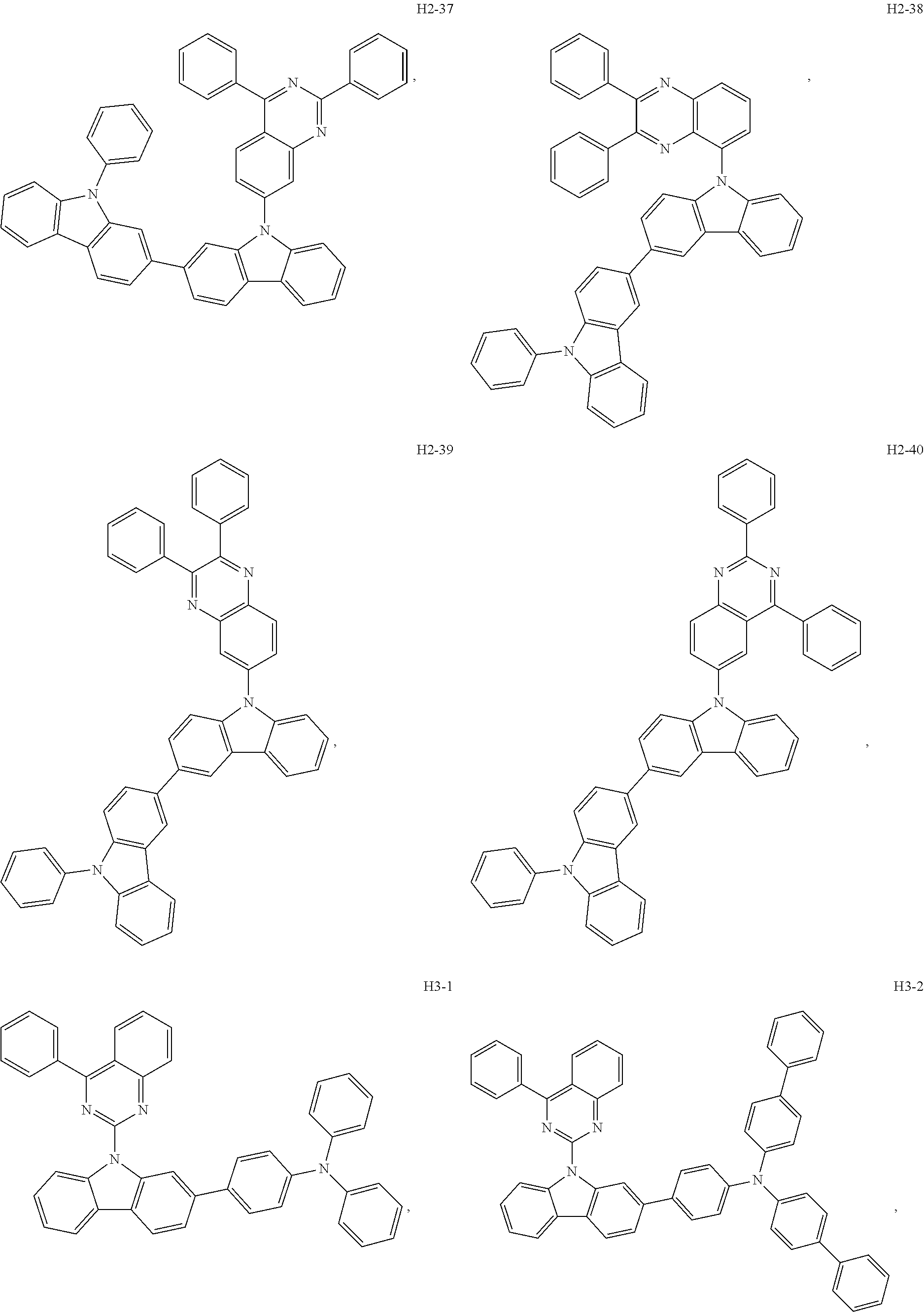

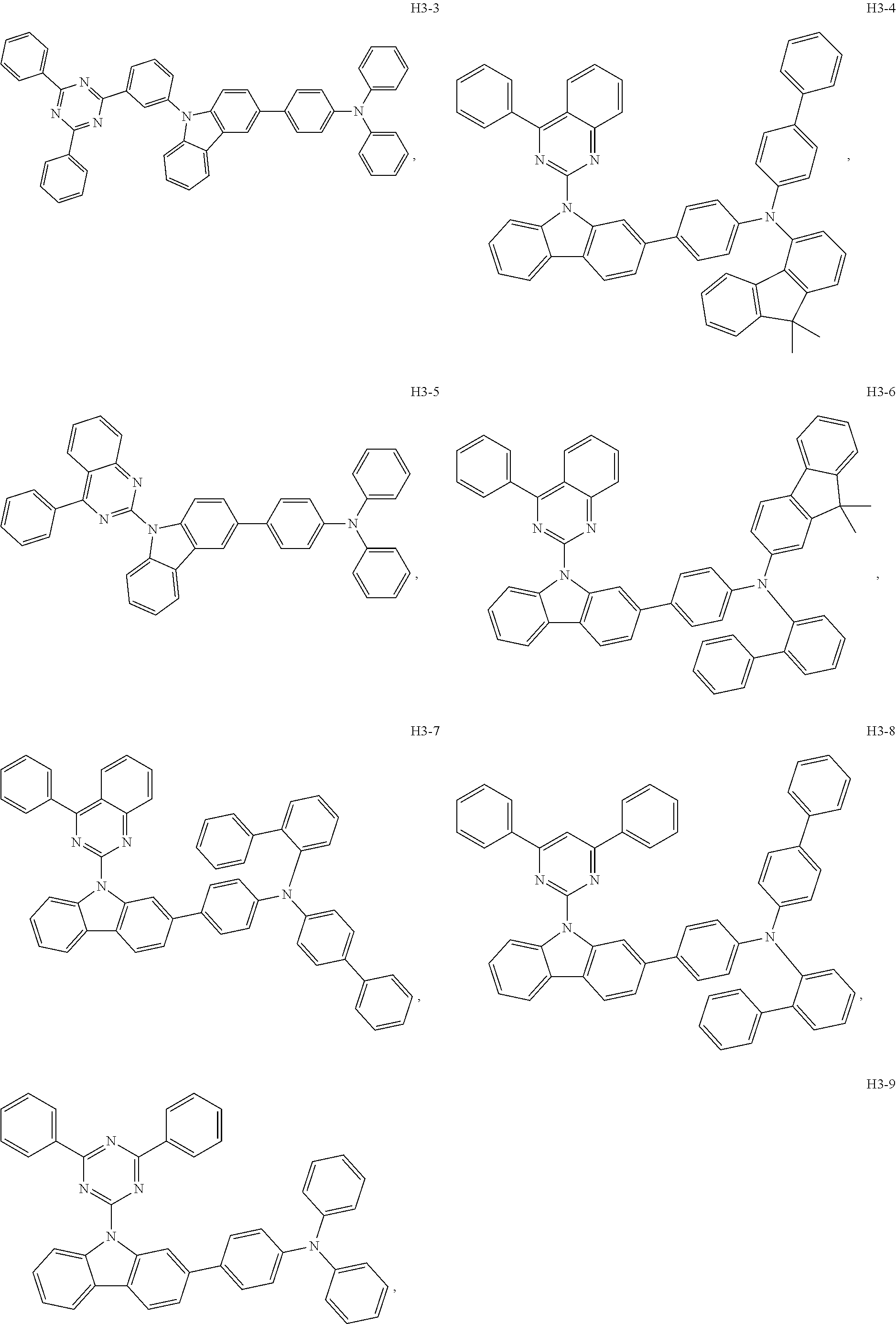

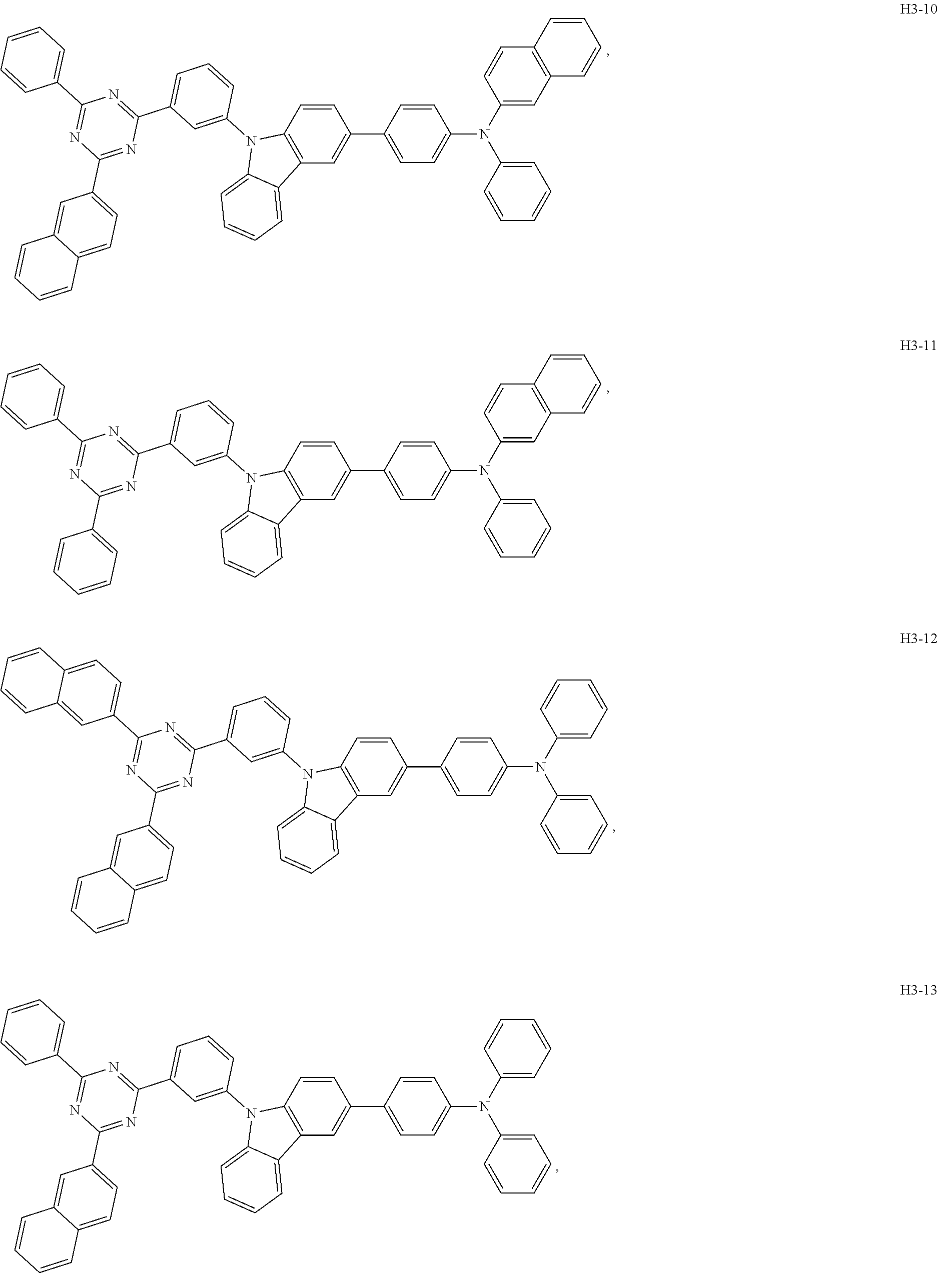 [SMILES: c1ccc(-c2nc(-c3cccc(-n4c5ccccc5c5cc(-c6ccc(N(c7ccccc7)c7ccc8ccccc8c7)cc6)ccc54)c3)nc(-c3ccc4ccccc4c3)n2)cc1 ; c1ccc(-c2nc(-c3ccccc3)nc(-c3cccc(-n4c5ccccc5c5cc(-c6ccc(N(c7ccccc7)c7ccc8ccccc8c7)cc6)ccc54)c3)n2)cc1 ; c1ccc(N(c2ccccc2)c2ccc(-c3ccc4c(c3)c3ccccc3n4-c3cccc(-c4nc(-c5ccc6ccccc6c5)nc(-c5ccc6ccccc6c5)n4)c3)cc2)cc1 ; c1ccc(-c2nc(-c3cccc(-n4c5ccccc5c5cc(-c6ccc(N(c7ccccc7)c7ccccc7)cc6)ccc54)c3)nc(-c3ccc4ccccc4c3)n2)cc1]

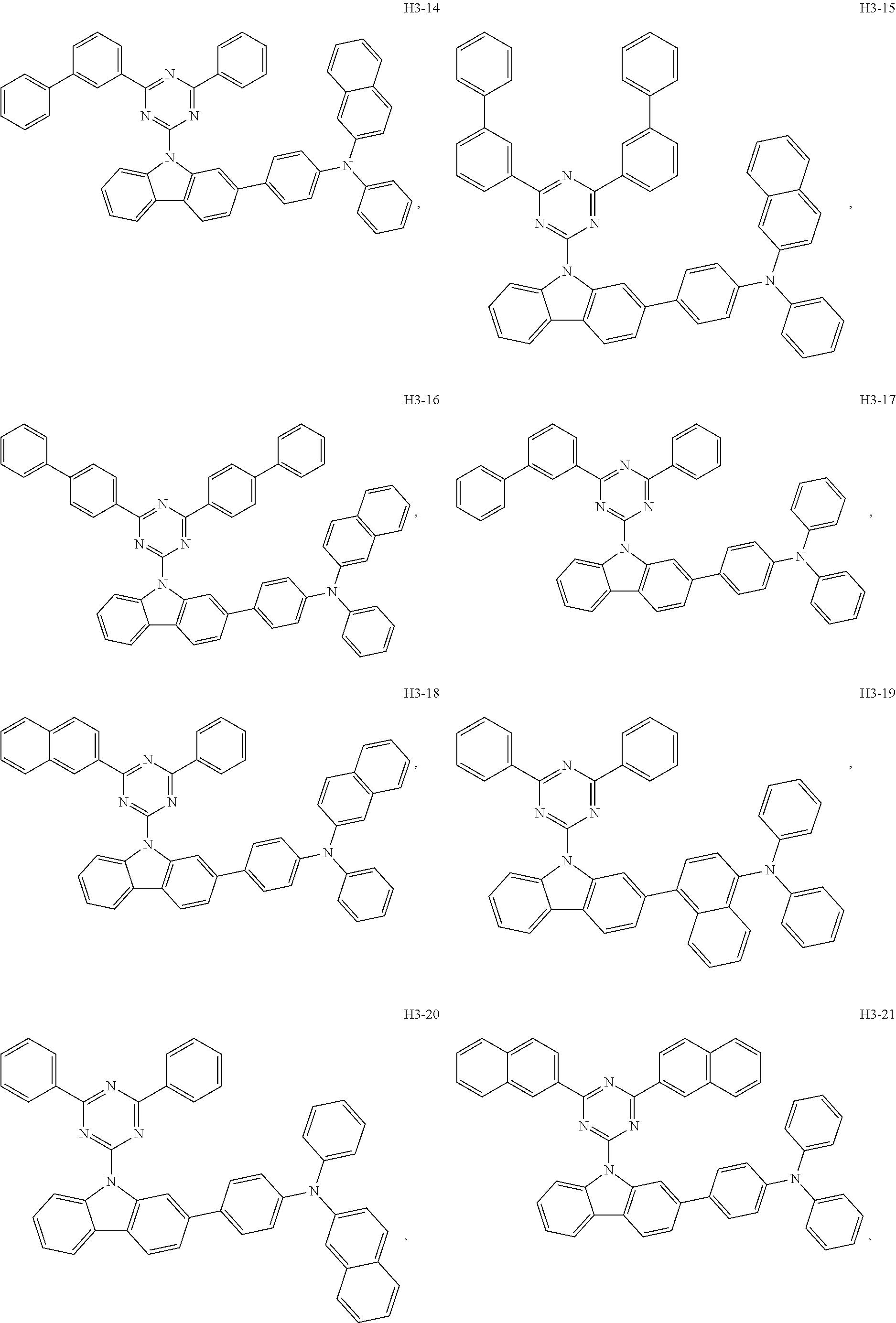

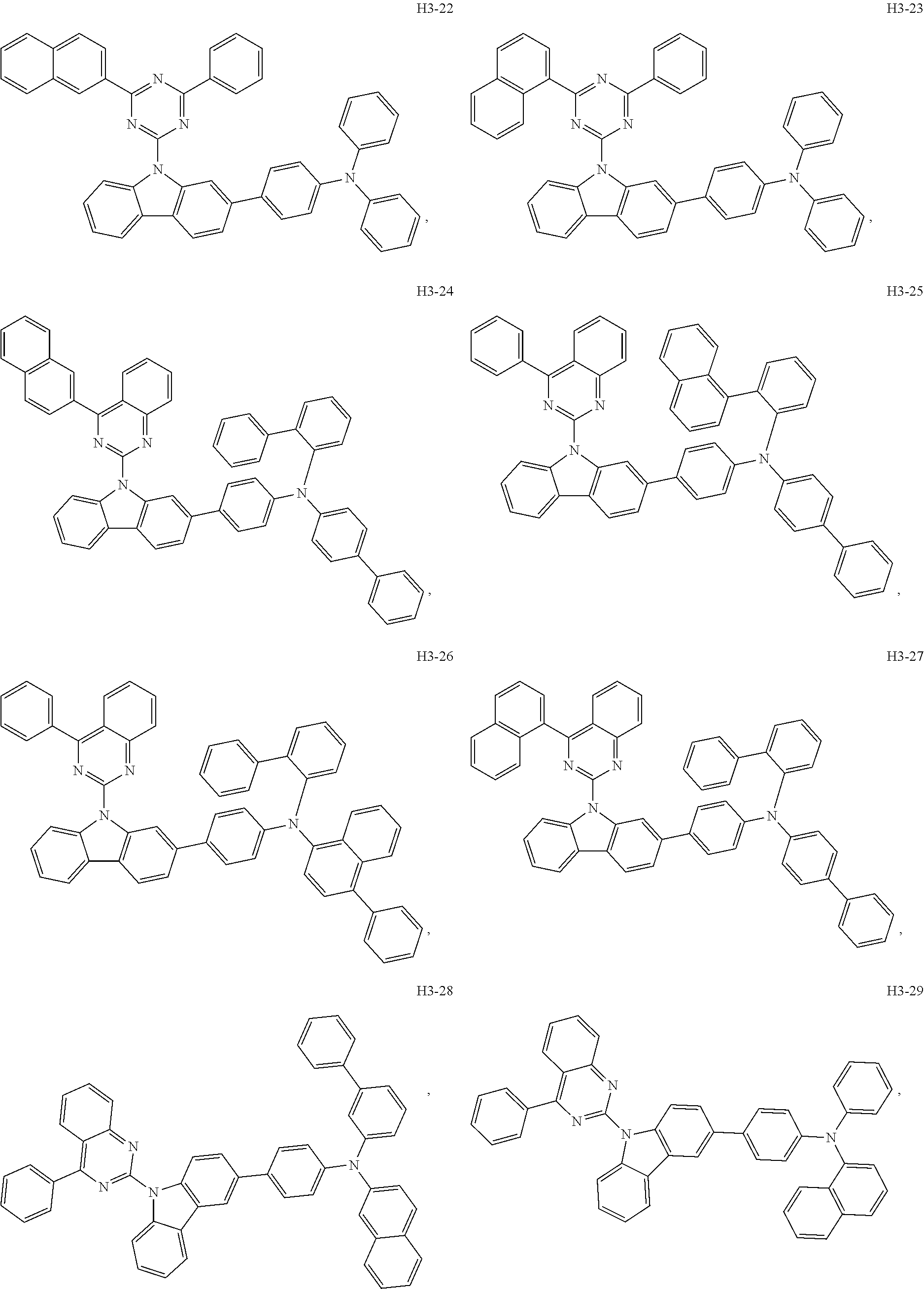

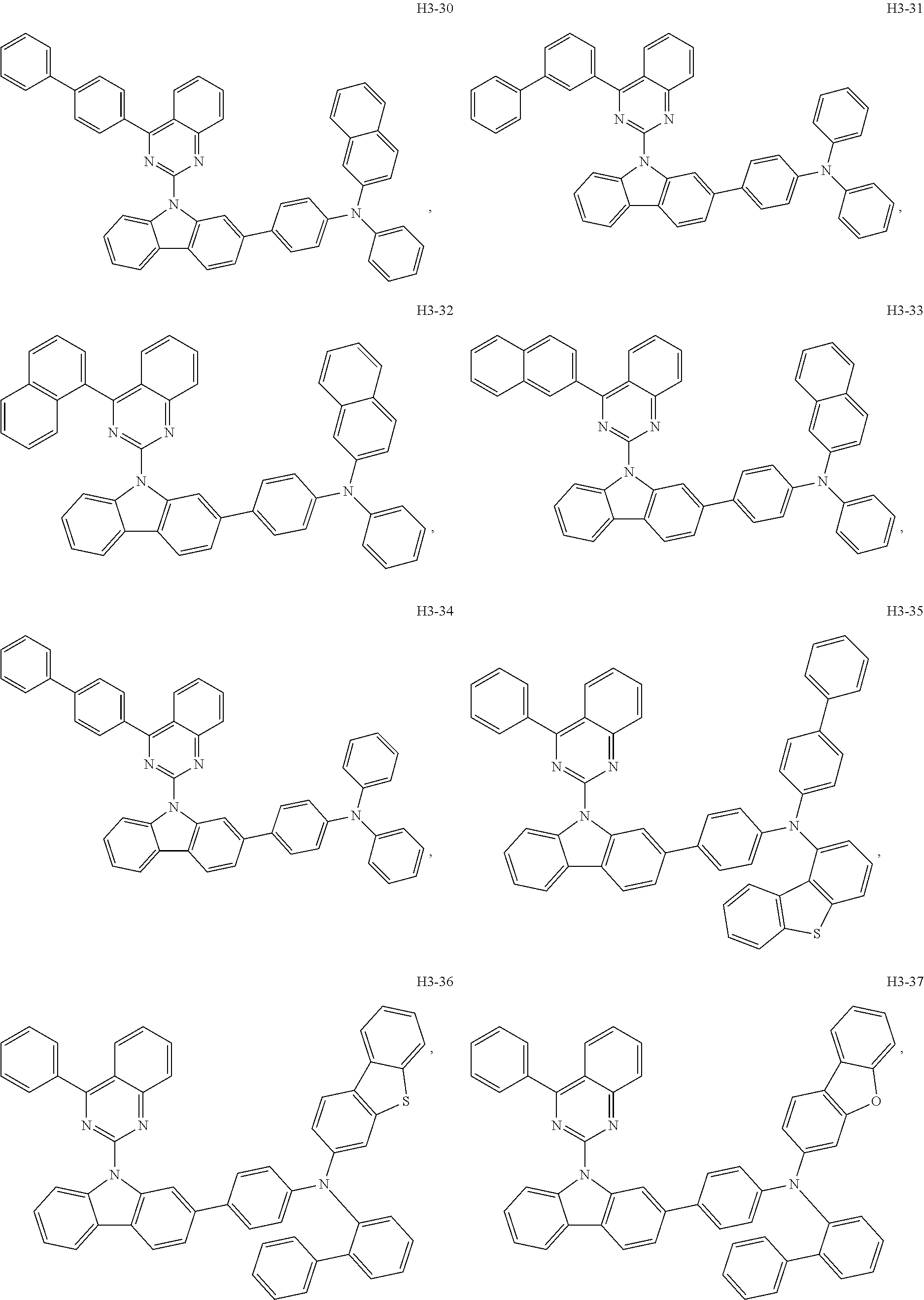

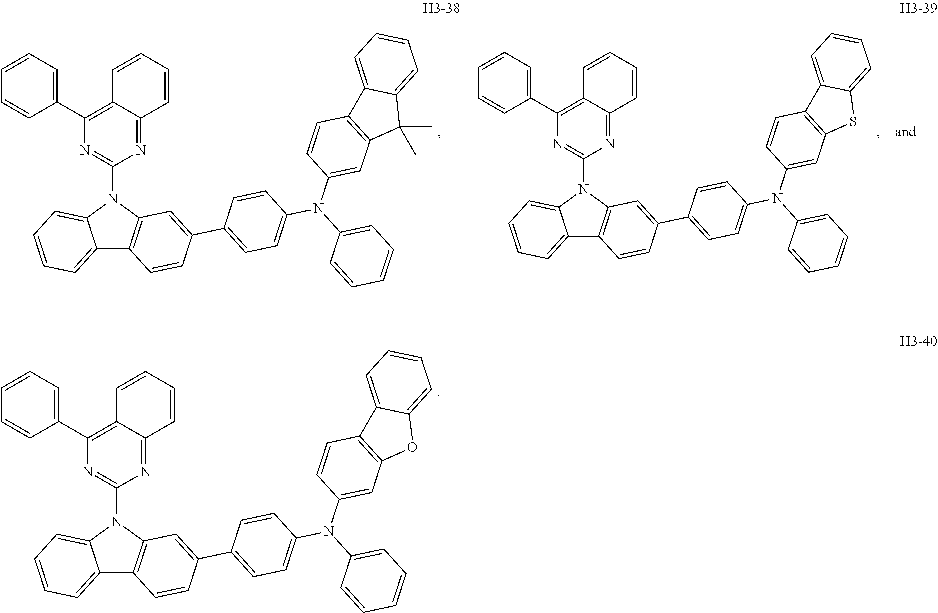 [SMILES: CC1(C)c2ccccc2-c2ccc(N(c3ccccc3)c3ccc(-c4ccc5c6ccccc6n(-c6nc(-c7ccccc7)c7ccccc7n6)c5c4)cc3)cc21 ; c1ccc(-c2nc(-n3c4ccccc4c4ccc(-c5ccc(N(c6ccccc6)c6ccc7c(c6)sc6ccccc67)cc5)cc43)nc3ccccc23)cc1 ; c1ccc(-c2nc(-n3c4ccccc4c4ccc(-c5ccc(N(c6ccccc6)c6ccc7c(c6)oc6ccccc67)cc5)cc43)nc3ccccc23)cc1]

31. The electroluminescent device according to claim 1, wherein the first compound is selected from the group consisting of the following structures:

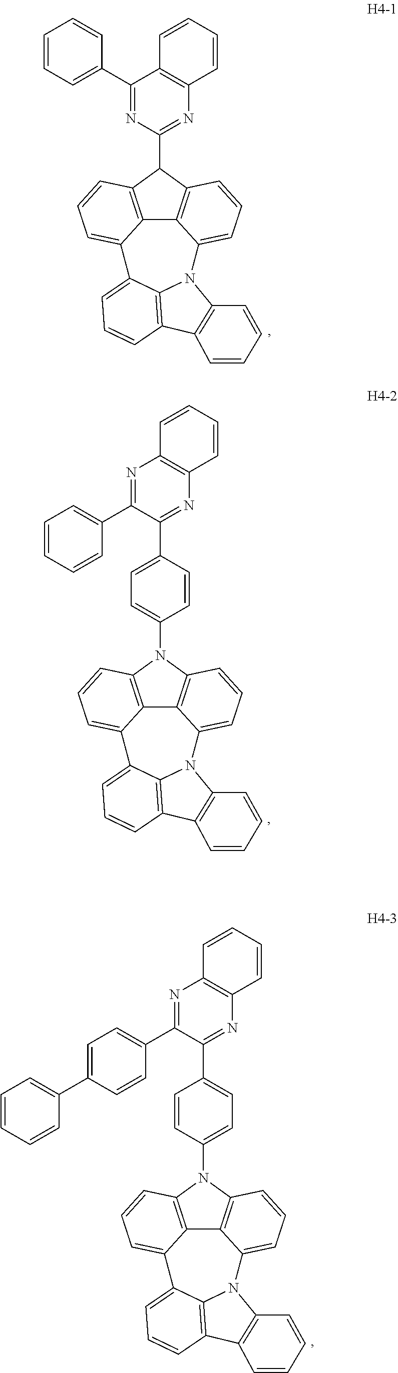 [SMILES: c1ccc(-c2nc(C3c4cccc5c4-c4c3cccc4-n3c4ccccc4c4cccc-5c43)nc3ccccc23)cc1 ; c1ccc(-c2nc3ccccc3nc2-c2ccc(-n3c4cccc5c6cccc7c8ccccc8n(c8cccc3c8c54)c67)cc2)cc1 ; c1ccc(-c2ccc(-c3nc4ccccc4nc3-c3ccc(-n4c5cccc6c7cccc8c9ccccc9n(c9cccc4c9c65)c78)cc3)cc2)cc1]

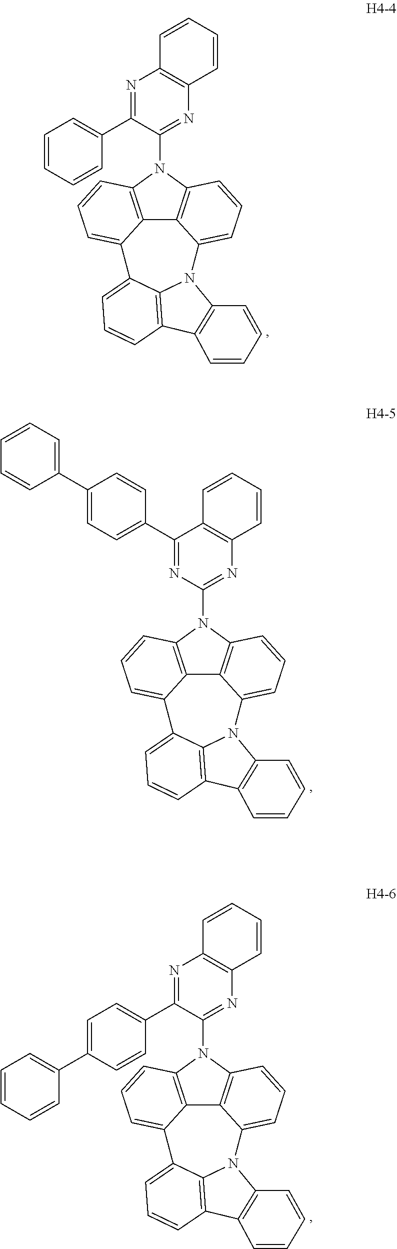 [SMILES: c1ccc(-c2nc3ccccc3nc2-n2c3cccc4c5cccc6c7ccccc7n(c7cccc2c7c43)c56)cc1 ; c1ccc(-c2ccc(-c3nc(-n4c5cccc6c7cccc8c9ccccc9n(c9cccc4c9c65)c78)nc4ccccc34)cc2)cc1 ; c1ccc(-c2ccc(-c3nc4ccccc4nc3-n3c4cccc5c6cccc7c8ccccc8n(c8cccc3c8c54)c67)cc2)cc1]

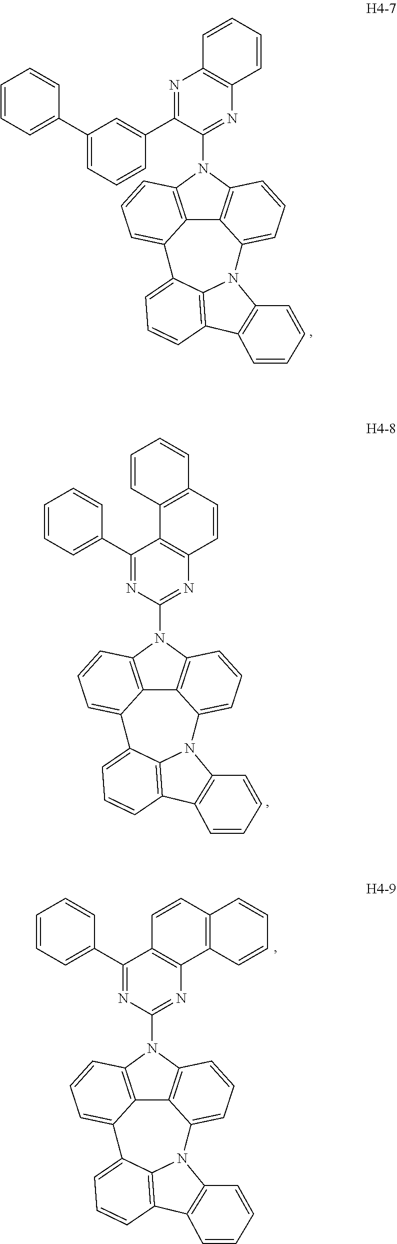 [SMILES: c1ccc(-c2cccc(-c3nc4ccccc4nc3-n3c4cccc5c6cccc7c8ccccc8n(c8cccc3c8c54)c67)c2)cc1 ; c1ccc(-c2nc(-n3c4cccc5c6cccc7c8ccccc8n(c8cccc3c8c54)c67)nc3ccc4ccccc4c23)cc1 ; c1ccc(-c2nc(-n3c4cccc5c6cccc7c8ccccc8n(c8cccc3c8c54)c67)nc3c2ccc2ccccc23)cc1]

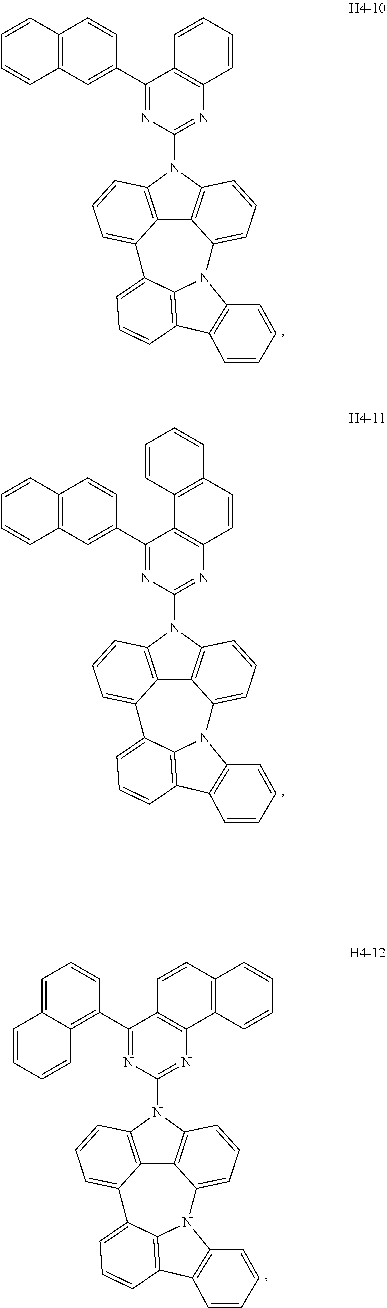 [SMILES: c1ccc2cc(-c3nc(-n4c5cccc6c7cccc8c9ccccc9n(c9cccc4c9c65)c78)nc4ccccc34)ccc2c1 ; c1ccc2cc(-c3nc(-n4c5cccc6c7cccc8c9ccccc9n(c9cccc4c9c65)c78)nc4ccc5ccccc5c34)ccc2c1 ; c1ccc2c(-c3nc(-n4c5cccc6c7cccc8c9ccccc9n(c9cccc4c9c65)c78)nc4c3ccc3ccccc34)cccc2c1]

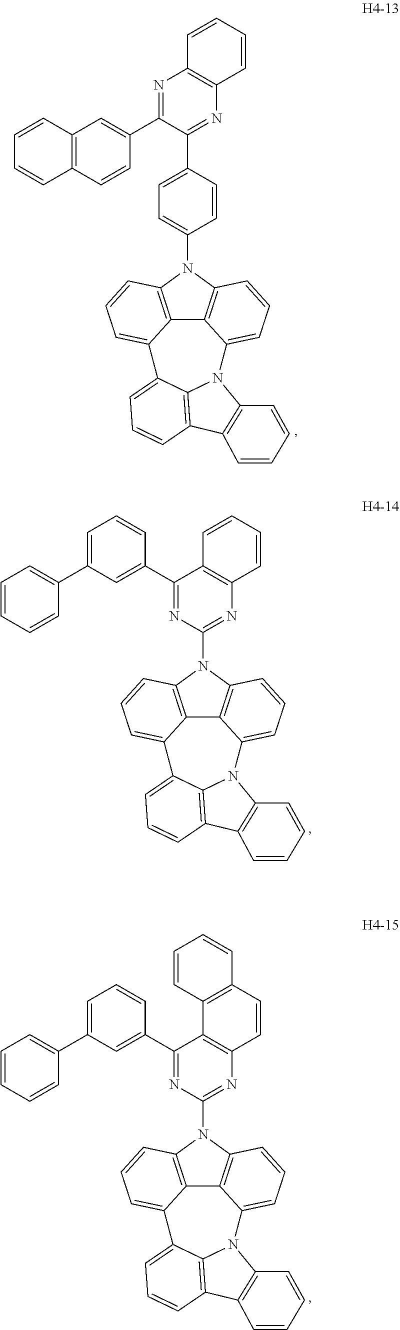 [SMILES: c1ccc2cc(-c3nc4ccccc4nc3-c3ccc(-n4c5cccc6c7cccc8c9ccccc9n(c9cccc4c9c65)c78)cc3)ccc2c1 ; c1ccc(-c2cccc(-c3nc(-n4c5cccc6c7cccc8c9ccccc9n(c9cccc4c9c65)c78)nc4ccccc34)c2)cc1 ; c1ccc(-c2cccc(-c3nc(-n4c5cccc6c7cccc8c9ccccc9n(c9cccc4c9c65)c78)nc4ccc5ccccc5c34)c2)cc1]

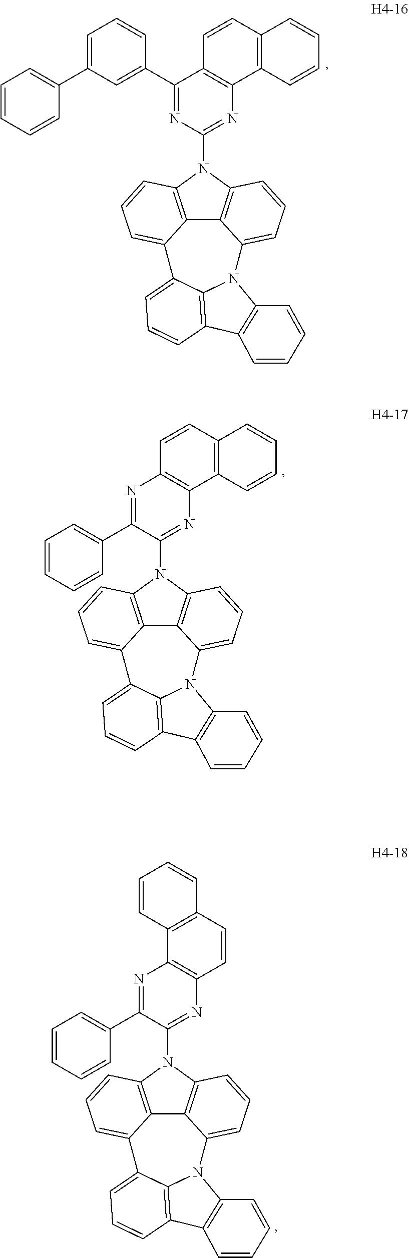 [SMILES: c1ccc(-c2cccc(-c3nc(-n4c5cccc6c7cccc8c9ccccc9n(c9cccc4c9c65)c78)nc4c3ccc3ccccc34)c2)cc1 ; c1ccc(-c2nc3ccc4ccccc4c3nc2-n2c3cccc4c5cccc6c7ccccc7n(c7cccc2c7c43)c56)cc1 ; c1ccc(-c2nc3c(ccc4ccccc43)nc2-n2c3cccc4c5cccc6c7ccccc7n(c7cccc2c7c43)c56)cc1]

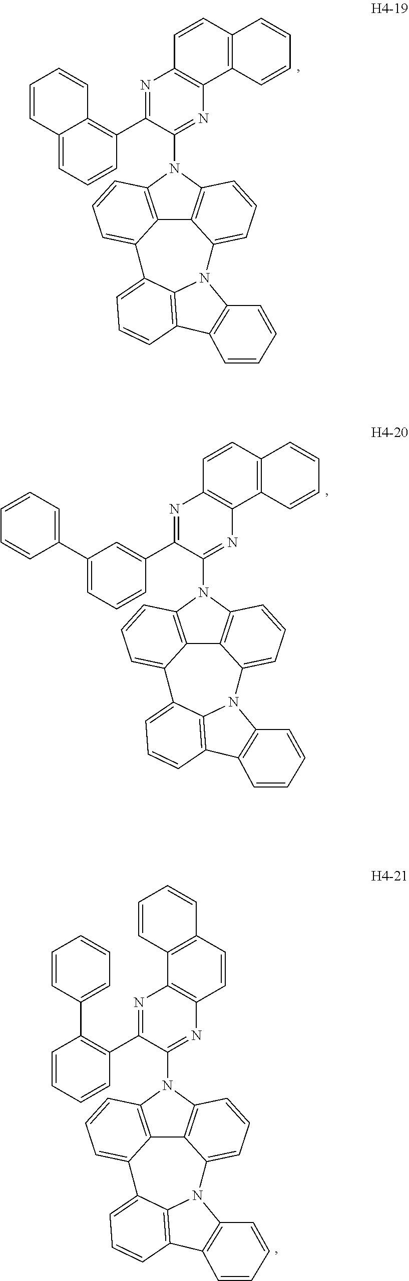 [SMILES: c1ccc2c(-c3nc4ccc5ccccc5c4nc3-n3c4cccc5c6cccc7c8ccccc8n(c8cccc3c8c54)c67)cccc2c1 ; c1ccc(-c2cccc(-c3nc4ccc5ccccc5c4nc3-n3c4cccc5c6cccc7c8ccccc8n(c8cccc3c8c54)c67)c2)cc1 ; c1ccc(-c2ccccc2-c2nc3c(ccc4ccccc43)nc2-n2c3cccc4c5cccc6c7ccccc7n(c7cccc2c7c43)c56)cc1]

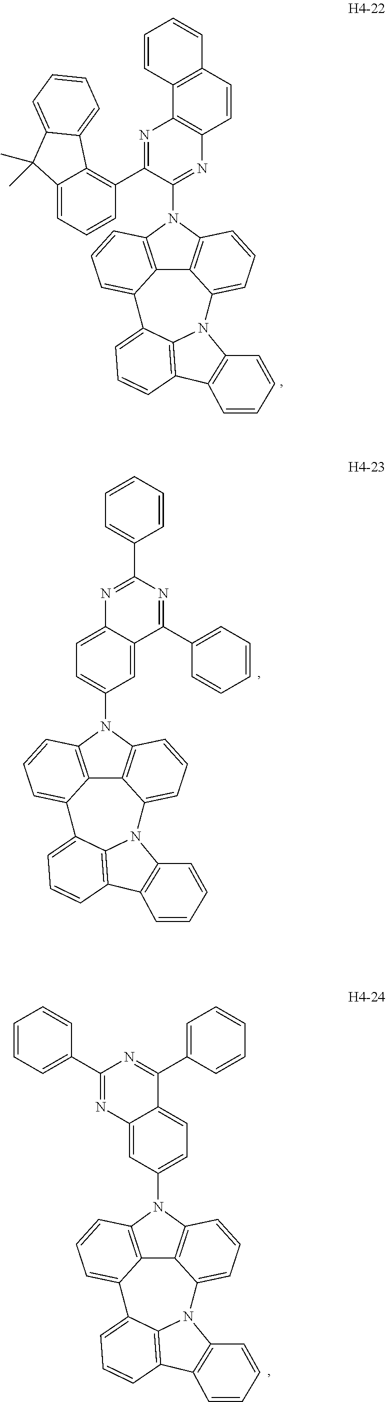 [SMILES: CC1(C)c2ccccc2-c2c(-c3nc4c(ccc5ccccc54)nc3-n3c4cccc5c6cccc7c8ccccc8n(c8cccc3c8c54)c67)cccc21 ; c1ccc(-c2nc(-c3ccccc3)c3cc(-n4c5cccc6c7cccc8c9ccccc9n(c9cccc4c9c65)c78)ccc3n2)cc1 ; c1ccc(-c2nc(-c3ccccc3)c3ccc(-n4c5cccc6c7cccc8c9ccccc9n(c9cccc4c9c65)c78)cc3n2)cc1]

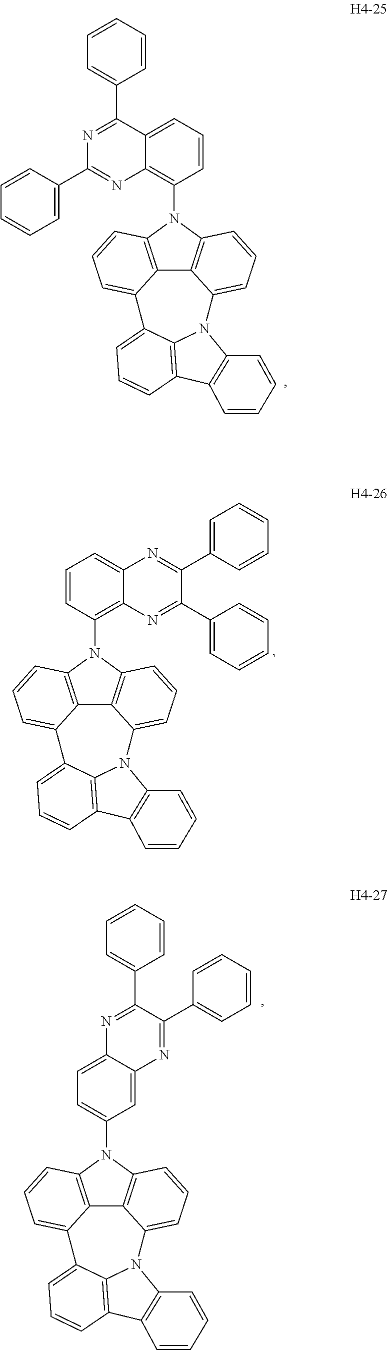 [SMILES: c1ccc(-c2nc(-c3ccccc3)c3cccc(-n4c5cccc6c7cccc8c9ccccc9n(c9cccc4c9c65)c78)c3n2)cc1 ; c1ccc(-c2nc3cccc(-n4c5cccc6c7cccc8c9ccccc9n(c9cccc4c9c65)c78)c3nc2-c2ccccc2)cc1 ; c1ccc(-c2nc3ccc(-n4c5cccc6c7cccc8c9ccccc9n(c9cccc4c9c65)c78)cc3nc2-c2ccccc2)cc1]

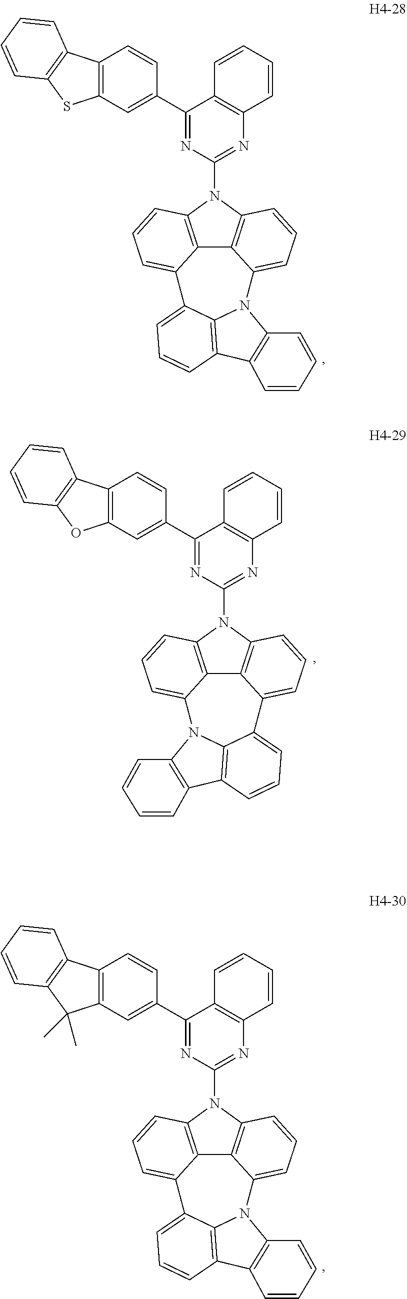 [SMILES: c1ccc2c(-c3ccc4c(c3)sc3ccccc34)nc(-n3c4cccc5c6cccc7c8ccccc8n(c8cccc3c8c54)c67)nc2c1 ; c1ccc2c(-c3ccc4c(c3)oc3ccccc34)nc(-n3c4cccc5c6cccc7c8ccccc8n(c8cccc3c8c54)c67)nc2c1 ; CC1(C)c2ccccc2-c2ccc(-c3nc(-n4c5cccc6c7cccc8c9ccccc9n(c9cccc4c9c65)c78)nc4ccccc34)cc21]

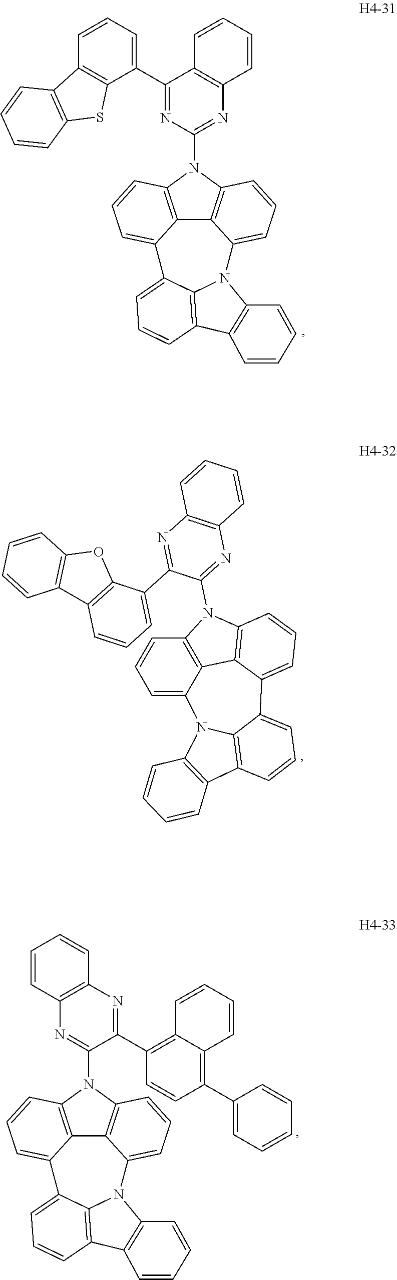 [SMILES: c1ccc2c(-c3cccc4c3sc3ccccc34)nc(-n3c4cccc5c6cccc7c8ccccc8n(c8cccc3c8c54)c67)nc2c1 ; c1ccc2nc(-n3c4cccc5c6cccc7c8ccccc8n(c8cccc3c8c54)c67)c(-c3cccc4c3oc3ccccc34)nc2c1 ; c1ccc(-c2ccc(-c3nc4ccccc4nc3-n3c4cccc5c6cccc7c8ccccc8n(c8cccc3c8c54)c67)c3ccccc23)cc1]

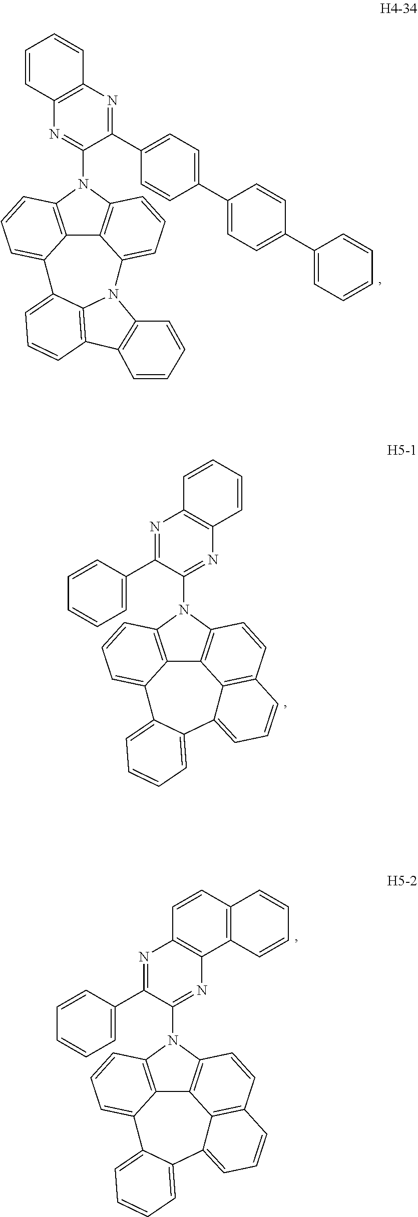 [SMILES: c1ccc(-c2ccc(-c3ccc(-c4nc5ccccc5nc4-n4c5cccc6c7cccc8c9ccccc9n(c9cccc4c9c65)c78)cc3)cc2)cc1 ; c1ccc(-c2nc3ccccc3nc2-n2c3cccc4c3c3c5c(cccc5ccc32)-c2ccccc2-4)cc1 ; c1ccc(-c2nc3ccc4ccccc4c3nc2-n2c3cccc4c3c3c5c(cccc5ccc32)-c2ccccc2-4)cc1]

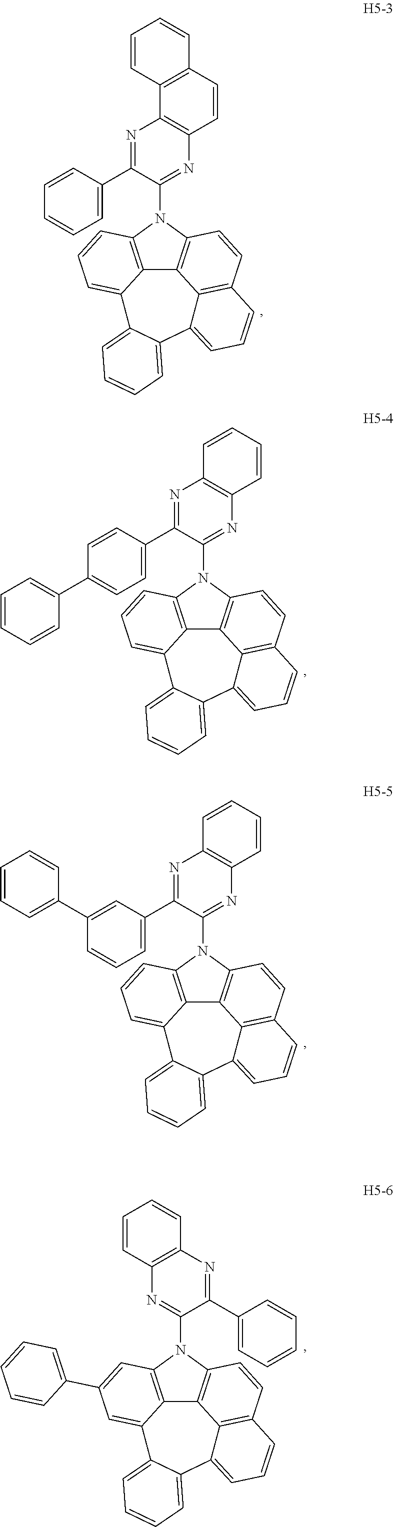 [SMILES: c1ccc(-c2nc3c(ccc4ccccc43)nc2-n2c3cccc4c3c3c5c(cccc5ccc32)-c2ccccc2-4)cc1 ; c1ccc(-c2ccc(-c3nc4ccccc4nc3-n3c4cccc5c4c4c6c(cccc6ccc43)-c3ccccc3-5)cc2)cc1 ; c1ccc(-c2cccc(-c3nc4ccccc4nc3-n3c4cccc5c4c4c6c(cccc6ccc43)-c3ccccc3-5)c2)cc1 ; c1ccc(-c2cc3c4c5c6c(cccc6ccc5n(-c5nc6ccccc6nc5-c5ccccc5)c4c2)-c2ccccc2-3)cc1]

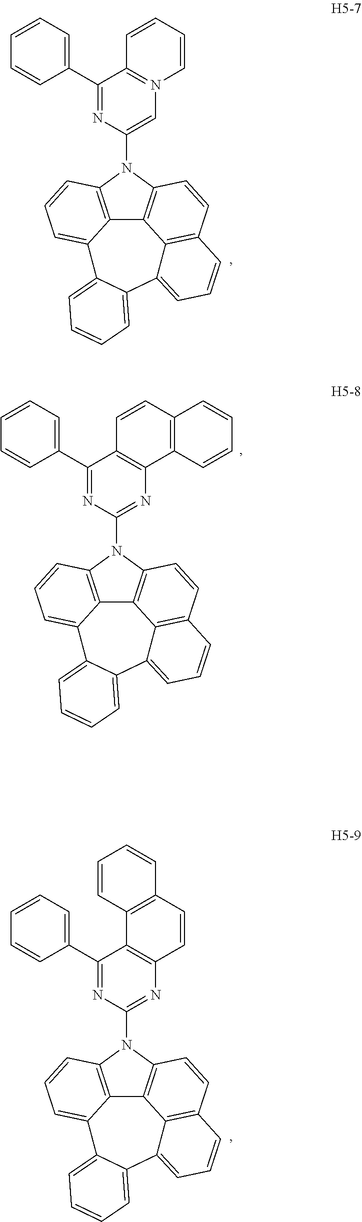

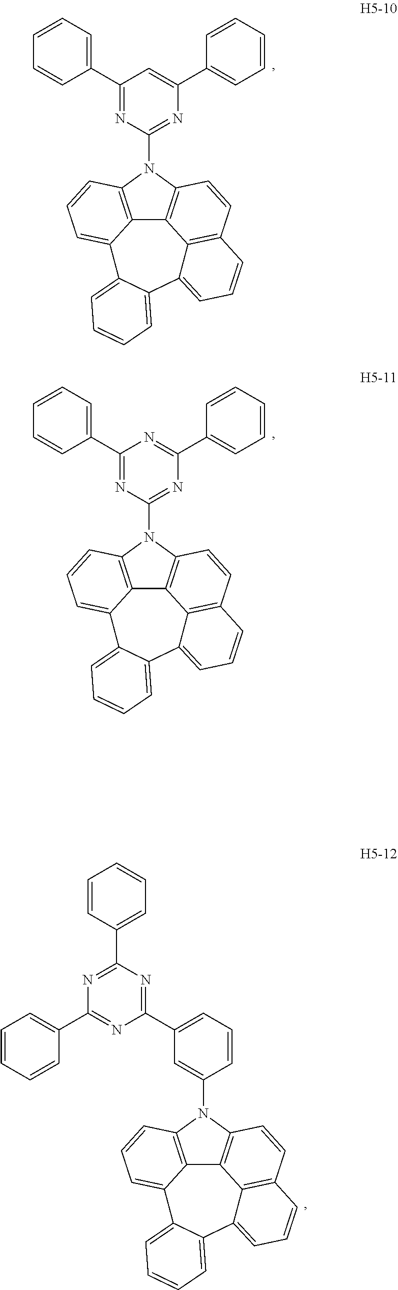 [SMILES: c1ccc(-c2cc(-c3ccccc3)nc(-n3c4cccc5c4c4c6c(cccc6ccc43)-c3ccccc3-5)n2)cc1 ; c1ccc(-c2nc(-c3ccccc3)nc(-n3c4cccc5c4c4c6c(cccc6ccc43)-c3ccccc3-5)n2)cc1 ; c1ccc(-c2nc(-c3ccccc3)nc(-c3cccc(-n4c5cccc6c5c5c7c(cccc7ccc54)-c4ccccc4-6)c3)n2)cc1]

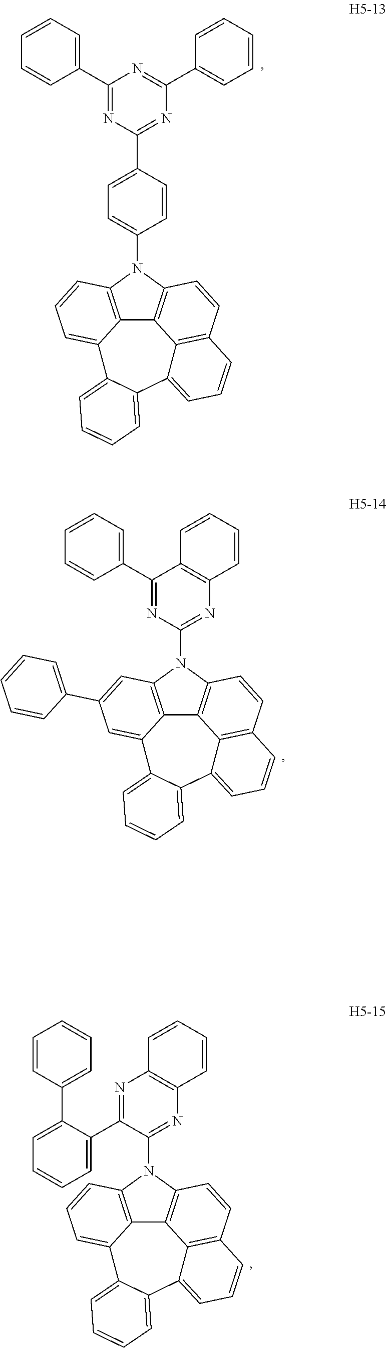 [SMILES: c1ccc(-c2nc(-c3ccccc3)nc(-c3ccc(-n4c5cccc6c5c5c7c(cccc7ccc54)-c4ccccc4-6)cc3)n2)cc1 ; c1ccc(-c2cc3c4c5c6c(cccc6ccc5n(-c5nc(-c6ccccc6)c6ccccc6n5)c4c2)-c2ccccc2-3)cc1 ; c1ccc(-c2ccccc2-c2nc3ccccc3nc2-n2c3cccc4c3c3c5c(cccc5ccc32)-c2ccccc2-4)cc1]

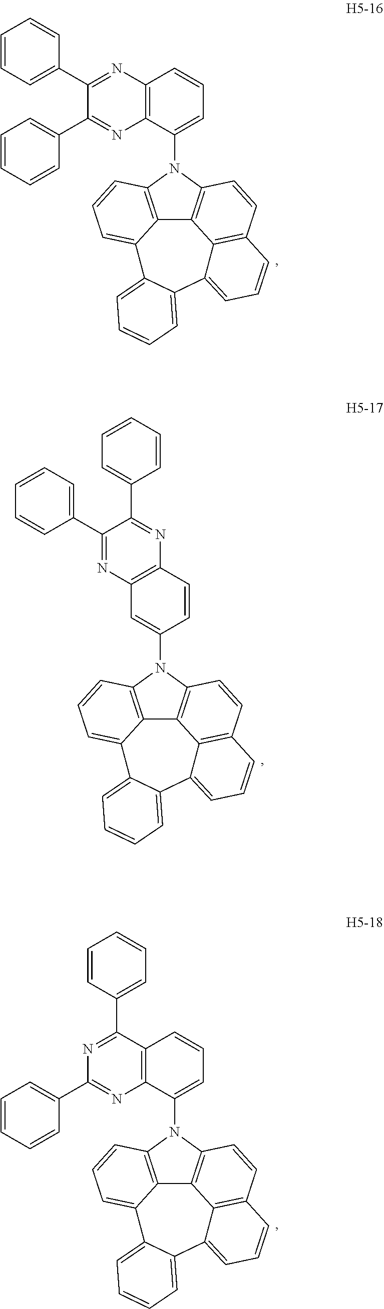 [SMILES: c1ccc(-c2nc3cccc(-n4c5cccc6c5c5c7c(cccc7ccc54)-c4ccccc4-6)c3nc2-c2ccccc2)cc1 ; c1ccc(-c2nc3ccc(-n4c5cccc6c5c5c7c(cccc7ccc54)-c4ccccc4-6)cc3nc2-c2ccccc2)cc1 ; c1ccc(-c2nc(-c3ccccc3)c3cccc(-n4c5cccc6c5c5c7c(cccc7ccc54)-c4ccccc4-6)c3n2)cc1]

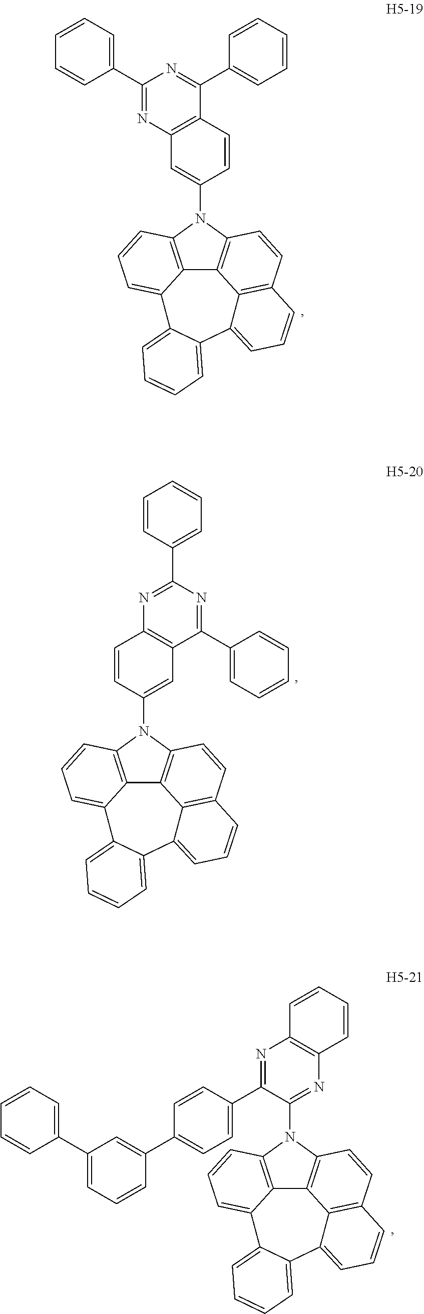 [SMILES: c1ccc(-c2nc(-c3ccccc3)c3ccc(-n4c5cccc6c5c5c7c(cccc7ccc54)-c4ccccc4-6)cc3n2)cc1 ; c1ccc(-c2nc(-c3ccccc3)c3cc(-n4c5cccc6c5c5c7c(cccc7ccc54)-c4ccccc4-6)ccc3n2)cc1 ; c1ccc(-c2cccc(-c3ccc(-c4nc5ccccc5nc4-n4c5cccc6c5c5c7c(cccc7ccc54)-c4ccccc4-6)cc3)c2)cc1]

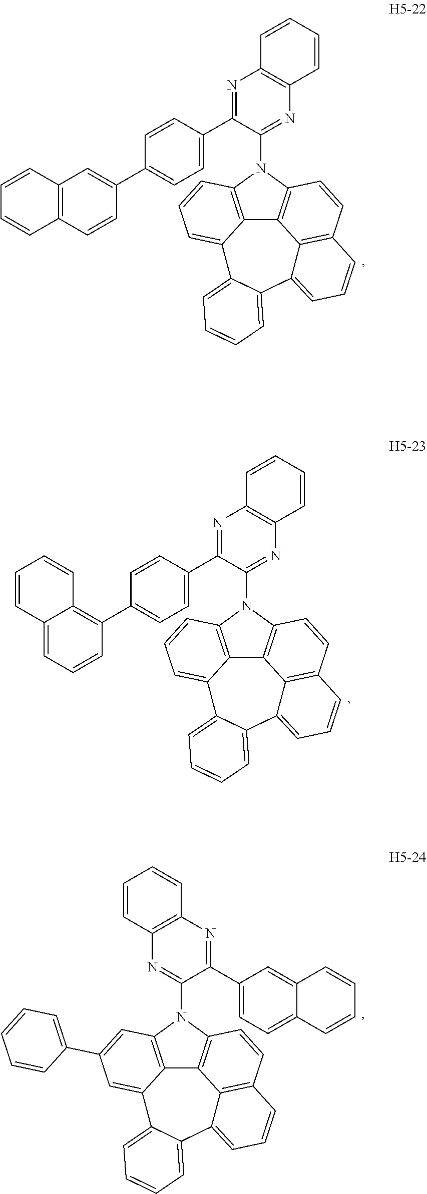 [SMILES: c1ccc2c(c1)-c1cccc3ccc4c(c13)c1c-2cccc1n4-c1nc2ccccc2nc1-c1ccc(-c2ccc3ccccc3c2)cc1 ; c1ccc2c(c1)-c1cccc3ccc4c(c13)c1c-2cccc1n4-c1nc2ccccc2nc1-c1ccc(-c2cccc3ccccc23)cc1 ; c1ccc(-c2cc3c4c5c6c(cccc6ccc5n(-c5nc6ccccc6nc5-c5ccc6ccccc6c5)c4c2)-c2ccccc2-3)cc1]

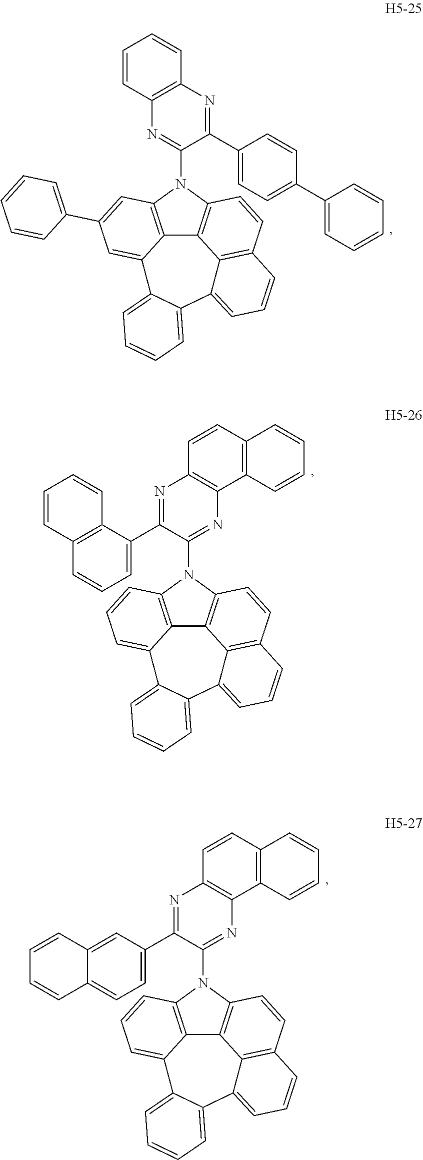 [SMILES: c1ccc(-c2ccc(-c3nc4ccccc4nc3-n3c4cc(-c5ccccc5)cc5c4c4c6c(cccc6ccc43)-c3ccccc3-5)cc2)cc1 ; c1ccc2c(c1)-c1cccc3ccc4c(c13)c1c-2cccc1n4-c1nc2c(ccc3ccccc32)nc1-c1cccc2ccccc12 ; c1ccc2c(c1)-c1cccc3ccc4c(c13)c1c-2cccc1n4-c1nc2c(ccc3ccccc32)nc1-c1ccc2ccccc2c1]

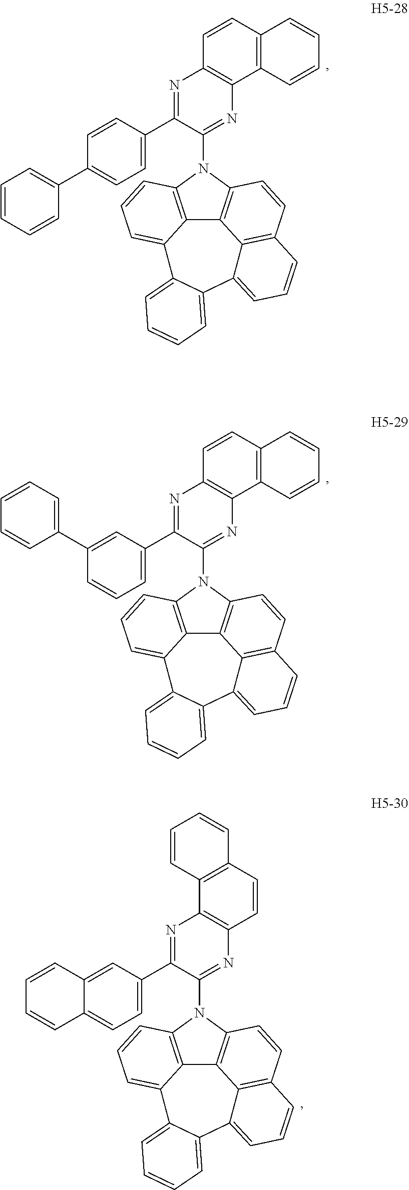 [SMILES: c1ccc(-c2ccc(-c3nc4ccc5ccccc5c4nc3-n3c4cccc5c4c4c6c(cccc6ccc43)-c3ccccc3-5)cc2)cc1 ; c1ccc(-c2cccc(-c3nc4ccc5ccccc5c4nc3-n3c4cccc5c4c4c6c(cccc6ccc43)-c3ccccc3-5)c2)cc1 ; c1ccc2c(c1)-c1cccc3ccc4c(c13)c1c-2cccc1n4-c1nc2ccc3ccccc3c2nc1-c1ccc2ccccc2c1]

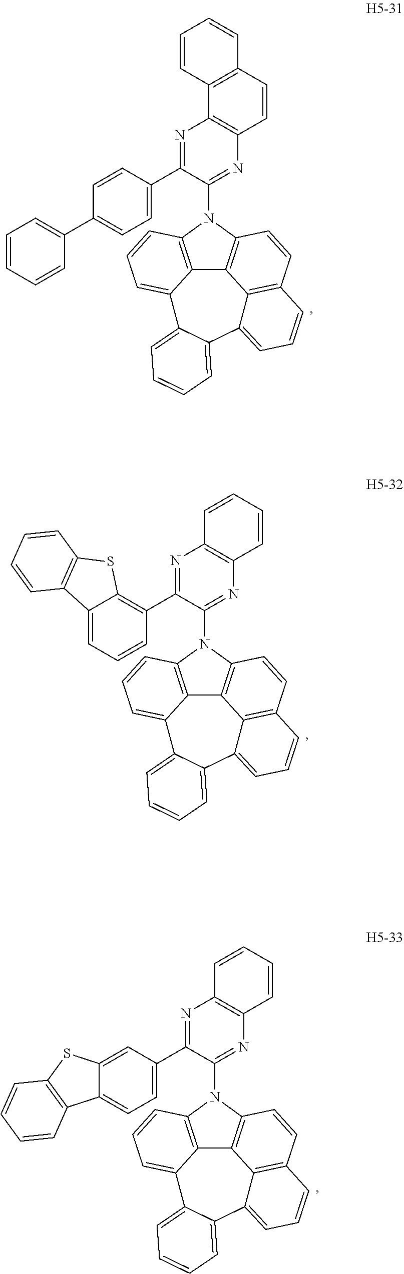 [SMILES: c1ccc(-c2ccc(-c3nc4c(ccc5ccccc54)nc3-n3c4cccc5c4c4c6c(cccc6ccc43)-c3ccccc3-5)cc2)cc1 ; c1ccc2c(c1)-c1cccc3ccc4c(c13)c1c-2cccc1n4-c1nc2ccccc2nc1-c1cccc2c1sc1ccccc12 ; c1ccc2c(c1)-c1cccc3ccc4c(c13)c1c-2cccc1n4-c1nc2ccccc2nc1-c1ccc2c(c1)sc1ccccc12]

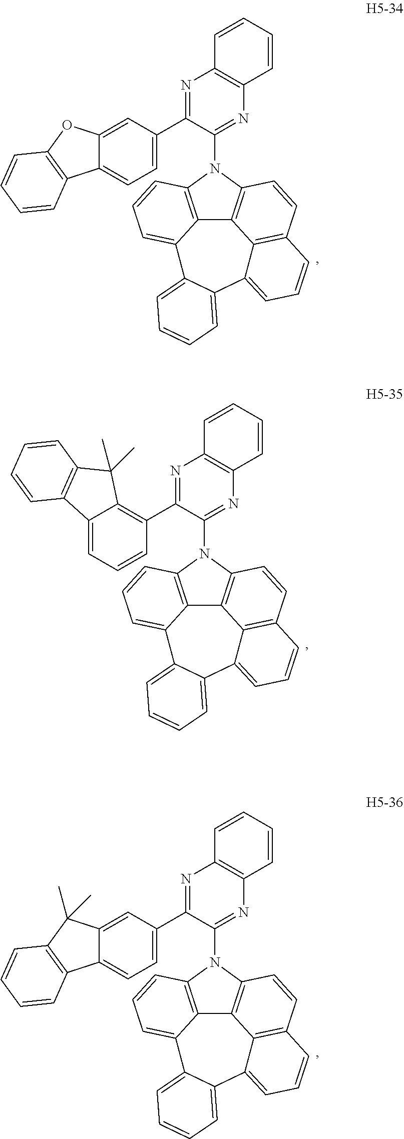 [SMILES: c1ccc2c(c1)-c1cccc3ccc4c(c13)c1c-2cccc1n4-c1nc2ccccc2nc1-c1ccc2c(c1)oc1ccccc12 ; CC1(C)c2ccccc2-c2cccc(-c3nc4ccccc4nc3-n3c4cccc5c4c4c6c(cccc6ccc43)-c3ccccc3-5)c21 ; CC1(C)c2ccccc2-c2ccc(-c3nc4ccccc4nc3-n3c4cccc5c4c4c6c(cccc6ccc43)-c3ccccc3-5)cc21]

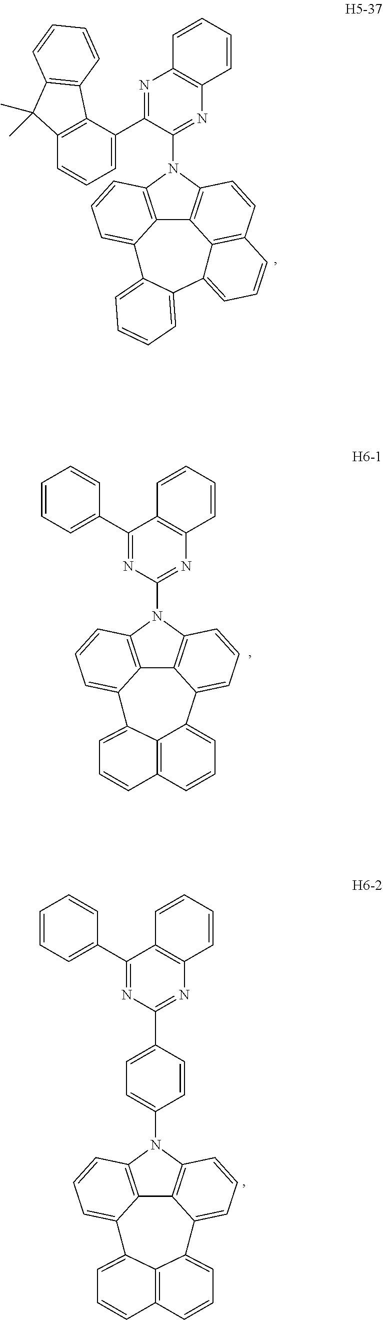

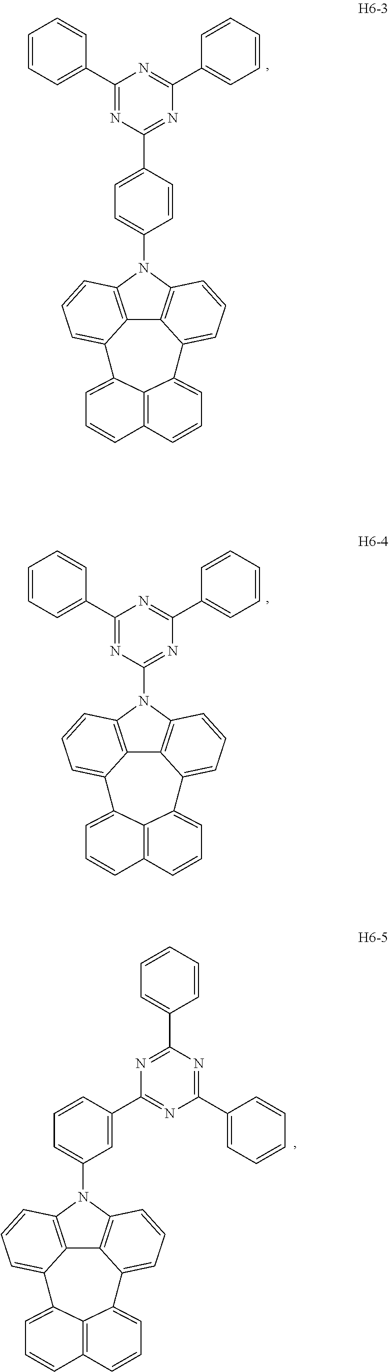 [SMILES: c1ccc(-c2nc(-c3ccccc3)nc(-c3ccc(-n4c5cccc6c5c5c(cccc54)-c4cccc5cccc-6c45)cc3)n2)cc1 ; c1ccc(-c2nc(-c3ccccc3)nc(-n3c4cccc5c4c4c(cccc43)-c3cccc4cccc-5c34)n2)cc1 ; c1ccc(-c2nc(-c3ccccc3)nc(-c3cccc(-n4c5cccc6c5c5c(cccc54)-c4cccc5cccc-6c45)c3)n2)cc1]

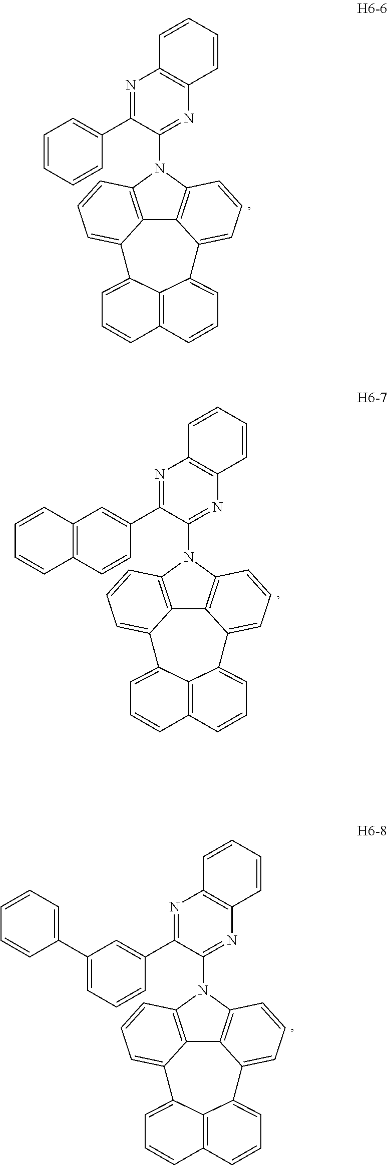 [SMILES: c1ccc(-c2nc3ccccc3nc2-n2c3cccc4c3c3c(cccc32)-c2cccc3cccc-4c23)cc1 ; c1ccc2cc(-c3nc4ccccc4nc3-n3c4cccc5c4c4c(cccc43)-c3cccc4cccc-5c34)ccc2c1 ; c1ccc(-c2cccc(-c3nc4ccccc4nc3-n3c4cccc5c4c4c(cccc43)-c3cccc4cccc-5c34)c2)cc1]

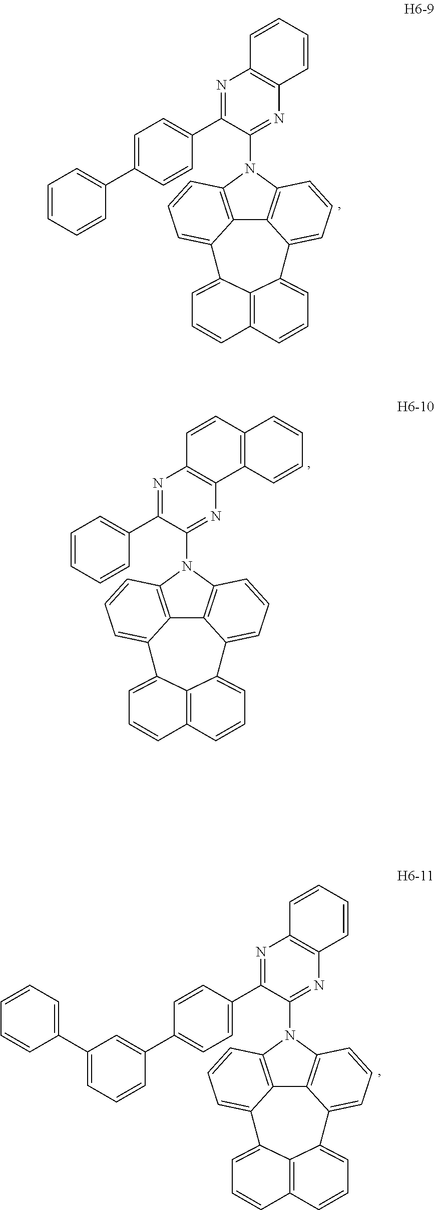 [SMILES: c1ccc(-c2ccc(-c3nc4ccccc4nc3-n3c4cccc5c4c4c(cccc43)-c3cccc4cccc-5c34)cc2)cc1 ; c1ccc(-c2nc3ccc4ccccc4c3nc2-n2c3cccc4c3c3c(cccc32)-c2cccc3cccc-4c23)cc1 ; c1ccc(-c2cccc(-c3ccc(-c4nc5ccccc5nc4-n4c5cccc6c5c5c(cccc54)-c4cccc5cccc-6c45)cc3)c2)cc1]

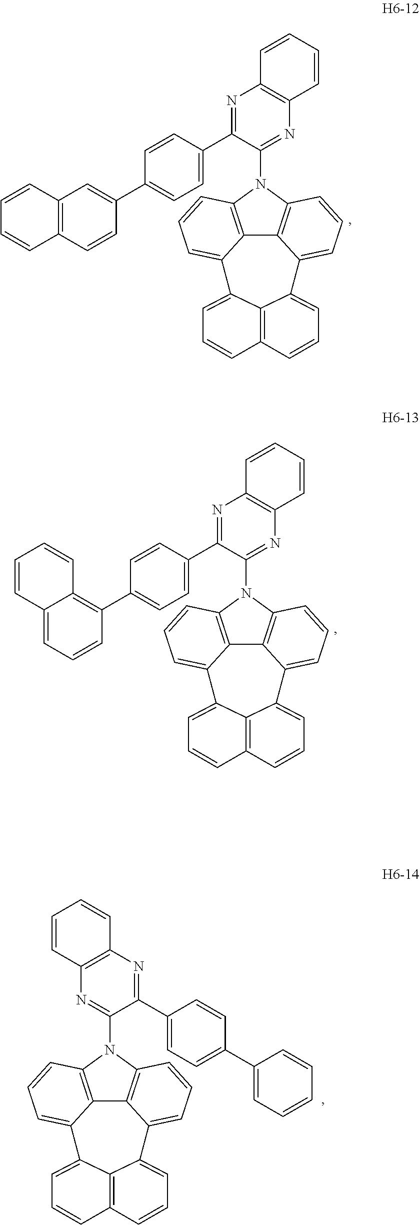 [SMILES: c1ccc2cc(-c3ccc(-c4nc5ccccc5nc4-n4c5cccc6c5c5c(cccc54)-c4cccc5cccc-6c45)cc3)ccc2c1 ; c1ccc2c(-c3ccc(-c4nc5ccccc5nc4-n4c5cccc6c5c5c(cccc54)-c4cccc5cccc-6c45)cc3)cccc2c1 ; c1ccc(-c2ccc(-c3nc4ccccc4nc3-n3c4cccc5c4c4c(cccc43)-c3cccc4cccc-5c34)cc2)cc1]

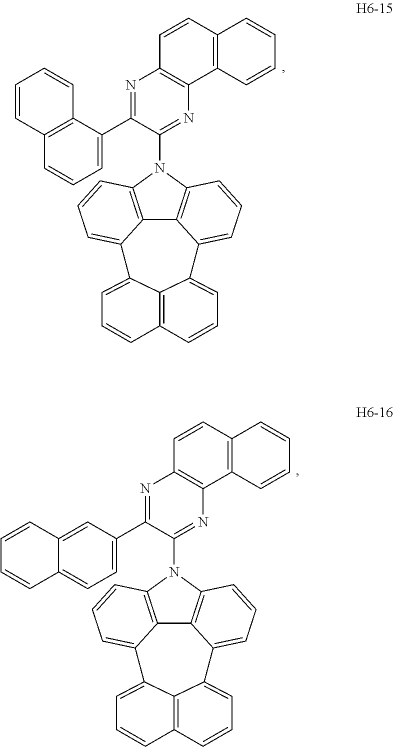 [SMILES: c1ccc2c(-c3nc4ccc5ccccc5c4nc3-n3c4cccc5c4c4c(cccc43)-c3cccc4cccc-5c34)cccc2c1 ; c1ccc2cc(-c3nc4ccc5ccccc5c4nc3-n3c4cccc5c4c4c(cccc43)-c3cccc4cccc-5c34)ccc2c1]

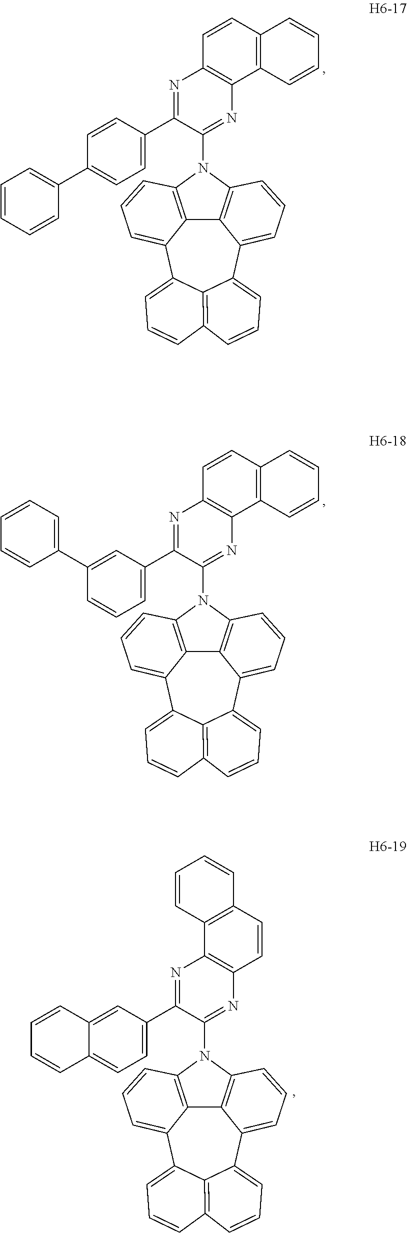 [SMILES: c1ccc(-c2ccc(-c3nc4ccc5ccccc5c4nc3-n3c4cccc5c4c4c(cccc43)-c3cccc4cccc-5c34)cc2)cc1 ; c1ccc(-c2cccc(-c3nc4ccc5ccccc5c4nc3-n3c4cccc5c4c4c(cccc43)-c3cccc4cccc-5c34)c2)cc1 ; c1ccc2cc(-c3nc4c(ccc5ccccc54)nc3-n3c4cccc5c4c4c(cccc43)-c3cccc4cccc-5c34)ccc2c1]

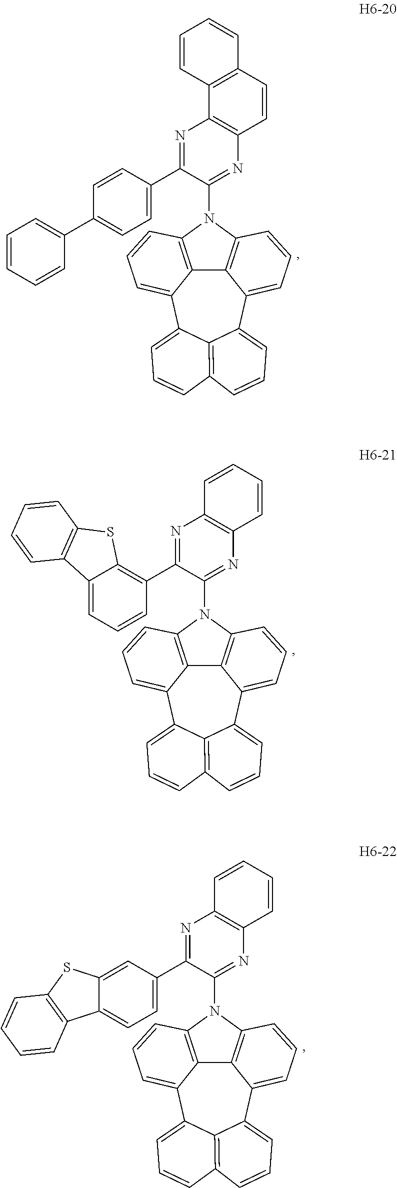 [SMILES: c1ccc(-c2ccc(-c3nc4c(ccc5ccccc54)nc3-n3c4cccc5c4c4c(cccc43)-c3cccc4cccc-5c34)cc2)cc1 ; c1cc2c3c(cccc3c1)-c1cccc3c1c1c-2cccc1n3-c1nc2ccccc2nc1-c1cccc2c1sc1ccccc12 ; c1cc2c3c(cccc3c1)-c1cccc3c1c1c-2cccc1n3-c1nc2ccccc2nc1-c1ccc2c(c1)sc1ccccc12]

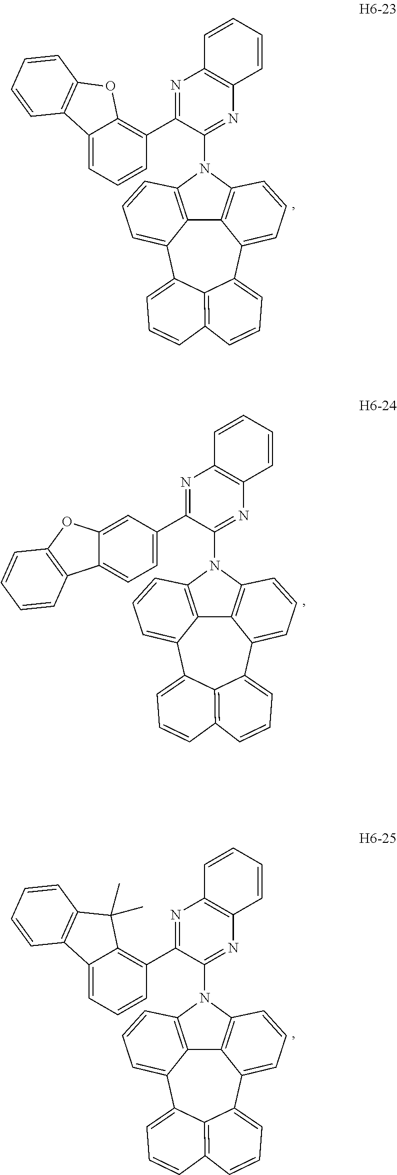 [SMILES: c1cc2c3c(cccc3c1)-c1cccc3c1c1c-2cccc1n3-c1nc2ccccc2nc1-c1cccc2c1oc1ccccc12 ; c1cc2c3c(cccc3c1)-c1cccc3c1c1c-2cccc1n3-c1nc2ccccc2nc1-c1ccc2c(c1)oc1ccccc12 ; CC1(C)c2ccccc2-c2cccc(-c3nc4ccccc4nc3-n3c4cccc5c4c4c(cccc43)-c3cccc4cccc-5c34)c21]

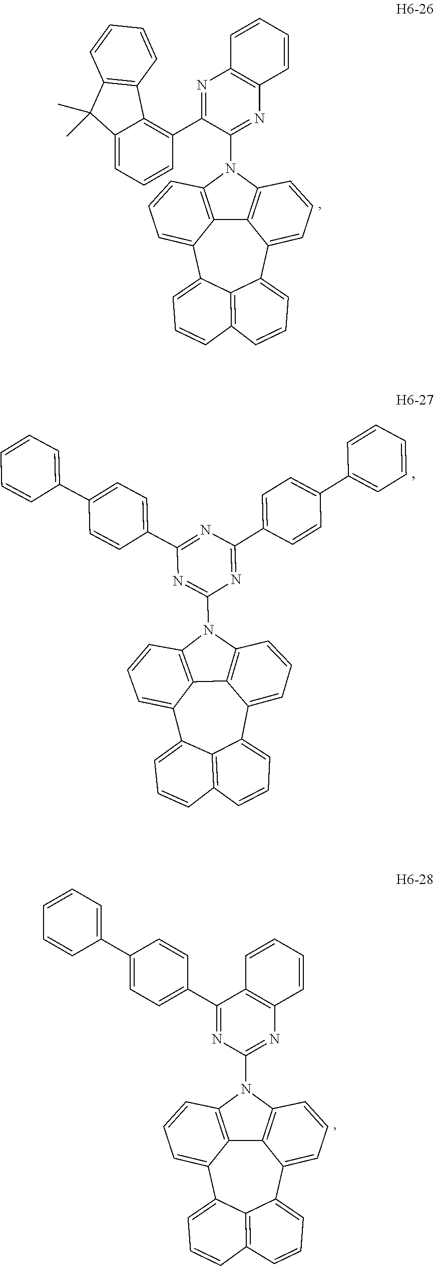 [SMILES: CC1(C)c2ccccc2-c2c(-c3nc4ccccc4nc3-n3c4cccc5c4c4c(cccc43)-c3cccc4cccc-5c34)cccc21 ; c1ccc(-c2ccc(-c3nc(-c4ccc(-c5ccccc5)cc4)nc(-n4c5cccc6c5c5c(cccc54)-c4cccc5cccc-6c45)n3)cc2)cc1 ; c1ccc(-c2ccc(-c3nc(-n4c5cccc6c5c5c(cccc54)-c4cccc5cccc-6c45)nc4ccccc34)cc2)cc1]

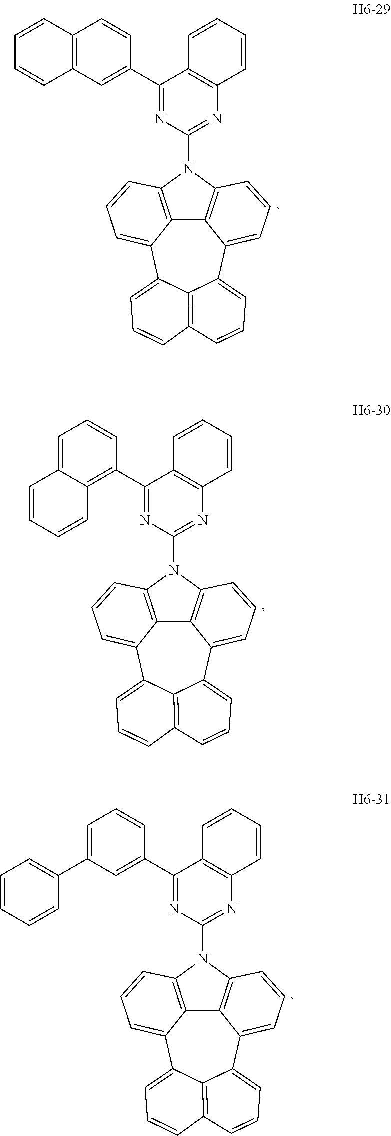 [SMILES: c1ccc2cc(-c3nc(-n4c5cccc6c5c5c(cccc54)-c4cccc5cccc-6c45)nc4ccccc34)ccc2c1 ; c1ccc2c(-c3nc(-n4c5cccc6c5c5c(cccc54)-c4cccc5cccc-6c45)nc4ccccc34)cccc2c1 ; c1ccc(-c2cccc(-c3nc(-n4c5cccc6c5c5c(cccc54)-c4cccc5cccc-6c45)nc4ccccc34)c2)cc1]

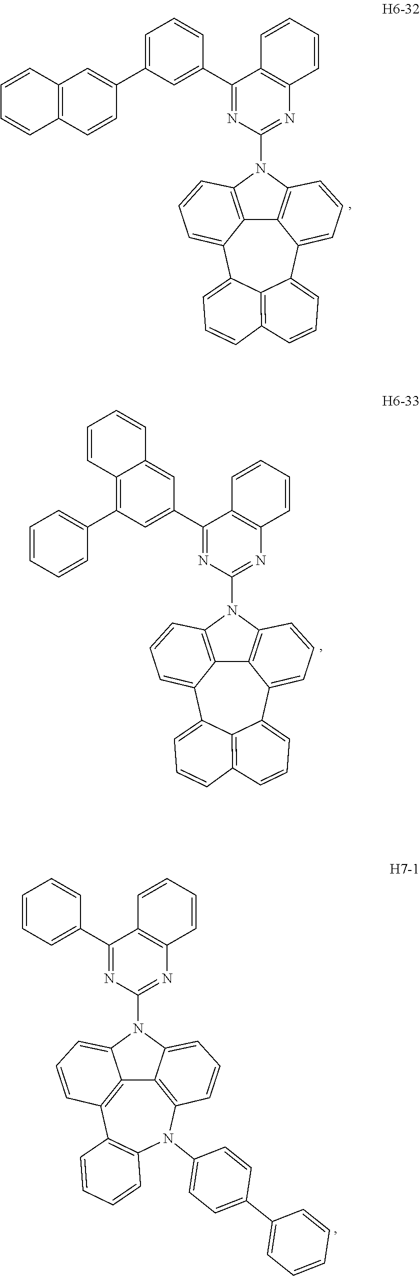 [SMILES: c1cc(-c2ccc3ccccc3c2)cc(-c2nc(-n3c4cccc5c4c4c(cccc43)-c3cccc4cccc-5c34)nc3ccccc23)c1 ; c1ccc(-c2cc(-c3nc(-n4c5cccc6c5c5c(cccc54)-c4cccc5cccc-6c45)nc4ccccc34)cc3ccccc23)cc1 ; c1ccc(-c2ccc(-n3c4ccccc4c4cccc5c4c4c3cccc4n5-c3nc(-c4ccccc4)c4ccccc4n3)cc2)cc1]

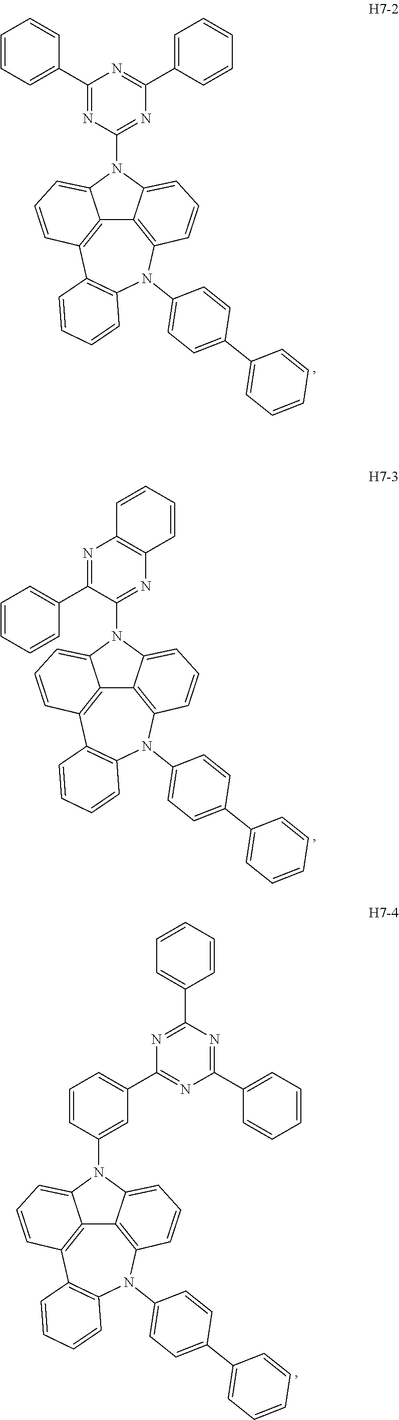 [SMILES: c1ccc(-c2ccc(-n3c4ccccc4c4cccc5c4c4c3cccc4n5-c3nc(-c4ccccc4)nc(-c4ccccc4)n3)cc2)cc1 ; c1ccc(-c2ccc(-n3c4ccccc4c4cccc5c4c4c3cccc4n5-c3nc4ccccc4nc3-c3ccccc3)cc2)cc1 ; c1ccc(-c2ccc(-n3c4ccccc4c4cccc5c4c4c3cccc4n5-c3cccc(-c4nc(-c5ccccc5)nc(-c5ccccc5)n4)c3)cc2)cc1]

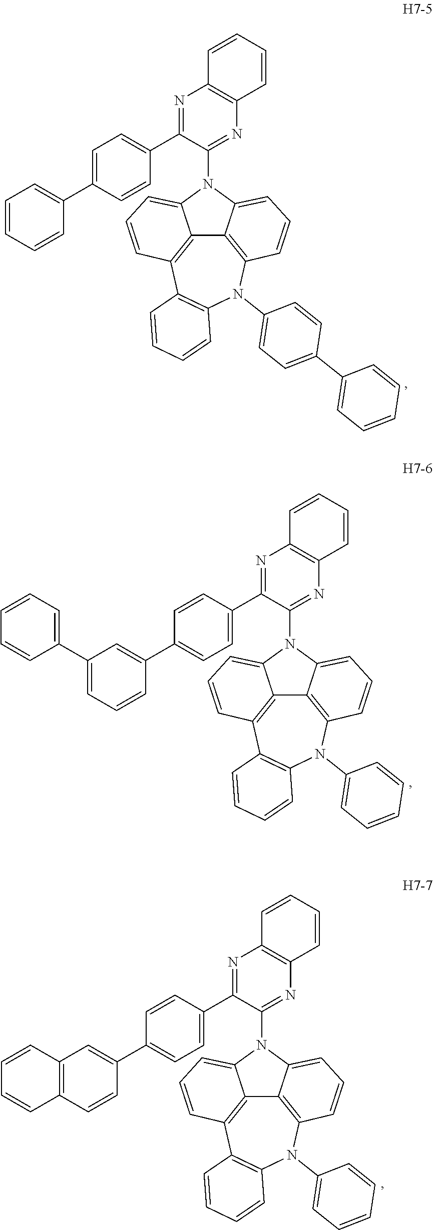 [SMILES: c1ccc(-c2ccc(-c3nc4ccccc4nc3-n3c4cccc5c6ccccc6n(-c6ccc(-c7ccccc7)cc6)c6cccc3c6c54)cc2)cc1 ; c1ccc(-c2cccc(-c3ccc(-c4nc5ccccc5nc4-n4c5cccc6c7ccccc7n(-c7ccccc7)c7cccc4c7c65)cc3)c2)cc1 ; c1ccc(-n2c3ccccc3c3cccc4c3c3c2cccc3n4-c2nc3ccccc3nc2-c2ccc(-c3ccc4ccccc4c3)cc2)cc1]

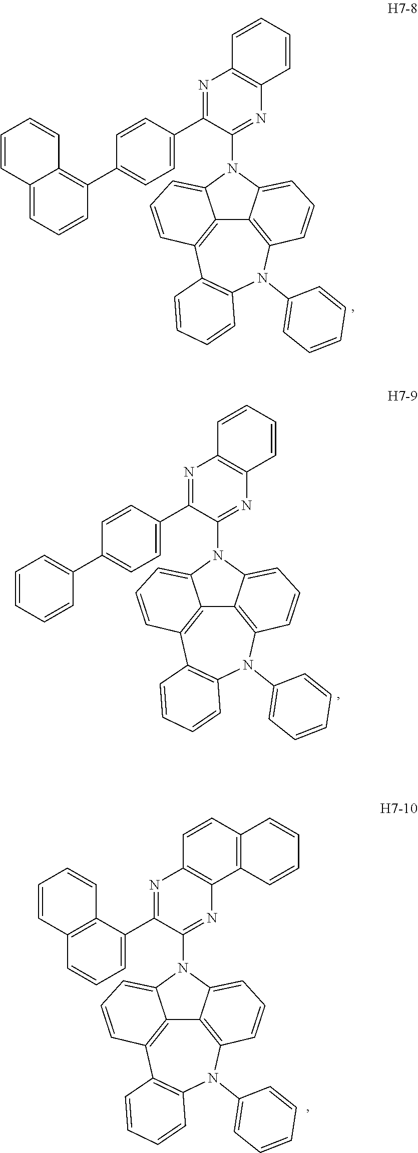 [SMILES: c1ccc(-n2c3ccccc3c3cccc4c3c3c2cccc3n4-c2nc3ccccc3nc2-c2ccc(-c3cccc4ccccc34)cc2)cc1 ; c1ccc(-c2ccc(-c3nc4ccccc4nc3-n3c4cccc5c6ccccc6n(-c6ccccc6)c6cccc3c6c54)cc2)cc1 ; c1ccc(-n2c3ccccc3c3cccc4c3c3c2cccc3n4-c2nc3c(ccc4ccccc43)nc2-c2cccc3ccccc23)cc1]

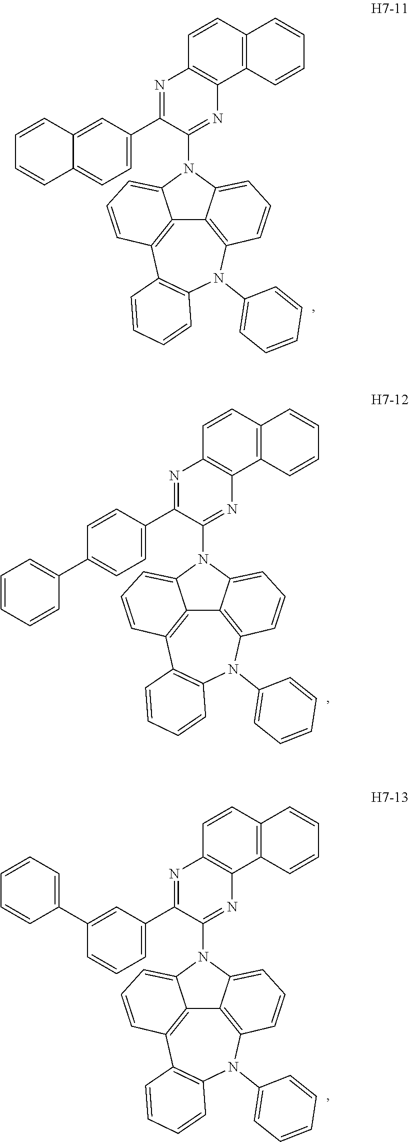 [SMILES: c1ccc(-n2c3ccccc3c3cccc4c3c3c2cccc3n4-c2nc3c(ccc4ccccc43)nc2-c2ccc3ccccc3c2)cc1 ; c1ccc(-c2ccc(-c3nc4ccc5ccccc5c4nc3-n3c4cccc5c6ccccc6n(-c6ccccc6)c6cccc3c6c54)cc2)cc1 ; c1ccc(-c2cccc(-c3nc4ccc5ccccc5c4nc3-n3c4cccc5c6ccccc6n(-c6ccccc6)c6cccc3c6c54)c2)cc1]

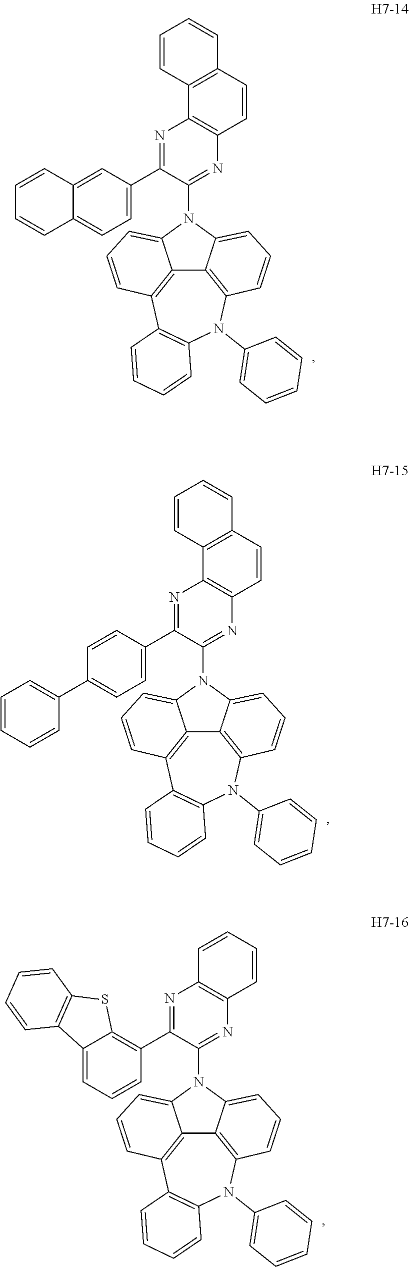 [SMILES: c1ccc(-n2c3ccccc3c3cccc4c3c3c2cccc3n4-c2nc3ccc4ccccc4c3nc2-c2ccc3ccccc3c2)cc1 ; c1ccc(-c2ccc(-c3nc4c(ccc5ccccc54)nc3-n3c4cccc5c6ccccc6n(-c6ccccc6)c6cccc3c6c54)cc2)cc1 ; c1ccc(-n2c3ccccc3c3cccc4c3c3c2cccc3n4-c2nc3ccccc3nc2-c2cccc3c2sc2ccccc23)cc1]

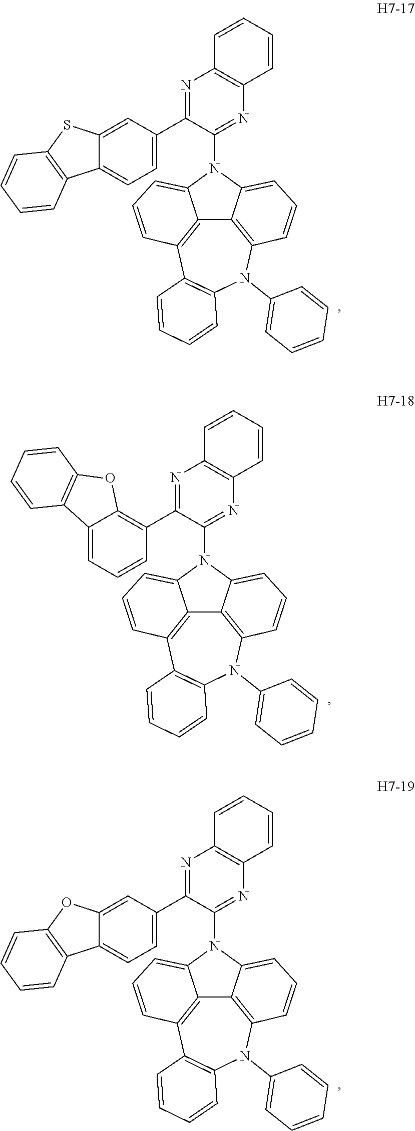 [SMILES: c1ccc(-n2c3ccccc3c3cccc4c3c3c2cccc3n4-c2nc3ccccc3nc2-c2ccc3c(c2)sc2ccccc23)cc1 ; c1ccc(-n2c3ccccc3c3cccc4c3c3c2cccc3n4-c2nc3ccccc3nc2-c2cccc3c2oc2ccccc23)cc1 ; c1ccc(-n2c3ccccc3c3cccc4c3c3c2cccc3n4-c2nc3ccccc3nc2-c2ccc3c(c2)oc2ccccc23)cc1]

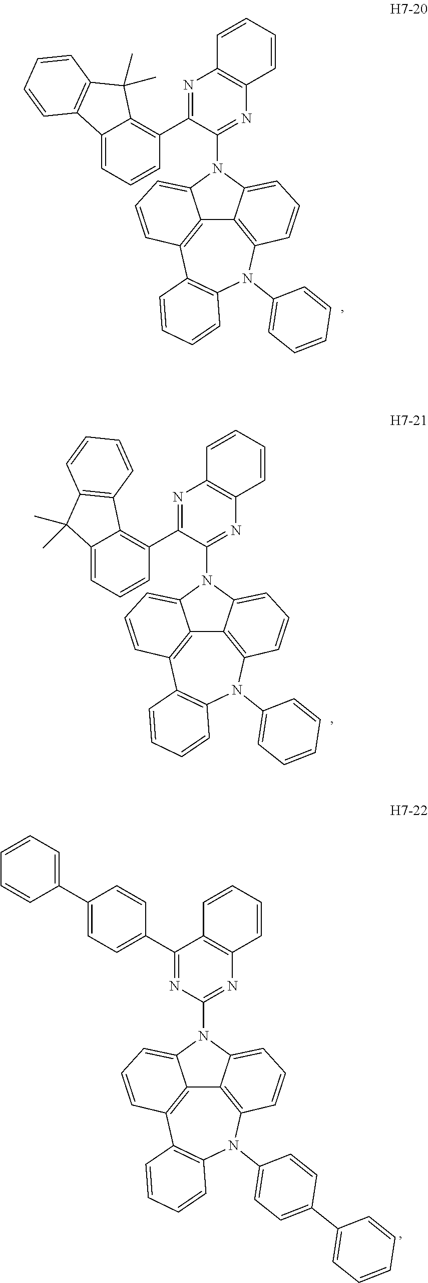 [SMILES: CC1(C)c2ccccc2-c2cccc(-c3nc4ccccc4nc3-n3c4cccc5c6ccccc6n(-c6ccccc6)c6cccc3c6c54)c21 ; CC1(C)c2ccccc2-c2c(-c3nc4ccccc4nc3-n3c4cccc5c6ccccc6n(-c6ccccc6)c6cccc3c6c54)cccc21 ; c1ccc(-c2ccc(-c3nc(-n4c5cccc6c7ccccc7n(-c7ccc(-c8ccccc8)cc7)c7cccc4c7c65)nc4ccccc34)cc2)cc1]

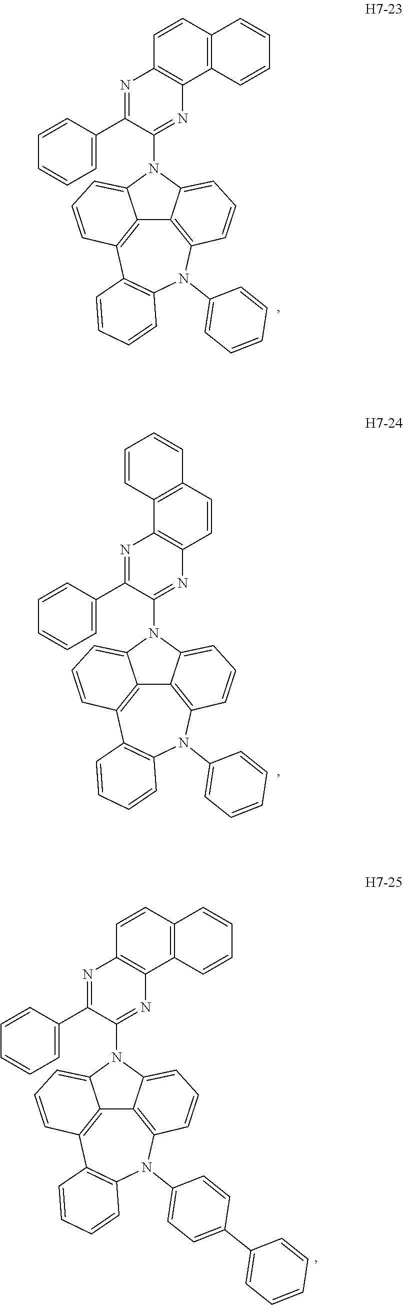 [SMILES: c1ccc(-c2nc3ccc4ccccc4c3nc2-n2c3cccc4c5ccccc5n(-c5ccccc5)c5cccc2c5c43)cc1 ; c1ccc(-c2nc3c(ccc4ccccc43)nc2-n2c3cccc4c5ccccc5n(-c5ccccc5)c5cccc2c5c43)cc1 ; c1ccc(-c2ccc(-n3c4ccccc4c4cccc5c4c4c3cccc4n5-c3nc4c(ccc5ccccc54)nc3-c3ccccc3)cc2)cc1]

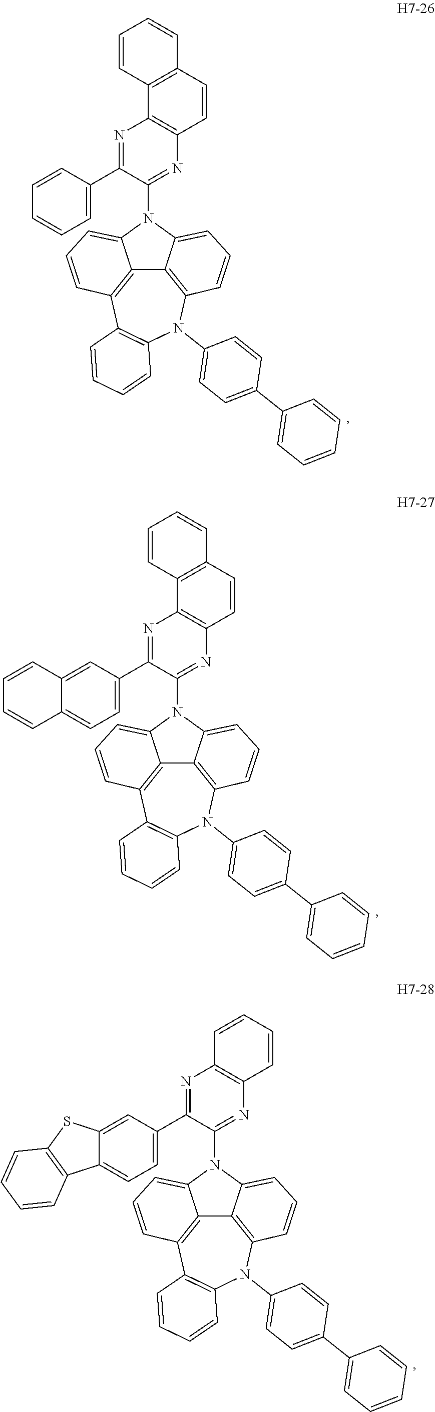 [SMILES: c1ccc(-c2ccc(-n3c4ccccc4c4cccc5c4c4c3cccc4n5-c3nc4ccc5ccccc5c4nc3-c3ccccc3)cc2)cc1 ; c1ccc(-c2ccc(-n3c4ccccc4c4cccc5c4c4c3cccc4n5-c3nc4ccc5ccccc5c4nc3-c3ccc4ccccc4c3)cc2)cc1 ; c1ccc(-c2ccc(-n3c4ccccc4c4cccc5c4c4c3cccc4n5-c3nc4ccccc4nc3-c3ccc4c(c3)sc3ccccc34)cc2)cc1]

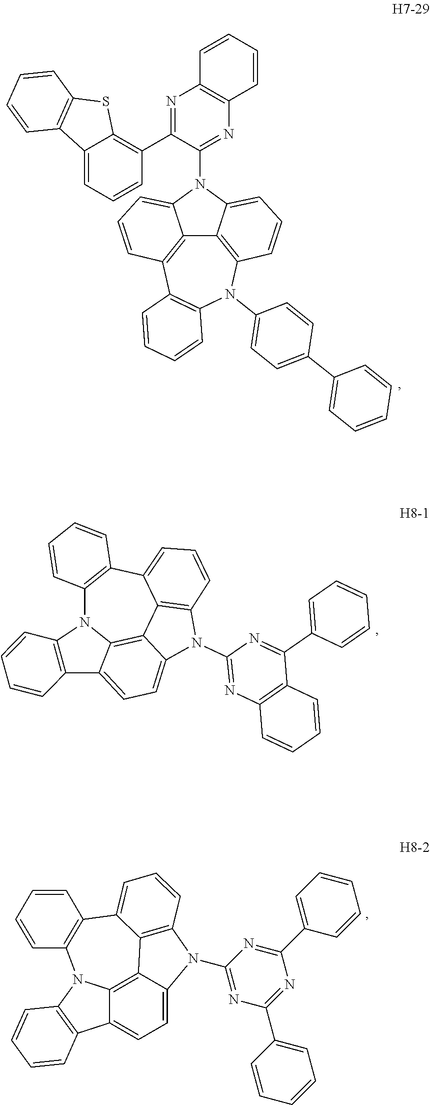 [SMILES: c1ccc(-c2ccc(-n3c4ccccc4c4cccc5c4c4c3cccc4n5-c3nc4ccccc4nc3-c3cccc4c3sc3ccccc34)cc2)cc1 ; c1ccc(-c2nc(-n3c4cccc5c6ccccc6n6c7ccccc7c7ccc3c(c54)c76)nc3ccccc23)cc1 ; c1ccc(-c2nc(-c3ccccc3)nc(-n3c4cccc5c6ccccc6n6c7ccccc7c7ccc3c(c54)c76)n2)cc1]

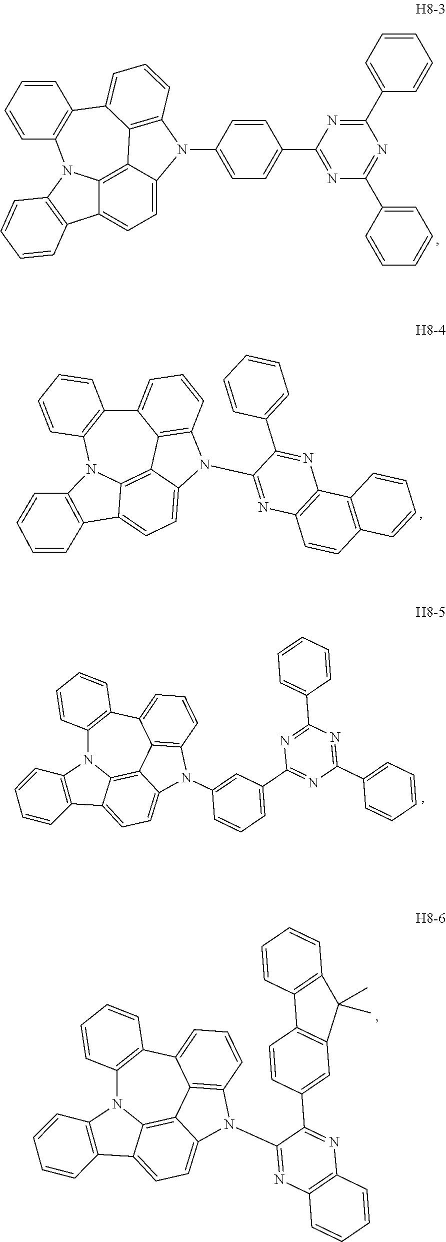 [SMILES: c1ccc(-c2nc(-c3ccccc3)nc(-c3ccc(-n4c5cccc6c7ccccc7n7c8ccccc8c8ccc4c(c65)c87)cc3)n2)cc1 ; c1ccc(-c2nc3c(ccc4ccccc43)nc2-n2c3cccc4c5ccccc5n5c6ccccc6c6ccc2c(c43)c65)cc1 ; c1ccc(-c2nc(-c3ccccc3)nc(-c3cccc(-n4c5cccc6c7ccccc7n7c8ccccc8c8ccc4c(c65)c87)c3)n2)cc1 ; CC1(C)c2ccccc2-c2ccc(-c3nc4ccccc4nc3-n3c4cccc5c6ccccc6n6c7ccccc7c7ccc3c(c54)c76)cc21]

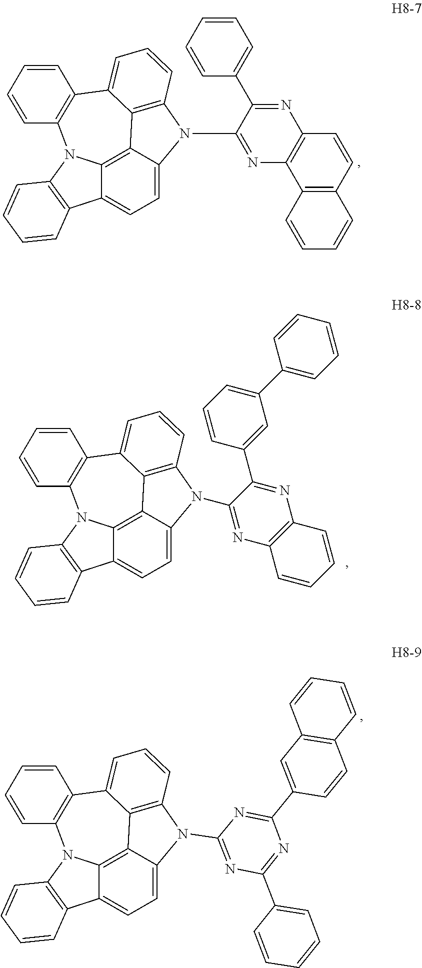 [SMILES: c1ccc(-c2nc3ccc4ccccc4c3nc2-n2c3cccc4c5ccccc5n5c6ccccc6c6ccc2c(c43)c65)cc1 ; c1ccc(-c2cccc(-c3nc4ccccc4nc3-n3c4cccc5c6ccccc6n6c7ccccc7c7ccc3c(c54)c76)c2)cc1 ; c1ccc(-c2nc(-c3ccc4ccccc4c3)nc(-n3c4cccc5c6ccccc6n6c7ccccc7c7ccc3c(c54)c76)n2)cc1]

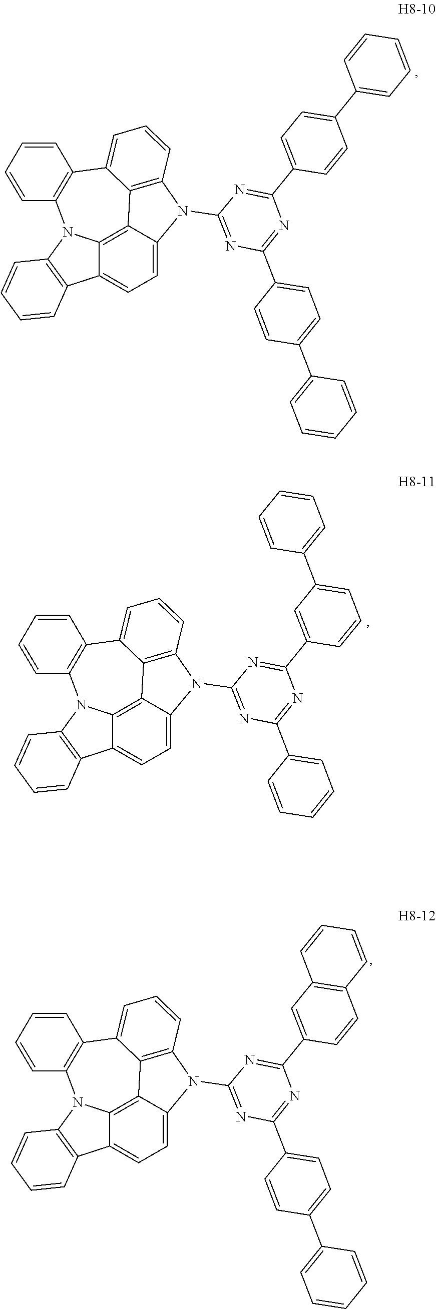 [SMILES: c1ccc(-c2ccc(-c3nc(-c4ccc(-c5ccccc5)cc4)nc(-n4c5cccc6c7ccccc7n7c8ccccc8c8ccc4c(c65)c87)n3)cc2)cc1 ; c1ccc(-c2cccc(-c3nc(-c4ccccc4)nc(-n4c5cccc6c7ccccc7n7c8ccccc8c8ccc4c(c65)c87)n3)c2)cc1 ; c1ccc(-c2ccc(-c3nc(-c4ccc5ccccc5c4)nc(-n4c5cccc6c7ccccc7n7c8ccccc8c8ccc4c(c65)c87)n3)cc2)cc1]

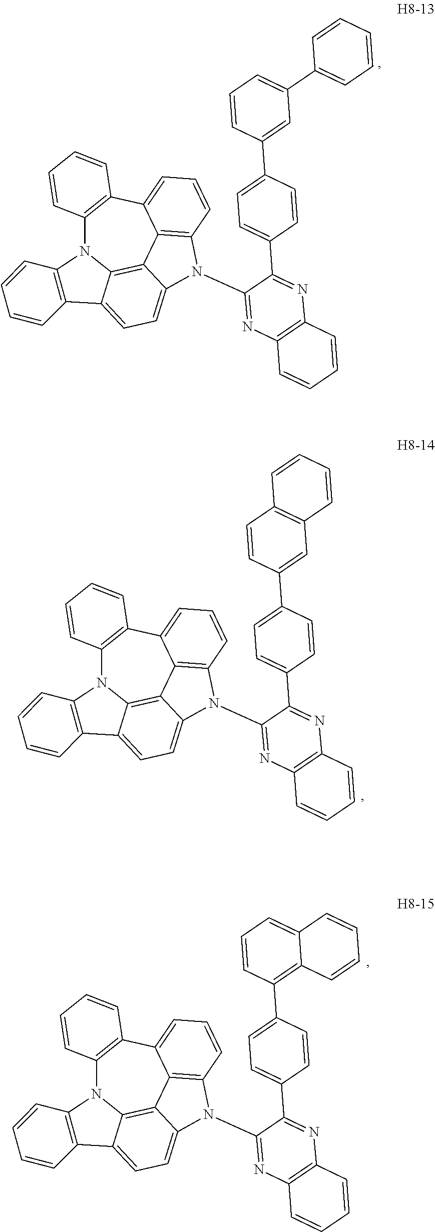 [SMILES: c1ccc(-c2cccc(-c3ccc(-c4nc5ccccc5nc4-n4c5cccc6c7ccccc7n7c8ccccc8c8ccc4c(c65)c87)cc3)c2)cc1 ; c1ccc2cc(-c3ccc(-c4nc5ccccc5nc4-n4c5cccc6c7ccccc7n7c8ccccc8c8ccc4c(c65)c87)cc3)ccc2c1 ; c1ccc2c(-c3ccc(-c4nc5ccccc5nc4-n4c5cccc6c7ccccc7n7c8ccccc8c8ccc4c(c65)c87)cc3)cccc2c1]

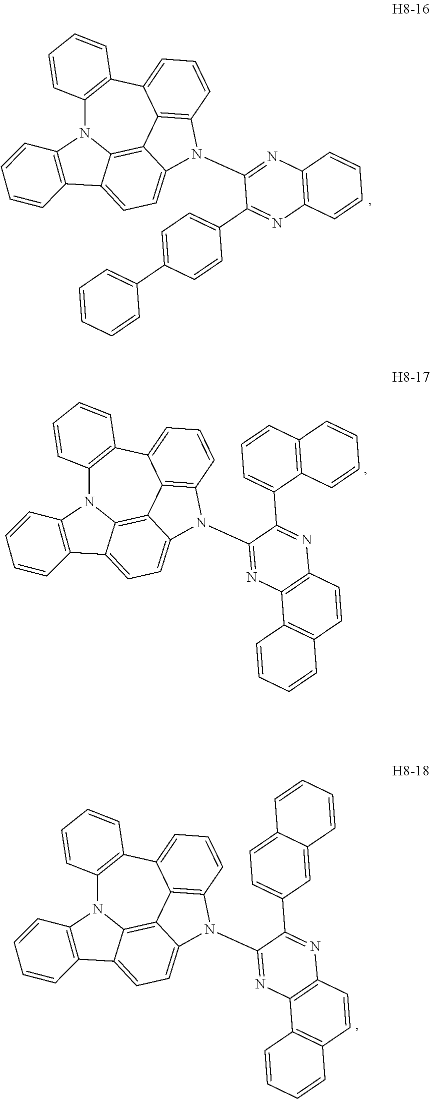 [SMILES: c1ccc(-c2ccc(-c3nc4ccccc4nc3-n3c4cccc5c6ccccc6n6c7ccccc7c7ccc3c(c54)c76)cc2)cc1 ; c1ccc2c(-c3nc4ccc5ccccc5c4nc3-n3c4cccc5c6ccccc6n6c7ccccc7c7ccc3c(c54)c76)cccc2c1 ; c1ccc2cc(-c3nc4ccc5ccccc5c4nc3-n3c4cccc5c6ccccc6n6c7ccccc7c7ccc3c(c54)c76)ccc2c1]

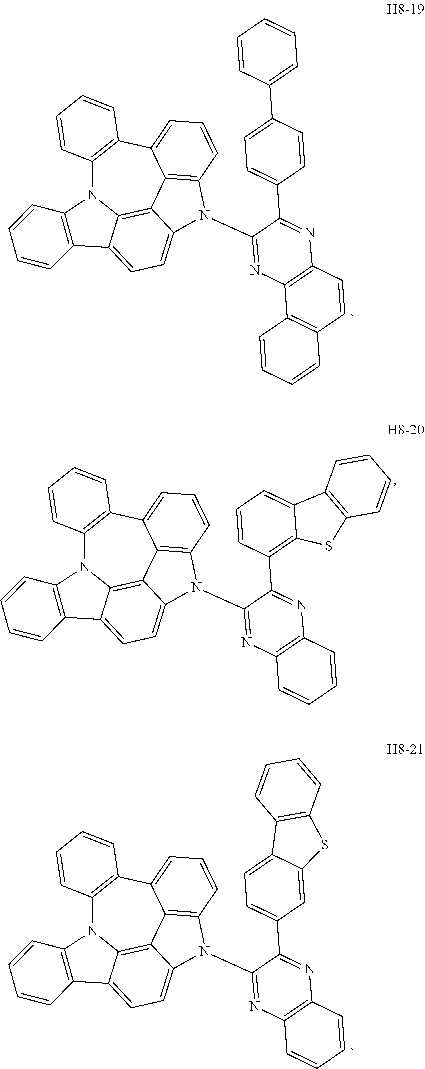 [SMILES: c1ccc(-c2ccc(-c3nc4ccc5ccccc5c4nc3-n3c4cccc5c6ccccc6n6c7ccccc7c7ccc3c(c54)c76)cc2)cc1 ; c1ccc2nc(-n3c4cccc5c6ccccc6n6c7ccccc7c7ccc3c(c54)c76)c(-c3cccc4c3sc3ccccc34)nc2c1 ; c1ccc2nc(-n3c4cccc5c6ccccc6n6c7ccccc7c7ccc3c(c54)c76)c(-c3ccc4c(c3)sc3ccccc34)nc2c1]

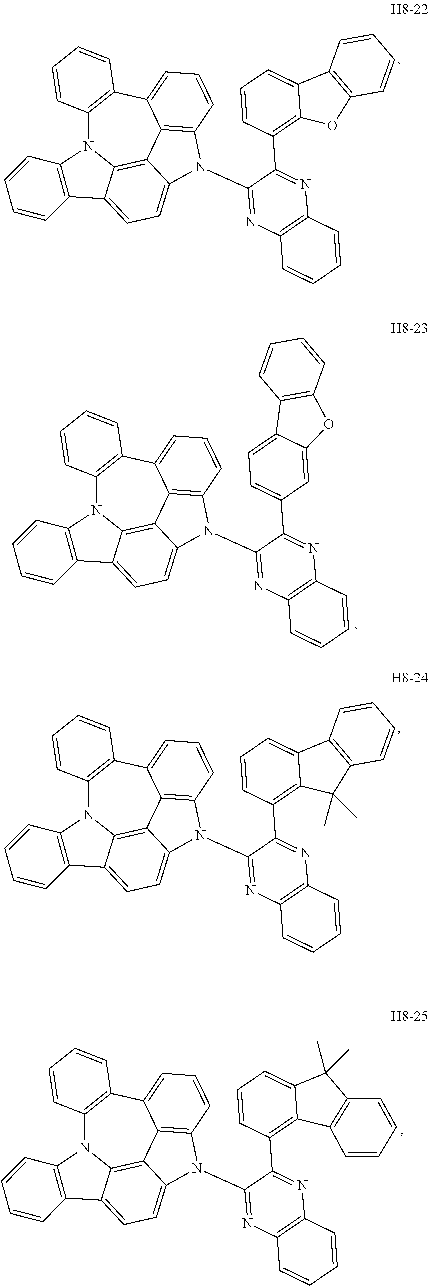 [SMILES: c1ccc2nc(-n3c4cccc5c6ccccc6n6c7ccccc7c7ccc3c(c54)c76)c(-c3cccc4c3oc3ccccc34)nc2c1 ; c1ccc2nc(-n3c4cccc5c6ccccc6n6c7ccccc7c7ccc3c(c54)c76)c(-c3ccc4c(c3)oc3ccccc34)nc2c1 ; CC1(C)c2ccccc2-c2cccc(-c3nc4ccccc4nc3-n3c4cccc5c6ccccc6n6c7ccccc7c7ccc3c(c54)c76)c21 ; CC1(C)c2ccccc2-c2c(-c3nc4ccccc4nc3-n3c4cccc5c6ccccc6n6c7ccccc7c7ccc3c(c54)c76)cccc21]

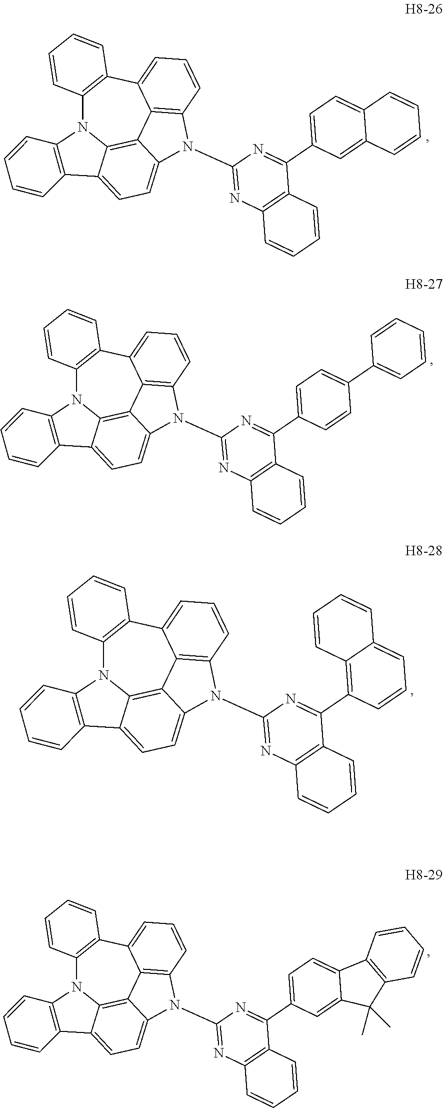 [SMILES: c1ccc2cc(-c3nc(-n4c5cccc6c7ccccc7n7c8ccccc8c8ccc4c(c65)c87)nc4ccccc34)ccc2c1 ; c1ccc(-c2ccc(-c3nc(-n4c5cccc6c7ccccc7n7c8ccccc8c8ccc4c(c65)c87)nc4ccccc34)cc2)cc1 ; c1ccc2c(-c3nc(-n4c5cccc6c7ccccc7n7c8ccccc8c8ccc4c(c65)c87)nc4ccccc34)cccc2c1 ; CC1(C)c2ccccc2-c2ccc(-c3nc(-n4c5cccc6c7ccccc7n7c8ccccc8c8ccc4c(c65)c87)nc4ccccc34)cc21]

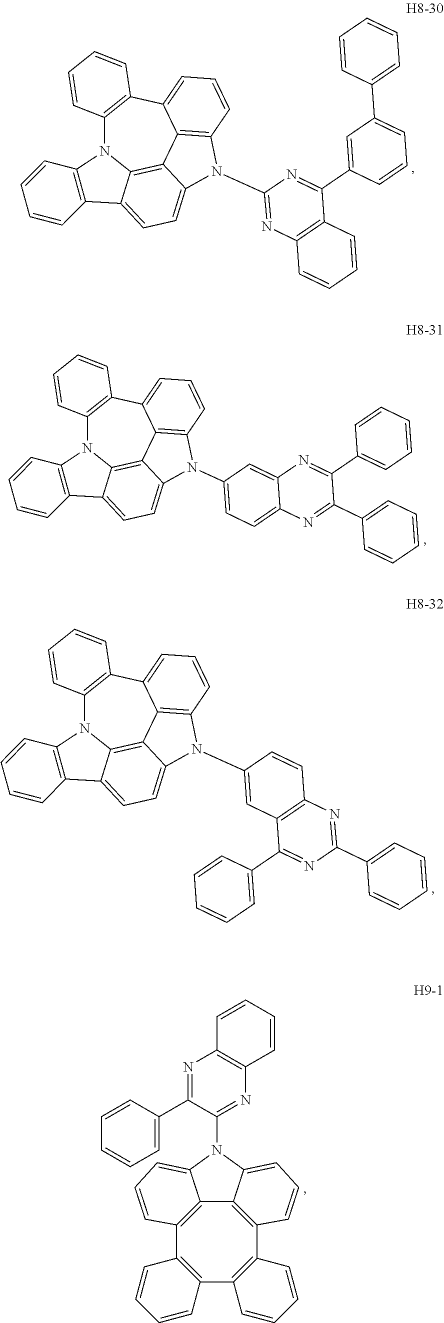 [SMILES: c1ccc(-c2cccc(-c3nc(-n4c5cccc6c7ccccc7n7c8ccccc8c8ccc4c(c65)c87)nc4ccccc34)c2)cc1 ; c1ccc(-c2nc3ccc(-n4c5cccc6c7ccccc7n7c8ccccc8c8ccc4c(c65)c87)cc3nc2-c2ccccc2)cc1 ; c1ccc(-c2nc(-c3ccccc3)c3cc(-n4c5cccc6c7ccccc7n7c8ccccc8c8ccc4c(c65)c87)ccc3n2)cc1 ; c1ccc(-c2nc3ccccc3nc2-n2c3cccc4c5ccccc5c5ccccc5c5cccc2c5c43)cc1]

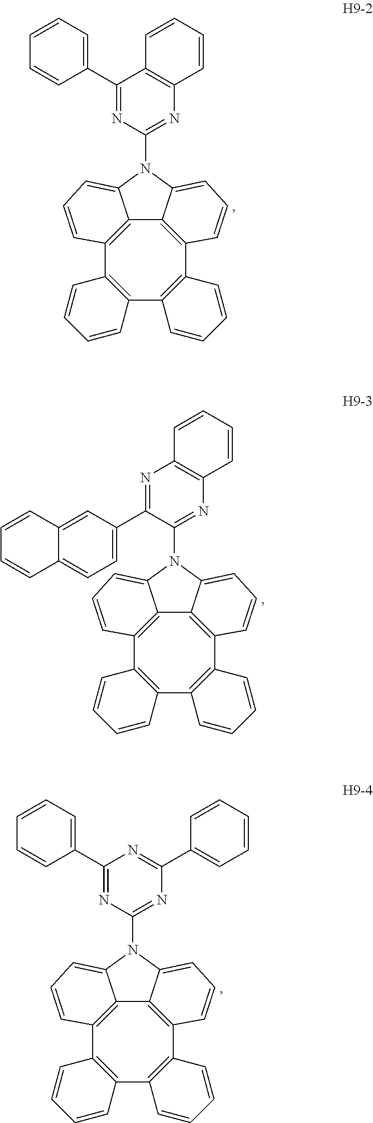 [SMILES: c1ccc(-c2nc(-n3c4cccc5c6ccccc6c6ccccc6c6cccc3c6c54)nc3ccccc23)cc1 ; c1ccc2cc(-c3nc4ccccc4nc3-n3c4cccc5c6ccccc6c6ccccc6c6cccc3c6c54)ccc2c1 ; c1ccc(-c2nc(-c3ccccc3)nc(-n3c4cccc5c6ccccc6c6ccccc6c6cccc3c6c54)n2)cc1]

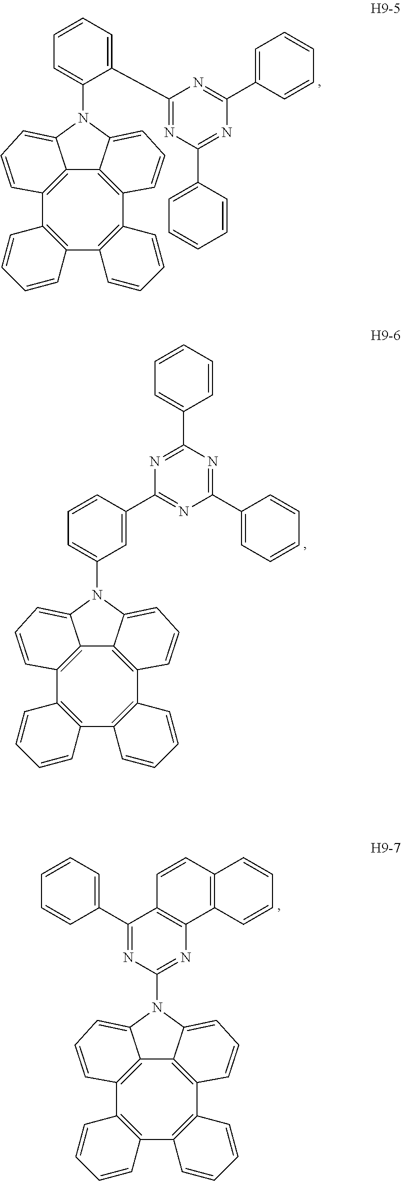 [SMILES: c1ccc(-c2nc(-c3ccccc3)nc(-c3ccccc3-n3c4cccc5c6ccccc6c6ccccc6c6cccc3c6c54)n2)cc1 ; c1ccc(-c2nc(-c3ccccc3)nc(-c3cccc(-n4c5cccc6c7ccccc7c7ccccc7c7cccc4c7c65)c3)n2)cc1 ; c1ccc(-c2nc(-n3c4cccc5c6ccccc6c6ccccc6c6cccc3c6c54)nc3c2ccc2ccccc23)cc1]

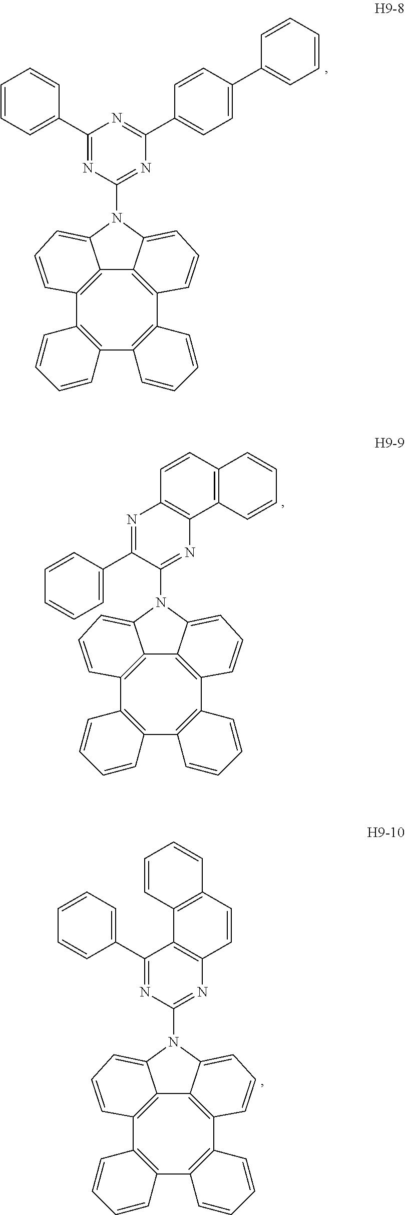 [SMILES: c1ccc(-c2ccc(-c3nc(-c4ccccc4)nc(-n4c5cccc6c7ccccc7c7ccccc7c7cccc4c7c65)n3)cc2)cc1 ; c1ccc(-c2nc3ccc4ccccc4c3nc2-n2c3cccc4c5ccccc5c5ccccc5c5cccc2c5c43)cc1 ; c1ccc(-c2nc(-n3c4cccc5c6ccccc6c6ccccc6c6cccc3c6c54)nc3ccc4ccccc4c23)cc1]

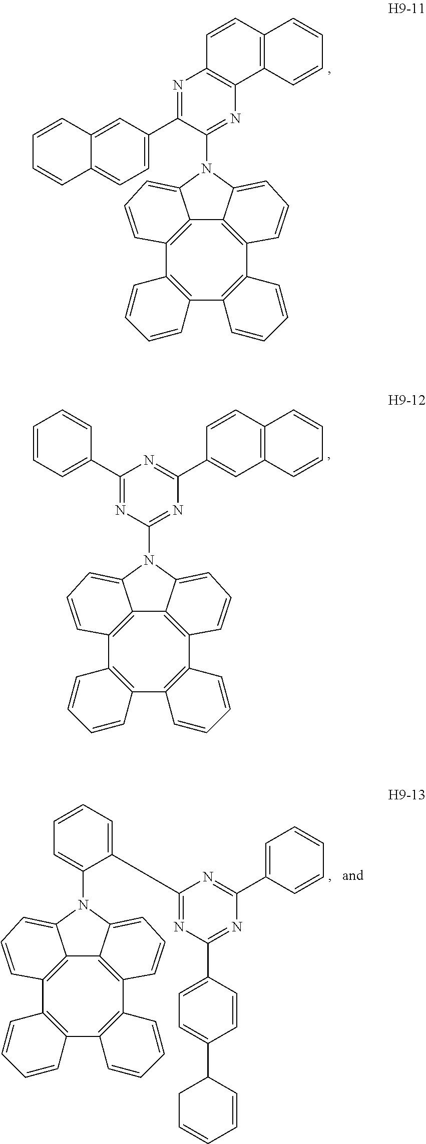 [SMILES: c1ccc2cc(-c3nc4ccc5ccccc5c4nc3-n3c4cccc5c6ccccc6c6ccccc6c6cccc3c6c54)ccc2c1 ; c1ccc(-c2nc(-c3ccc4ccccc4c3)nc(-n3c4cccc5c6ccccc6c6ccccc6c6cccc3c6c54)n2)cc1 ; C1=CCC(c2ccc(-c3nc(-c4ccccc4)nc(-c4ccccc4-n4c5cccc6c7ccccc7c7ccccc7c7cccc4c7c65)n3)cc2)C=C1]

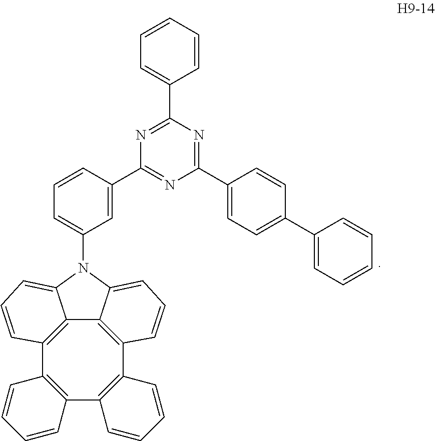 [SMILES: c1ccc(-c2ccc(-c3nc(-c4ccccc4)nc(-c4cccc(-n5c6cccc7c8ccccc8c8ccccc8c8cccc5c8c76)c4)n3)cc2)cc1]

32. The electroluminescent device of claim 1, wherein the organic layer is an emissive layer, the first metal complex is a light-emitting material, and the first compound is a host material.

33. The electroluminescent device of claim 1, wherein the electroluminescent device emits red light or white light.

34. An electronic apparatus, comprising the electroluminescent device according to claim 1.

35. A compound combination, comprising a first metal complex and a first compound;
wherein
the first metal complex comprises a ligand Lₐ coordinated with a metal, and the metal is selected from metals having a relative atomic mass greater than 40; Lₐ has a structure represented by Formula 1: 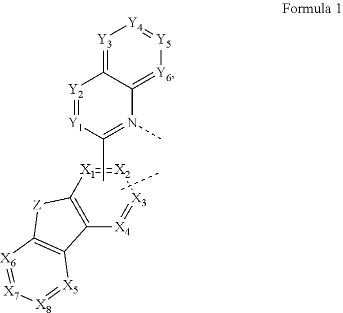
wherein X₁ to X₈ are, at each occurrence identically or differently, selected from C, CRₓ or N;
Y₁ to Y₆ are, at each occurrence identically or differently, selected from CR_{y1}, CR_{y2} or N; the R_{y2} has a structure of -L₁-SiRₛ₁Rₛ₂Rₛ₃;
Rₓ, R_{y1}, Rₛ₁, Rₛ₂, and Rₛ₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y1}, Rₛ₁, Rₛ₂, Rₛ₃ can be optionally joined to form a ring;
Z is selected from O, S or Se;
L₁ is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof; and
wherein
the first compound has a structure represented by Formula 2: 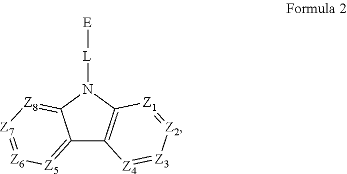
wherein Z₁ and Z₈ are, at each occurrence identically or differently, selected from CR_{z1} or N;
Z₂, Z₃, Z₆, and Z₇ are, at each occurrence identically or differently, selected from CR_{z2} or N;
Z₄ and Z₅ are, at each occurrence identically or differently, selected from CR_{z3} or N;
E has a structure represented by Formula 3-1 or Formula 3-2: 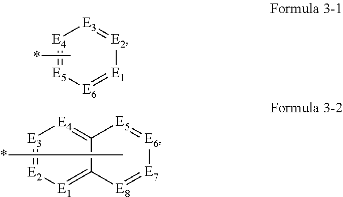
in Formula 3-1 and Formula 3-2, E₁ to E₈ are, at each occurrence identically or differently, selected from C, CRₑ or N; in Formula 3-1, at least two of E₁ to E₆ are N, and in Formula 3-2, at least two of E₁ to E₈ are N;
* represents a position where E is joined to L;
L is selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
R_{z1} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkylsilyl having 3 to 20 carbon atoms, substituted or unsubstituted arylsilyl having 6 to 20 carbon atoms, and combinations thereof;
R_{z2}, R_{z3}, and Rₑ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{z1}, R_{z2}, R_{z3} can be optionally joined to form a ring;
adjacent substituents Rₑ can be optionally joined to form a ring.
